(19) United States
(12) Patent Application Publication
(10) Pub. No.: US 2019/0355912 A1
(43) Pub. Date: Nov. 21, 2019

(54) ORGANIC ELECTROLUMINESCENT DEVICE

(71) Applicant: ROHM AND HAAS ELECTRONIC MATERIALS KOREA LTD., Chungcheongnam-do (KR)

(72) Inventors: Sang-Hee CHO, Gyeonggi-do (KR); Bitnari KIM, Gyeonggi-do (KR)

(21) Appl. No.: 16/468,587

(22) PCT Filed: Jan. 9, 2018
(86) PCT No.: PCT/KR2018/000398

§ 371 Date: Jun. 11, 2019

(30) Foreign Application Priority Data
Jan. 10, 2017 (KR) 10-2017-0003673
Jan. 5, 2018 (KR) 10-2018-0001844

(51) Int. Cl. H01L 51/00

(52) U.S. Cl. CPC H01L 51/0072; H01L 51/0073; H01L 51/5004; H01L 51/0074; H01L 51/0069; H01L 51/0067

(57) ABSTRACT

The present disclosure relates to an organic electroluminescent device. The organic electroluminescent device of the present disclosure can exhibit low driving voltage, high efficiency and/or long lifespan by comprising a specific combination of a light-emitting layer and an electron transport zone.

### TECHNICAL FIELD

The present disclosure relates to an organic electroluminescent device comprising a light-emitting layer and an electron transport zone.

### BACKGROUND ART

An electroluminescent device (EL device) is a self-light-emitting display device which has advantages in that it provides a wider viewing angle, a greater contrast ratio, and a faster response time. The first organic EL device was developed by Eastman Kodak in 1987, by using small aromatic diamine molecules and aluminum complexes as materials for forming a light-emitting layer [Appl. Phys. Lett. 51, 913, 1987].

An organic EL device (OLED) changes electric energy into light by applying electricity to an organic light-emitting material, and commonly comprises an anode, a cathode, and an organic layer formed between the two electrodes. The organic layer of the OLED may comprise a hole injection layer, a hole transport layer, a hole auxiliary layer, a light-emitting auxiliary layer, an electron blocking layer, a light-emitting layer (containing host and dopant materials), an electron buffer layer, a hole blocking layer, an electron transport layer, an electron injection layer, etc., if necessary. The materials used in the organic layer can be classified into a hole injection material, a hole transport material, a hole auxiliary material, a light-emitting auxiliary material, an electron blocking material, a light-emitting material, an electron buffer material, a hole blocking material, an electron transport material, an electron injection material, etc., depending on functions. In the OLED, holes from an anode and electrons from a cathode are injected into a light-emitting layer by the application of electric voltage, and an exciton having high energy is produced by the recombination of the holes and electrons. The organic light-emitting compound moves into an excited state by the energy and emits light from energy when the organic light-emitting compound returns to the ground state from the excited state.

The most important factor determining luminous efficiency in an organic EL device is light-emitting materials. The light-emitting materials are required to have the following features: high quantum efficiency, high movement degree of an electron and a hole, and uniformality and stability of the formed light-emitting material layer. The light-emitting material is classified into blue, green, and red light-emitting materials according to the light-emitting color, and further includes yellow or orange light-emitting materials. Furthermore, the light-emitting material is classified into a host material and a dopant material in a functional aspect. Recently, an urgent task is the development of an OLED having high efficiency and long lifespan. In particular, the development of highly excellent light-emitting material over conventional materials is urgently required, considering the EL properties necessary for medium- and large-sized OLED panels.

In an OLED, an electron transport material actively transports electrons from a cathode to a light-emitting layer and inhibits transport of holes which are not recombined in the light-emitting layer to increase recombination opportunity of holes and electrons in the light-emitting layer. Thus, electron-affinitive materials are used as an electron transport material. Organic metal complexes having light-emitting function such as Alq₃ are excellent in transporting electrons, and thus have been conventionally used as an electron transport material. However, Alq3 has problems in that it moves to other layers and shows reduction of lifespan. Therefore, new electron transport materials have been required, which do not have the above problems, are highly electron-affinitive, and quickly transport electrons in organic EL devices to provide organic EL devices having high luminous efficiency.

Also, an electron buffer layer is equipped to improve a problem of light-emitting luminance reduction which may occur due to the change of current properties in the device when the device is exposed to a high temperature during a process of producing panels. Thus, the properties of the compounds comprised in the electron buffer layer are important. In addition, the compound used in the electron buffer layer is desirable to perform a role of controlling an electron injection by the electron withdrawing characteristics and the electron affinity LUMO (lowest unoccupied molecular orbital) energy level, and thus may perform a role to improve the efficiency and the lifespan of the organic electroluminescent device.

Korean Patent Application Laid-Open No. 2015-0077513 discloses an organic electroluminescent device comprising a benzoindolocarbazole and quinoxaline derivative as a host and an imidazole derivative as an electron transport material.

Korean Patent Application Laid-Open No. 2015-0071685 discloses an organic electroluminescent device comprising a carbazole derivative as a first host, a quinoxaline derivative as a second host, and an imidazole derivative as an electron transport material.

Korean Patent No. 1511072 discloses an organic electroluminescent device comprising a benzoindolocarbazole derivative as a host, and Alq₃ as an electron transport material.

Tetrahedron Letters 52, 6942 (2011) discloses an organic electroluminescent material comprising a quinoxaline derivative.

### DISCLOSURE OF THE INVENTION

### Problems to Be Solved

The objective of the present disclosure is to provide an organic electroluminescent device having low driving voltage, high efficiency and/or long lifespan by comprising a specific combination of a light-emitting layer and an electron transport zone.

### Solution to Problems

The light-emitting layer comprising a phosphorescent dopant is advantageous in that the hole and electron current characteristics of the material of the light-emitting layer are high for low driving voltage, high efficiency and long lifespan, and that the material has excellent thermal stability in order to improve the lifespan. In order to efficiently transfer energy from the host to the dopant of the light-emitting layer, a charge trap is minimized by using a light-emitting material having a narrow energy band gap, thereby contributing to a driving voltage and a luminous efficiency. The derivatives of benzoindolocarbazole and quinoxaline of the present disclosure can have not only excellent thermal stability due to their twisted structure, but also a narrow energy band gap by controlling the position of a substituent. The present inventors found that an organic electroluminescent device can have low driving voltage, high efficiency and/or long lifespan properties by comprising a derivative compound of benzoindolocarbazole and quinoxaline in a light-emitting layer and a heterocyclic derivative compound containing azines of the present disclosure in an electron transport zone. Specifically, the above objective can be achieved by an organic electroluminescent device comprising a first electrode, a second electrode facing the first electrode, a light-emitting layer between the first electrode and the second electrode, and an electron transport zone between the light-emitting layer and the second electrode, wherein the light-emitting layer comprises a compound represented by the following formula 1:

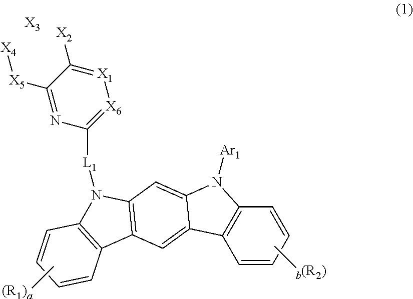

wherein,

L₁ represents a single bond, a substituted or unsubstituted (C₆-C₃₀)arylene, or a substituted or unsubstituted (5- to 30-membered)heteroarylene,

X₁ to X₆, each independently, represent N or CR₃, with a proviso that at least one of X₁ to X₆ represent N,

Ar₁ represents a substituted or unsubstituted (C6-C30)aryl, or a substituted or unsubstituted (5- to 30-membered)heteroaryl,

R₁ to R₃, each independently, represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (C3-C30)cycloalkyl, a substituted or unsubstituted (3- to 7-membered)heterocycloalkyl, a substituted or unsubstituted (C6-C30)aryl(C1-C30)alkyl, —NR₁₁R₁₂, —SiR₁₃R₁₄R₁₅, —SR₁₆, —OR₁₇, a cyano, a nitro, or a hydroxy, with a proviso that in at least one group of the adjacent two R₁ groups and the adjacent two R₂ groups, the adjacent two R₁ or the adjacent two R₂, each independently, are linked to form at least one substituted or unsubstituted benzene ring,

R₁₁ to R₁₇, each independently, represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (3- to 7-membered)heterocycloalkyl, or a substituted or unsubstituted (C3-C30)cycloalkyl; or may be linked to an adjacent substituent to form a substituted or unsubstituted, mono- or polycyclic, (C3-C30) alicyclic or aromatic ring, or a combination of alicyclic and aromatic rings, whose carbon atom(s) may be replaced with at least one heteroatom selected from nitrogen, oxygen, and sulfur, and

a and b, each independently, represent an integer of 1 to 4, where if a and b, each independently, are an integer of 2 or more, each of R₁ and R₂ may be the same or different; and

the electron transport zone comprises a compound represented by the following formula 11:

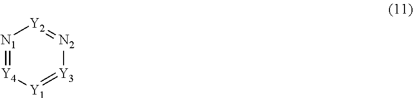

wherein,

N₁ and N₂, each independently, represent N or CR₁₈, with a proviso that at least one of N₁ and N₂ represent N,

Y₁ to Y₄, each independently, represent N or CR₁₉,

R₁₈ and R₁₉, each independently, represent hydrogen, deuterium, a halogen, a cyano, a substituted or unsubstituted (C1-C30)alkyl, a substituted or unsubstituted (C6-C50)aryl, a substituted or unsubstituted (3- to 50-membered)heteroaryl, a substituted or unsubstituted (C1-C30)cycloalkyl, a substituted or unsubstituted (3- to 7-membered)heterocycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di- (C1-C30)alkylamino, a substituted or unsubstituted mono- or di- (C6-C30)arylamino, or a substituted or unsubstituted (C1-C30)alkyl(C6-C30)arylamino; or may be linked to an adjacent substituent to form a substituted or unsubstituted, mono- or polycyclic, (C3-C30) alicyclic or aromatic ring, or a combination of alicyclic and aromatic rings, whose carbon atom(s) may be replaced with at least one heteroatom selected from nitrogen, oxygen, and sulfur,

the heteroaryl(ene) contains at least one heteroatom selected from B, N, O, S, Si, and P; and

the heterocycloalkyl contains at least one heteroatom selected from O, S, and N.

### Effects of the Invention

The present disclosure provides an organic electroluminescent device having low driving voltage, high efficiency and/or long lifespan, and a display system or a lighting system can be produced by using the device.

### BRIEF DESCRIPTION OF THE FIGURES

FIG. 1 illustrates a molecular structure of a compound represented by formula 1 according to an embodiment of the present disclosure in 3D form.

FIG. 2 illustrates the current efficiency of the organic electroluminescent devices of Comparative Example 1 and Device Example 3 with respect to the luminance.

### EMBODIMENTS OF THE INVENTION

Hereinafter, the present disclosure will be described in detail. However, the following description is intended to explain the invention, and is not meant in any way to restrict the scope of the invention.

The present disclosure relates to an organic electroluminescent device comprising a first electrode, a second electrode facing the first electrode, a light-emitting layer between the first electrode and the second electrode, and an electron transport zone between the light-emitting layer and the second electrode, wherein the light-emitting layer comprises a compound represented by formula 1, and the electron transport zone comprises a compound represented by formula 11. According to one embodiment of the present disclosure, the electron transport zone may comprise at least one of an electron transport layer and an electron buffer layer, and the compound represented by formula 11 may be comprised in at least one of the electron transport layer and the electron buffer layer. In addition, the electron buffer layer may be comprised between the light-emitting layer and the electron transport layer, or between the electron transport layer and the second electrode.

The organic electroluminescent device of the present disclosure comprises a substrate, a first electrode formed on the substrate, an organic layer formed on the first electrode, and a second electrode formed on the organic layer and facing the first electrode. The organic layer may comprise a hole injection layer, a hole transport layer formed on the hole injection layer, and a light-emitting layer formed on the hole transport layer. The organic layer may comprise an electron transport zone formed on the light-emitting layer, and the electron transport zone may comprise at least one of an electron transport layer, an electron injection layer and an electron buffer layer. Each of the electron transport layer, the electron injection layer, and the electron buffer layer may be composed of two or more layers. The organic layer may comprise an electron buffer layer formed on the light-emitting layer and an electron transport layer formed on the electron buffer layer, or may comprise an electron buffer layer or an electron transport layer formed on the light-emitting layer.

Hereinafter, the compound represented by formula 1 will be described in more detail.

In formula 1, L₁ represents a single bond, a substituted or unsubstituted (C6-C30)arylene, or a substituted or unsubstituted (5- to 30-membered)heteroarylene; preferably, a single bond, a substituted or unsubstituted (C6-C25)arylene, or a substituted or unsubstituted (5- to 25-membered)heteroarylene; more preferably, a single bond, a substituted or unsubstituted (C6-C18)arylene, or a substituted or unsubstituted (5- to 18-membered)heteroarylene; and for example, a single bond, an unsubstituted phenylene, an unsubstituted naphthylene, or an unsubstituted pyridinylene.

In formula 1, X₁ to X₆, each independently, represent N or CR₃, with a proviso that at least one of X₁ to X₆ represent N. According to one embodiment of the present disclosure, at least one of X₁ to X₆ may represent N, and X₂ to X₅ may represent CR₃.

In formula 1, the structure of

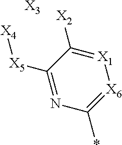

may represent a substituted or unsubstituted quinoxalinyl, a substituted or unsubstituted quinazolinyl, a substituted or unsubstituted naphthyridinyl, a substituted or unsubstituted pyridopyrimidinyl, or a substituted or unsubstituted pyridopyrazinyl; preferably, a substituted or unsubstituted quinoxalinyl, or a substituted or unsubstituted quinazolinyl, and wherein, * represents a bonding site with L₁.

In formula 1, Ar₁ represents a substituted or unsubstituted (C6-C30)aryl, or a substituted or unsubstituted (5- to 30-membered)heteroaryl; preferably, a substituted or unsubstituted (C6-C25)aryl, or a substituted or unsubstituted (5- to 25-membered)heteroaryl; more preferably, a substituted or unsubstituted (C6-C18)aryl, or a substituted or unsubstituted (5- to 18-membered)heteroaryl; and for example, an unsubstituted phenyl, an unsubstituted naphthyl, an unsubstituted biphenyl, a fluorenyl substituted with a dimethyl, an unsubstituted phenanthrenyl, or an unsubstituted pyridinyl.

In formula 1, R₁ to R₃, each independently, represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (C3-C30)cycloalkyl, a substituted or unsubstituted (3- to 7-membered)heterocycloalkyl, a substituted or unsubstituted (C6-C30)aryl(C1-C30)alkyl, —NR₁₁R₁₂, —SiR₁₃R₁₄R₁₅, —SR₁₆, —OR₁₇, a cyano, a nitro, or a hydroxy; preferably, hydrogen, or a substituted or unsubstituted (C6-C25)aryl; and more preferably, hydrogen, or a substituted or unsubstituted (C6-C18)aryl. According to one embodiment of the present disclosure, R₁ and R₂, each independently, may represent hydrogen, or an unsubstituted phenyl, and R₃ may represent hydrogen, a phenyl unsubstituted or substituted with at least one methyl, an unsubstituted naphthyl, an unsubstituted biphenyl, an unsubstituted naphthylphenyl, a fluorenyl substituted with a dimethyl, or an unsubstituted phenanthrenyl. With a proviso that in at least one group of the adjacent two R₁ groups and the adjacent two R₂ groups, the adjacent two R₁ or the adjacent two R₂, each independently, are linked to form at least one substituted or unsubstituted benzene ring. Also, the adjacent two R₁ groups and the adjacent two R₂ groups, each independently, are linked to the adjacent two R₁ or the adjacent two R₂ to form a substituted or unsubstituted benzene ring, and preferably, an unsubstituted benzene ring. When X₁ or X₆ represents CR₃, R₃ may represent a substituted or unsubstituted (C6-C18)aryl. Also, when X₂ to X₅ represent CR₃, R₃ may represent hydrogen. R₁₁ to R₁₇, each independently, represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (3- to 7-membered)heterocycloalkyl, or a substituted or unsubstituted (C3-C30)cycloalkyl; or may be linked to an adjacent substituent to form a substituted or unsubstituted, mono- or polycyclic, (C3-C30) alicyclic or aromatic ring, or a combination of alicyclic and aromatic rings, whose carbon atom(s) may be replaced with at least one heteroatom selected from nitrogen, oxygen, and sulfur.

In formula 1, a and b, each independently, represent an integer of 1 to 4, and preferably an integer of 1 to 3. If a and b, each independently, are an integer of 2 or more, each of R₁ and R₂ may be the same or different.

Formula 1 may be represented by any one of the following formulas 2 to 7.

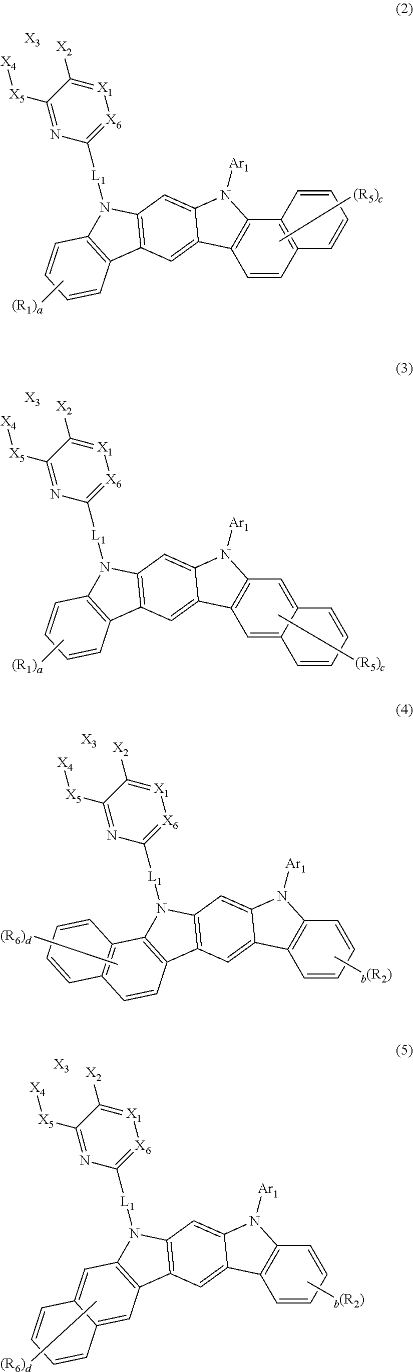

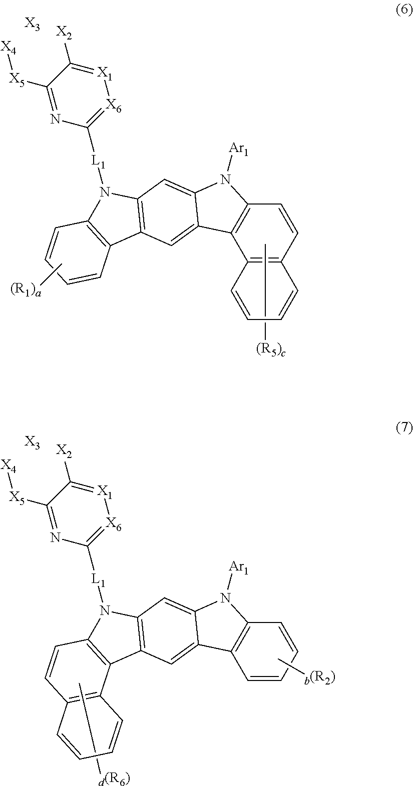

In formulas 2 to 7, L₁, Ar₁, R₁, R₂, X₁ to X₆, a and b are as defined in formula 1; and R₅ and R₆ are each independently identical to the definition of R₁.

In formulas 2 to 7, c and d, each independently, represent an integer of 1 to 6; preferably 1 or 2; and more preferably, 1. If c and d are an integer of 2 or more, each of R₅ and R₆ may be the same or different.

In formula 11, N₁ and N₂, each independently, represent N or CR₁₈, with a proviso that at least one of N₁ and N₂ represent N. According to one embodiment of the present disclosure, both N₁ and N₂ represent N.

In formula 11, Y₁ to Y₄, each independently, represent N or CR₁₉. According to one embodiment of the present disclosure, Y₁ may represent N or CR₁₉, and Y₂ to Y₄, each independently, represent CR₁₉.

In formula 11, R₁₈ and R₁₉, each independently, represent hydrogen, deuterium, a halogen, a cyano, a substituted or unsubstituted (C1-C30)alkyl, a substituted or unsubstituted (C6-C50)aryl, a substituted or unsubstituted (3- to 50-membered)heteroaryl, a substituted or unsubstituted (C3-C30)cycloalkyl, a substituted or unsubstituted (3- to 7-membered)heterocycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di- (C1-C30)alkylamino, a substituted or unsubstituted mono- or di- (C6-C30)arylamino, or a substituted or unsubstituted (C1-C30)alkyl(C6-C30)arylamino; or may be linked to an adjacent substituent to form a substituted or unsubstituted, mono- or polycyclic, (C3-C30) alicyclic or aromatic ring, or a combination of alicyclic and aromatic rings, whose carbon atom(s) may be replaced with at least one heteroatom selected from nitrogen, oxygen, and sulfur. Preferably, R₁₈ and R₁₉, each independently, may represent hydrogen, a substituted or unsubstituted (C6-C40)aryl, or a substituted or unsubstituted (5- to 45-membered)heteroaryl; or may be linked to an adjacent substituent to form a substituted or unsubstituted, mono- or polycyclic, (C3-C25) alicyclic or aromatic ring, or a combination of alicyclic and aromatic rings, whose carbon atom(s) may be replaced with at least one heteroatom selected from nitrogen, oxygen, and sulfur. More preferably, R₁₈ and R₁₉, each independently, may represent hydrogen, a substituted or unsubstituted (C6-C30)aryl, or a substituted or unsubstituted (5- to 40-membered)heteroaryl; or may be linked to an adjacent substituent to form a substituted or unsubstituted, mono- or polycyclic, (C3-C18) aromatic ring, whose carbon atom(s) may be replaced with at least one heteroatom selected from nitrogen, oxygen, and sulfur. For example, R₁₈ and R_{19,} each independently, may represent hydrogen, a substituted or unsubstituted phenyl, a substituted indole, a substituted or unsubstituted naphthyl, a substituted biphenyl, a substituted phenylnaphthyl, a substituted biphenylnaphthyl, a fluorenyl substituted with a dimethyl, an unsubstituted terphenyl, a substituted carbazolyl, a substituted benzocarbazolyl, an unsubstituted dibenzofuran, or a substituted or unsubstituted (16- to 38-membered)heteroaryl containing at least one of nitrogen, oxygen, and sulfur; or may be linked to an adjacent substituent to form an unsubstituted benzofuran ring.

Formula 11 may be represented by the following formula 12:

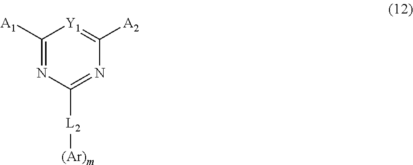

In formula 12, Y₁ is as defined in formula 11; A₁ and A₂ are each independently identical to the definition of R19 of formula 11; and m represents 1 or 2.

In formula 12, L₂ represents a single bond, a substituted or unsubstituted (C6-C50)arylene, or a substituted or unsubstituted (5- to 50-membered)heteroarylene; preferably, a single bond, a substituted or unsubstituted (C6-C45)arylene, or a substituted or unsubstituted (5- to 45-membered)heteroarylene; more preferably, a single bond, a substituted or unsubstituted (C6-C30)arylene, or a substituted or unsubstituted (5- to 30-membered)heteroarylene; and for example, a single bond, a phenylene unsubstituted or substituted with a pyridinyl(s), an unsubstituted naphthylene, an unsubstituted biphenylene, an unsubstituted phenylnaphthylene, an unsubstituted biphenylnaphthylene, an indolylene substituted with a phenyl(s), a carbazolylene unsubstituted or substituted with a phenyl(s), or an unsubstituted benzocarbazolylene.

In formula 12, Ar represents a substituted or unsubstituted (C6-C50)aryl, or a substituted or unsubstituted (5- to 50-membered)heteroaryl; preferably, a substituted or unsubstituted (C6-C45)aryl, or a substituted or unsubstituted (5- to 45-membered)heteroaryl; and more preferably, a substituted or unsubstituted (C6-C30)aryl, or a substituted or unsubstituted (5- to 40-membered)heteroaryl. For example, Ar may represent a phenyl unsubstituted or substituted with a pyridinyl(s), an unsubstituted naphthyl, a fluorenyl substituted with a dimethyl(s), an unsubstituted phenanthrenyl, an unsubstituted triphenylenyl, an unsubstituted pyridinyl, a benzimidazolyl substituted with a phenyl(s), an indolyl substituted with at least one phenyl, an unsubstituted quinolyl, a substituted or unsubstituted carbazolyl, an unsubstituted dibenzothiophenyl, an unsubstituted dibenzofuranyl, a benzocarbazolyl unsubstituted or substituted with a phenyl(s), an unsubstituted dibenzocarbazolyl, an unsubstituted benzophenanthrothiophenyl, or a substituted or unsubstituted (13- to 38-membered)heteroaryl containing at least one of nitrogen, oxygen, and sulfur, and may be a spiro structure. The substituent of the substituted carbazolyl may be at least one of a methyl, a phenyl, a dibenzothiophenyl, a dibenzofuranyl, a fluorenyl substituted with a phenyl, and a carbazolyl substituted with a phenyl. The substituent of the substituted (13- to 38-membered)heteroaryl may be at least one of a methyl, a tert-butyl, a phenyl, a naphthyl, and a biphenyl.

In formulas 1 and 11, the heteroaryl(ene) contains at least one heteroatom selected from B, N, O, S, Si, and P; and preferably, at least one heteroatom selected from N, O, and S.

In formulas 1 and 11, the heterocycloalkyl contains at least one heteroatom selected from O, S, and N.

Herein, the term “(C1-C30)alkyl” is meant to be a linear or branched alkyl(ene) having 1 to 30 carbon atoms constituting the chain, in which the number of carbon atoms is preferably 1 to 10, and more preferably 1 to 6. The above alkyl may include methyl, ethyl, n-propyl, iso-propyl, n-butyl, iso-butyl, tert-butyl, etc. The term “(C3-C30)cycloalkyl” is meant to be a mono- or polycyclic hydrocarbon having 3 to 30 ring backbone carbon atoms, in which the number of carbon atoms is preferably 3 to 20, and more preferably 3 to 7. The above cycloalkyl may include cyclopropyl, cyclobutyl, cyclopentyl, cyclohexyl, etc. The term “(3- to 7-membered)heterocycloalkyl” is meant to be a cycloalkyl having 3 to 7 ring backbone atoms, and including at least one heteroatom selected from the group consisting of B, N, O, S, Si, and P, and preferably the group consisting of O, S, and N. The above heterocycloalkyl may include tetrahydrofuran, pyrrolidine, thiolan, tetrahydropyran, etc. The term “(C6-C30)aryl(ene)” is meant to be a monocyclic or fused ring radical derived from an aromatic hydrocarbon having 6 to 30 ring backbone carbon atoms, in which the number of the ring backbone carbon atoms is preferably 6 to 20, more preferably 6 to 15. The above aryl may be partially saturated, and may comprise a spiro structure. The above aryl may include phenyl, biphenyl, terphenyl, naphthyl, binaphthyl, phenylnaphthyl, naphthylphenyl, fluorenyl, phenylfluorenyl, benzofluorenyl, dibenzofluorenyl, phenanthrenyl, phenylphenanthrenyl, anthracenyl, indenyl, triphenylenyl, pyrenyl, tetracenyl, perylenyl, chrysenyl, naphthacenyl, fluoranthenyl, etc. The term “(3- to 30-membered)heteroaryl(ene)” is an aryl having 3 to 30 ring backbone atoms, and including at least one, preferably 1 to 4 heteroatoms selected from the group consisting of B, N, O, S, Si, and P. The number of the ring backbone atoms is preferably 3 to 20, more preferably 5 to 15. The above heteroaryl may be a monocyclic ring, or a fused ring condensed with at least one benzene ring; may be partially saturated; may be one formed by linking at least one heteroaryl or aryl group to a heteroaryl group via a single bond(s); and may comprise a spiro structure. The above heteroaryl(ene) may include a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridinyl, pyrazinyl, pyrimidinyl, and pyridazinyl, and a fused ring-type heteroaryl such as benzofuranyl, benzothiophenyl, isobenzofuranyl, dibenzofuranyl, dibenzothiophenyl, benzonaphthothiophenyl, benzimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, and benzodioxolyl. Furthermore, “halogen” includes F, Cl, Br, and I.

Herein, “substituted” in the expression “substituted or unsubstituted” means that a hydrogen atom in a certain functional group is replaced with another atom or another functional group, i.e. a substituent. The substituents of the substituted alkyl, the substituted aryl(ene), the substituted heteroaryl(ene), the substituted cycloalkyl, the substituted heterocycloalkyl, the substituted alkoxy, the substituted trialkylsilyl, the substituted dialkylarylsilyl, the substituted alkyldiarylsilyl, the substituted triarylsilyl, the substituted mono- or di- alkylamino, the substituted mono- or di-arylamino, the substituted alkylarylamino, the substituted arylalkyl, the substituted benzene ring, and the substituted mono- or polycyclic, alicyclic or aromatic ring, or a combination of alicyclic and aromatic rings in L₁, L₂, Ar₁, R₁ to R₃, R₁₁ to R₁₉, and Ar of formulas 1, 11 and 12, each independently, are at least one selected from the group consisting of deuterium; a halogen; a cyano; a carboxyl; a nitro; a hydroxyl; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (C3- to 7-membered)heterocycloalkyl; a (C6-C30)aryloxy; a (C6-C30)arylthio; a (C6-C30)aryl unsubstituted or substituted with a (C1-C30)alkyl and/or a (3- to 50-membered)heteroaryl; a (5- to 50-membered)heteroaryl unsubstituted or substituted with a (C1-C30)alkyl and/or a (C6-C30)aryl; a tri(C1-C30)alkylsilyl; a tri(C6-C30)arylsilyl; a di(C1-C30)alkyl(C6-C30)arylsilyl; a (C1-C30)alkyldi(C6-C30)arylsilyl; an amino; a mono- or di- (C1-C30)alkylamino; a mono- or di- (C6-C30)arylamino; a (C-C30)alkyl(C6-C30)arylamino; a (C1-C30)alkylcarbonyl; a (C1-C30)alkoxycarbonyl; a (C6-C30)arylcarbonyl; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl. Preferably, the substituents may be at least one selected from the group consisting of a (C1-C20)alkyl; a (C6-C25)aryl unsubstituted or substituted with a (C1-C20)alkyl and/or a (3- to 30-membered)heteroaryl; and a (5- to 40-membered)heteroaryl unsubstituted or substituted with a (C1-C20)alkyl and/or a (C6-C25)aryl. For example, the substituents may be at least one of a methyl, a tert-butyl, a phenyl unsubstituted or substituted with a pyridinyl, a naphthyl, a biphenyl, a dimethylfluorenyl, a phenylfluorenyl, a diphenylfluorenyl, a phenanthrenyl, a triphenylenyl, a pyridinyl, an indolyl substituted with a diphenyl, a benzimidazolyl substituted with a phenyl, a quinolyl, a substituted or unsubstituted carbazolyl, a dibenzofuranyl, a dibenzothiophenyl, a benzocarbazolyl unsubstituted or substituted with a phenyl, a dibenzocarbazolyl, a benzophenanthrothiophenyl, and a substituted or unsubstituted (16- to 33-membered)heteroaryl containing at least one of nitrogen, oxygen and sulfur.

The compound represented by formula 1 includes the following compounds, but is not limited thereto.

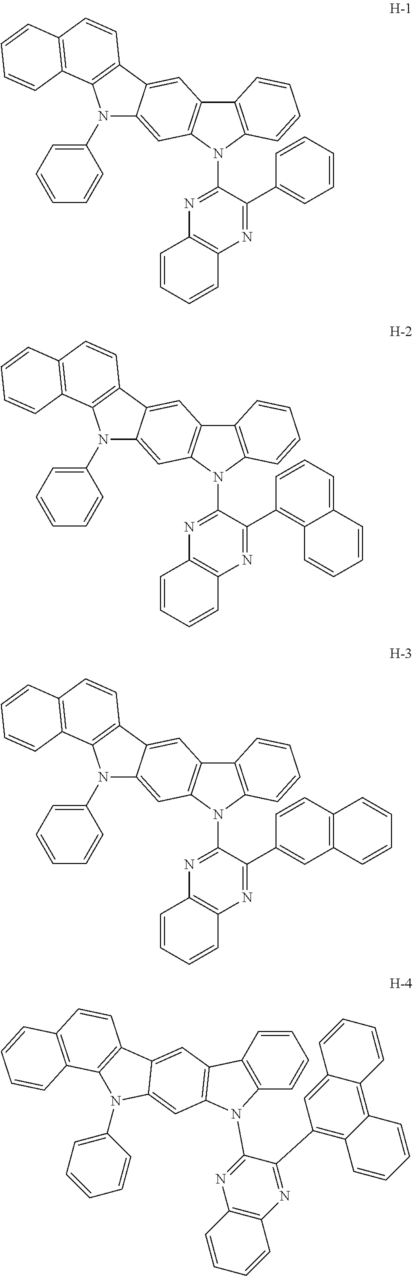 [SMILES: c1ccc(-c2nc3ccccc3nc2-n2c3ccccc3c3cc4c5ccc6ccccc6c5n(-c5ccccc5)c4cc32)cc1 ; c1ccc(-n2c3cc4c(cc3c3ccc5ccccc5c32)c2ccccc2n4-c2nc3ccccc3nc2-c2cccc3ccccc23)cc1 ; c1ccc(-n2c3cc4c(cc3c3ccc5ccccc5c32)c2ccccc2n4-c2nc3ccccc3nc2-c2ccc3ccccc3c2)cc1 ; c1ccc(-n2c3cc4c(cc3c3ccc5ccccc5c32)c2ccccc2n4-c2nc3ccccc3nc2-c2cc3ccccc3c3ccccc23)cc1]

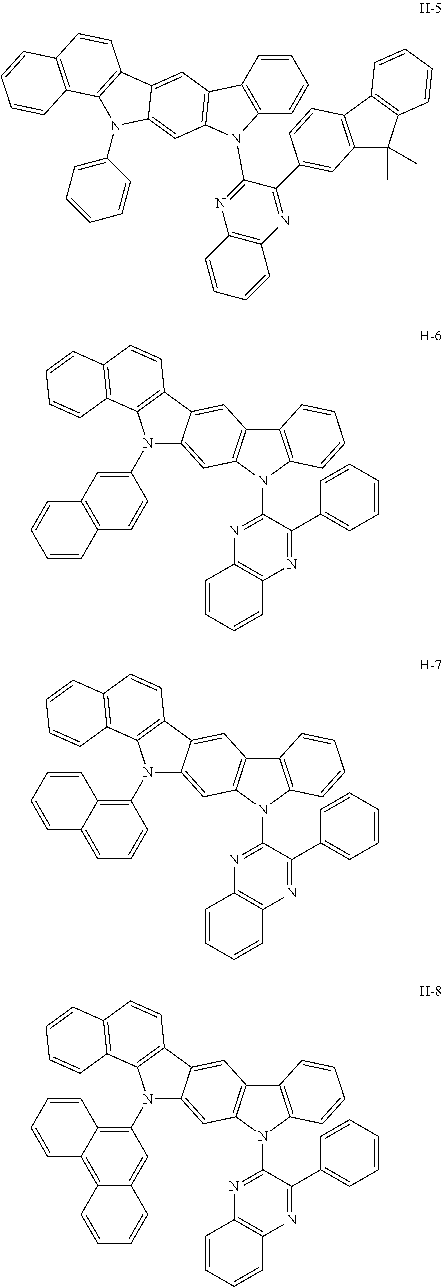 [SMILES: CC1(C)c2ccccc2-c2ccc(-c3nc4ccccc4nc3-n3c4ccccc4c4cc5c6ccc7ccccc7c6n(-c6ccccc6)c5cc43)cc21 ; c1ccc(-c2nc3ccccc3nc2-n2c3ccccc3c3cc4c5ccc6ccccc6c5n(-c5ccc6ccccc6c5)c4cc32)cc1 ; c1ccc(-c2nc3ccccc3nc2-n2c3ccccc3c3cc4c5ccc6ccccc6c5n(-c5cccc6ccccc56)c4cc32)cc1 ; c1ccc(-c2nc3ccccc3nc2-n2c3ccccc3c3cc4c5ccc6ccccc6c5n(-c5cc6ccccc6c6ccccc56)c4cc32)cc1]

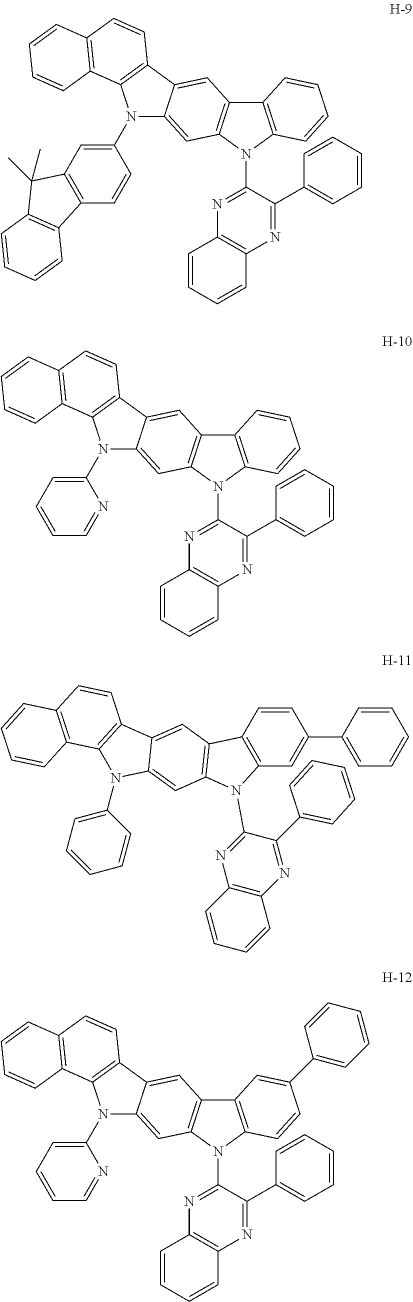 [SMILES: CC1(C)c2ccccc2-c2ccc(-n3c4cc5c(cc4c4ccc6ccccc6c43)c3ccccc3n5-c3nc4ccccc4nc3-c3ccccc3)cc21 ; c1ccc(-c2nc3ccccc3nc2-n2c3ccccc3c3cc4c5ccc6ccccc6c5n(-c5ccccn5)c4cc32)cc1 ; c1ccc(-c2ccc3c4cc5c6ccc7ccccc7c6n(-c6ccccc6)c5cc4n(-c4nc5ccccc5nc4-c4ccccc4)c3c2)cc1 ; c1ccc(-c2ccc3c(c2)c2cc4c5ccc6ccccc6c5n(-c5ccccn5)c4cc2n3-c2nc3ccccc3nc2-c2ccccc2)cc1]

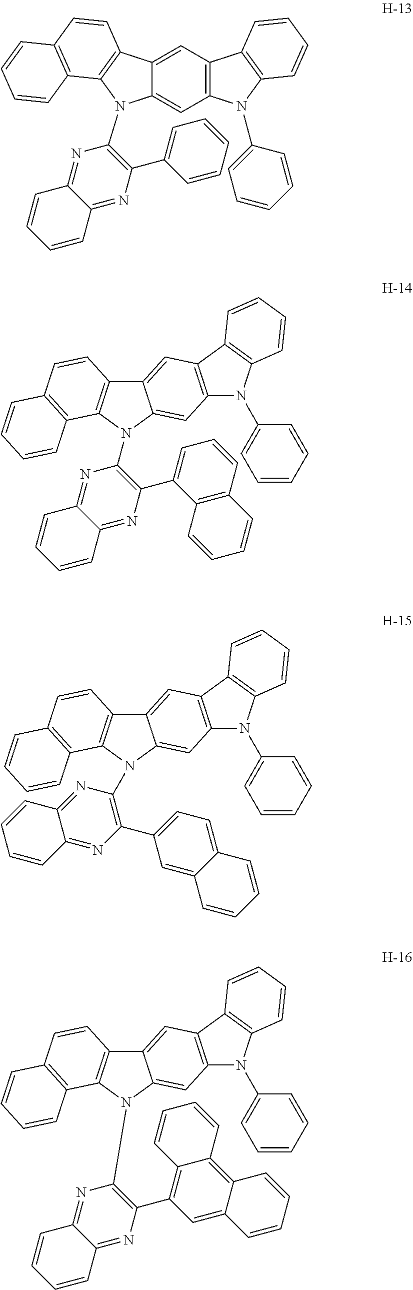 [SMILES: c1ccc(-c2nc3ccccc3nc2-n2c3cc4c(cc3c3ccc5ccccc5c32)c2ccccc2n4-c2ccccc2)cc1 ; c1ccc(-n2c3ccccc3c3cc4c5ccc6ccccc6c5n(-c5nc6ccccc6nc5-c5cccc6ccccc56)c4cc32)cc1 ; c1ccc(-n2c3ccccc3c3cc4c5ccc6ccccc6c5n(-c5nc6ccccc6nc5-c5ccc6ccccc6c5)c4cc32)cc1 ; c1ccc(-n2c3ccccc3c3cc4c5ccc6ccccc6c5n(-c5nc6ccccc6nc5-c5cc6ccccc6c6ccccc56)c4cc32)cc1]

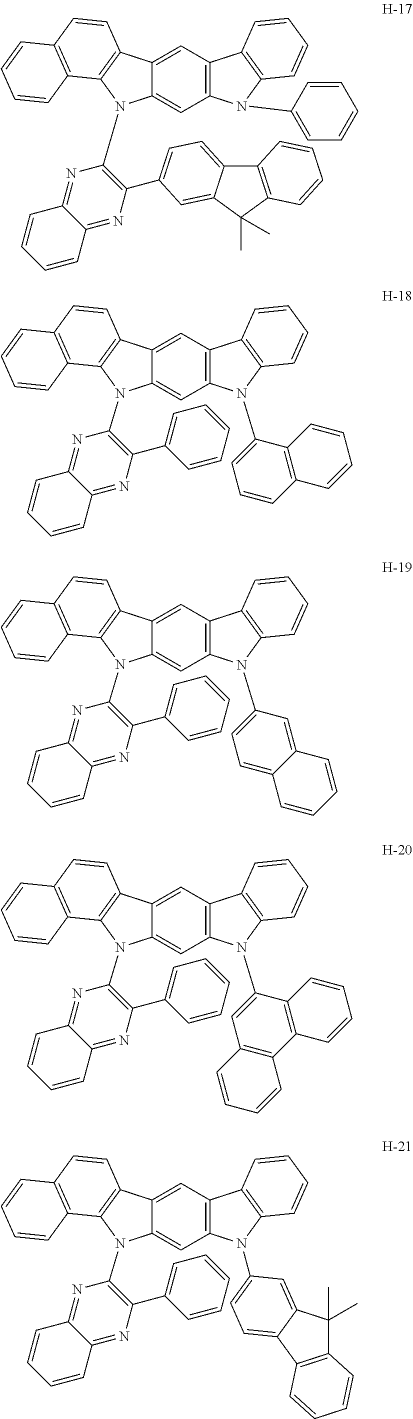

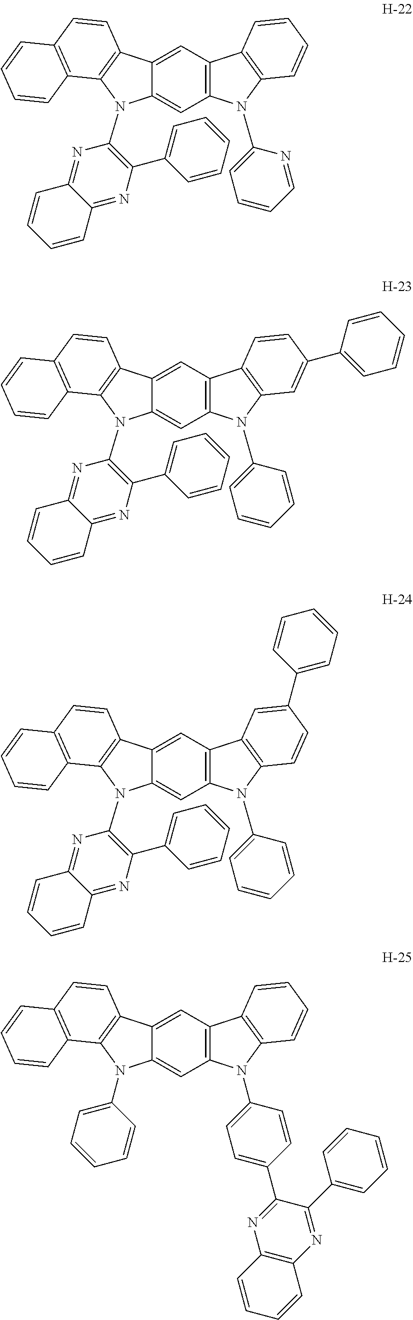 [SMILES: c1ccc(-c2nc3ccccc3nc2-n2c3cc4c(cc3c3ccc5ccccc5c32)c2ccccc2n4-c2ccccn2)cc1 ; c1ccc(-c2ccc3c4cc5c6ccc7ccccc7c6n(-c6nc7ccccc7nc6-c6ccccc6)c5cc4n(-c4ccccc4)c3c2)cc1 ; c1ccc(-c2ccc3c(c2)c2cc4c5ccc6ccccc6c5n(-c5nc6ccccc6nc5-c5ccccc5)c4cc2n3-c2ccccc2)cc1 ; c1ccc(-c2nc3ccccc3nc2-c2ccc(-n3c4ccccc4c4cc5c6ccc7ccccc7c6n(-c6ccccc6)c5cc43)cc2)cc1]

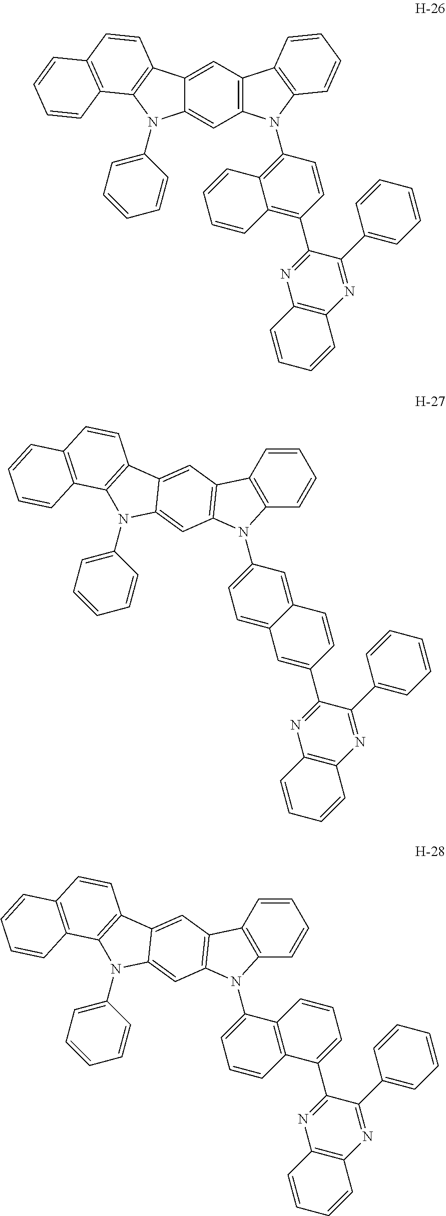 [SMILES: c1ccc(-c2nc3ccccc3nc2-c2ccc(-n3c4ccccc4c4cc5c6ccc7ccccc7c6n(-c6ccccc6)c5cc43)c3ccccc23)cc1 ; c1ccc(-c2nc3ccccc3nc2-c2ccc3cc(-n4c5ccccc5c5cc6c7ccc8ccccc8c7n(-c7ccccc7)c6cc54)ccc3c2)cc1 ; c1ccc(-c2nc3ccccc3nc2-c2cccc3c(-n4c5ccccc5c5cc6c7ccc8ccccc8c7n(-c7ccccc7)c6cc54)cccc23)cc1]

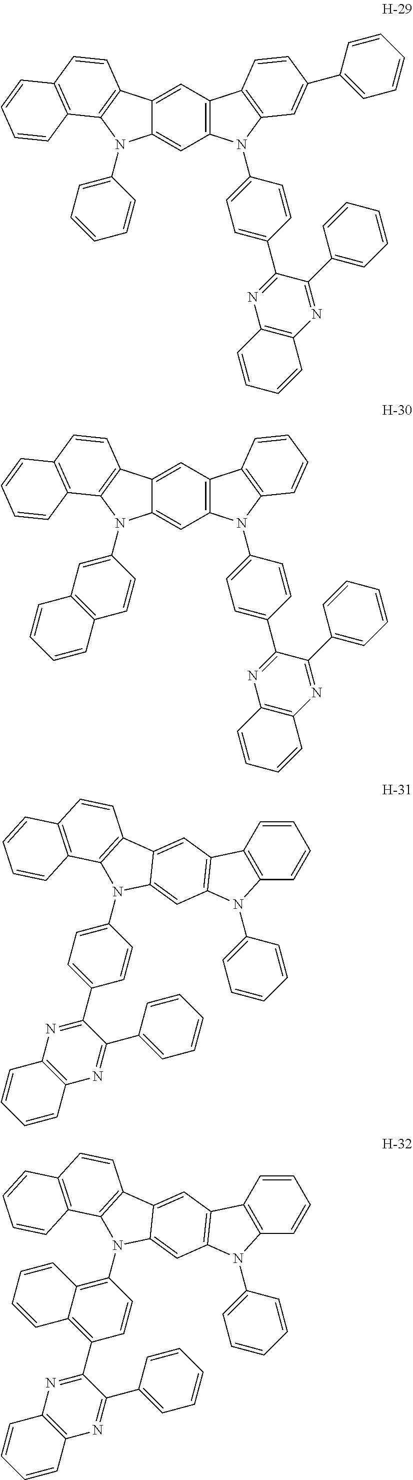

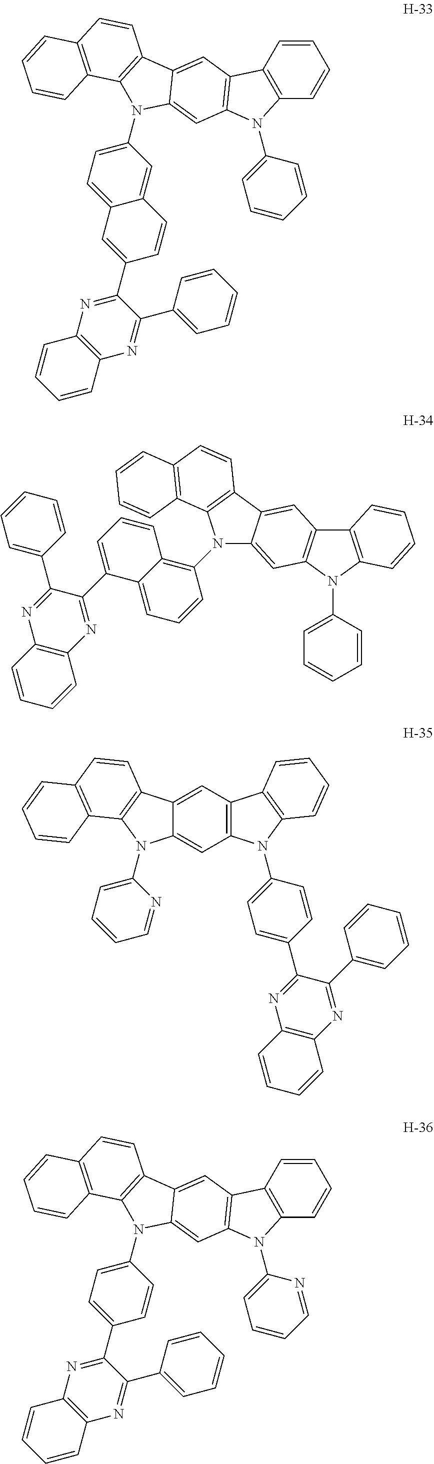 [SMILES: c1ccc(-c2nc3ccccc3nc2-c2ccc3cc(-n4c5cc6c(cc5c5ccc7ccccc7c54)c4ccccc4n6-c4ccccc4)ccc3c2)cc1 ; c1ccc(-c2nc3ccccc3nc2-c2cccc3c(-n4c5cc6c(cc5c5ccc7ccccc7c54)c4ccccc4n6-c4ccccc4)cccc23)cc1 ; c1ccc(-c2nc3ccccc3nc2-c2ccc(-n3c4ccccc4c4cc5c6ccc7ccccc7c6n(-c6ccccn6)c5cc43)cc2)cc1 ; c1ccc(-c2nc3ccccc3nc2-c2ccc(-n3c4cc5c(cc4c4ccc6ccccc6c43)c3ccccc3n5-c3ccccn3)cc2)cc1]

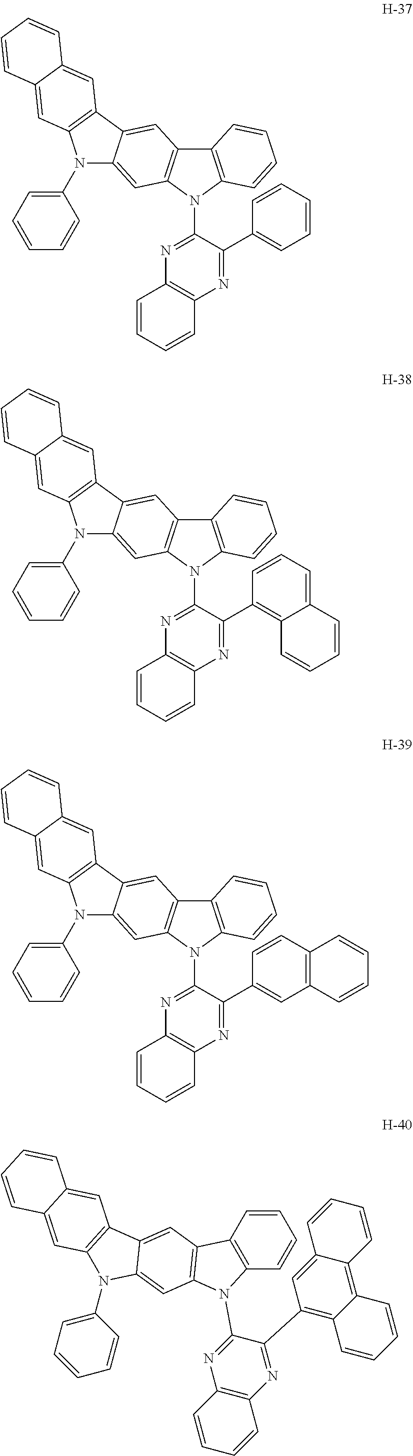 [SMILES: c1ccc(-c2nc3ccccc3nc2-n2c3ccccc3c3cc4c5cc6ccccc6cc5n(-c5ccccc5)c4cc32)cc1 ; c1ccc(-n2c3cc4ccccc4cc3c3cc4c5ccccc5n(-c5nc6ccccc6nc5-c5cccc6ccccc56)c4cc32)cc1 ; c1ccc(-n2c3cc4ccccc4cc3c3cc4c5ccccc5n(-c5nc6ccccc6nc5-c5ccc6ccccc6c5)c4cc32)cc1 ; c1ccc(-n2c3cc4ccccc4cc3c3cc4c5ccccc5n(-c5nc6ccccc6nc5-c5cc6ccccc6c6ccccc56)c4cc32)cc1]

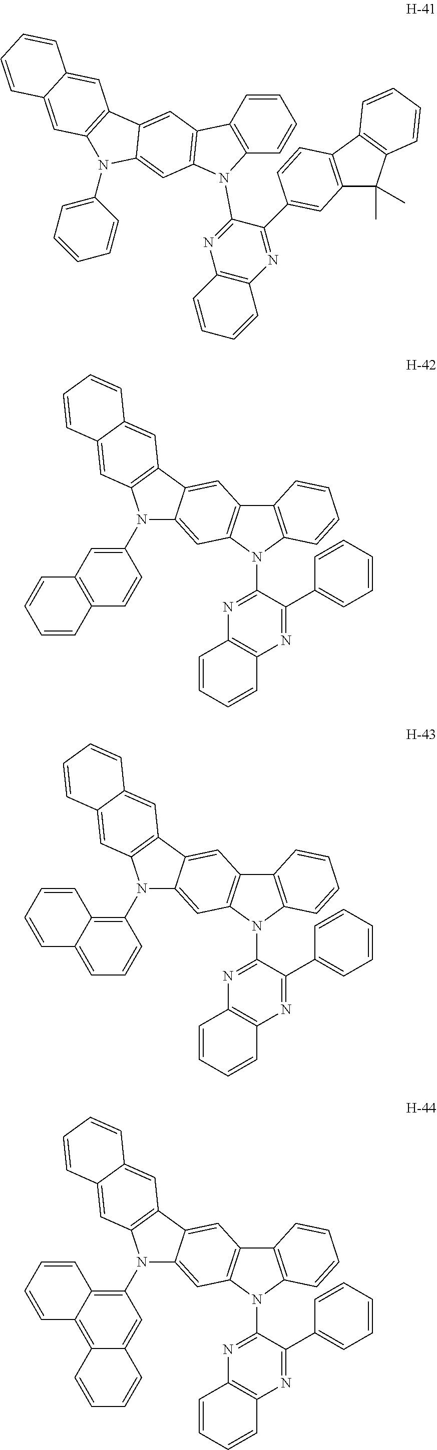 [SMILES: CC1(C)c2ccccc2-c2ccc(-c3nc4ccccc4nc3-n3c4ccccc4c4cc5c6cc7ccccc7cc6n(-c6ccccc6)c5cc43)cc21 ; c1ccc(-c2nc3ccccc3nc2-n2c3ccccc3c3cc4c5cc6ccccc6cc5n(-c5ccc6ccccc6c5)c4cc32)cc1 ; c1ccc(-c2nc3ccccc3nc2-n2c3ccccc3c3cc4c5cc6ccccc6cc5n(-c5cccc6ccccc56)c4cc32)cc1 ; c1ccc(-c2nc3ccccc3nc2-n2c3ccccc3c3cc4c5cc6ccccc6cc5n(-c5cc6ccccc6c6ccccc56)c4cc32)cc1]

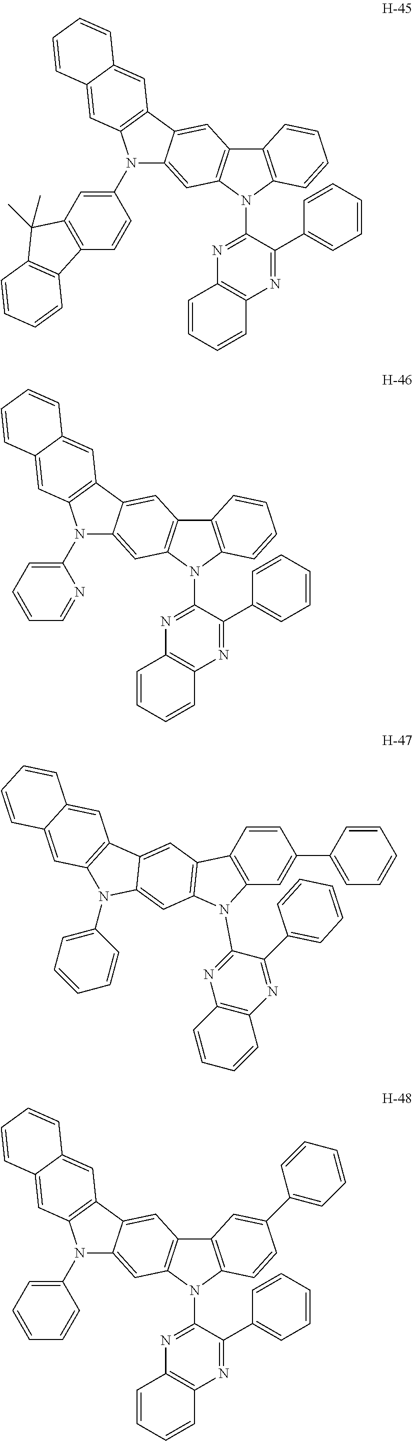 [SMILES: CC1(C)c2ccccc2-c2ccc(-n3c4cc5ccccc5cc4c4cc5c6ccccc6n(-c6nc7ccccc7nc6-c6ccccc6)c5cc43)cc21 ; c1ccc(-c2nc3ccccc3nc2-n2c3ccccc3c3cc4c5cc6ccccc6cc5n(-c5ccccn5)c4cc32)cc1 ; c1ccc(-c2ccc3c4cc5c6cc7ccccc7cc6n(-c6ccccc6)c5cc4n(-c4nc5ccccc5nc4-c4ccccc4)c3c2)cc1 ; c1ccc(-c2ccc3c(c2)c2cc4c5cc6ccccc6cc5n(-c5ccccc5)c4cc2n3-c2nc3ccccc3nc2-c2ccccc2)cc1]

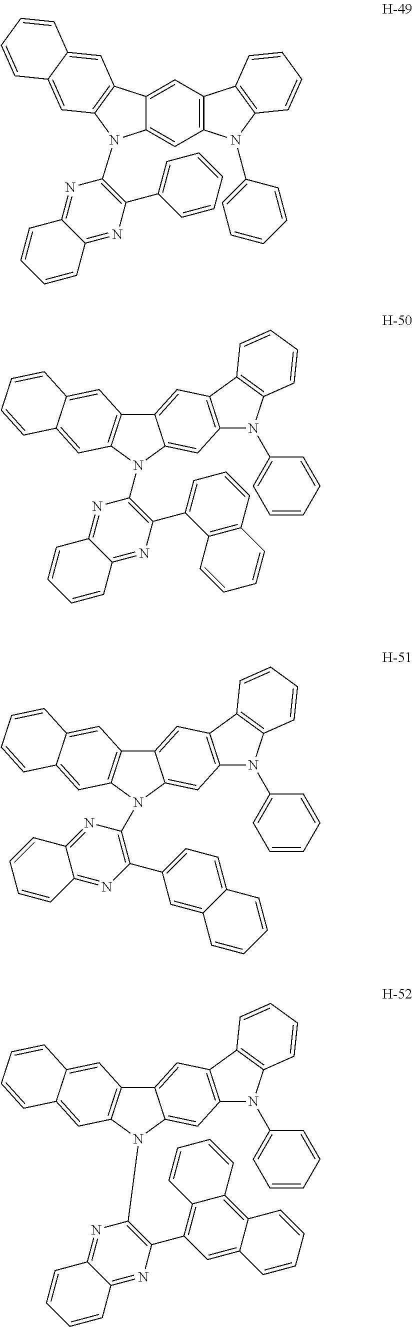 [SMILES: c1ccc(-c2nc3ccccc3nc2-n2c3cc4ccccc4cc3c3cc4c5ccccc5n(-c5ccccc5)c4cc32)cc1 ; c1ccc(-n2c3ccccc3c3cc4c5cc6ccccc6cc5n(-c5nc6ccccc6nc5-c5cccc6ccccc56)c4cc32)cc1 ; c1ccc(-n2c3ccccc3c3cc4c5cc6ccccc6cc5n(-c5nc6ccccc6nc5-c5ccc6ccccc6c5)c4cc32)cc1 ; c1ccc(-n2c3ccccc3c3cc4c5cc6ccccc6cc5n(-c5nc6ccccc6nc5-c5cc6ccccc6c6ccccc56)c4cc32)cc1]

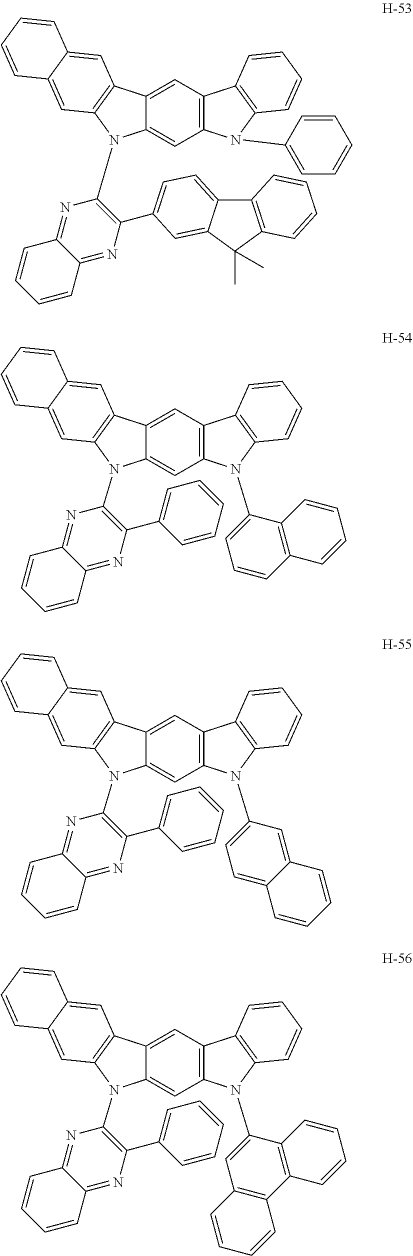 [SMILES: CC1(C)c2ccccc2-c2ccc(-c3nc4ccccc4nc3-n3c4cc5ccccc5cc4c4cc5c6ccccc6n(-c6ccccc6)c5cc43)cc21 ; c1ccc(-c2nc3ccccc3nc2-n2c3cc4ccccc4cc3c3cc4c5ccccc5n(-c5cccc6ccccc56)c4cc32)cc1 ; c1ccc(-c2nc3ccccc3nc2-n2c3cc4ccccc4cc3c3cc4c5ccccc5n(-c5ccc6ccccc6c5)c4cc32)cc1 ; c1ccc(-c2nc3ccccc3nc2-n2c3cc4ccccc4cc3c3cc4c5ccccc5n(-c5cc6ccccc6c6ccccc56)c4cc32)cc1]

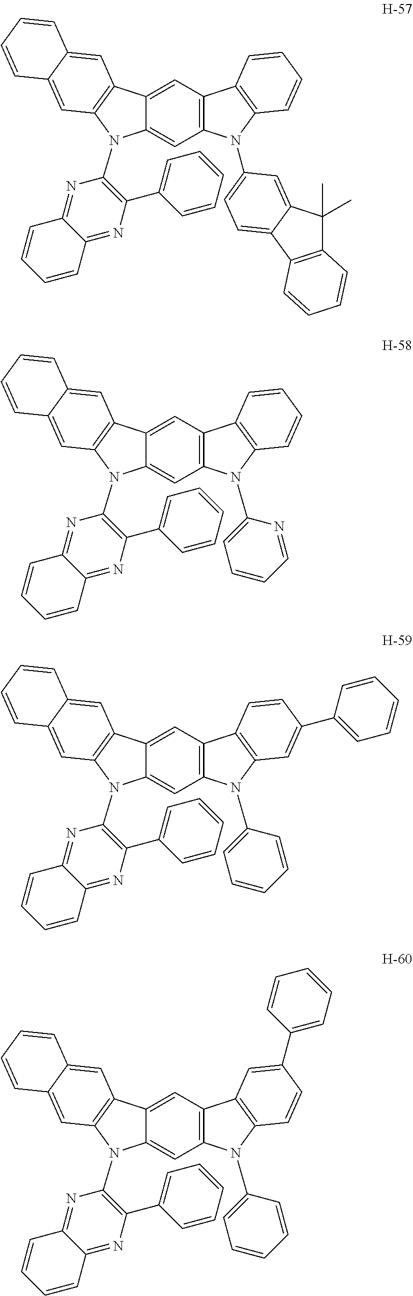 [SMILES: CC1(C)c2ccccc2-c2ccc(-n3c4ccccc4c4cc5c6cc7ccccc7cc6n(-c6nc7ccccc7nc6-c6ccccc6)c5cc43)cc21 ; c1ccc(-c2nc3ccccc3nc2-n2c3cc4ccccc4cc3c3cc4c5ccccc5n(-c5ccccn5)c4cc32)cc1 ; c1ccc(-c2ccc3c4cc5c6cc7ccccc7cc6n(-c6nc7ccccc7nc6-c6ccccc6)c5cc4n(-c4ccccc4)c3c2)cc1 ; c1ccc(-c2ccc3c(c2)c2cc4c5cc6ccccc6cc5n(-c5nc6ccccc6nc5-c5ccccc5)c4cc2n3-c2ccccc2)cc1]

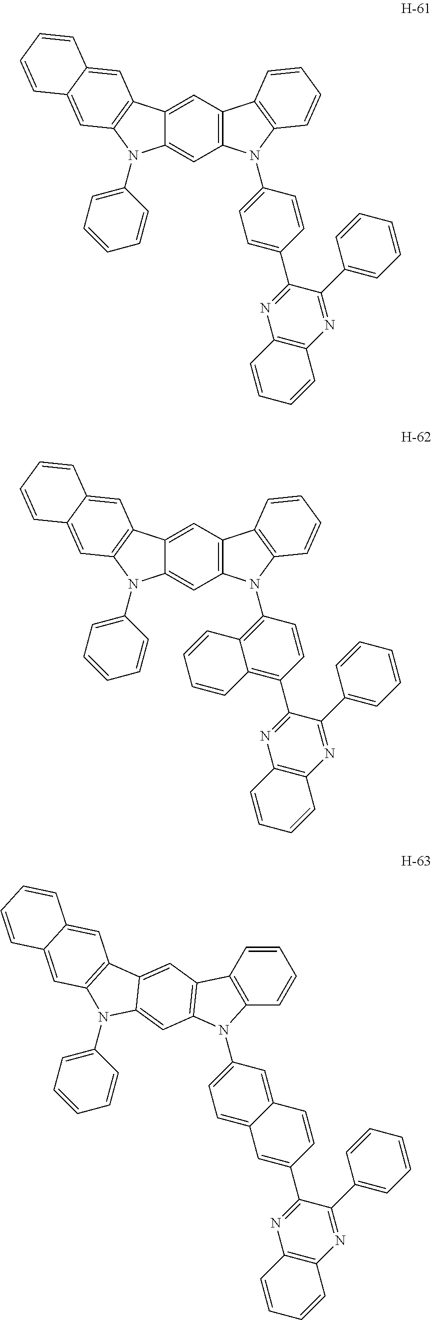 [SMILES: c1ccc(-c2nc3ccccc3nc2-c2ccc(-n3c4ccccc4c4cc5c6cc7ccccc7cc6n(-c6ccccc6)c5cc43)cc2)cc1 ; c1ccc(-c2nc3ccccc3nc2-c2ccc(-n3c4ccccc4c4cc5c6cc7ccccc7cc6n(-c6ccccc6)c5cc43)c3ccccc23)cc1 ; c1ccc(-c2nc3ccccc3nc2-c2ccc3cc(-n4c5ccccc5c5cc6c7cc8ccccc8cc7n(-c7ccccc7)c6cc54)ccc3c2)cc1]

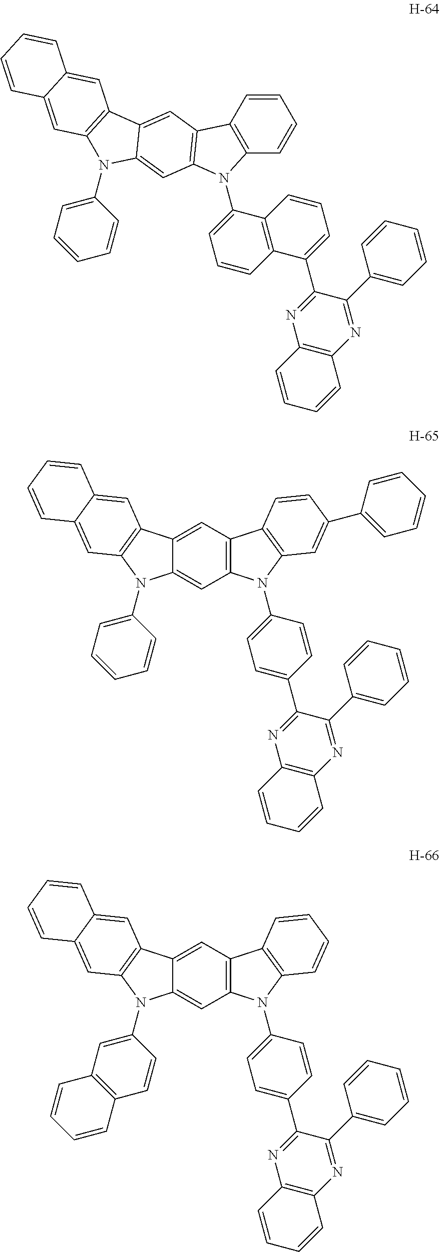 [SMILES: c1ccc(-c2nc3ccccc3nc2-c2cccc3c(-n4c5ccccc5c5cc6c7cc8ccccc8cc7n(-c7ccccc7)c6cc54)cccc23)cc1 ; c1ccc(-c2ccc3c4cc5c6cc7ccccc7cc6n(-c6ccccc6)c5cc4n(-c4ccc(-c5nc6ccccc6nc5-c5ccccc5)cc4)c3c2)cc1 ; c1ccc(-c2nc3ccccc3nc2-c2ccc(-n3c4ccccc4c4cc5c6cc7ccccc7cc6n(-c6ccc7ccccc7c6)c5cc43)cc2)cc1]

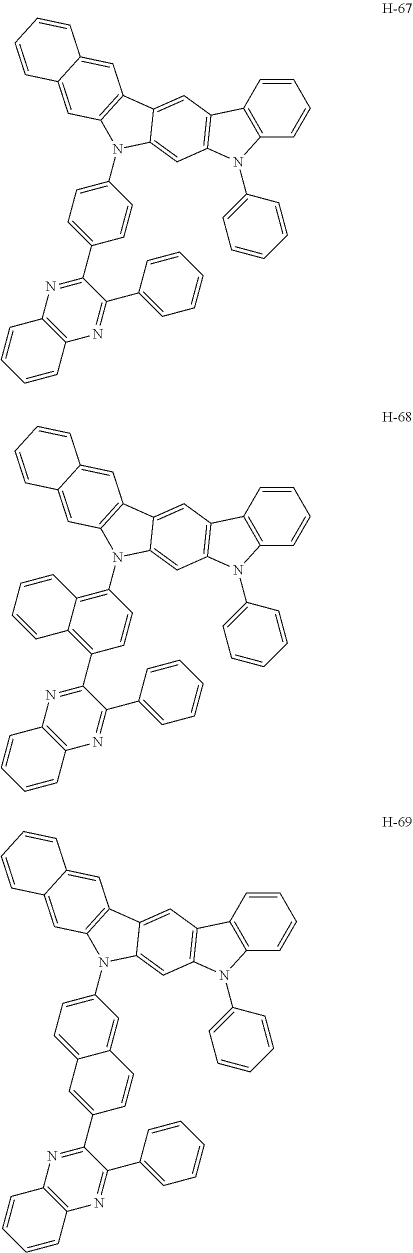

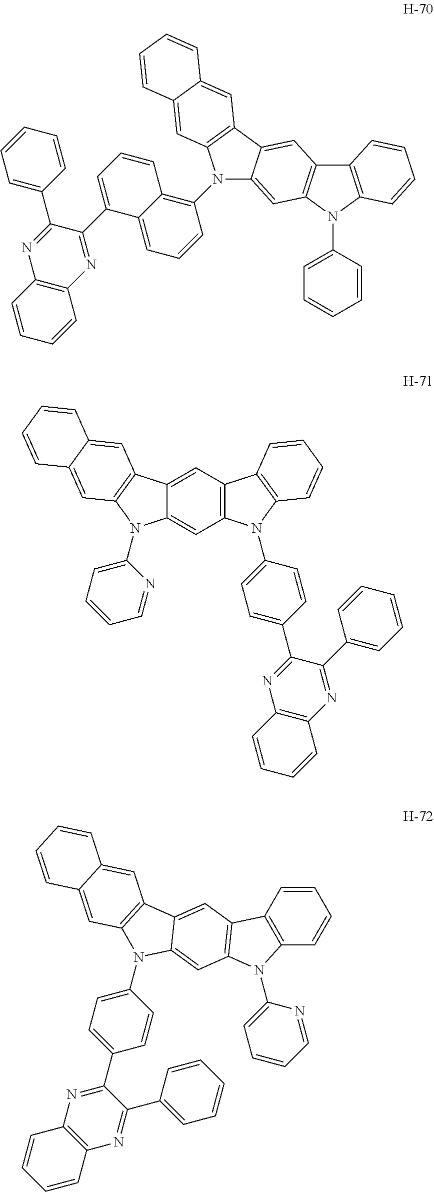 [SMILES: c1ccc(-c2nc3ccccc3nc2-c2cccc3c(-n4c5cc6ccccc6cc5c5cc6c7ccccc7n(-c7ccccc7)c6cc54)cccc23)cc1 ; c1ccc(-c2nc3ccccc3nc2-c2ccc(-n3c4ccccc4c4cc5c6cc7ccccc7cc6n(-c6ccccn6)c5cc43)cc2)cc1 ; c1ccc(-c2nc3ccccc3nc2-c2ccc(-n3c4cc5ccccc5cc4c4cc5c6ccccc6n(-c6ccccn6)c5cc43)cc2)cc1]

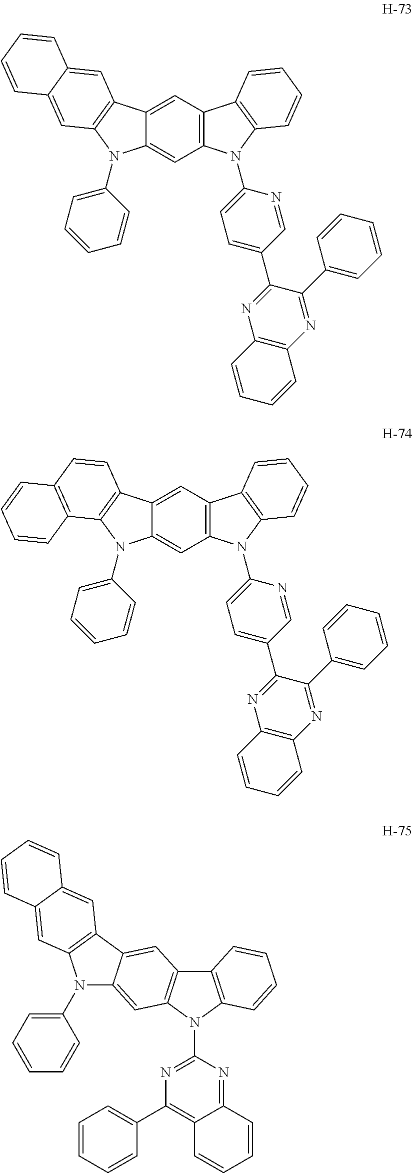 [SMILES: c1ccc(-c2nc3ccccc3nc2-c2ccc(-n3c4ccccc4c4cc5c6cc7ccccc7cc6n(-c6ccccc6)c5cc43)nc2)cc1 ; c1ccc(-c2nc3ccccc3nc2-c2ccc(-n3c4ccccc4c4cc5c6ccc7ccccc7c6n(-c6ccccc6)c5cc43)nc2)cc1 ; c1ccc(-c2nc(-n3c4ccccc4c4cc5c6cc7ccccc7cc6n(-c6ccccc6)c5cc43)nc3ccccc23)cc1]

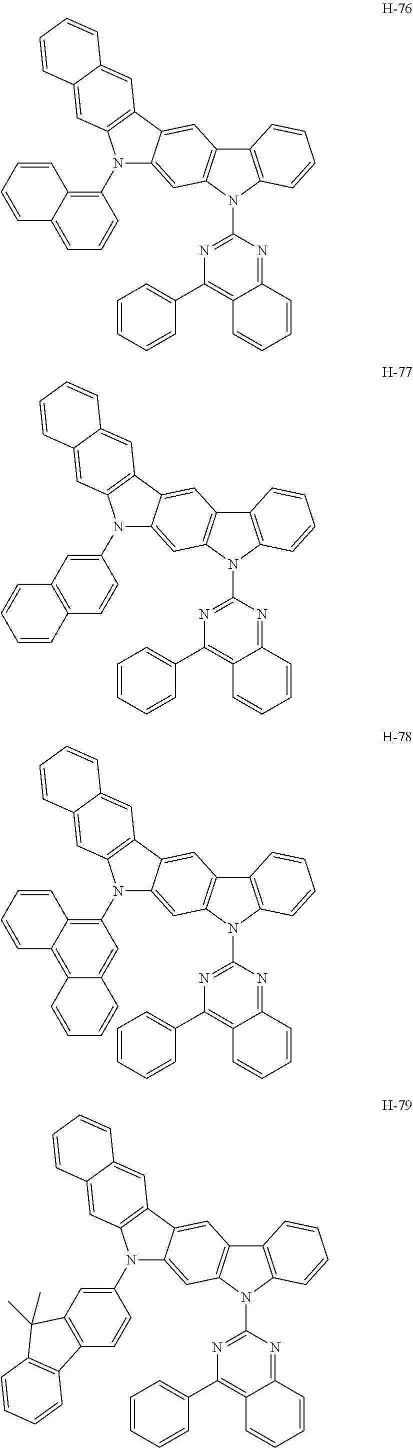 [SMILES: c1ccc(-c2nc(-n3c4ccccc4c4cc5c6cc7ccccc7cc6n(-c6cccc7ccccc67)c5cc43)nc3ccccc23)cc1 ; c1ccc(-c2nc(-n3c4ccccc4c4cc5c6cc7ccccc7cc6n(-c6ccc7ccccc7c6)c5cc43)nc3ccccc23)cc1 ; c1ccc(-c2nc(-n3c4ccccc4c4cc5c6cc7ccccc7cc6n(-c6cc7ccccc7c7ccccc67)c5cc43)nc3ccccc23)cc1 ; CC1(C)c2ccccc2-c2ccc(-n3c4cc5ccccc5cc4c4cc5c6ccccc6n(-c6nc(-c7ccccc7)c7ccccc7n6)c5cc43)cc21]

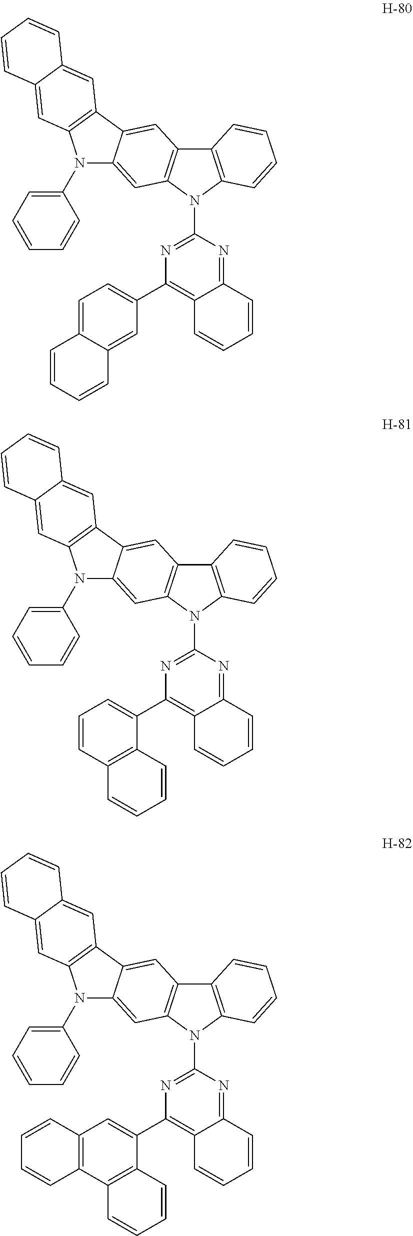 [SMILES: c1ccc(-n2c3cc4ccccc4cc3c3cc4c5ccccc5n(-c5nc(-c6ccc7ccccc7c6)c6ccccc6n5)c4cc32)cc1 ; c1ccc(-n2c3cc4ccccc4cc3c3cc4c5ccccc5n(-c5nc(-c6cccc7ccccc67)c6ccccc6n5)c4cc32)cc1 ; c1ccc(-n2c3cc4ccccc4cc3c3cc4c5ccccc5n(-c5nc(-c6cc7ccccc7c7ccccc67)c6ccccc6n5)c4cc32)cc1]

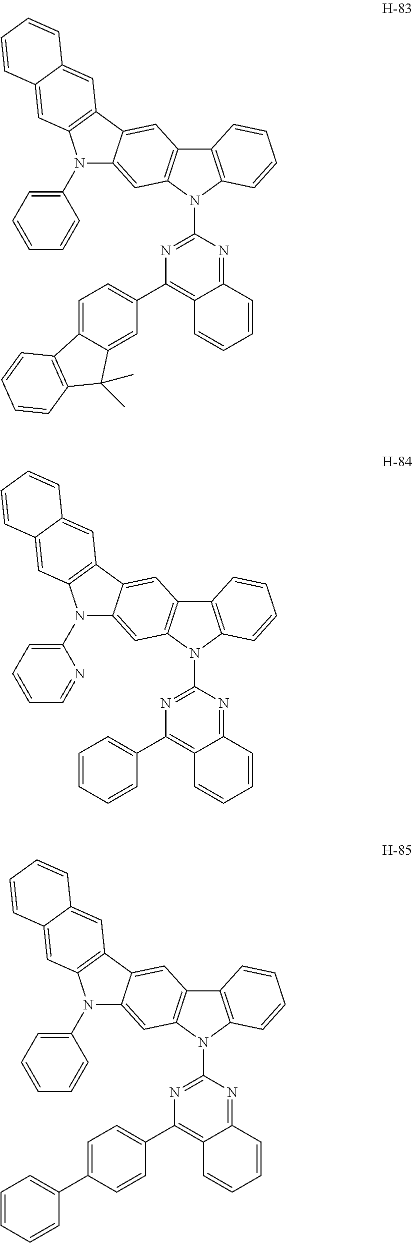 [SMILES: CC1(C)c2ccccc2-c2ccc(-c3nc(-n4c5ccccc5c5cc6c7cc8ccccc8cc7n(-c7ccccc7)c6cc54)nc4ccccc34)cc21 ; c1ccc(-c2nc(-n3c4ccccc4c4cc5c6cc7ccccc7cc6n(-c6ccccn6)c5cc43)nc3ccccc23)cc1 ; c1ccc(-c2ccc(-c3nc(-n4c5ccccc5c5cc6c7cc8ccccc8cc7n(-c7ccccc7)c6cc54)nc4ccccc34)cc2)cc1]

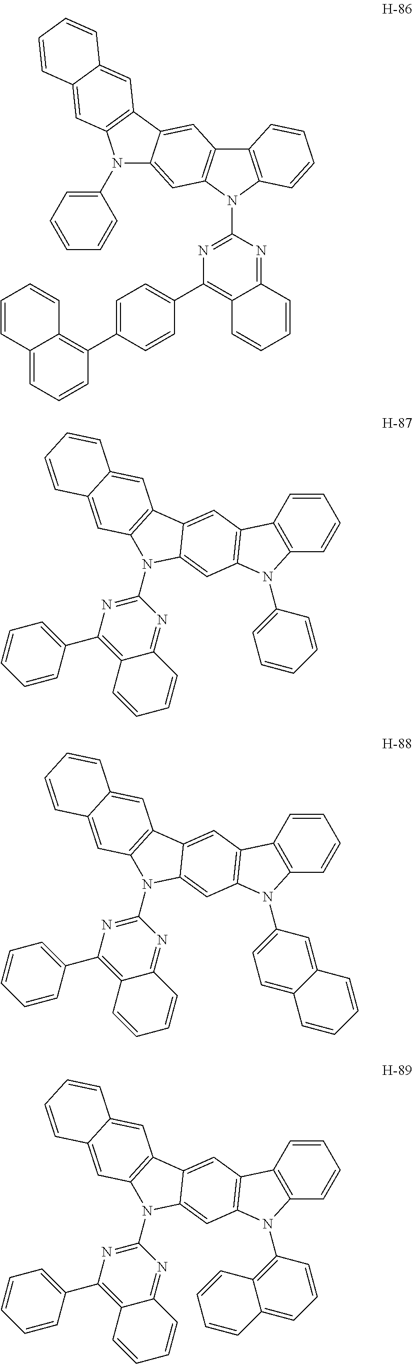

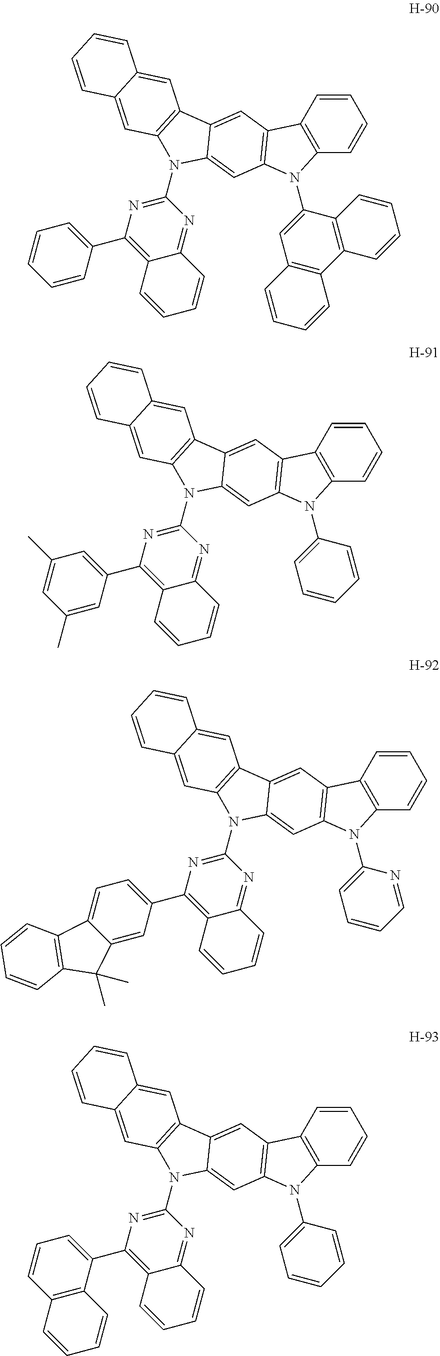

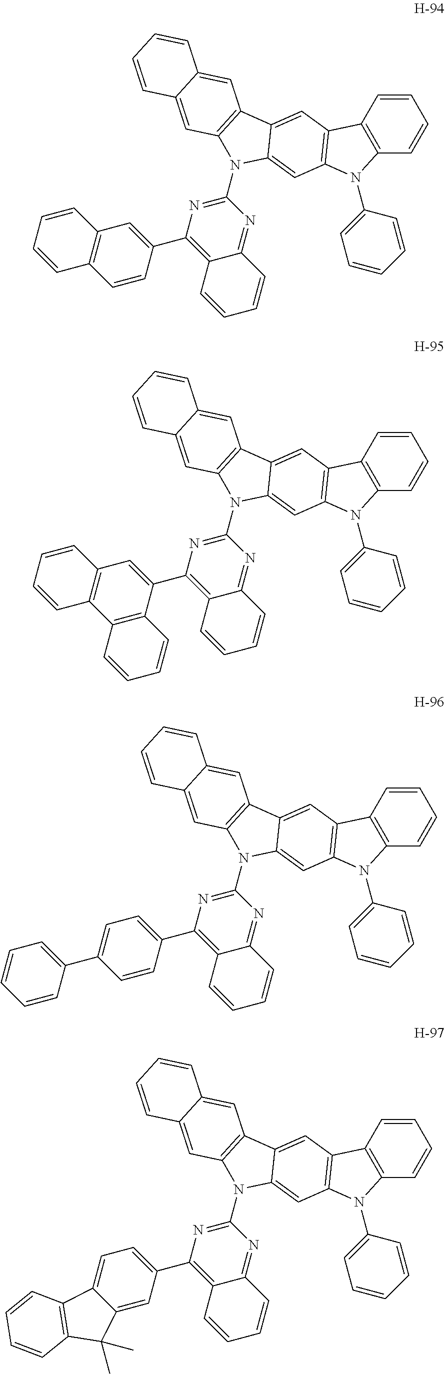 [SMILES: c1ccc(-n2c3ccccc3c3cc4c5cc6ccccc6cc5n(-c5nc(-c6ccc7ccccc7c6)c6ccccc6n5)c4cc32)cc1 ; c1ccc(-n2c3ccccc3c3cc4c5cc6ccccc6cc5n(-c5nc(-c6cc7ccccc7c7ccccc67)c6ccccc6n5)c4cc32)cc1 ; c1ccc(-c2ccc(-c3nc(-n4c5cc6ccccc6cc5c5cc6c7ccccc7n(-c7ccccc7)c6cc54)nc4ccccc34)cc2)cc1 ; CC1(C)c2ccccc2-c2ccc(-c3nc(-n4c5cc6ccccc6cc5c5cc6c7ccccc7n(-c7ccccc7)c6cc54)nc4ccccc34)cc21]

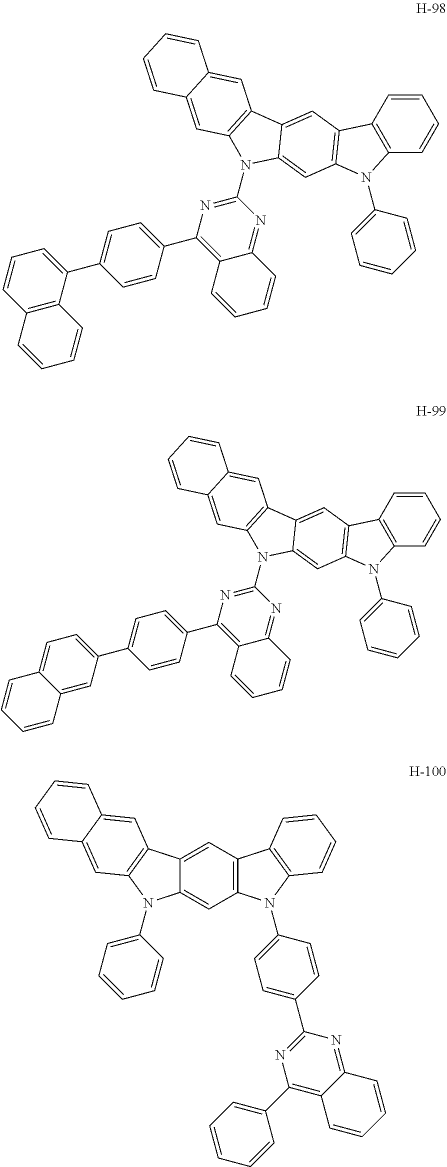 [SMILES: c1ccc(-n2c3ccccc3c3cc4c5cc6ccccc6cc5n(-c5nc(-c6ccc(-c7cccc8ccccc78)cc6)c6ccccc6n5)c4cc32)cc1 ; c1ccc(-n2c3ccccc3c3cc4c5cc6ccccc6cc5n(-c5nc(-c6ccc(-c7ccc8ccccc8c7)cc6)c6ccccc6n5)c4cc32)cc1 ; c1ccc(-c2nc(-c3ccc(-n4c5ccccc5c5cc6c7cc8ccccc8cc7n(-c7ccccc7)c6cc54)cc3)nc3ccccc23)cc1]

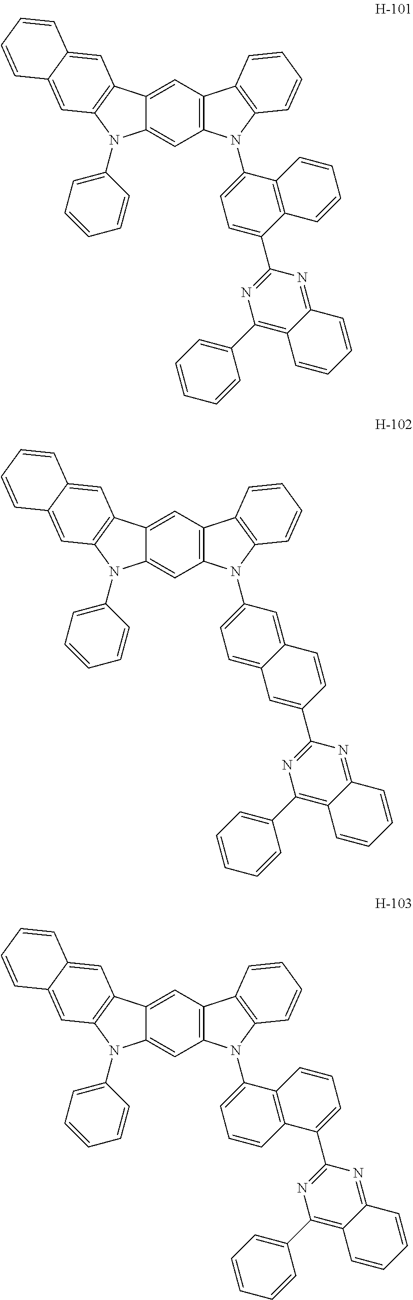 [SMILES: c1ccc(-c2nc(-c3ccc(-n4c5ccccc5c5cc6c7cc8ccccc8cc7n(-c7ccccc7)c6cc54)c4ccccc34)nc3ccccc23)cc1 ; c1ccc(-c2nc(-c3ccc4cc(-n5c6ccccc6c6cc7c8cc9ccccc9cc8n(-c8ccccc8)c7cc65)ccc4c3)nc3ccccc23)cc1 ; c1ccc(-c2nc(-c3cccc4c(-n5c6ccccc6c6cc7c8cc9ccccc9cc8n(-c8ccccc8)c7cc65)cccc34)nc3ccccc23)cc1]

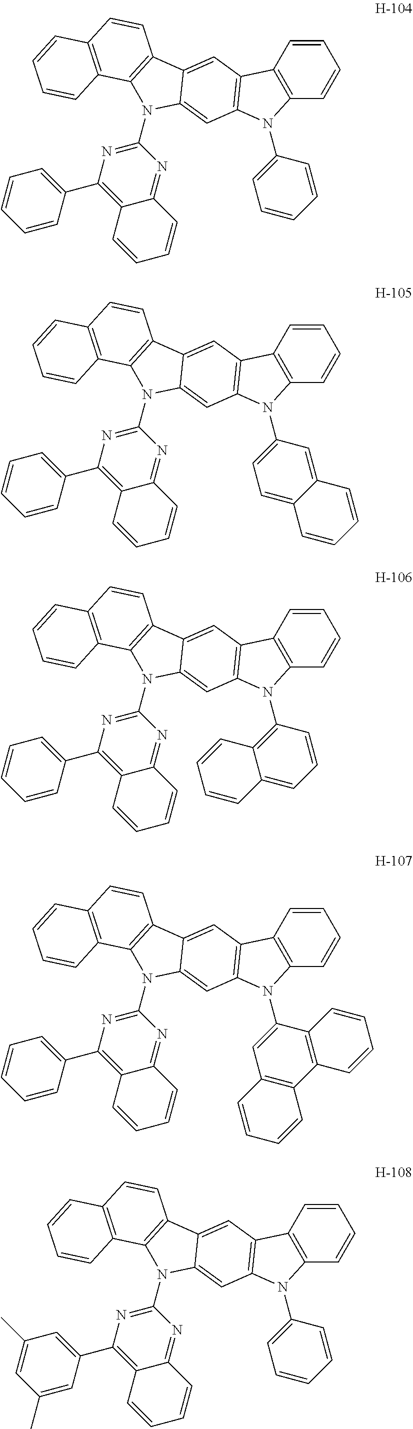 [SMILES: c1ccc(-c2nc(-n3c4cc5c(cc4c4ccc6ccccc6c43)c3ccccc3n5-c3ccccc3)nc3ccccc23)cc1 ; c1ccc(-c2nc(-n3c4cc5c(cc4c4ccc6ccccc6c43)c3ccccc3n5-c3ccc4ccccc4c3)nc3ccccc23)cc1 ; c1ccc(-c2nc(-n3c4cc5c(cc4c4ccc6ccccc6c43)c3ccccc3n5-c3cccc4ccccc34)nc3ccccc23)cc1 ; c1ccc(-c2nc(-n3c4cc5c(cc4c4ccc6ccccc6c43)c3ccccc3n5-c3cc4ccccc4c4ccccc34)nc3ccccc23)cc1 ; Cc1cc(C)cc(-c2nc(-n3c4cc5c(cc4c4ccc6ccccc6c43)c3ccccc3n5-c3ccccc3)nc3ccccc23)c1]

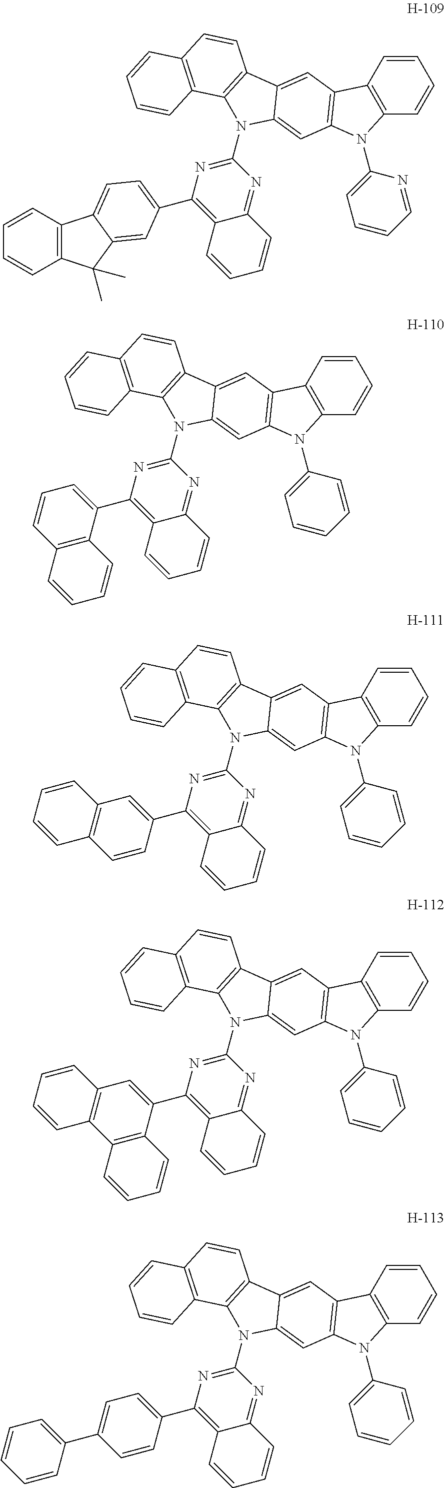 [SMILES: CC1(C)c2ccccc2-c2ccc(-c3nc(-n4c5cc6c(cc5c5ccc7ccccc7c54)c4ccccc4n6-c4ccccn4)nc4ccccc34)cc21 ; c1ccc(-n2c3ccccc3c3cc4c5ccc6ccccc6c5n(-c5nc(-c6cccc7ccccc67)c6ccccc6n5)c4cc32)cc1 ; c1ccc(-n2c3ccccc3c3cc4c5ccc6ccccc6c5n(-c5nc(-c6ccc7ccccc7c6)c6ccccc6n5)c4cc32)cc1 ; c1ccc(-n2c3ccccc3c3cc4c5ccc6ccccc6c5n(-c5nc(-c6cc7ccccc7c7ccccc67)c6ccccc6n5)c4cc32)cc1 ; c1ccc(-c2ccc(-c3nc(-n4c5cc6c(cc5c5ccc7ccccc7c54)c4ccccc4n6-c4ccccc4)nc4ccccc34)cc2)cc1]

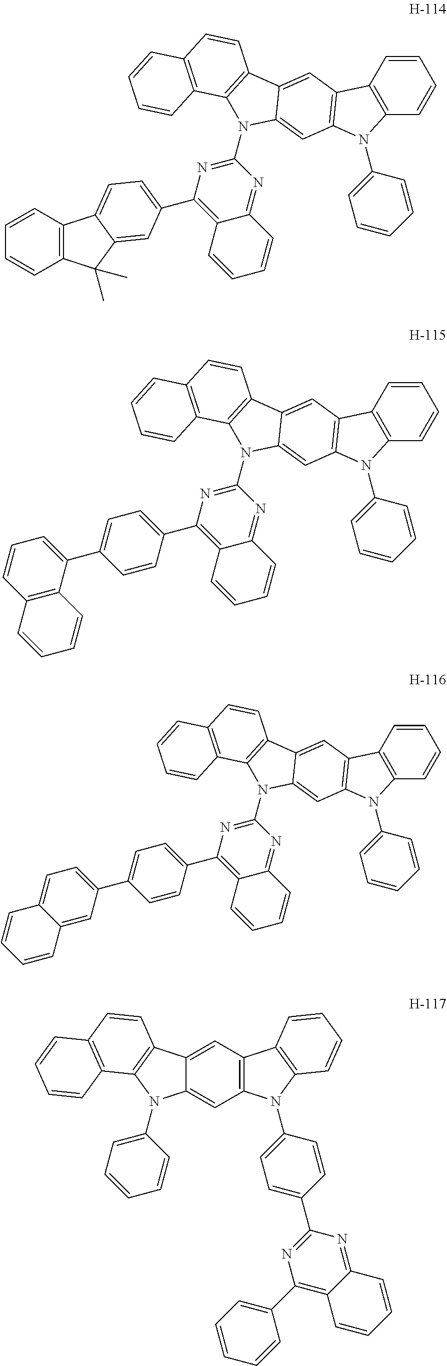 [SMILES: CC1(C)c2ccccc2-c2ccc(-c3nc(-n4c5cc6c(cc5c5ccc7ccccc7c54)c4ccccc4n6-c4ccccc4)nc4ccccc34)cc21 ; c1ccc(-n2c3ccccc3c3cc4c5ccc6ccccc6c5n(-c5nc(-c6ccc(-c7cccc8ccccc78)cc6)c6ccccc6n5)c4cc32)cc1 ; c1ccc(-n2c3ccccc3c3cc4c5ccc6ccccc6c5n(-c5nc(-c6ccc(-c7ccc8ccccc8c7)cc6)c6ccccc6n5)c4cc32)cc1 ; c1ccc(-c2nc(-c3ccc(-n4c5ccccc5c5cc6c7ccc8ccccc8c7n(-c7ccccc7)c6cc54)cc3)nc3ccccc23)cc1]

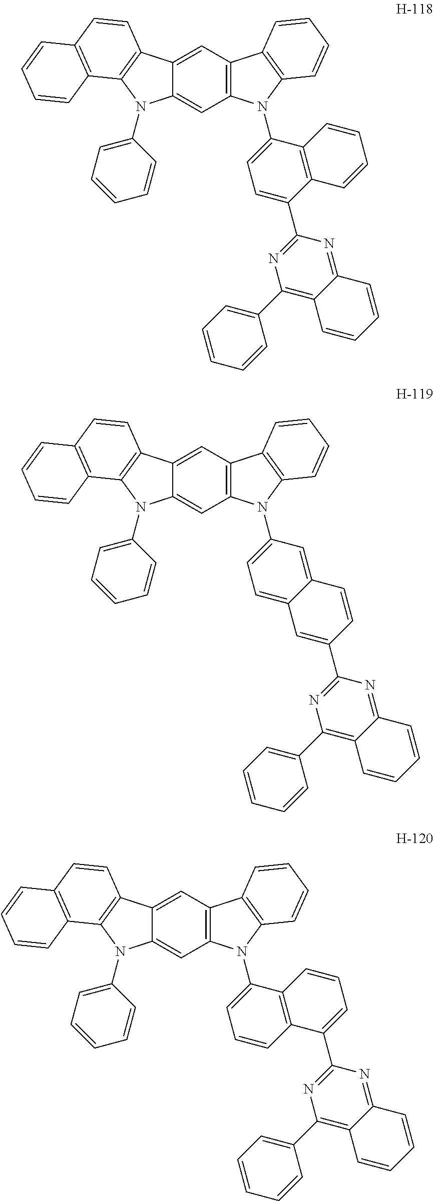 [SMILES: c1ccc(-c2nc(-c3ccc(-n4c5ccccc5c5cc6c7ccc8ccccc8c7n(-c7ccccc7)c6cc54)c4ccccc34)nc3ccccc23)cc1 ; c1ccc(-c2nc(-c3ccc4cc(-n5c6ccccc6c6cc7c8ccc9ccccc9c8n(-c8ccccc8)c7cc65)ccc4c3)nc3ccccc23)cc1 ; c1ccc(-c2nc(-c3cccc4c(-n5c6ccccc6c6cc7c8ccc9ccccc9c8n(-c8ccccc8)c7cc65)cccc34)nc3ccccc23)cc1]

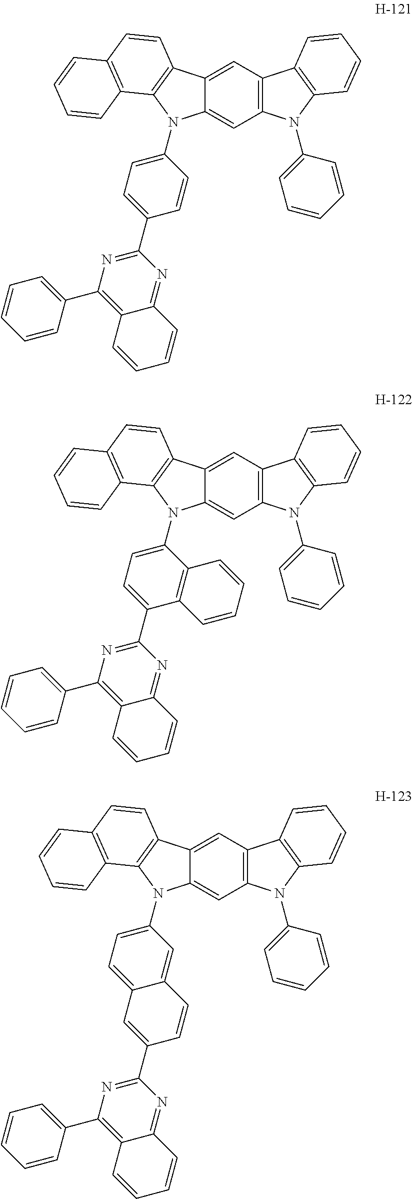 [SMILES: c1ccc(-c2nc(-c3ccc(-n4c5cc6c(cc5c5ccc7ccccc7c54)c4ccccc4n6-c4ccccc4)cc3)nc3ccccc23)cc1 ; c1ccc(-c2nc(-c3ccc(-n4c5cc6c(cc5c5ccc7ccccc7c54)c4ccccc4n6-c4ccccc4)c4ccccc34)nc3ccccc23)cc1 ; c1ccc(-c2nc(-c3ccc4cc(-n5c6cc7c(cc6c6ccc8ccccc8c65)c5ccccc5n7-c5ccccc5)ccc4c3)nc3ccccc23)cc1]

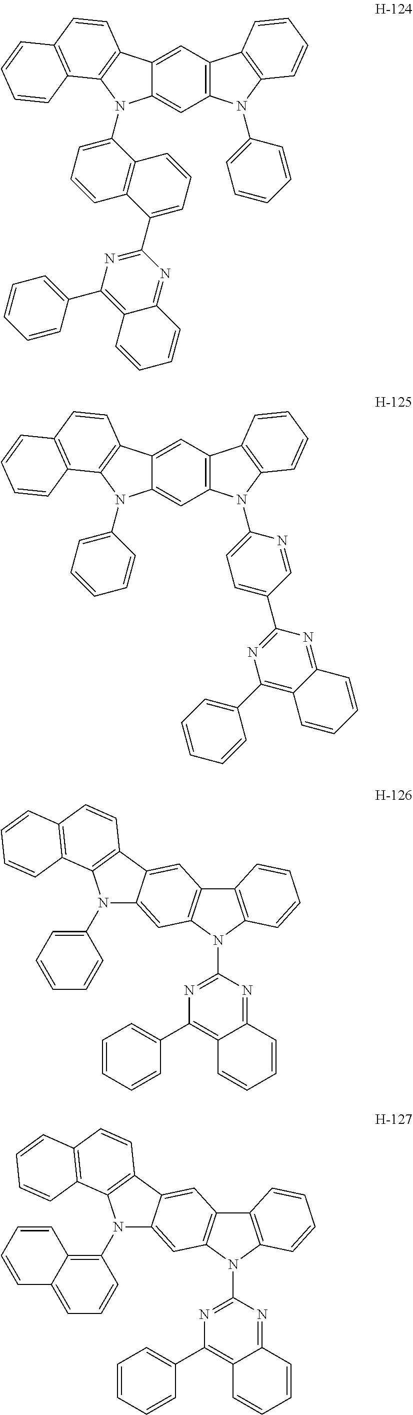 [SMILES: c1ccc(-c2nc(-c3cccc4c(-n5c6cc7c(cc6c6ccc8ccccc8c65)c5ccccc5n7-c5ccccc5)cccc34)nc3ccccc23)cc1 ; c1ccc(-c2nc(-c3ccc(-n4c5ccccc5c5cc6c7ccc8ccccc8c7n(-c7ccccc7)c6cc54)nc3)nc3ccccc23)cc1 ; c1ccc(-c2nc(-n3c4ccccc4c4cc5c6ccc7ccccc7c6n(-c6ccccc6)c5cc43)nc3ccccc23)cc1 ; c1ccc(-c2nc(-n3c4ccccc4c4cc5c6ccc7ccccc7c6n(-c6cccc7ccccc67)c5cc43)nc3ccccc23)cc1]

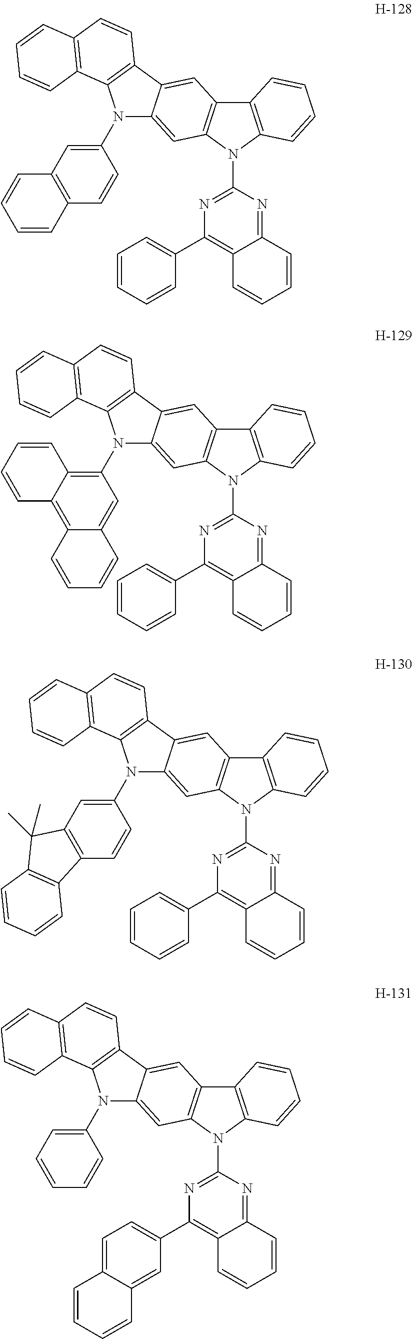 [SMILES: c1ccc(-c2nc(-n3c4ccccc4c4cc5c6ccc7ccccc7c6n(-c6ccc7ccccc7c6)c5cc43)nc3ccccc23)cc1 ; c1ccc(-c2nc(-n3c4ccccc4c4cc5c6ccc7ccccc7c6n(-c6cc7ccccc7c7ccccc67)c5cc43)nc3ccccc23)cc1 ; CC1(C)c2ccccc2-c2ccc(-n3c4cc5c(cc4c4ccc6ccccc6c43)c3ccccc3n5-c3nc(-c4ccccc4)c4ccccc4n3)cc21 ; c1ccc(-n2c3cc4c(cc3c3ccc5ccccc5c32)c2ccccc2n4-c2nc(-c3ccc4ccccc4c3)c3ccccc3n2)cc1]

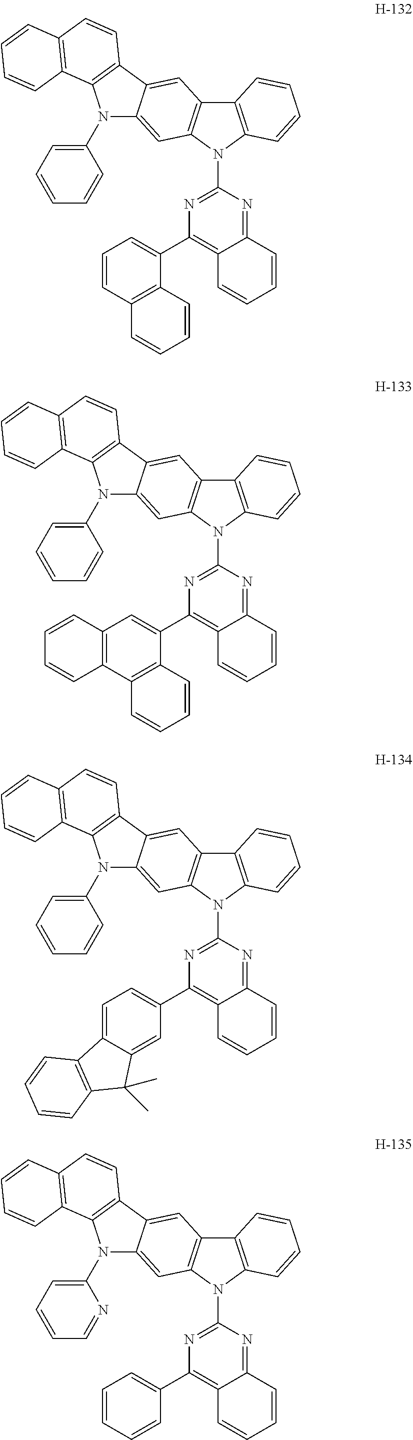

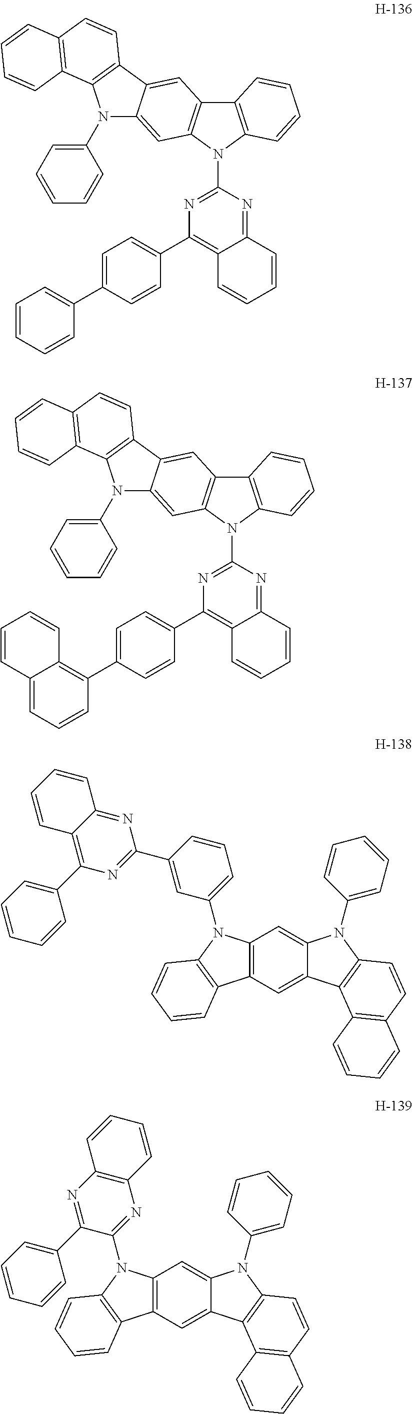

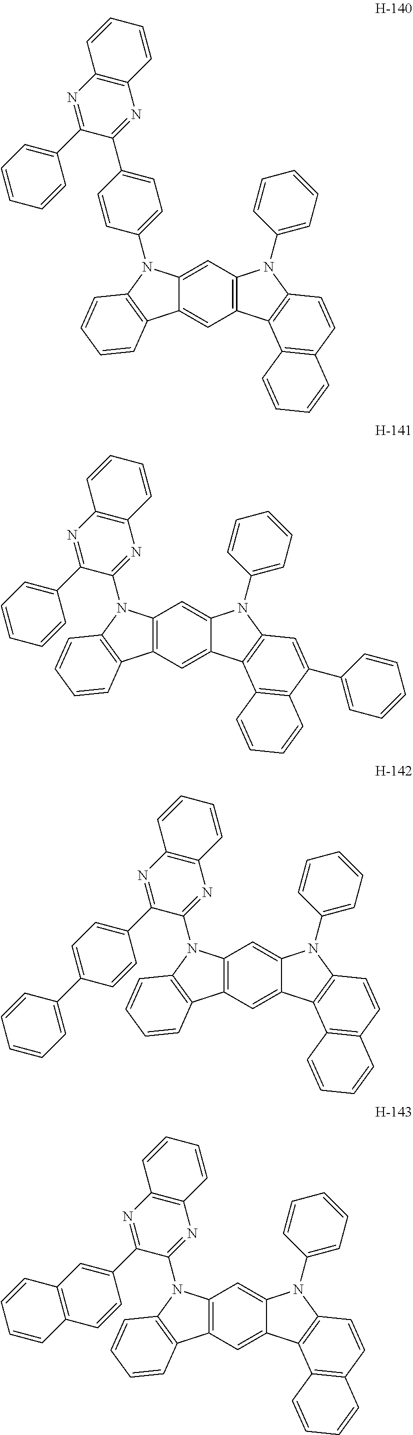 [SMILES: c1ccc(-c2nc3ccccc3nc2-c2ccc(-n3c4ccccc4c4cc5c6c7ccccc7ccc6n(-c6ccccc6)c5cc43)cc2)cc1 ; c1ccc(-c2nc3ccccc3nc2-n2c3ccccc3c3cc4c5c6ccccc6c(-c6ccccc6)cc5n(-c5ccccc5)c4cc32)cc1 ; c1ccc(-c2ccc(-c3nc4ccccc4nc3-n3c4ccccc4c4cc5c6c7ccccc7ccc6n(-c6ccccc6)c5cc43)cc2)cc1 ; c1ccc(-n2c3cc4c(cc3c3c5ccccc5ccc32)c2ccccc2n4-c2nc3ccccc3nc2-c2ccc3ccccc3c2)cc1]

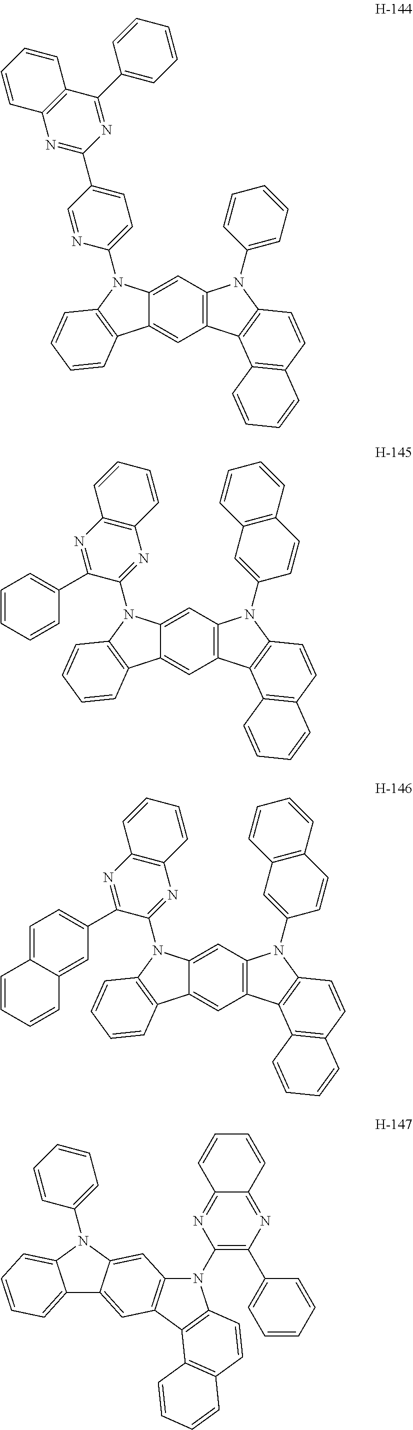

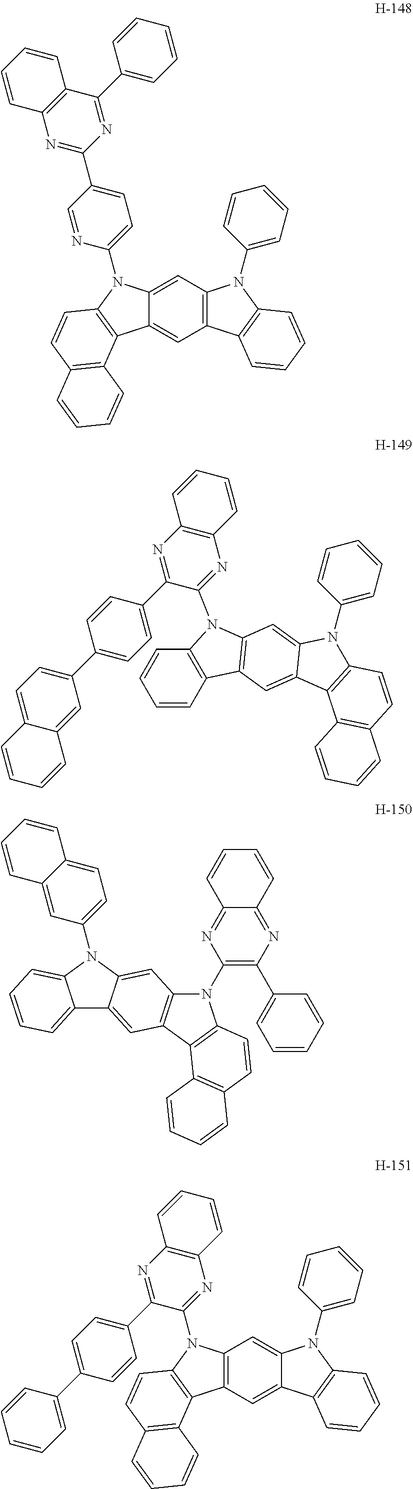

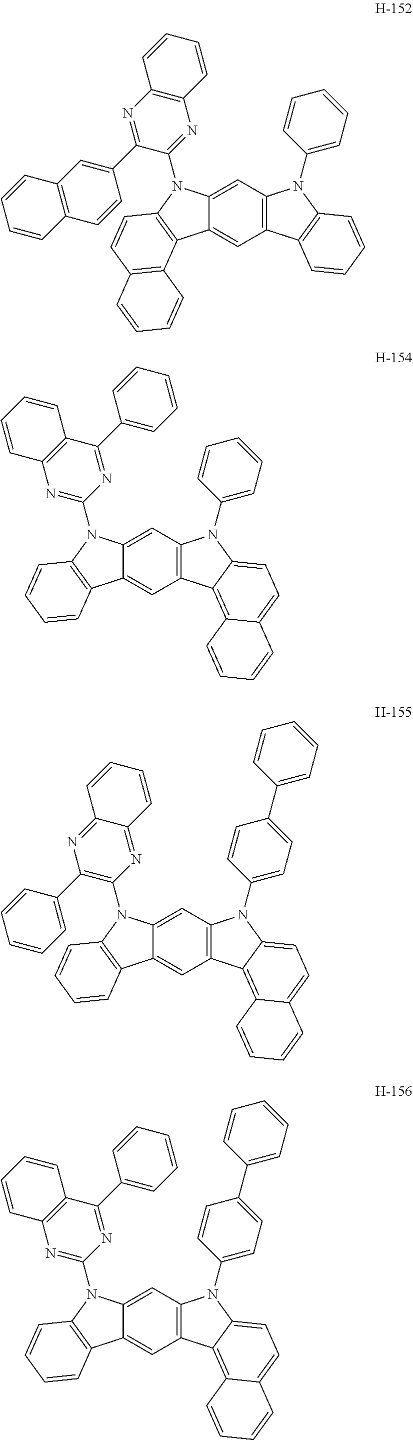

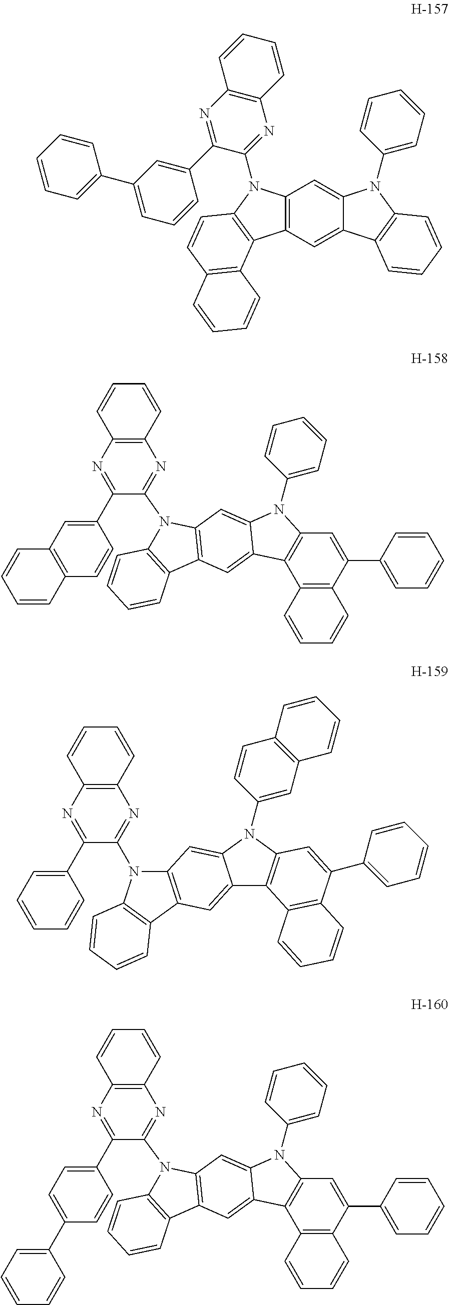 [SMILES: c1ccc(-c2cccc(-c3nc4ccccc4nc3-n3c4cc5c(cc4c4c6ccccc6ccc43)c3ccccc3n5-c3ccccc3)c2)cc1 ; c1ccc(-c2cc3c(c4ccccc24)c2cc4c5ccccc5n(-c5nc6ccccc6nc5-c5ccc6ccccc6c5)c4cc2n3-c2ccccc2)cc1 ; c1ccc(-c2nc3ccccc3nc2-n2c3ccccc3c3cc4c5c6ccccc6c(-c6ccccc6)cc5n(-c5ccc6ccccc6c5)c4cc32)cc1 ; c1ccc(-c2ccc(-c3nc4ccccc4nc3-n3c4ccccc4c4cc5c6c7ccccc7c(-c7ccccc7)cc6n(-c6ccccc6)c5cc43)cc2)cc1]

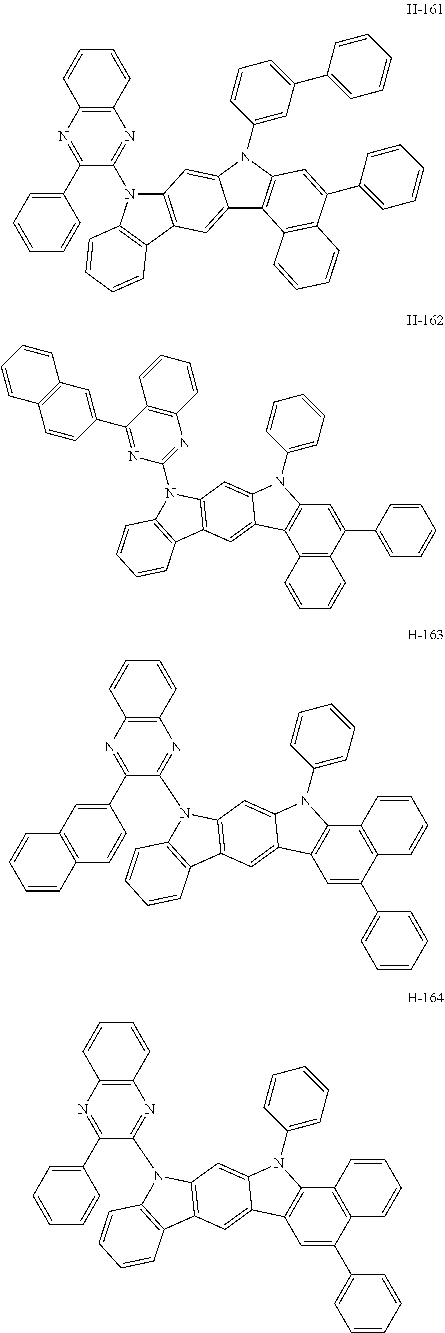 [SMILES: c1ccc(-c2cccc(-n3c4cc5c(cc4c4c6ccccc6c(-c6ccccc6)cc43)c3ccccc3n5-c3nc4ccccc4nc3-c3ccccc3)c2)cc1 ; c1ccc(-c2cc3c(c4ccccc24)c2cc4c5ccccc5n(-c5nc(-c6ccc7ccccc7c6)c6ccccc6n5)c4cc2n3-c2ccccc2)cc1 ; c1ccc(-c2cc3c4cc5c6ccccc6n(-c6nc7ccccc7nc6-c6ccc7ccccc7c6)c5cc4n(-c4ccccc4)c3c3ccccc23)cc1 ; c1ccc(-c2nc3ccccc3nc2-n2c3ccccc3c3cc4c5cc(-c6ccccc6)c6ccccc6c5n(-c5ccccc5)c4cc32)cc1]

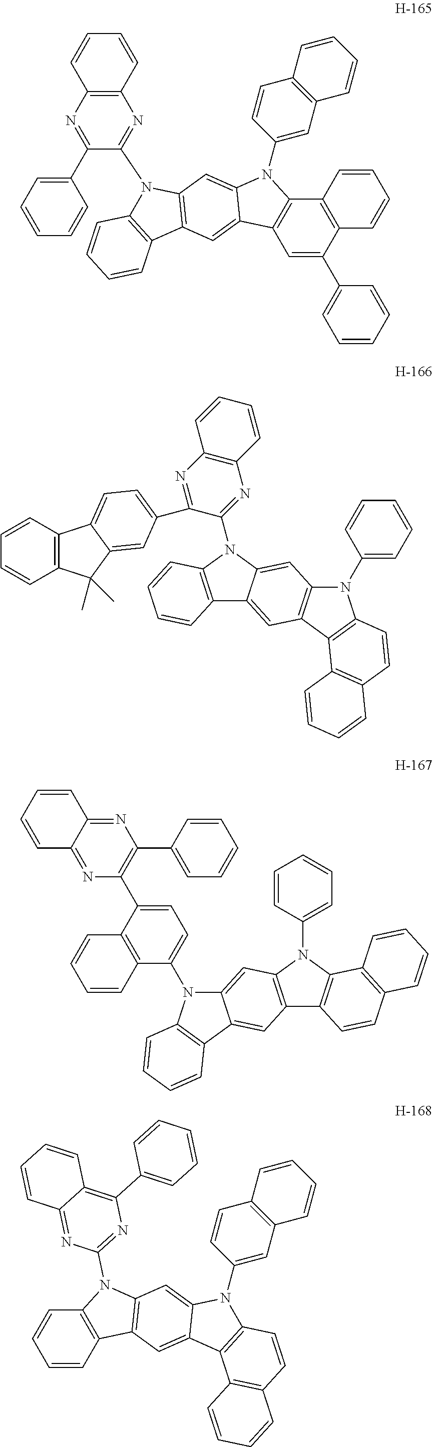

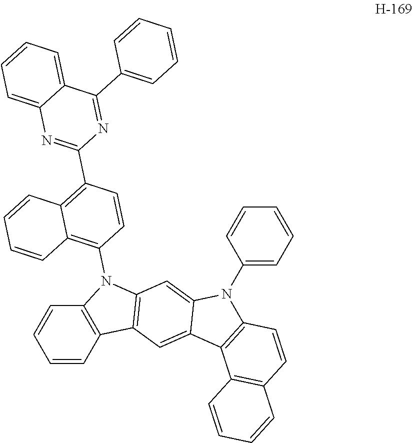 [SMILES: c1ccc(-c2nc(-c3ccc(-n4c5ccccc5c5cc6c7c8ccccc8ccc7n(-c7ccccc7)c6cc54)c4ccccc34)nc3ccccc23)cc1]

The compound represented by formula 11 includes the following compounds, but is not limited thereto.

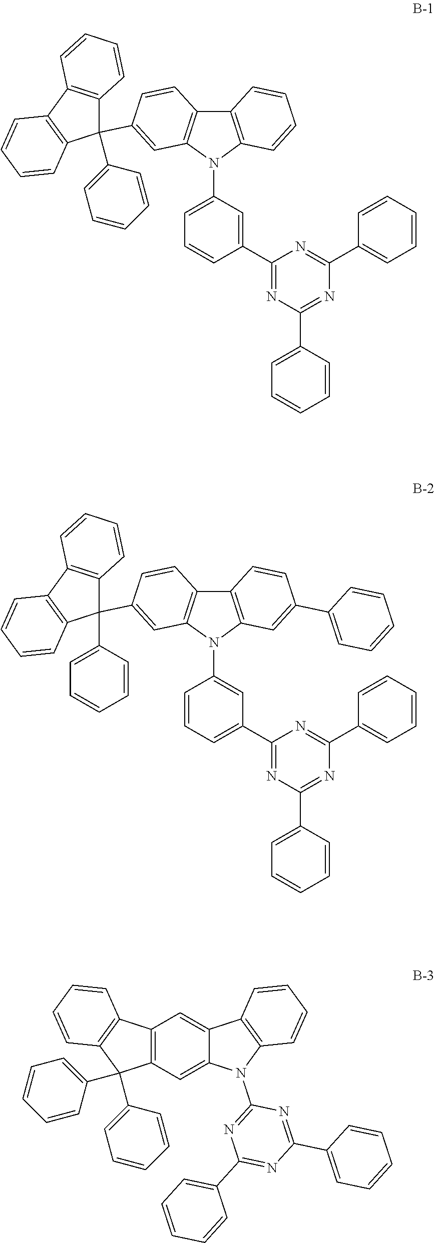 [SMILES: c1ccc(-c2nc(-c3ccccc3)nc(-c3cccc(-n4c5ccccc5c5ccc(C6(c7ccccc7)c7ccccc7-c7ccccc76)cc54)c3)n2)cc1 ; c1ccc(-c2ccc3c4ccc(C5(c6ccccc6)c6ccccc6-c6ccccc65)cc4n(-c4cccc(-c5nc(-c6ccccc6)nc(-c6ccccc6)n5)c4)c3c2)cc1 ; c1ccc(-c2nc(-c3ccccc3)nc(-n3c4ccccc4c4cc5c(cc43)C(c3ccccc3)(c3ccccc3)c3ccccc3-5)n2)cc1]

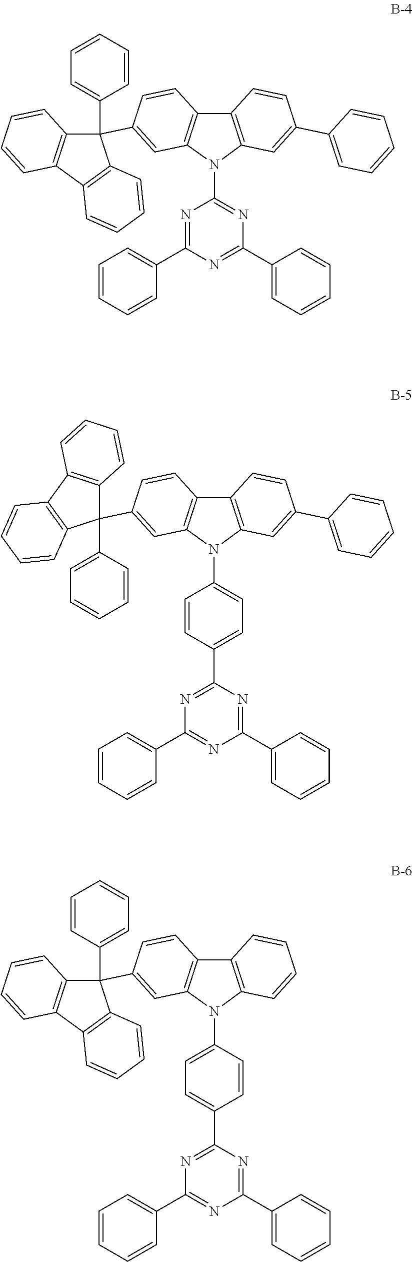 [SMILES: c1ccc(-c2ccc3c4ccc(C5(c6ccccc6)c6ccccc6-c6ccccc65)cc4n(-c4nc(-c5ccccc5)nc(-c5ccccc5)n4)c3c2)cc1 ; c1ccc(-c2ccc3c4ccc(C5(c6ccccc6)c6ccccc6-c6ccccc65)cc4n(-c4ccc(-c5nc(-c6ccccc6)nc(-c6ccccc6)n5)cc4)c3c2)cc1 ; c1ccc(-c2nc(-c3ccccc3)nc(-c3ccc(-n4c5ccccc5c5ccc(C6(c7ccccc7)c7ccccc7-c7ccccc76)cc54)cc3)n2)cc1]

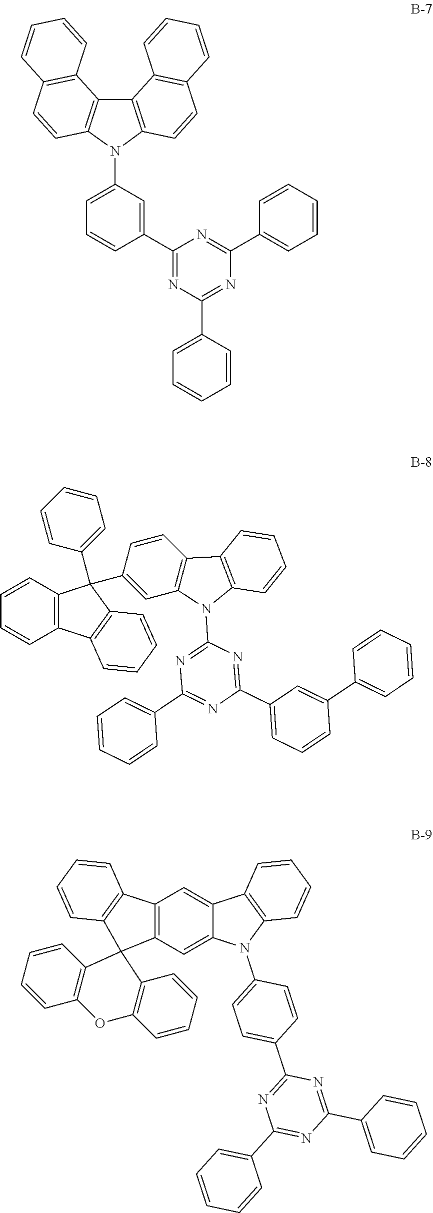 [SMILES: c1ccc(-c2nc(-c3ccccc3)nc(-c3cccc(-n4c5ccc6ccccc6c5c5c6ccccc6ccc54)c3)n2)cc1 ; c1ccc(-c2cccc(-c3nc(-c4ccccc4)nc(-n4c5ccccc5c5ccc(C6(c7ccccc7)c7ccccc7-c7ccccc76)cc54)n3)c2)cc1 ; c1ccc(-c2nc(-c3ccccc3)nc(-c3ccc(-n4c5ccccc5c5cc6c(cc54)C4(c5ccccc5Oc5ccccc54)c4ccccc4-6)cc3)n2)cc1]

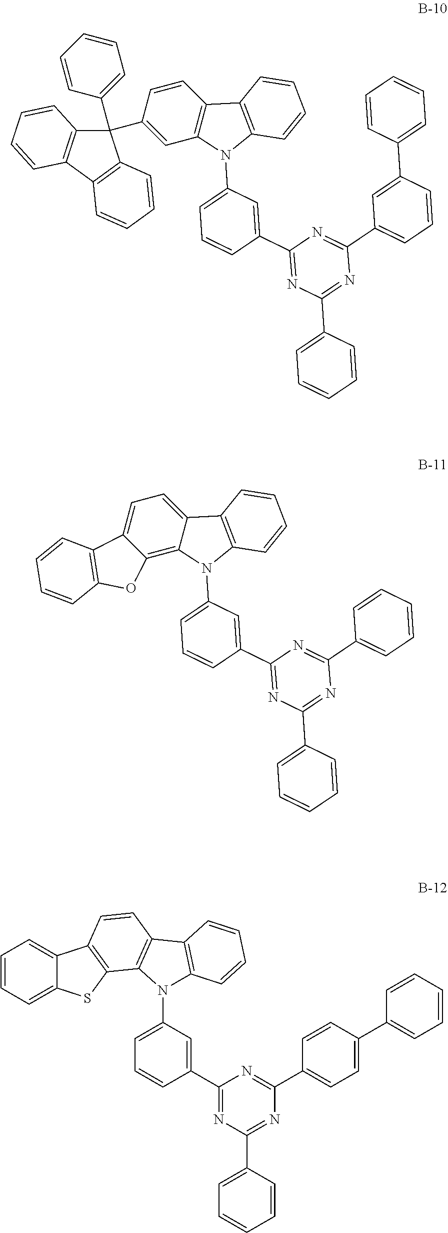 [SMILES: c1ccc(-c2cccc(-c3nc(-c4ccccc4)nc(-c4cccc(-n5c6ccccc6c6ccc(C7(c8ccccc8)c8ccccc8-c8ccccc87)cc65)c4)n3)c2)cc1 ; c1ccc(-c2nc(-c3ccccc3)nc(-c3cccc(-n4c5ccccc5c5ccc6c7ccccc7oc6c54)c3)n2)cc1 ; c1ccc(-c2ccc(-c3nc(-c4ccccc4)nc(-c4cccc(-n5c6ccccc6c6ccc7c8ccccc8sc7c65)c4)n3)cc2)cc1]

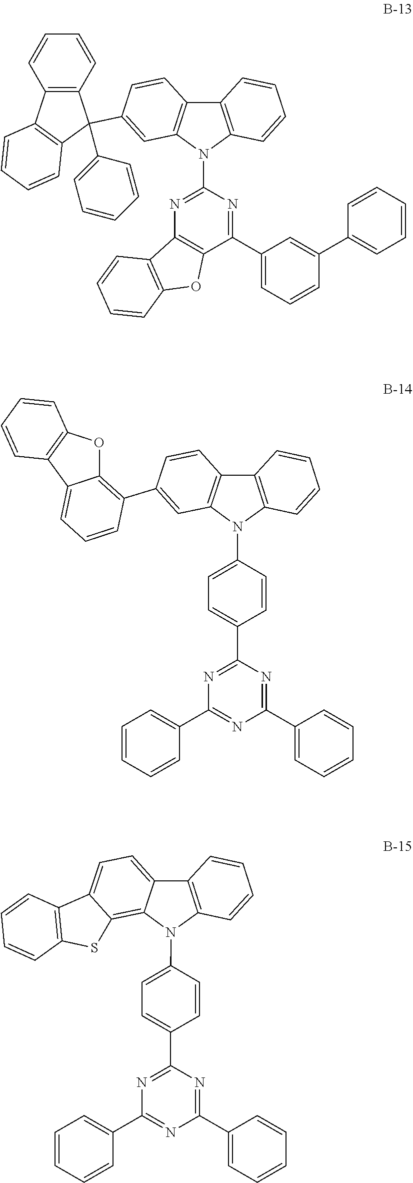 [SMILES: c1ccc(-c2cccc(-c3nc(-n4c5ccccc5c5ccc(C6(c7ccccc7)c7ccccc7-c7ccccc76)cc54)nc4c3oc3ccccc34)c2)cc1 ; c1ccc(-c2nc(-c3ccccc3)nc(-c3ccc(-n4c5ccccc5c5ccc(-c6cccc7c6oc6ccccc67)cc54)cc3)n2)cc1 ; c1ccc(-c2nc(-c3ccccc3)nc(-c3ccc(-n4c5ccccc5c5ccc6c7ccccc7sc6c54)cc3)n2)cc1]

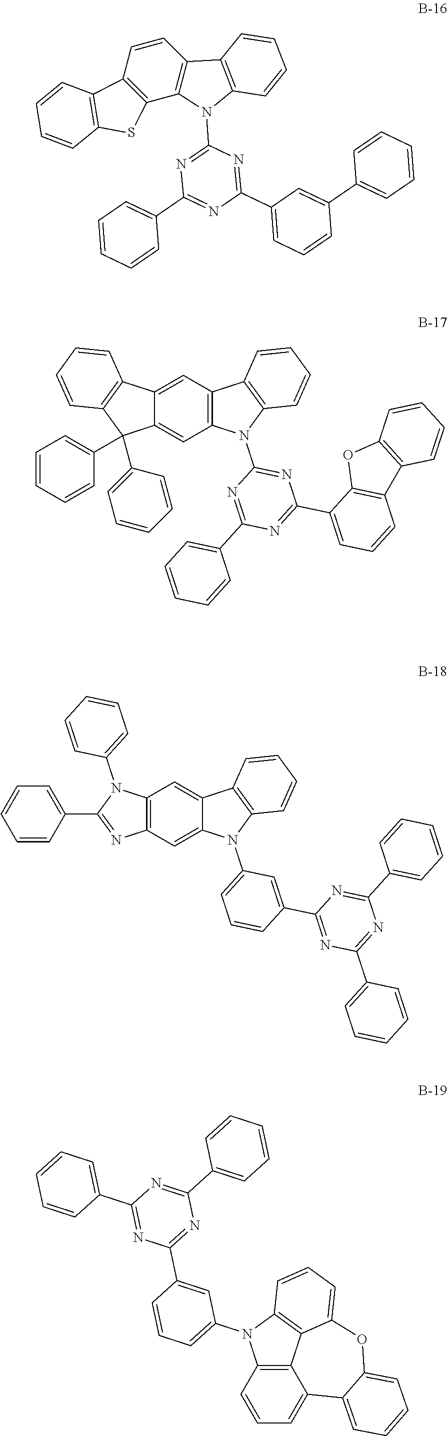 [SMILES: c1ccc(-c2cccc(-c3nc(-c4ccccc4)nc(-n4c5ccccc5c5ccc6c7ccccc7sc6c54)n3)c2)cc1 ; c1ccc(-c2nc(-c3cccc4c3oc3ccccc34)nc(-n3c4ccccc4c4cc5c(cc43)C(c3ccccc3)(c3ccccc3)c3ccccc3-5)n2)cc1 ; c1ccc(-c2nc(-c3ccccc3)nc(-c3cccc(-n4c5ccccc5c5cc6c(cc54)nc(-c4ccccc4)n6-c4ccccc4)c3)n2)cc1 ; c1ccc(-c2nc(-c3ccccc3)nc(-c3cccc(-n4c5cccc6oc7ccccc7c7cccc4c7c65)c3)n2)cc1]

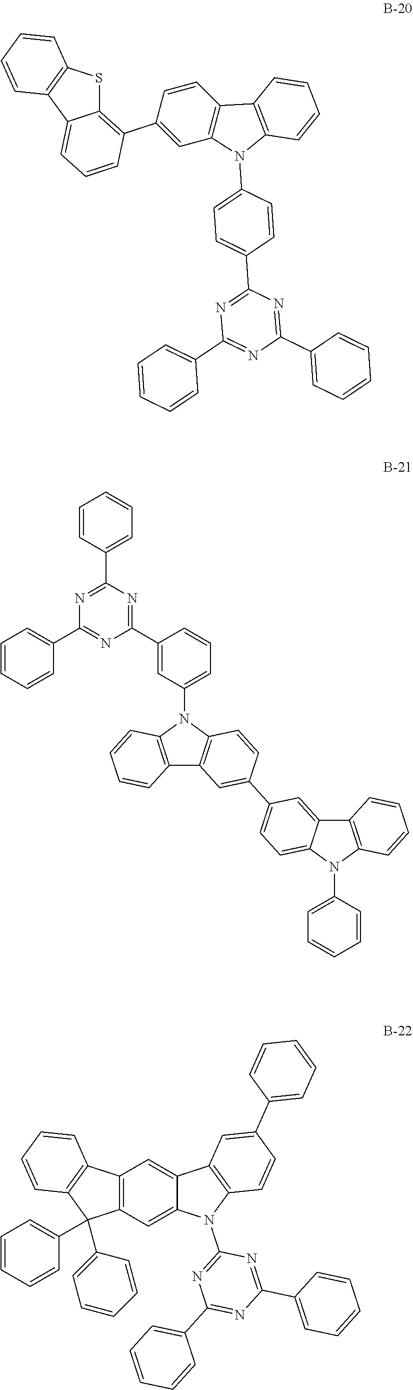 [SMILES: c1ccc(-c2nc(-c3ccccc3)nc(-c3ccc(-n4c5ccccc5c5ccc(-c6cccc7c6sc6ccccc67)cc54)cc3)n2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc3c(c2)c2cc4c(cc2n3-c2nc(-c3ccccc3)nc(-c3ccccc3)n2)C(c2ccccc2)(c2ccccc2)c2ccccc2-4)cc1]

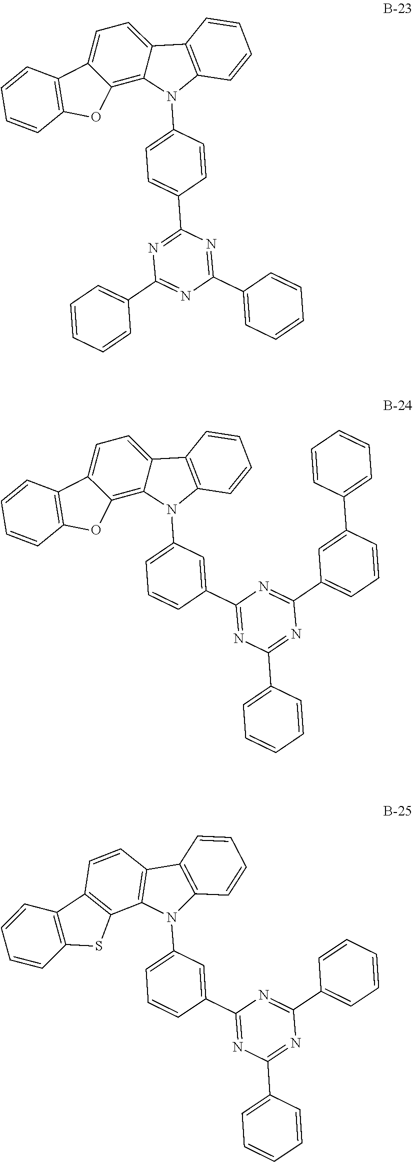 [SMILES: c1ccc(-c2nc(-c3ccccc3)nc(-c3ccc(-n4c5ccccc5c5ccc6c7ccccc7oc6c54)cc3)n2)cc1 ; c1ccc(-c2cccc(-c3nc(-c4ccccc4)nc(-c4cccc(-n5c6ccccc6c6ccc7c8ccccc8oc7c65)c4)n3)c2)cc1 ; c1ccc(-c2nc(-c3ccccc3)nc(-c3cccc(-n4c5ccccc5c5ccc6c7ccccc7sc6c54)c3)n2)cc1]

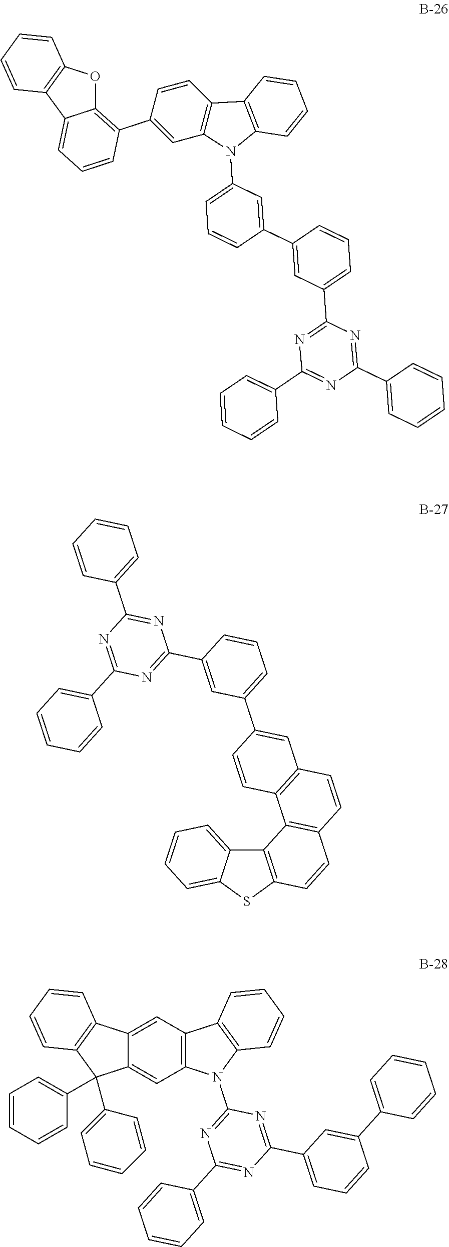 [SMILES: c1ccc(-c2nc(-c3ccccc3)nc(-c3cccc(-c4cccc(-n5c6ccccc6c6ccc(-c7cccc8c7oc7ccccc78)cc65)c4)c3)n2)cc1 ; c1ccc(-c2nc(-c3ccccc3)nc(-c3cccc(-c4ccc5c(ccc6ccc7sc8ccccc8c7c65)c4)c3)n2)cc1 ; c1ccc(-c2cccc(-c3nc(-c4ccccc4)nc(-n4c5ccccc5c5cc6c(cc54)C(c4ccccc4)(c4ccccc4)c4ccccc4-6)n3)c2)cc1]

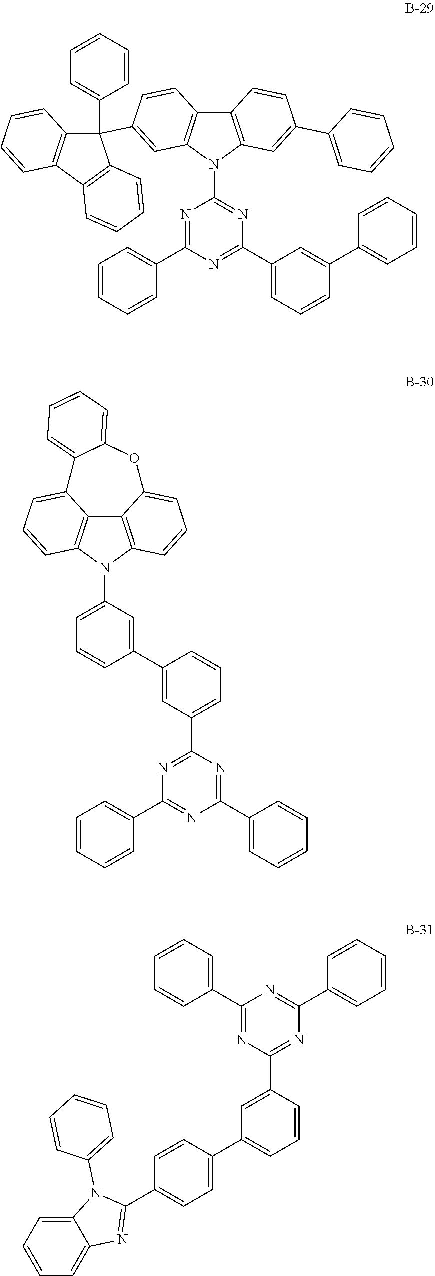 [SMILES: c1ccc(-c2cccc(-c3nc(-c4ccccc4)nc(-n4c5cc(-c6ccccc6)ccc5c5ccc(C6(c7ccccc7)c7ccccc7-c7ccccc76)cc54)n3)c2)cc1 ; c1ccc(-c2nc(-c3ccccc3)nc(-c3cccc(-c4cccc(-n5c6cccc7oc8ccccc8c8cccc5c8c76)c4)c3)n2)cc1 ; c1ccc(-c2nc(-c3ccccc3)nc(-c3cccc(-c4ccc(-c5nc6ccccc6n5-c5ccccc5)cc4)c3)n2)cc1]

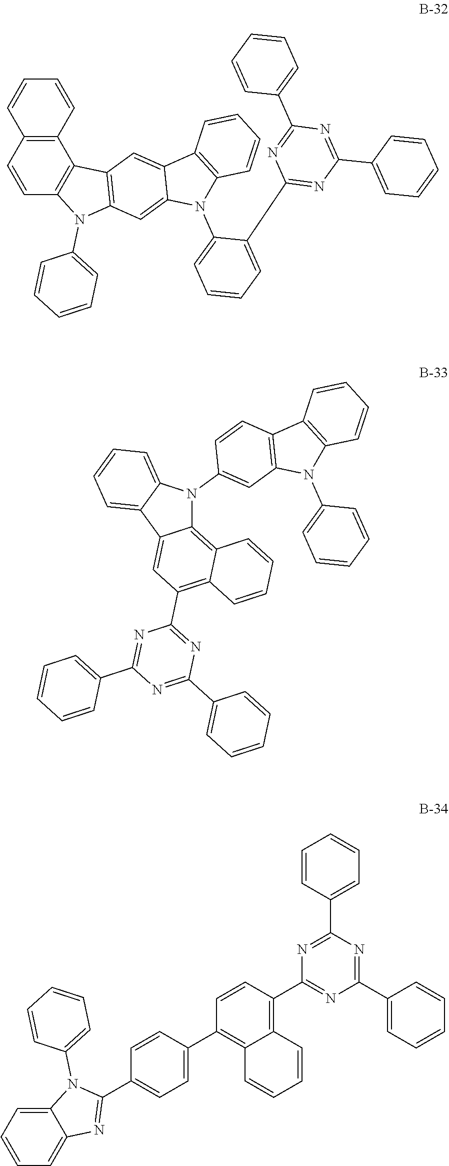 [SMILES: c1ccc(-c2nc(-c3ccccc3)nc(-c3ccccc3-n3c4ccccc4c4cc5c6c7ccccc7ccc6n(-c6ccccc6)c5cc43)n2)cc1 ; c1ccc(-c2nc(-c3ccccc3)nc(-c3cc4c5ccccc5n(-c5ccc6c7ccccc7n(-c7ccccc7)c6c5)c4c4ccccc34)n2)cc1 ; c1ccc(-c2nc(-c3ccccc3)nc(-c3ccc(-c4ccc(-c5nc6ccccc6n5-c5ccccc5)cc4)c4ccccc34)n2)cc1]

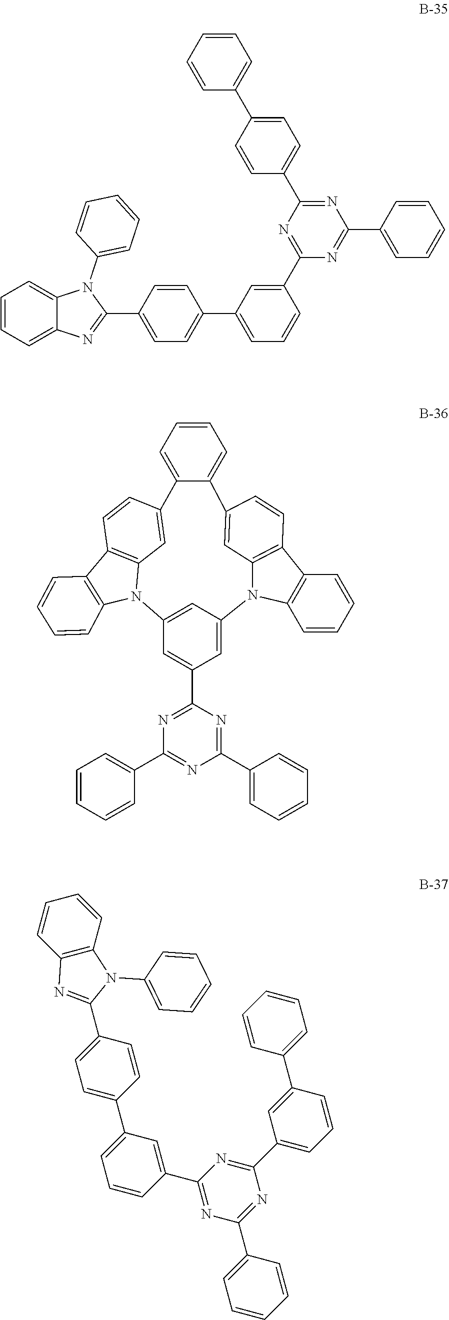 [SMILES: c1ccc(-c2ccc(-c3nc(-c4ccccc4)nc(-c4cccc(-c5ccc(-c6nc7ccccc7n6-c6ccccc6)cc5)c4)n3)cc2)cc1 ; c1ccc(-c2nc(-c3ccccc3)nc(-c3cc4cc(c3)n3c5ccccc5c5ccc(cc53)c3ccccc3c3ccc5c6ccccc6n4c5c3)n2)cc1 ; c1ccc(-c2cccc(-c3nc(-c4ccccc4)nc(-c4cccc(-c5ccc(-c6nc7ccccc7n6-c6ccccc6)cc5)c4)n3)c2)cc1]

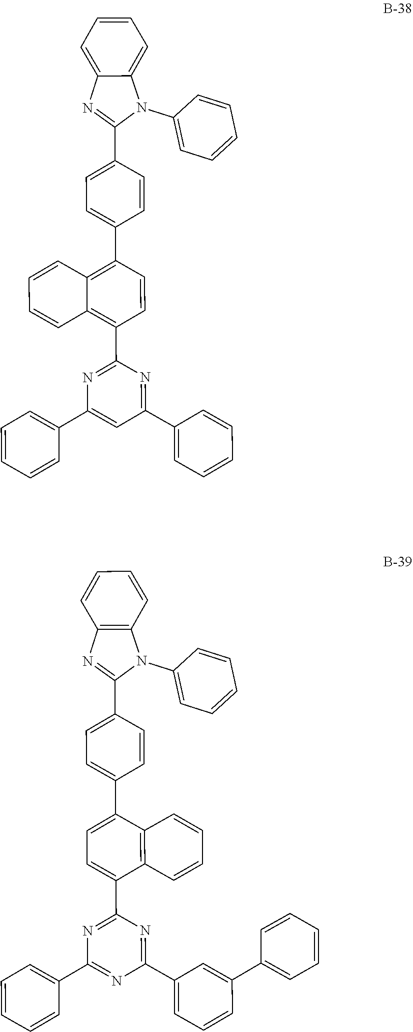 [SMILES: c1ccc(-c2cc(-c3ccccc3)nc(-c3ccc(-c4ccc(-c5nc6ccccc6n5-c5ccccc5)cc4)c4ccccc34)n2)cc1 ; c1ccc(-c2cccc(-c3nc(-c4ccccc4)nc(-c4ccc(-c5ccc(-c6nc7ccccc7n6-c6ccccc6)cc5)c5ccccc45)n3)c2)cc1]

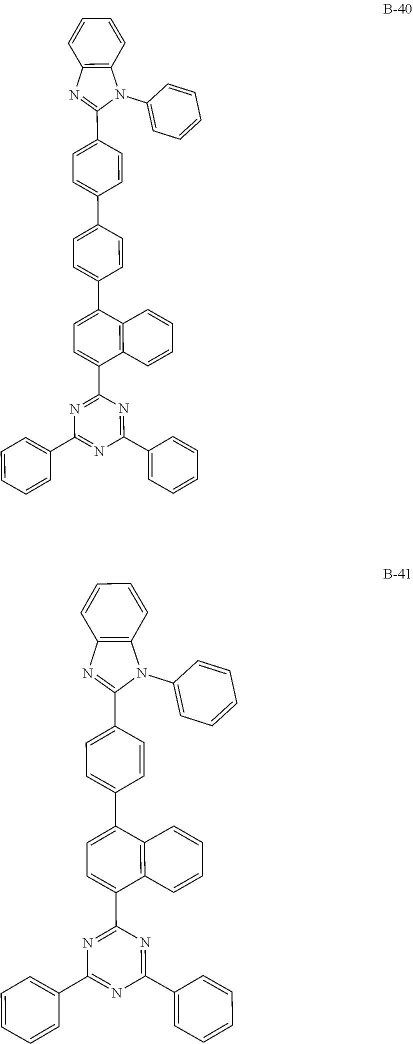 [SMILES: c1ccc(-c2nc(-c3ccccc3)nc(-c3ccc(-c4ccc(-c5ccc(-c6nc7ccccc7n6-c6ccccc6)cc5)cc4)c4ccccc34)n2)cc1 ; c1ccc(-c2nc(-c3ccccc3)nc(-c3ccc(-c4ccc(-c5nc6ccccc6n5-c5ccccc5)cc4)c4ccccc34)n2)cc1]

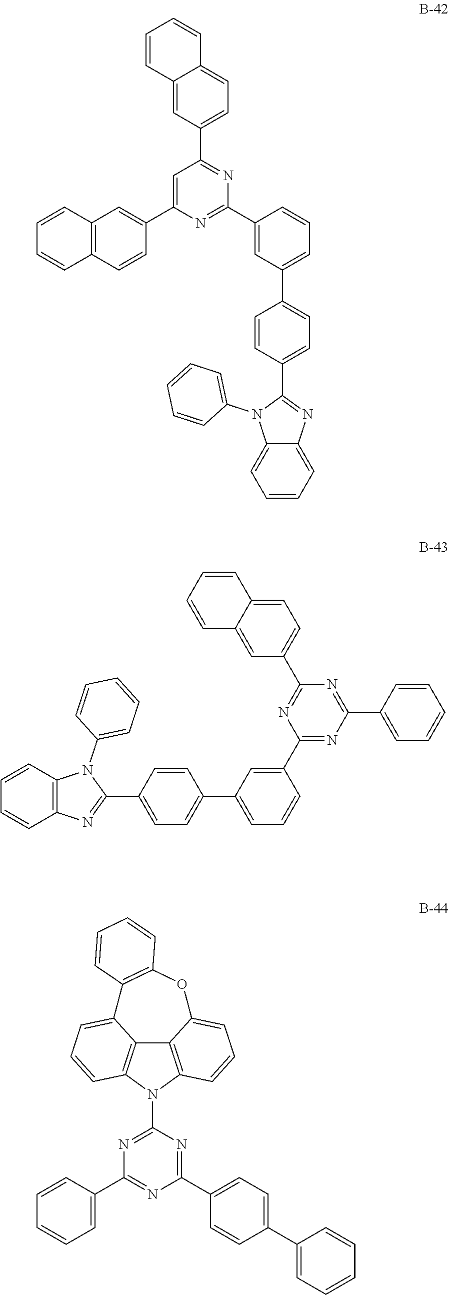 [SMILES: c1ccc(-n2c(-c3ccc(-c4cccc(-c5nc(-c6ccc7ccccc7c6)cc(-c6ccc7ccccc7c6)n5)c4)cc3)nc3ccccc32)cc1 ; c1ccc(-c2nc(-c3cccc(-c4ccc(-c5nc6ccccc6n5-c5ccccc5)cc4)c3)nc(-c3ccc4ccccc4c3)n2)cc1 ; c1ccc(-c2ccc(-c3nc(-c4ccccc4)nc(-n4c5cccc6oc7ccccc7c7cccc4c7c65)n3)cc2)cc1]

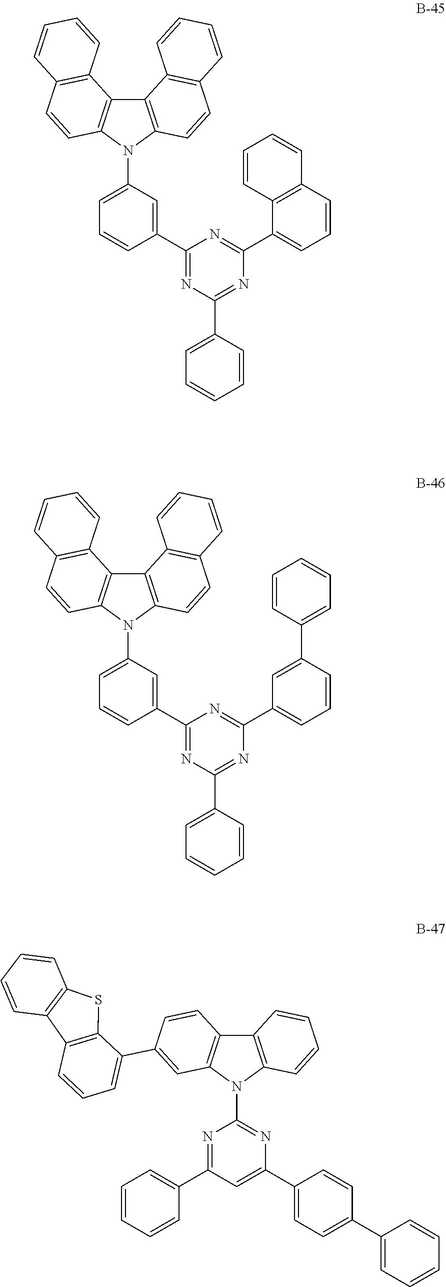 [SMILES: c1ccc(-c2nc(-c3cccc(-n4c5ccc6ccccc6c5c5c6ccccc6ccc54)c3)nc(-c3cccc4ccccc34)n2)cc1 ; c1ccc(-c2cccc(-c3nc(-c4ccccc4)nc(-c4cccc(-n5c6ccc7ccccc7c6c6c7ccccc7ccc65)c4)n3)c2)cc1 ; c1ccc(-c2ccc(-c3cc(-c4ccccc4)nc(-n4c5ccccc5c5ccc(-c6cccc7c6sc6ccccc67)cc54)n3)cc2)cc1]

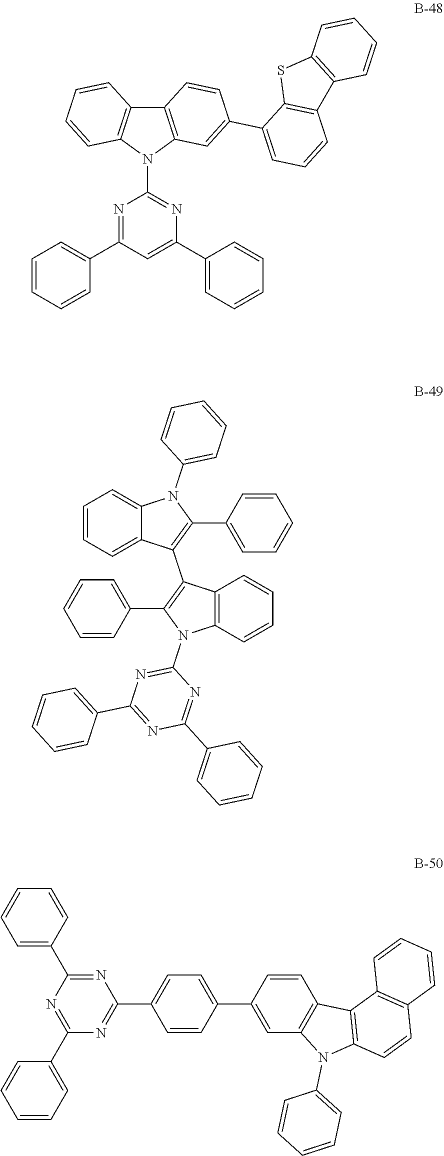 [SMILES: c1ccc(-c2cc(-c3ccccc3)nc(-n3c4ccccc4c4ccc(-c5cccc6c5sc5ccccc56)cc43)n2)cc1 ; c1ccc(-c2nc(-c3ccccc3)nc(-n3c(-c4ccccc4)c(-c4c(-c5ccccc5)n(-c5ccccc5)c5ccccc45)c4ccccc43)n2)cc1 ; c1ccc(-c2nc(-c3ccccc3)nc(-c3ccc(-c4ccc5c6c7ccccc7ccc6n(-c6ccccc6)c5c4)cc3)n2)cc1]

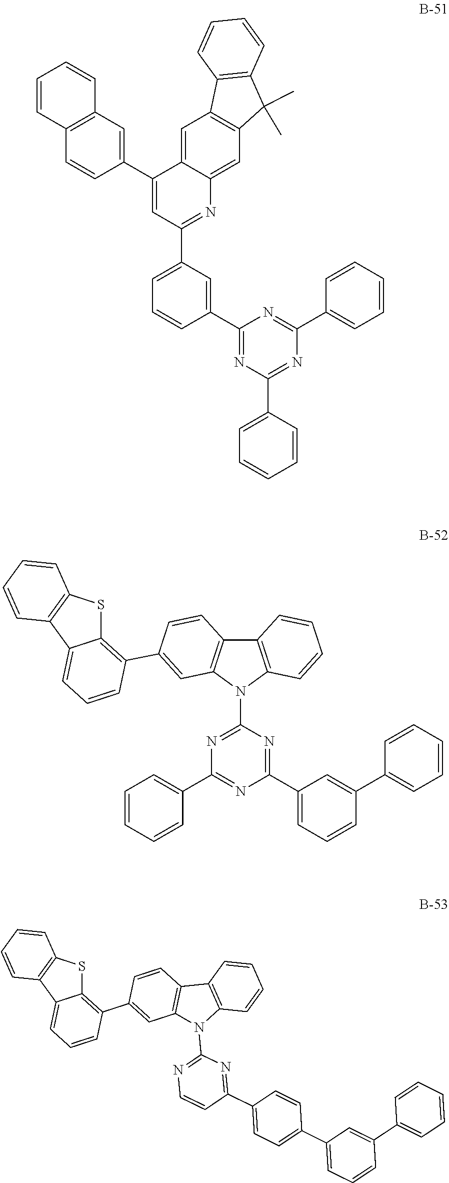 [SMILES: CC1(C)c2ccccc2-c2cc3c(-c4ccc5ccccc5c4)cc(-c4cccc(-c5nc(-c6ccccc6)nc(-c6ccccc6)n5)c4)nc3cc21 ; c1ccc(-c2cccc(-c3nc(-c4ccccc4)nc(-n4c5ccccc5c5ccc(-c6cccc7c6sc6ccccc67)cc54)n3)c2)cc1 ; c1ccc(-c2cccc(-c3ccc(-c4ccnc(-n5c6ccccc6c6ccc(-c7cccc8c7sc7ccccc78)cc65)n4)cc3)c2)cc1]

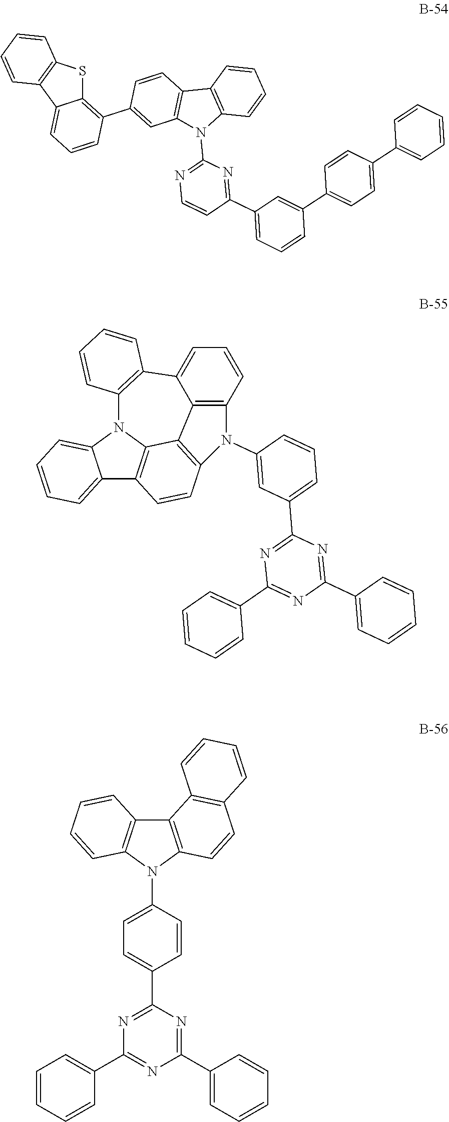 [SMILES: c1ccc(-c2ccc(-c3cccc(-c4ccnc(-n5c6ccccc6c6ccc(-c7cccc8c7sc7ccccc78)cc65)n4)c3)cc2)cc1 ; c1ccc(-c2nc(-c3ccccc3)nc(-c3cccc(-n4c5cccc6c7ccccc7n7c8ccccc8c8ccc4c(c65)c87)c3)n2)cc1 ; c1ccc(-c2nc(-c3ccccc3)nc(-c3ccc(-n4c5ccccc5c5c6ccccc6ccc54)cc3)n2)cc1]

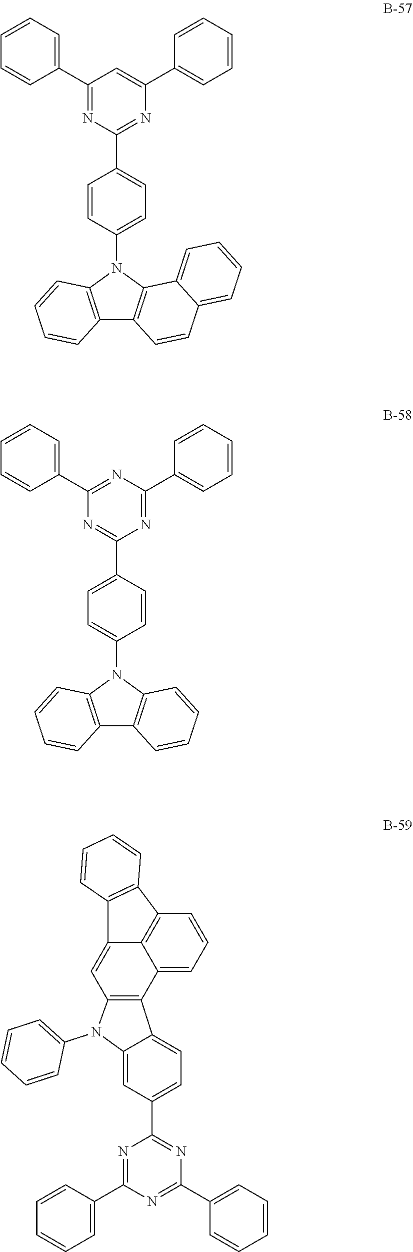 [SMILES: c1ccc(-c2cc(-c3ccccc3)nc(-c3ccc(-n4c5ccccc5c5ccc6ccccc6c54)cc3)n2)cc1 ; c1ccc(-c2nc(-c3ccccc3)nc(-c3ccc(-n4c5ccccc5c5ccccc54)cc3)n2)cc1 ; c1ccc(-c2nc(-c3ccccc3)nc(-c3ccc4c5c6cccc7c6c(cc5n(-c5ccccc5)c4c3)-c3ccccc3-7)n2)cc1]

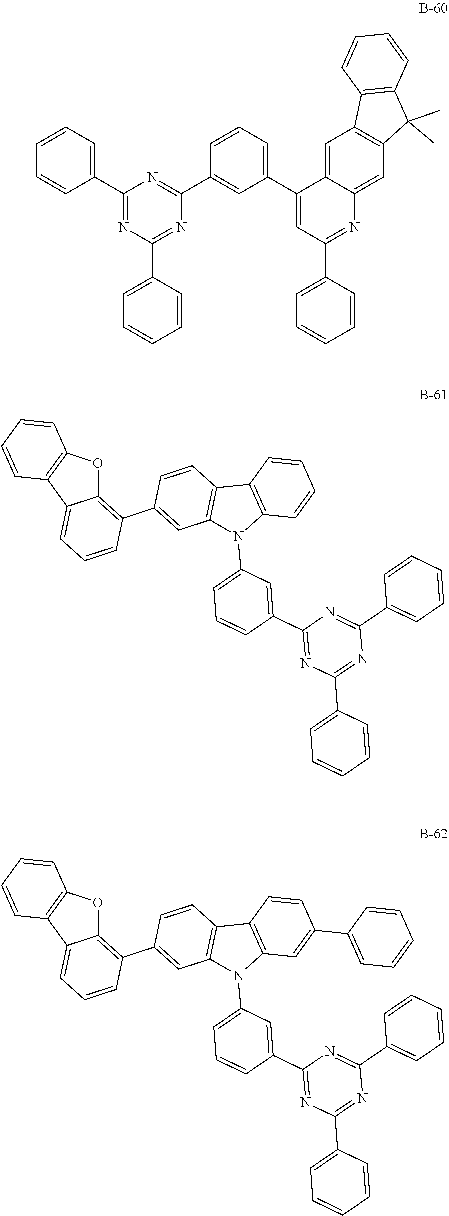 [SMILES: CC1(C)c2ccccc2-c2cc3c(-c4cccc(-c5nc(-c6ccccc6)nc(-c6ccccc6)n5)c4)cc(-c4ccccc4)nc3cc21 ; c1ccc(-c2nc(-c3ccccc3)nc(-c3cccc(-n4c5ccccc5c5ccc(-c6cccc7c6oc6ccccc67)cc54)c3)n2)cc1 ; c1ccc(-c2ccc3c4ccc(-c5cccc6c5oc5ccccc56)cc4n(-c4cccc(-c5nc(-c6ccccc6)nc(-c6ccccc6)n5)c4)c3c2)cc1]

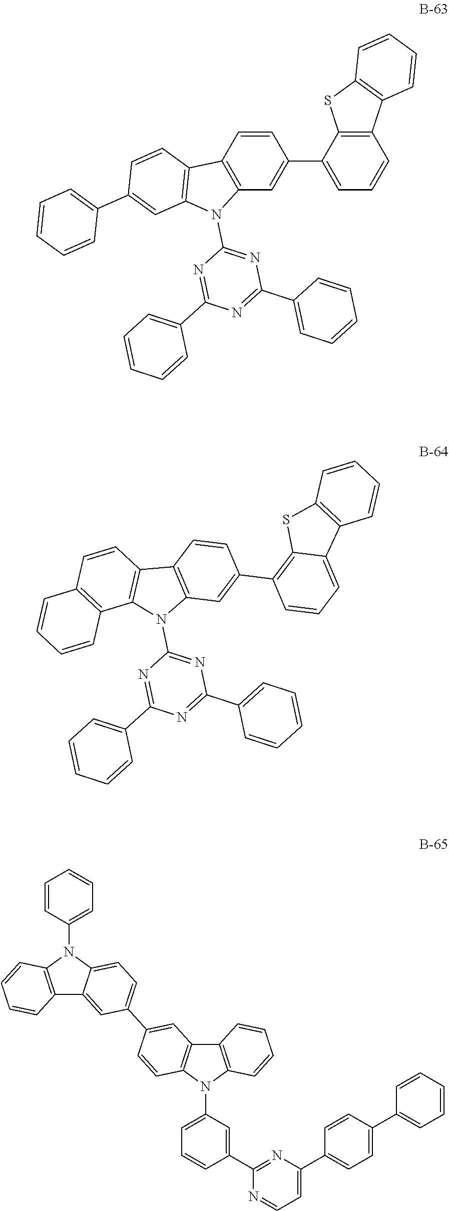 [SMILES: c1ccc(-c2ccc3c4ccc(-c5cccc6c5sc5ccccc56)cc4n(-c4nc(-c5ccccc5)nc(-c5ccccc5)n4)c3c2)cc1 ; c1ccc(-c2nc(-c3ccccc3)nc(-n3c4cc(-c5cccc6c5sc5ccccc56)ccc4c4ccc5ccccc5c43)n2)cc1 ; c1ccc(-c2ccc(-c3ccnc(-c4cccc(-n5c6ccccc6c6cc(-c7ccc8c(c7)c7ccccc7n8-c7ccccc7)ccc65)c4)n3)cc2)cc1]

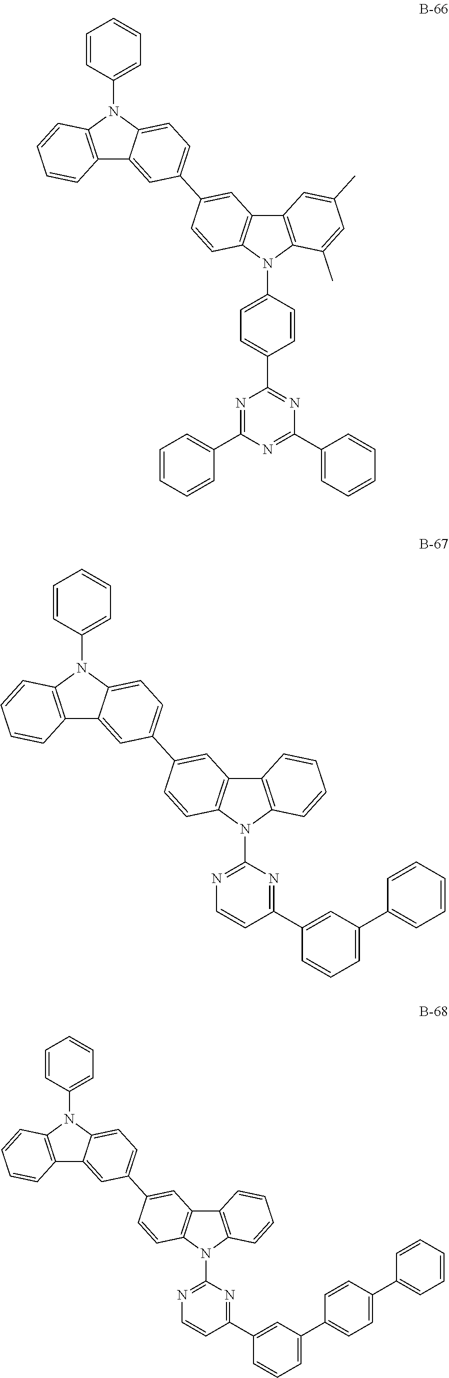 [SMILES: Cc1cc(C)c2c(c1)c1cc(-c3ccc4c(c3)c3ccccc3n4-c3ccccc3)ccc1n2-c1ccc(-c2nc(-c3ccccc3)nc(-c3ccccc3)n2)cc1 ; c1ccc(-c2cccc(-c3ccnc(-n4c5ccccc5c5cc(-c6ccc7c(c6)c6ccccc6n7-c6ccccc6)ccc54)n3)c2)cc1 ; c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1]

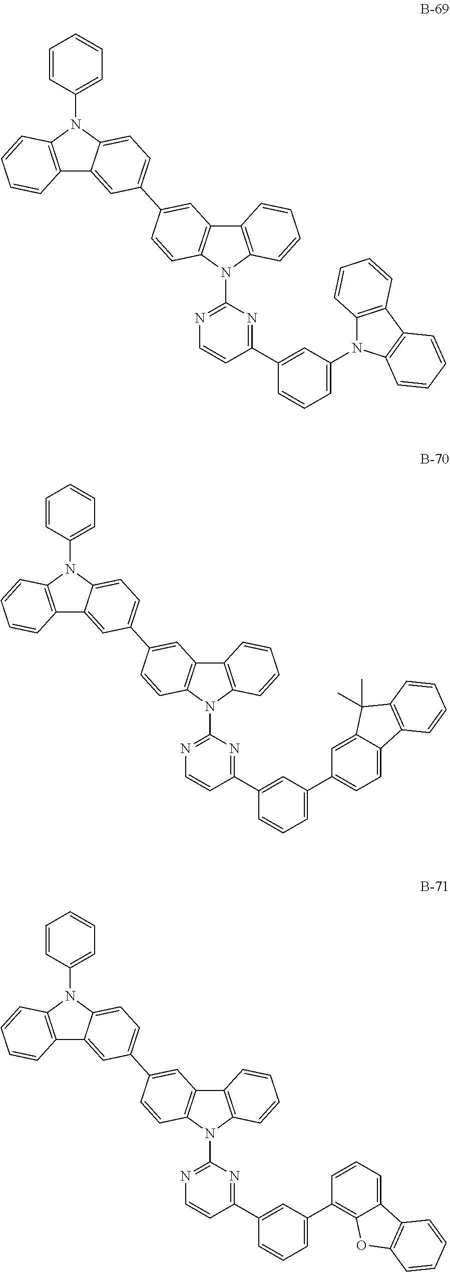 [SMILES: c1ccc(-n2c3ccccc3c3cc(-c4ccc5c(c4)c4ccccc4n5-c4nccc(-c5cccc(-n6c7ccccc7c7ccccc76)c5)n4)ccc32)cc1 ; CC1(C)c2ccccc2-c2ccc(-c3cccc(-c4ccnc(-n5c6ccccc6c6cc(-c7ccc8c(c7)c7ccccc7n8-c7ccccc7)ccc65)n4)c3)cc21 ; c1ccc(-n2c3ccccc3c3cc(-c4ccc5c(c4)c4ccccc4n5-c4nccc(-c5cccc(-c6cccc7c6oc6ccccc67)c5)n4)ccc32)cc1]

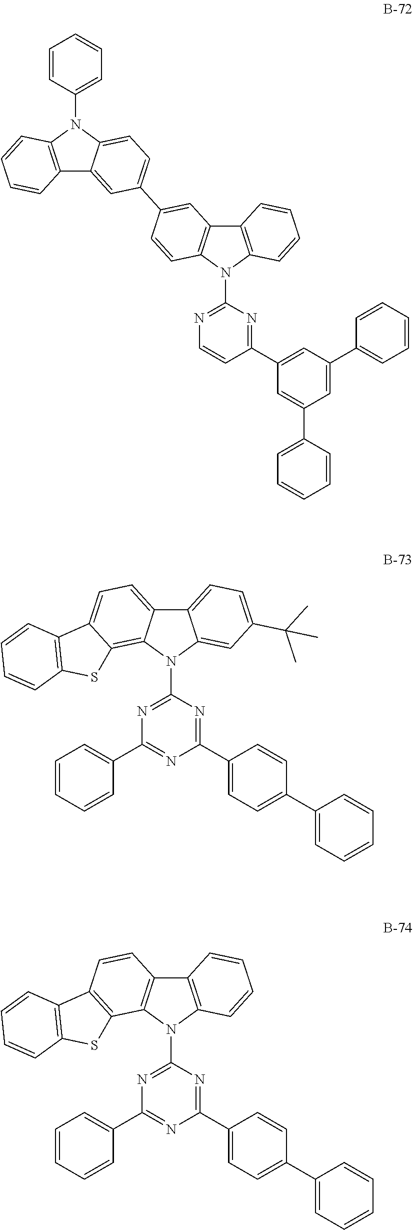 [SMILES: c1ccc(-c2cc(-c3ccccc3)cc(-c3ccnc(-n4c5ccccc5c5cc(-c6ccc7c(c6)c6ccccc6n7-c6ccccc6)ccc54)n3)c2)cc1 ; CC(C)(C)c1ccc2c3ccc4c5ccccc5sc4c3n(-c3nc(-c4ccccc4)nc(-c4ccc(-c5ccccc5)cc4)n3)c2c1 ; c1ccc(-c2ccc(-c3nc(-c4ccccc4)nc(-n4c5ccccc5c5ccc6c7ccccc7sc6c54)n3)cc2)cc1]

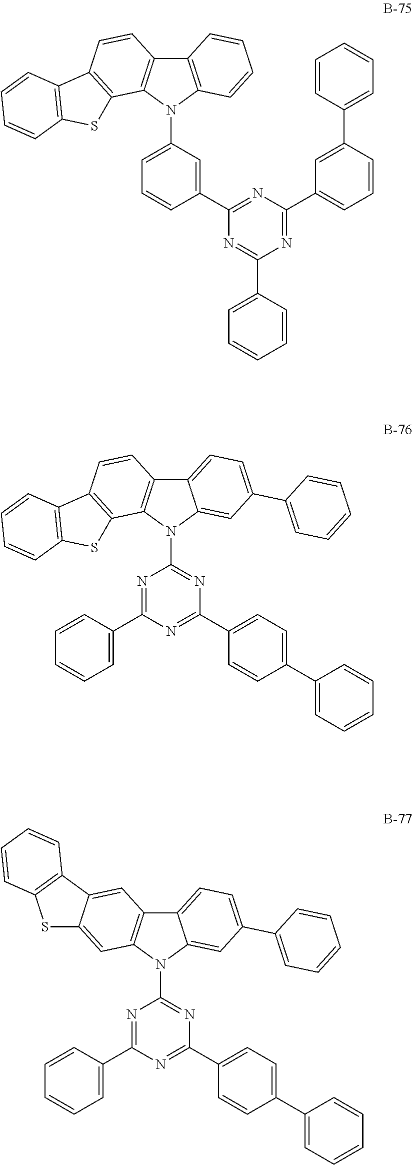 [SMILES: c1ccc(-c2cccc(-c3nc(-c4ccccc4)nc(-c4cccc(-n5c6ccccc6c6ccc7c8ccccc8sc7c65)c4)n3)c2)cc1 ; c1ccc(-c2ccc(-c3nc(-c4ccccc4)nc(-n4c5cc(-c6ccccc6)ccc5c5ccc6c7ccccc7sc6c54)n3)cc2)cc1 ; c1ccc(-c2ccc(-c3nc(-c4ccccc4)nc(-n4c5cc(-c6ccccc6)ccc5c5cc6c(cc54)sc4ccccc46)n3)cc2)cc1]

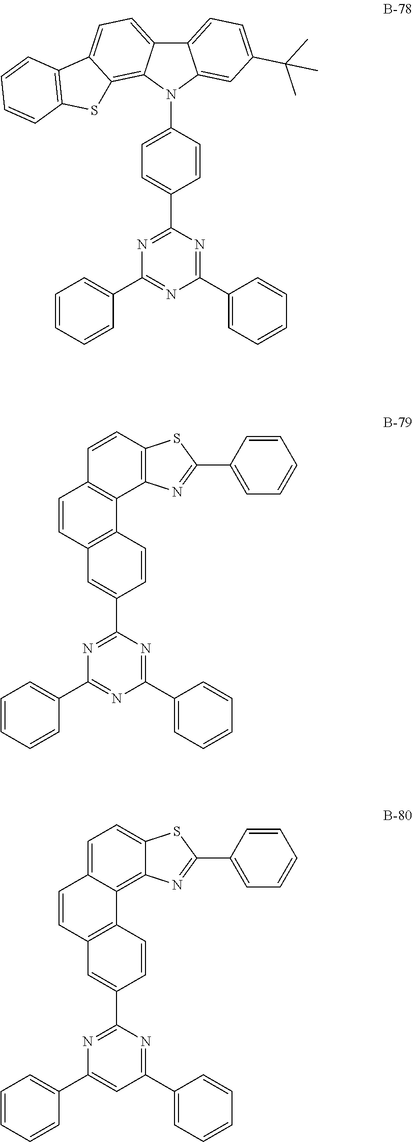 [SMILES: CC(C)(C)c1ccc2c3ccc4c5ccccc5sc4c3n(-c3ccc(-c4nc(-c5ccccc5)nc(-c5ccccc5)n4)cc3)c2c1 ; c1ccc(-c2nc(-c3ccccc3)nc(-c3ccc4c(ccc5ccc6sc(-c7ccccc7)nc6c54)c3)n2)cc1 ; c1ccc(-c2cc(-c3ccccc3)nc(-c3ccc4c(ccc5ccc6sc(-c7ccccc7)nc6c54)c3)n2)cc1]

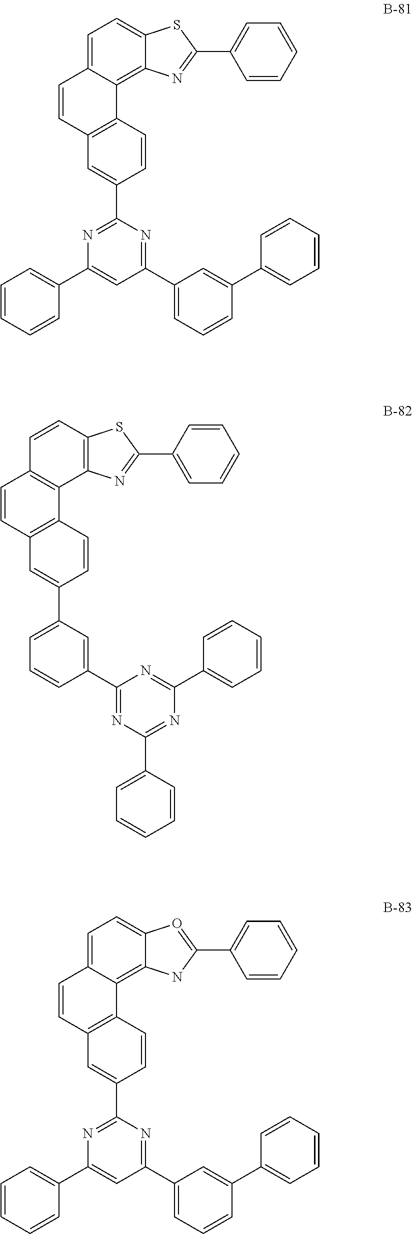

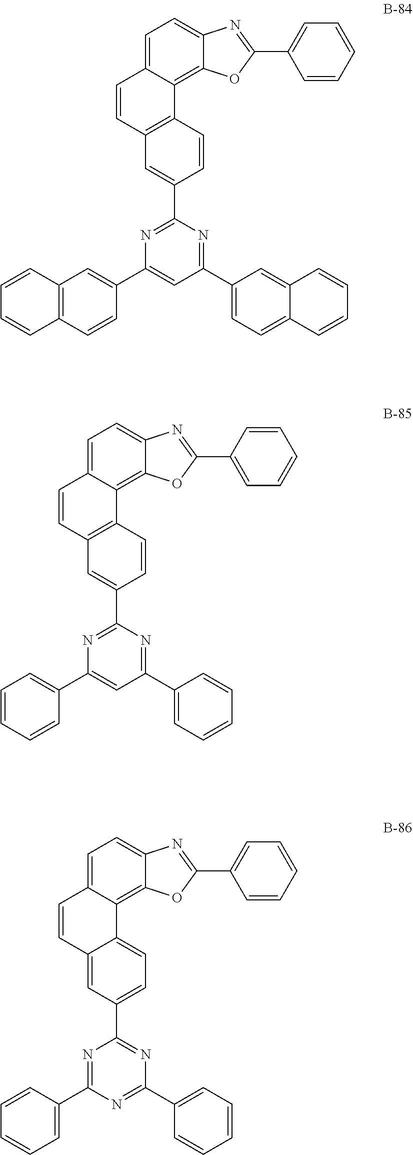 [SMILES: c1ccc(-c2nc3ccc4ccc5cc(-c6nc(-c7ccc8ccccc8c7)cc(-c7ccc8ccccc8c7)n6)ccc5c4c3o2)cc1 ; c1ccc(-c2cc(-c3ccccc3)nc(-c3ccc4c(ccc5ccc6nc(-c7ccccc7)oc6c54)c3)n2)cc1 ; c1ccc(-c2nc(-c3ccccc3)nc(-c3ccc4c(ccc5ccc6nc(-c7ccccc7)oc6c54)c3)n2)cc1]

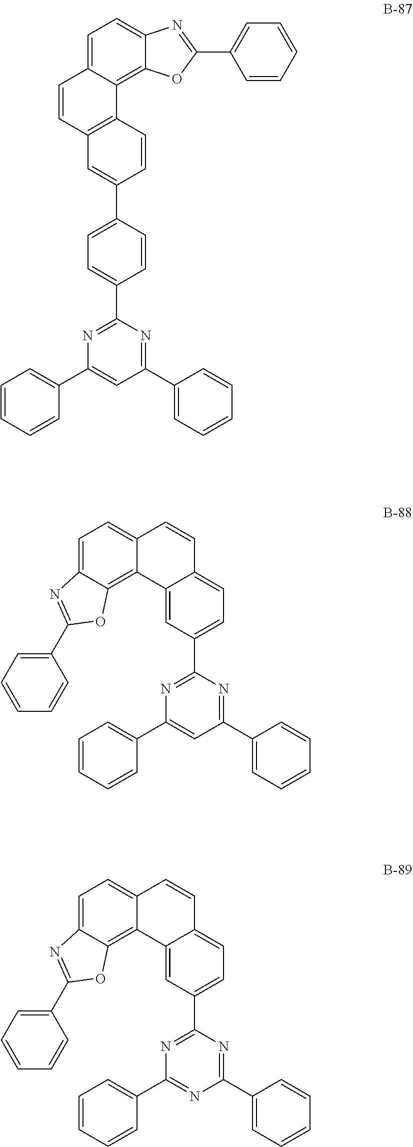 [SMILES: c1ccc(-c2cc(-c3ccccc3)nc(-c3ccc(-c4ccc5c(ccc6ccc7nc(-c8ccccc8)oc7c65)c4)cc3)n2)cc1 ; c1ccc(-c2cc(-c3ccccc3)nc(-c3ccc4ccc5ccc6nc(-c7ccccc7)oc6c5c4c3)n2)cc1 ; c1ccc(-c2nc(-c3ccccc3)nc(-c3ccc4ccc5ccc6nc(-c7ccccc7)oc6c5c4c3)n2)cc1]

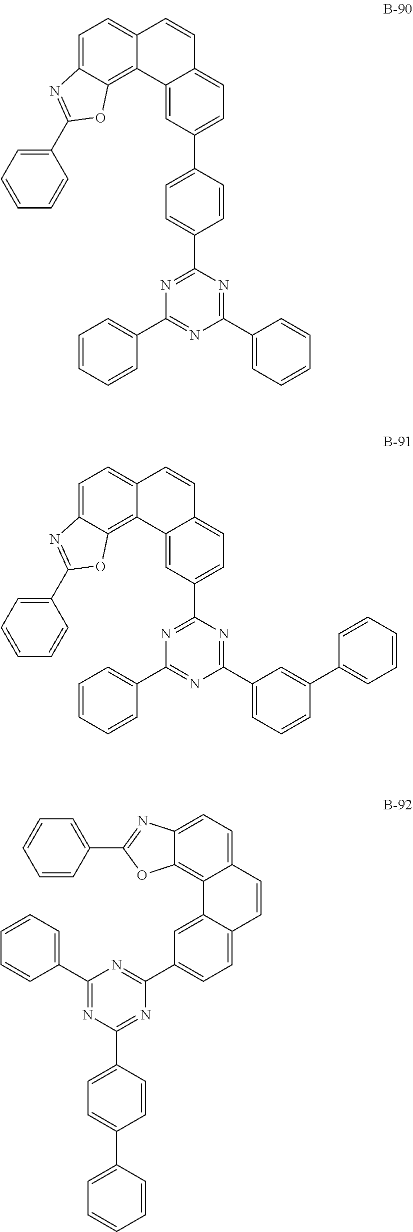 [SMILES: c1ccc(-c2nc(-c3ccccc3)nc(-c3ccc(-c4ccc5ccc6ccc7nc(-c8ccccc8)oc7c6c5c4)cc3)n2)cc1 ; c1ccc(-c2cccc(-c3nc(-c4ccccc4)nc(-c4ccc5ccc6ccc7nc(-c8ccccc8)oc7c6c5c4)n3)c2)cc1 ; c1ccc(-c2ccc(-c3nc(-c4ccccc4)nc(-c4ccc5ccc6ccc7nc(-c8ccccc8)oc7c6c5c4)n3)cc2)cc1]

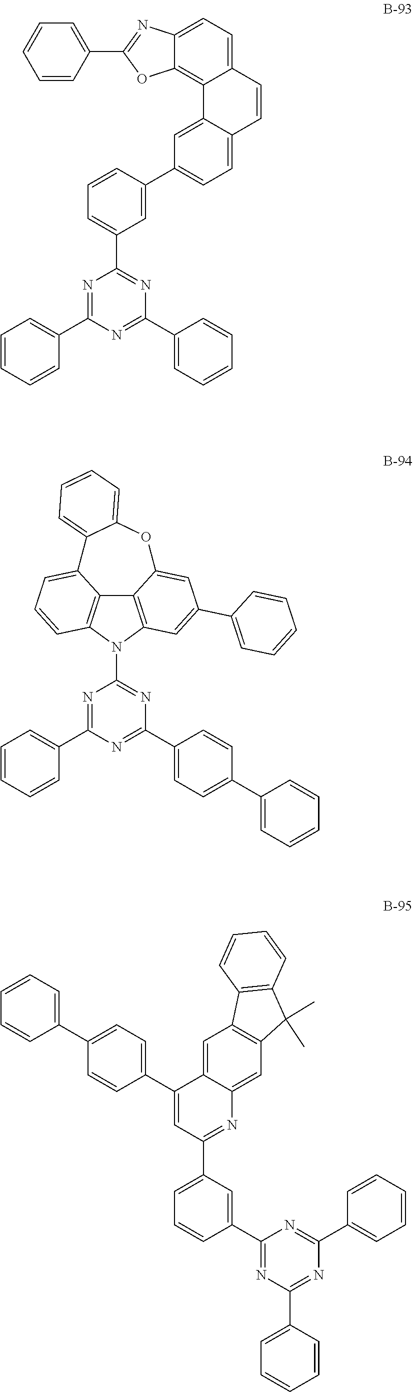 [SMILES: c1ccc(-c2nc(-c3ccccc3)nc(-c3cccc(-c4ccc5ccc6ccc7nc(-c8ccccc8)oc7c6c5c4)c3)n2)cc1 ; c1ccc(-c2ccc(-c3nc(-c4ccccc4)nc(-n4c5cc(-c6ccccc6)cc6oc7ccccc7c7cccc4c7c65)n3)cc2)cc1 ; CC1(C)c2ccccc2-c2cc3c(-c4ccc(-c5ccccc5)cc4)cc(-c4cccc(-c5nc(-c6ccccc6)nc(-c6ccccc6)n5)c4)nc3cc21]

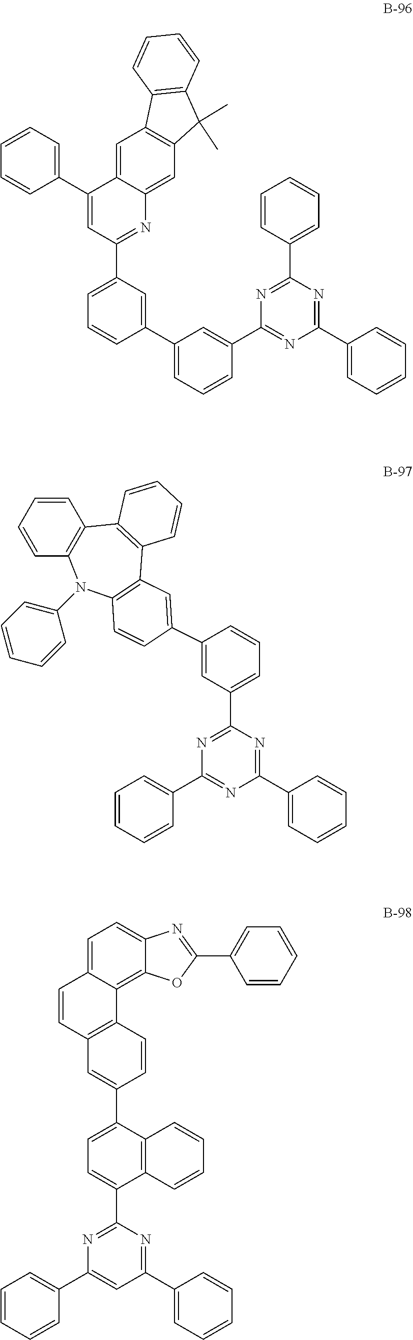 [SMILES: CC1(C)c2ccccc2-c2cc3c(-c4ccccc4)cc(-c4cccc(-c5cccc(-c6nc(-c7ccccc7)nc(-c7ccccc7)n6)c5)c4)nc3cc21 ; c1ccc(-c2nc(-c3ccccc3)nc(-c3cccc(-c4ccc5c(c4)-c4ccccc4-c4ccccc4N5c4ccccc4)c3)n2)cc1 ; c1ccc(-c2cc(-c3ccccc3)nc(-c3ccc(-c4ccc5c(ccc6ccc7nc(-c8ccccc8)oc7c65)c4)c4ccccc34)n2)cc1]

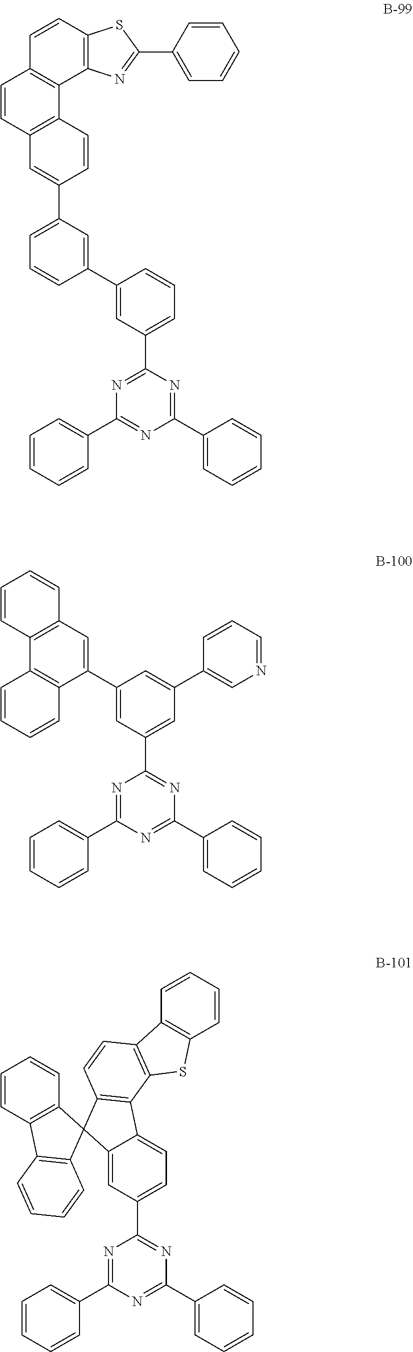 [SMILES: c1ccc(-c2nc(-c3ccccc3)nc(-c3cccc(-c4cccc(-c5ccc6c(ccc7ccc8sc(-c9ccccc9)nc8c76)c5)c4)c3)n2)cc1 ; c1ccc(-c2nc(-c3ccccc3)nc(-c3cc(-c4cccnc4)cc(-c4cc5ccccc5c5ccccc45)c3)n2)cc1 ; c1ccc(-c2nc(-c3ccccc3)nc(-c3ccc4c(c3)C3(c5ccccc5-c5ccccc53)c3ccc5c(sc6ccccc65)c3-4)n2)cc1]

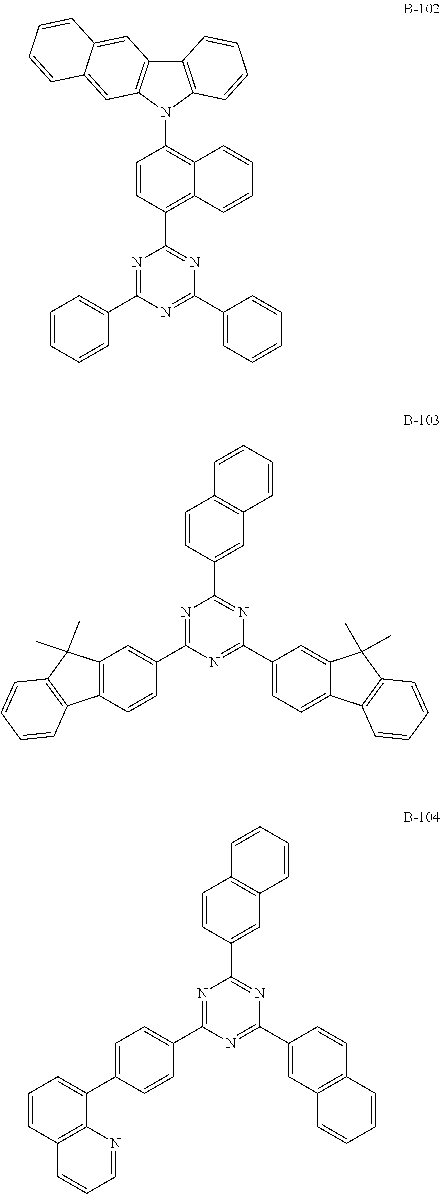 [SMILES: c1ccc(-c2nc(-c3ccccc3)nc(-c3ccc(-n4c5ccccc5c5cc6ccccc6cc54)c4ccccc34)n2)cc1 ; CC1(C)c2ccccc2-c2ccc(-c3nc(-c4ccc5c(c4)C(C)(C)c4ccccc4-5)nc(-c4ccc5ccccc5c4)n3)cc21 ; c1ccc2cc(-c3nc(-c4ccc(-c5cccc6cccnc56)cc4)nc(-c4ccc5ccccc5c4)n3)ccc2c1]

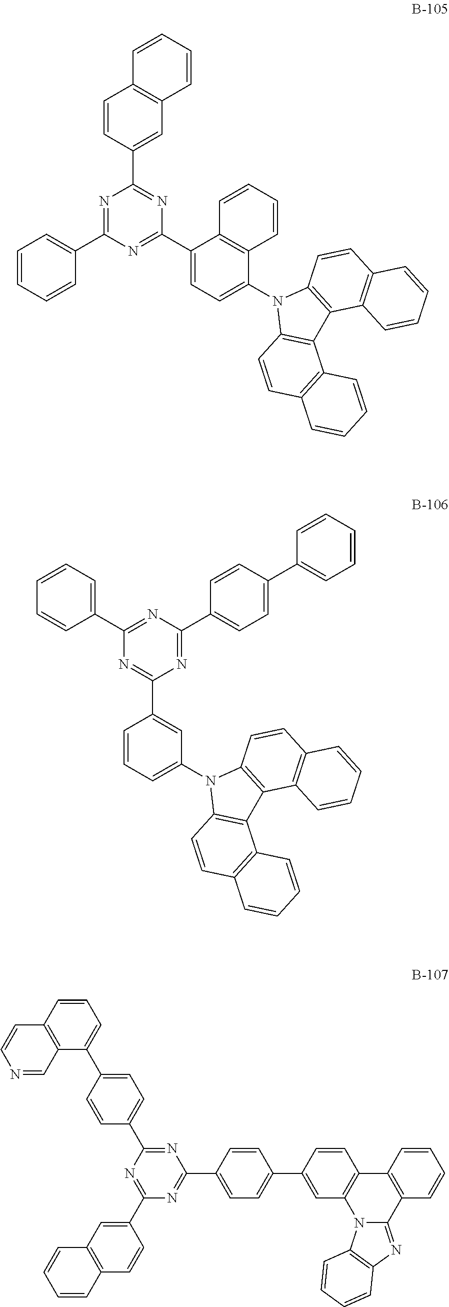 [SMILES: c1ccc(-c2nc(-c3ccc4ccccc4c3)nc(-c3ccc(-n4c5ccc6ccccc6c5c5c6ccccc6ccc54)c4ccccc34)n2)cc1 ; c1ccc(-c2ccc(-c3nc(-c4ccccc4)nc(-c4cccc(-n5c6ccc7ccccc7c6c6c7ccccc7ccc65)c4)n3)cc2)cc1 ; c1ccc2cc(-c3nc(-c4ccc(-c5ccc6c7ccccc7c7nc8ccccc8n7c6c5)cc4)nc(-c4ccc(-c5cccc6ccncc56)cc4)n3)ccc2c1]

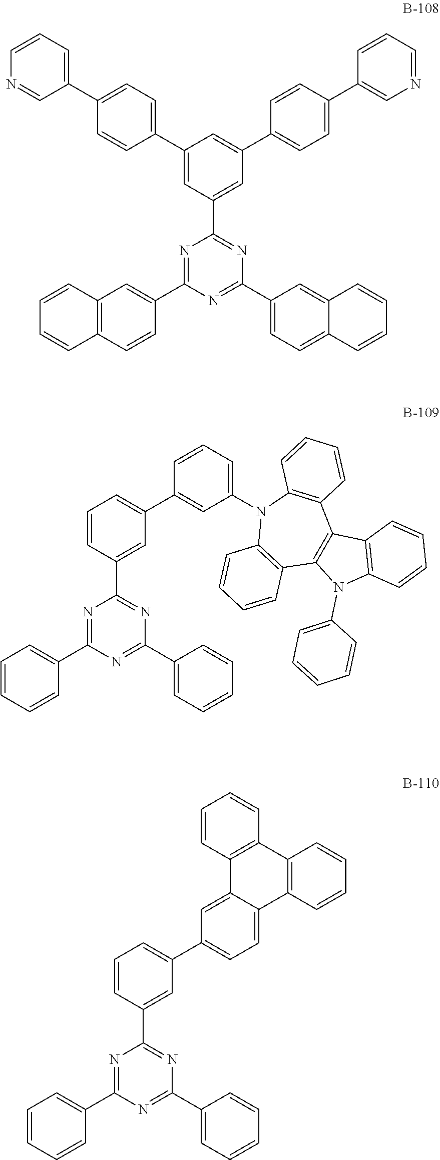 [SMILES: c1cncc(-c2ccc(-c3cc(-c4ccc(-c5cccnc5)cc4)cc(-c4nc(-c5ccc6ccccc6c5)nc(-c5ccc6ccccc6c5)n4)c3)cc2)c1 ; c1ccc(-c2nc(-c3ccccc3)nc(-c3cccc(-c4cccc(N5c6ccccc6-c6c(n(-c7ccccc7)c7ccccc67)-c6ccccc65)c4)c3)n2)cc1 ; c1ccc(-c2nc(-c3ccccc3)nc(-c3cccc(-c4ccc5c6ccccc6c6ccccc6c5c4)c3)n2)cc1]

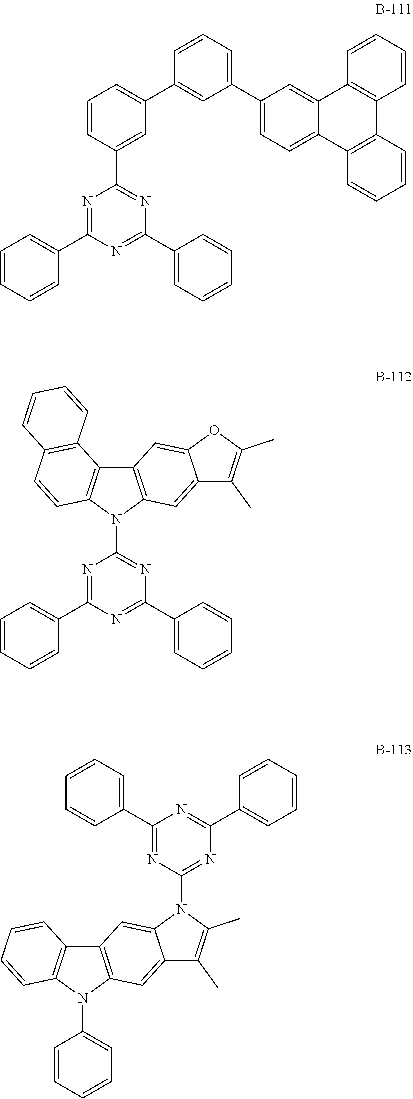 [SMILES: c1ccc(-c2nc(-c3ccccc3)nc(-c3cccc(-c4cccc(-c5ccc6c7ccccc7c7ccccc7c6c5)c4)c3)n2)cc1 ; Cc1oc2cc3c4c5ccccc5ccc4n(-c4nc(-c5ccccc5)nc(-c5ccccc5)n4)c3cc2c1C ; Cc1c(C)n(-c2nc(-c3ccccc3)nc(-c3ccccc3)n2)c2cc3c4ccccc4n(-c4ccccc4)c3cc12]

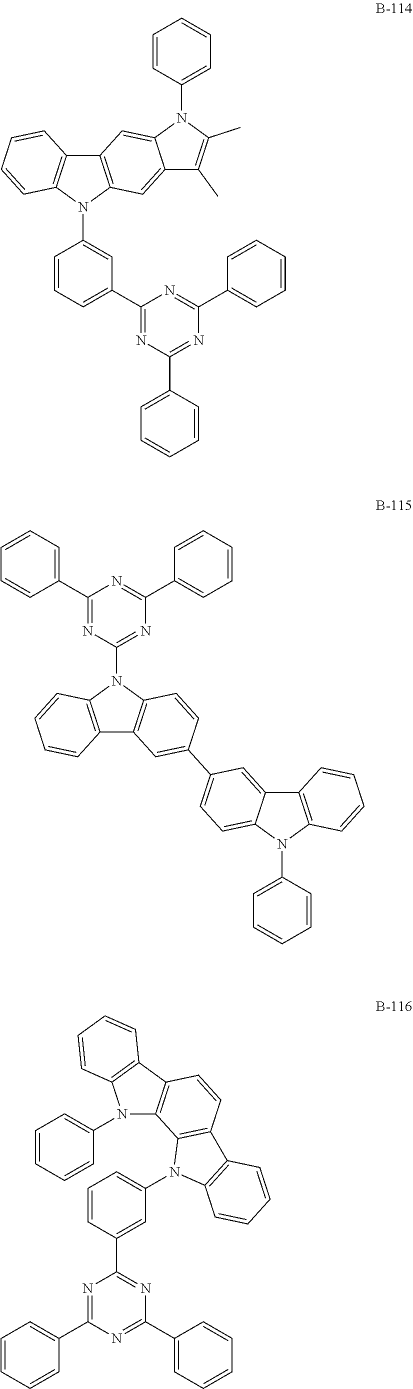 [SMILES: Cc1c(C)n(-c2ccccc2)c2cc3c4ccccc4n(-c4cccc(-c5nc(-c6ccccc6)nc(-c6ccccc6)n5)c4)c3cc12 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3cccc(-n4c5ccccc5c5ccc6c7ccccc7n(-c7ccccc7)c6c54)c3)n2)cc1]

The compound of formula 1 according to the present disclosure may be produced by a synthetic method known to one skilled in the art, and for example, may be synthesized with reference to the following reaction schemes 1 to 6, but is not limited thereto.

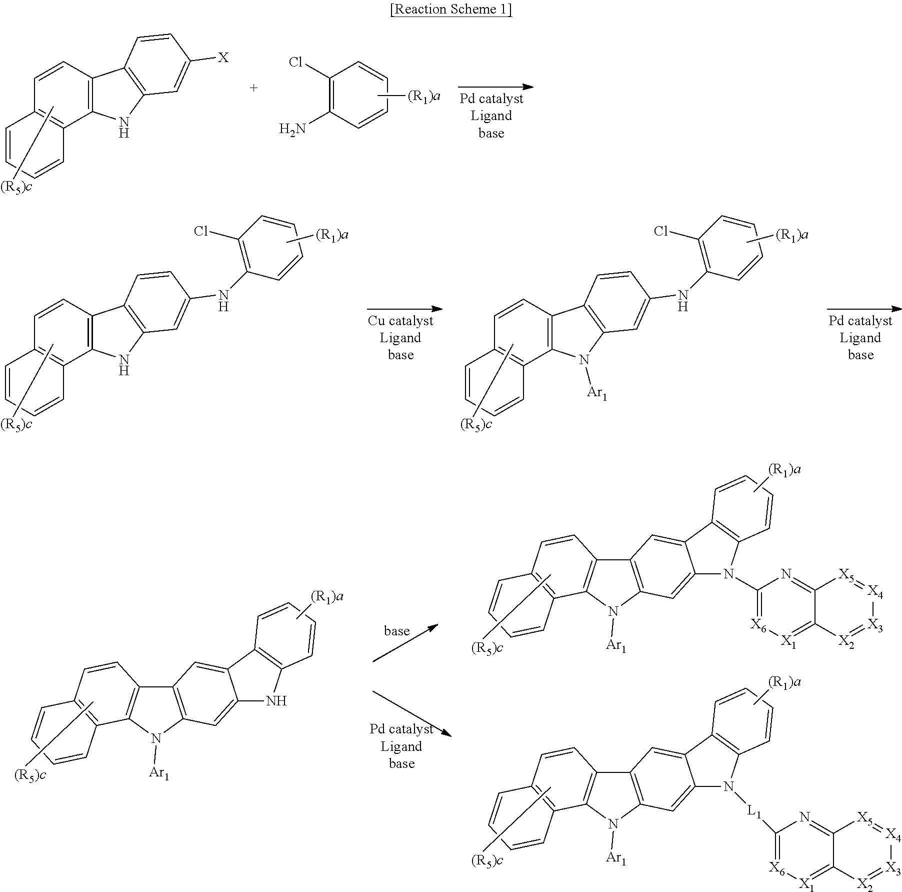

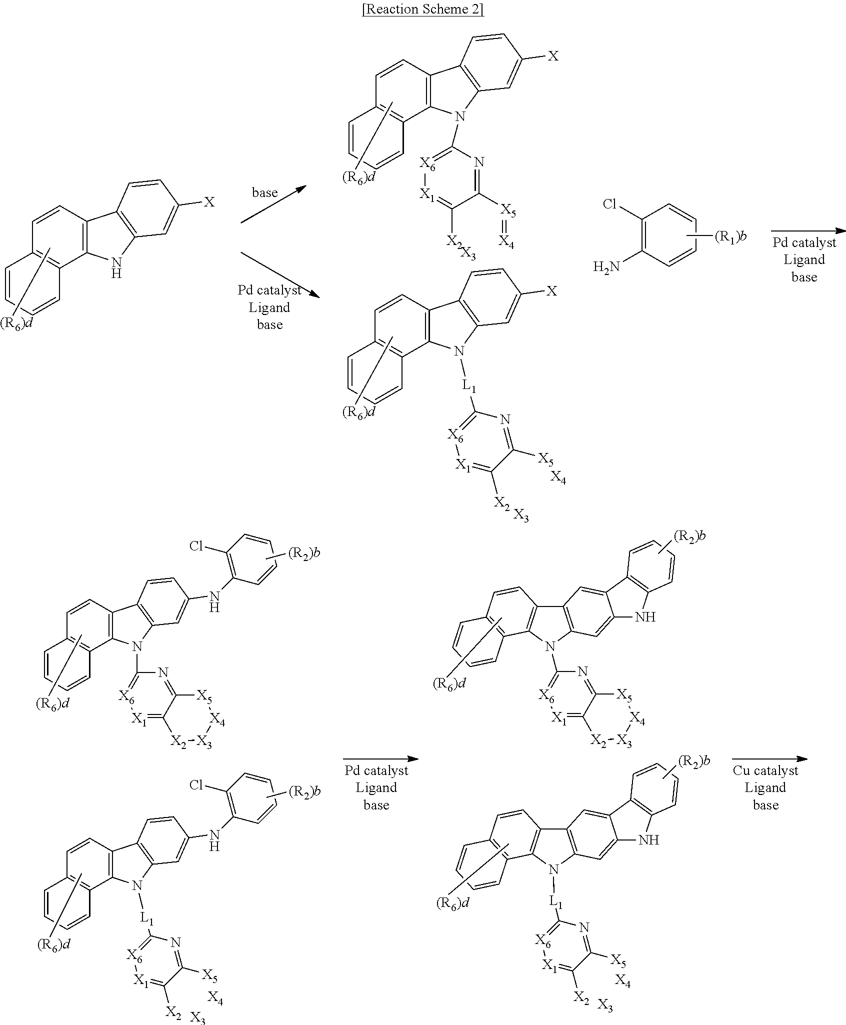

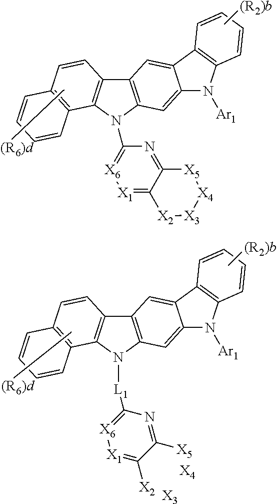

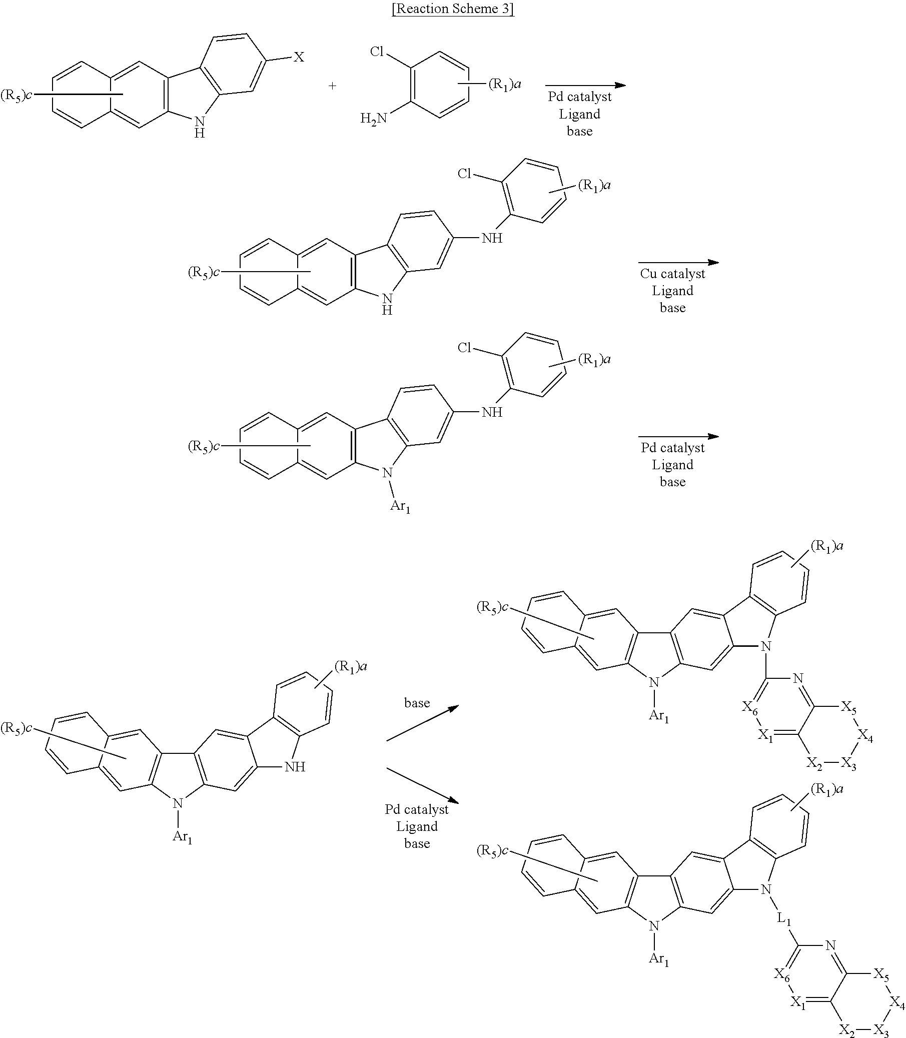

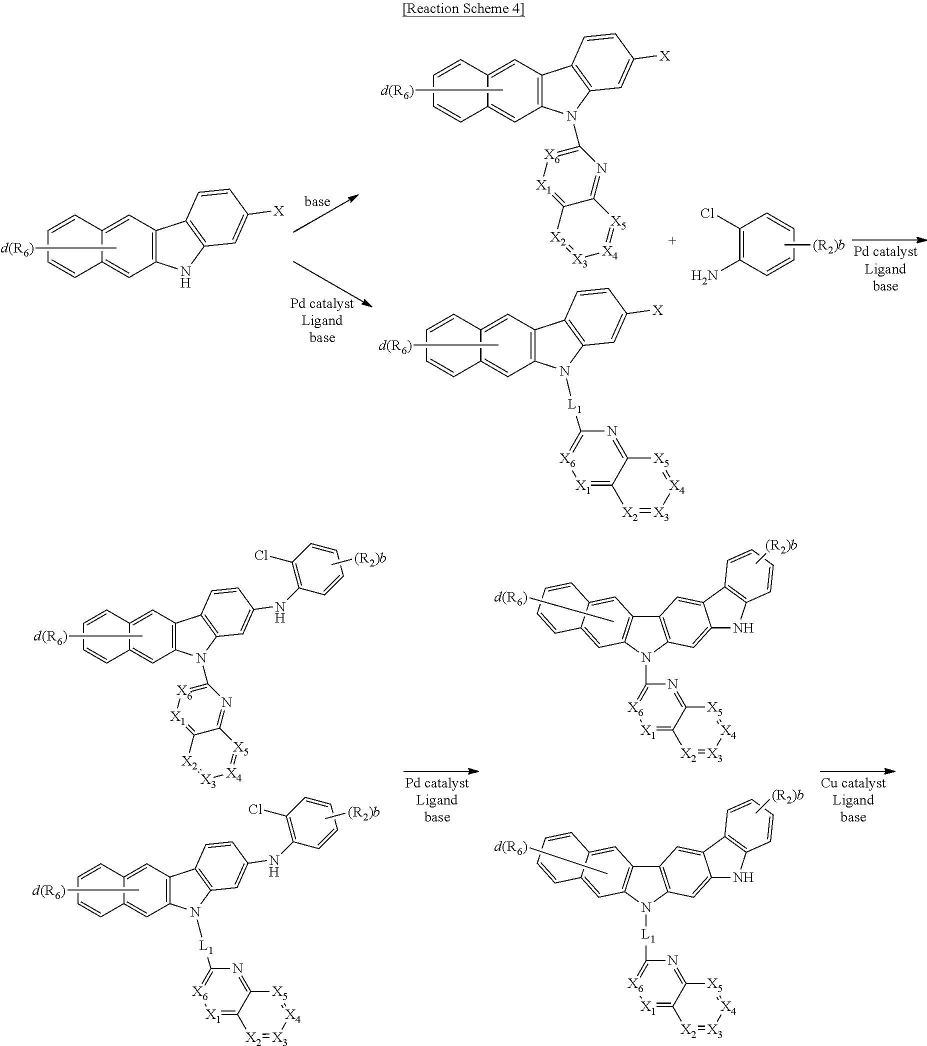

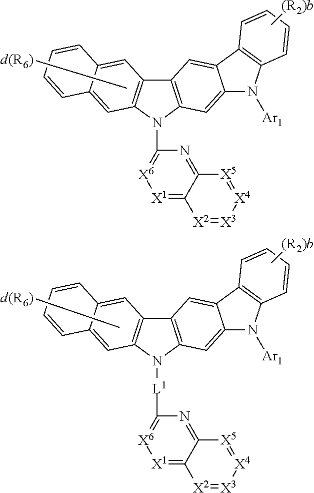

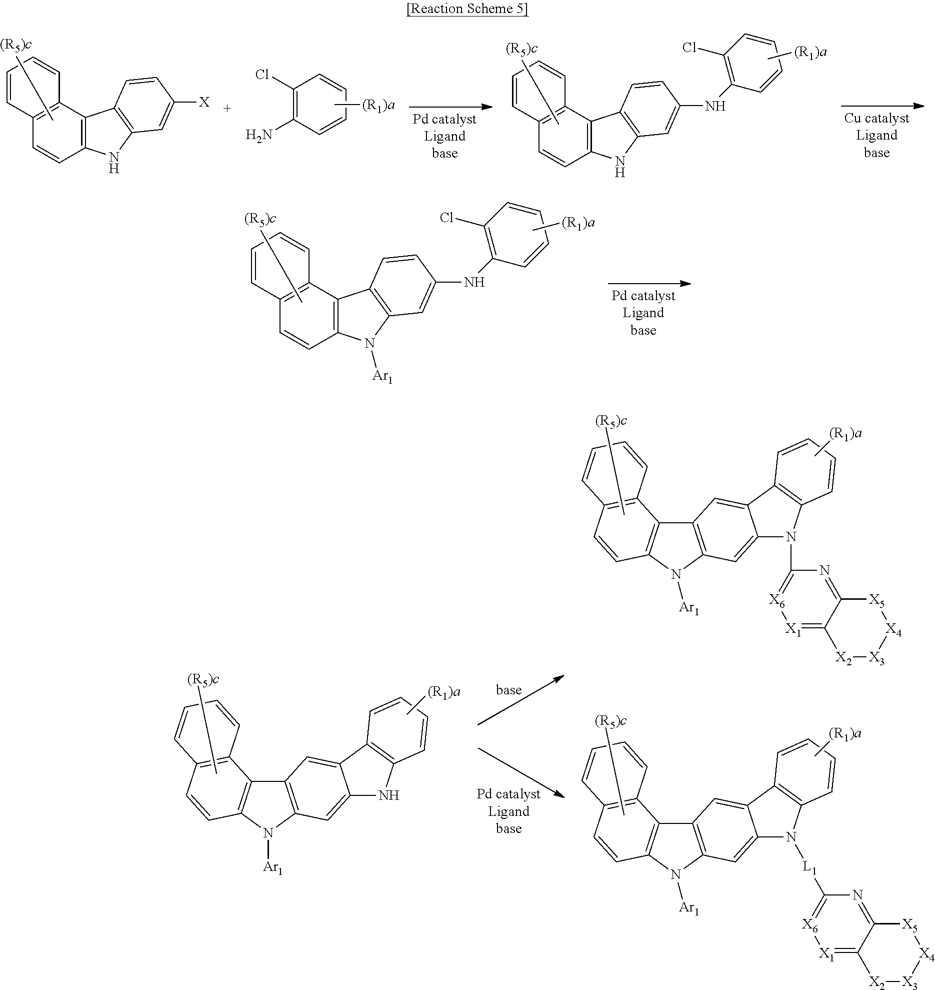

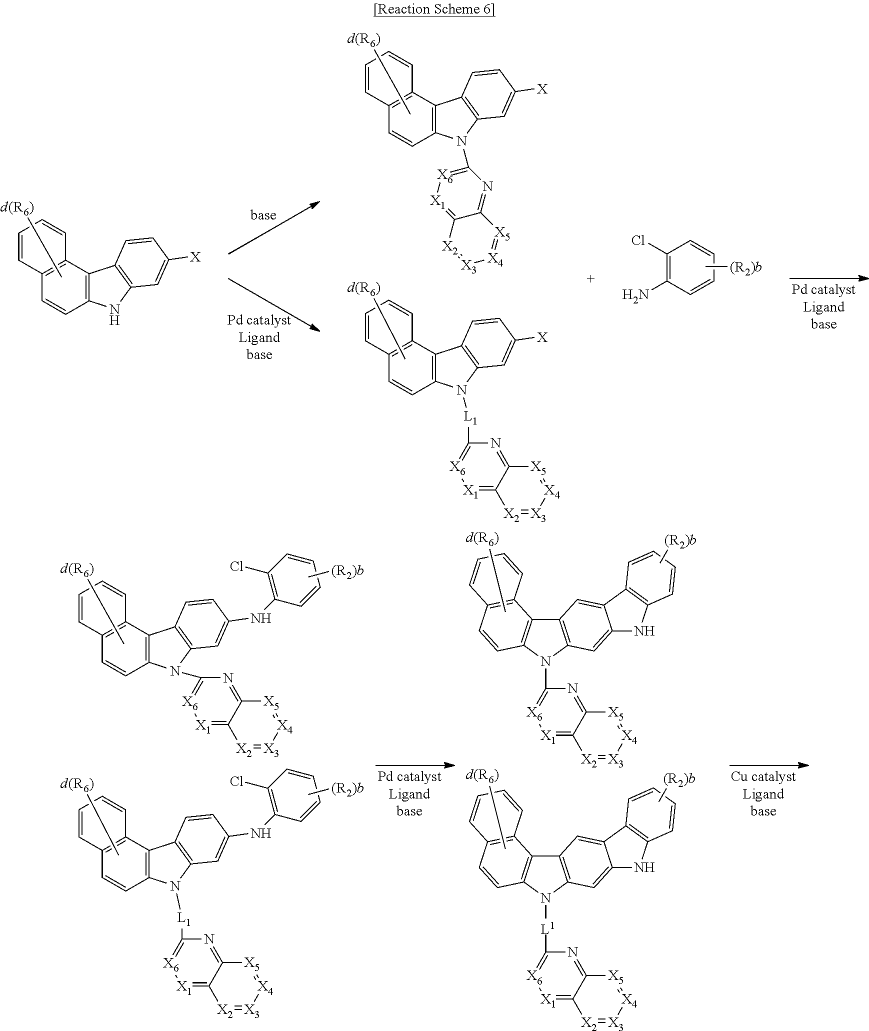

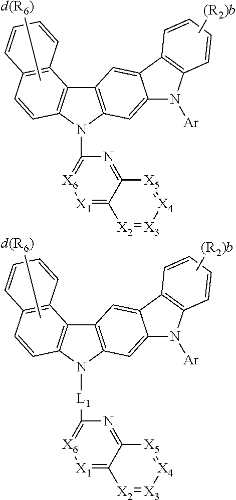

In reaction schemes 1 to 6, L₁, Ar₁, R₁, R₂, R₅, R₆, X₁ to X₆, a, b, c, and d are as defined in formulas 1 to 7, and X is a halogen.

The compound of formula 11 according to the present disclosure may be produced by a synthetic method known to one skilled in the art, but is not limited thereto.

The light-emitting layer of the present disclosure may be formed by using a host compound and a dopant compound. The host compound may consist of the compound represented by formula 1 as a sole compound, or may further comprise conventional materials generally comprised in organic electroluminescent materials. The dopant compound is not particulary limited, but may be preferably selected from the metallated complex compounds of iridium (Ir), osmium (Os), copper (Cu), and platinum (Pt), more preferably selected from ortho-metallated complex compounds of iridium (Ir), osmium (Os), copper (Cu), and platinum (Pt), and even more preferably ortho-metallated iridium complex compounds.

The dopant comprised in the organic electroluminescent device of the present disclosure may comprise the compounds represented by the following formulas 101 to 104, but is not limited thereto.

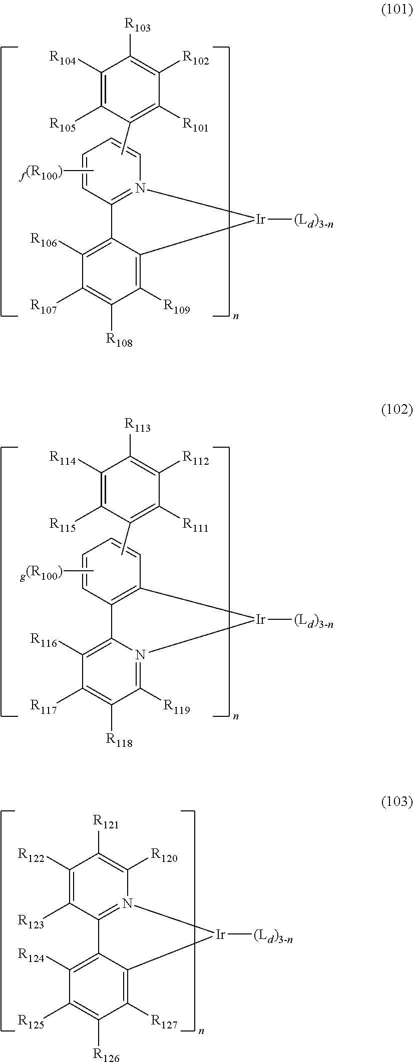

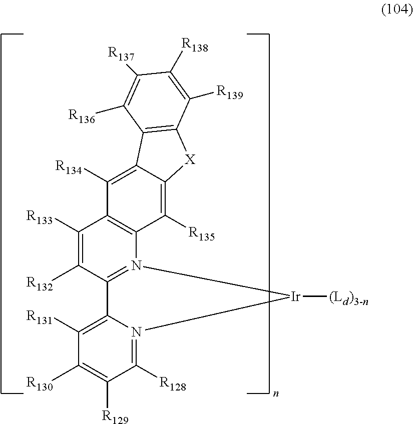

In formulas 101 to 104, La is selected from the following structures:

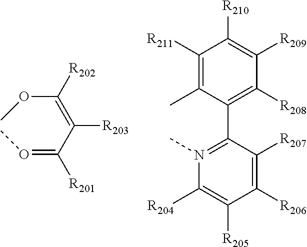

R₁₀₀, R₁₃₄, and R₁₃₅, each independently, represent hydrogen, deuterium, a substituted or unsubstituted (C1-C30)alkyl, or a substituted or unsubstituted (C3-C30)cycloalkyl;

R₁₀₁ to R₁₀₉ and R₁₁₁ to R₁₂₃, each independently, represent hydrogen, deuterium, a halogen, a (C1-C30)alkyl unsubstituted or substituted with deuterium or a halogen, a substituted or unsubstituted (C3-C30)cycloalkyl, a substituted or unsubstituted (C6-C30)aryl, a cyano, or a substituted or unsubstituted (C1-C30)alkoxy, where R₁₀₆ to R₁₀₉ may be linked to adjacent R₁₀₆ to R₁₀₉ to form a substituted or unsubstituted fused ring, e.g., a fluorene unsubstituted or substituted with an alkyl, a dibenzothiophene unsubstituted or substituted with an alkyl, or a dibenzofuran unsubstituted or substituted with an alkyl; and R₁₂₀ to R₁₂₃ may be linked to adjacent R₁₂₀ to R₁₂₃ to form a substituted or unsubstituted fused ring, e.g., a quinoline unsubstituted or substituted with at least one selected from an alkyl, an aryl, an arylalkyl, and an alkylaryl;

R₁₂₄ to R₁₃₃ and R₁₃₆ to R₁₃₉, each independently, represent hydrogen, deuterium, a halogen, a substituted or unsubstituted (C1-C30)alkyl, or a substituted or unsubstituted (C6-C30)aryl, where R₁₂₄ to R₁₂₇ may be linked to adjacent R₁₂₄ to R₁₂₇ to form a substituted or unsubstituted fused ring, e.g., a fluorene unsubstituted or substituted with an alkyl, a dibenzothiophene unsubstituted or substituted with an alkyl, or a dibenzofuran unsubstituted or substituted with an alkyl;

X represents CR₂₁R₂₂, O, or S;

R₂₁ and R₂₂, each independently, represent a substituted or unsubstituted (C1-C10)alkyl, or a substituted or unsubstituted (C6-C30)aryl;

R₂₀₁ to R_{211,} each independently, represent hydrogen, deuterium, a halogen, a (C1-C30)alkyl unsubstituted or substituted with deuterium or a halogen, a substituted or unsubstituted (C3-C30)cycloalkyl, or a (C6-C30)aryl unsubstituted or substituted with an alkyl or deuterium, where R₂₀₈ to R₂₁₁ may be linked to adjacent R₂₀₈ to R₂₁₁ to form a substituted or unsubstituted fused ring, e.g., a fluorene unsubstituted or substituted with an alkyl, a dibenzothiophene unsubstituted or substituted with an alkyl, or a dibenzofuran unsubstituted or substituted with an alkyl;

f and g, each independently, represent an integer of 1 to 3; where if f or g is an integer of 2 or more, each R₁₀₀ may be the same or different; and

n represents an integer of 1 to 3.

Specifically, the dopant compound includes the following compounds, but is not limited thereto.

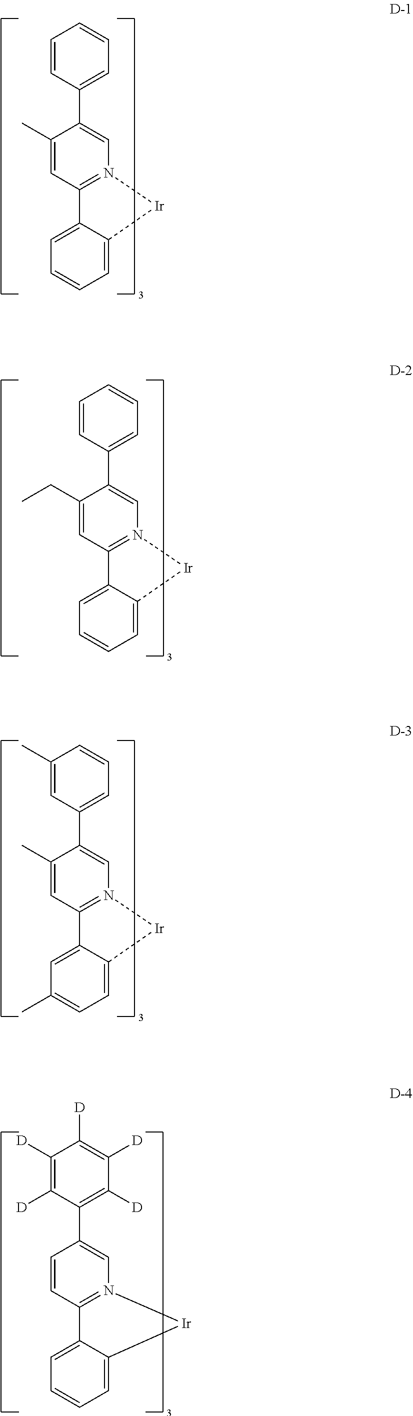

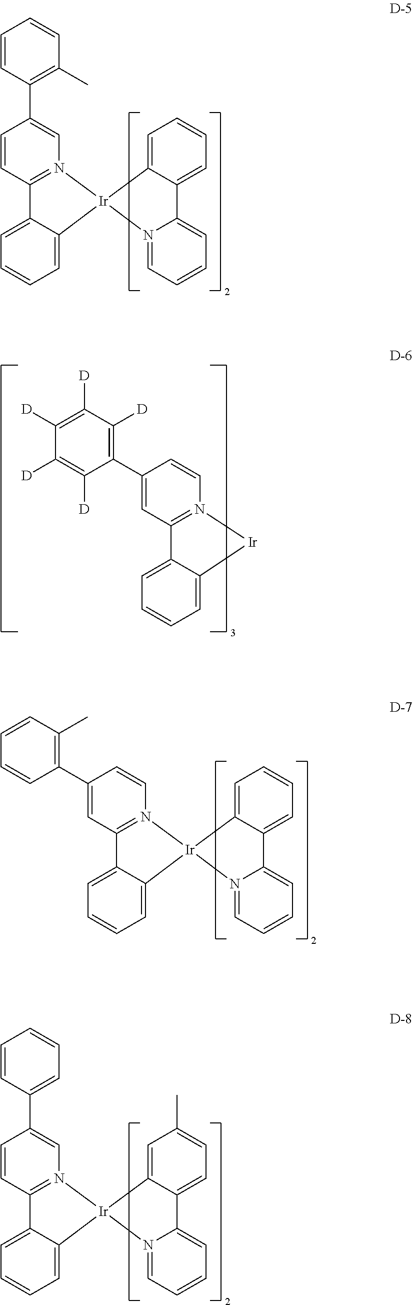

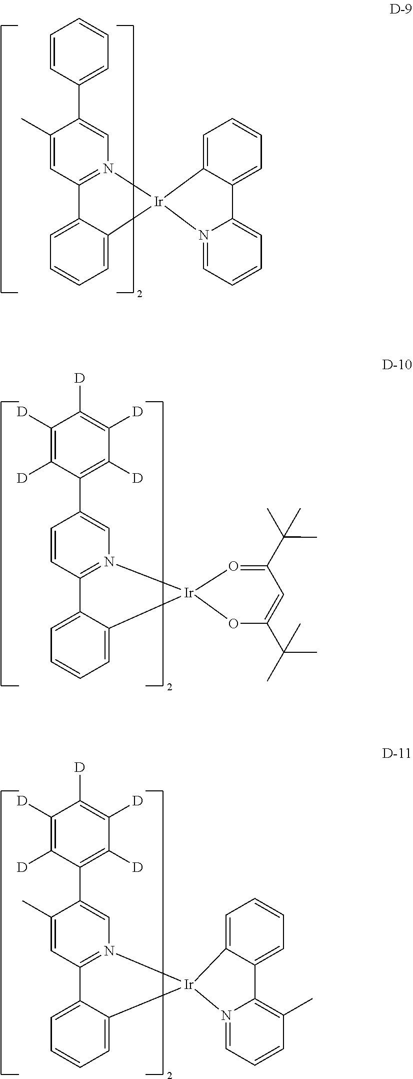

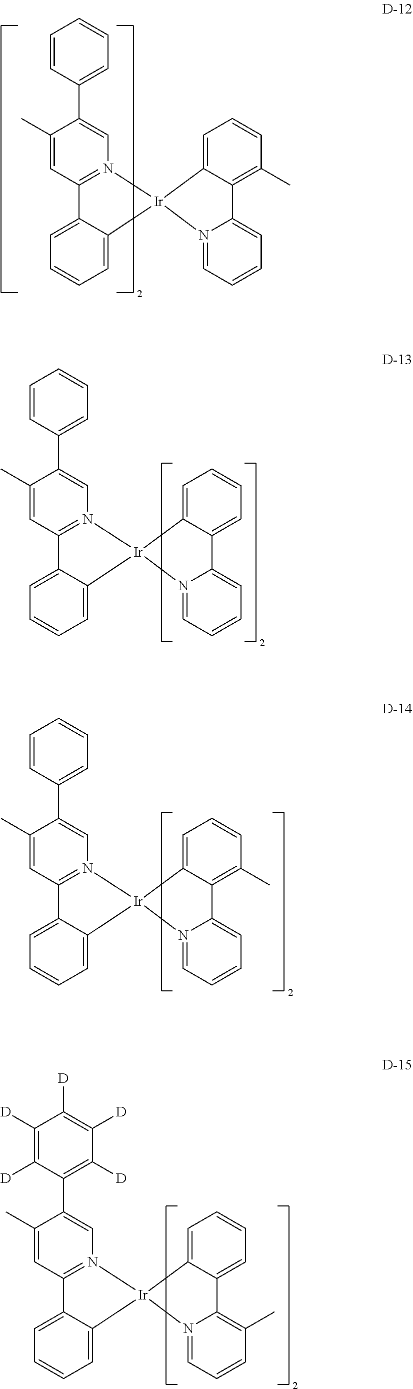

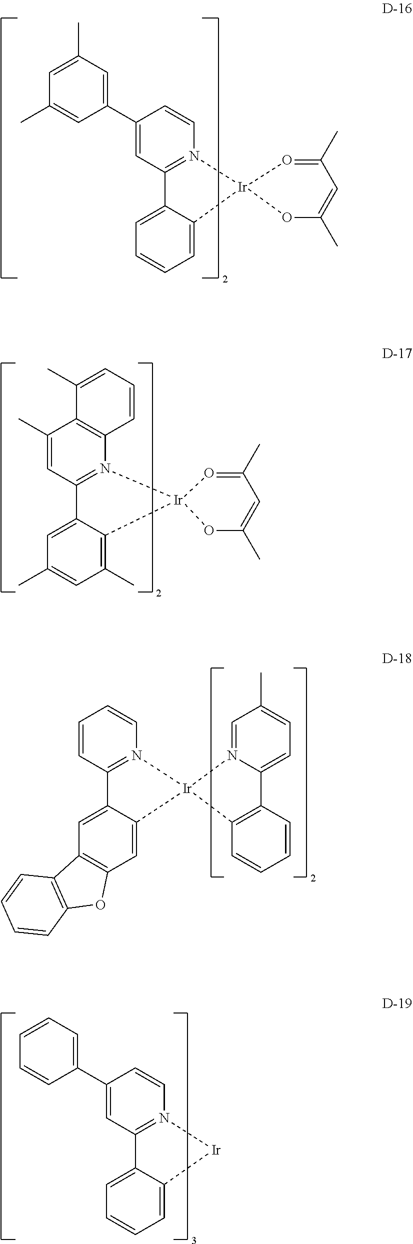

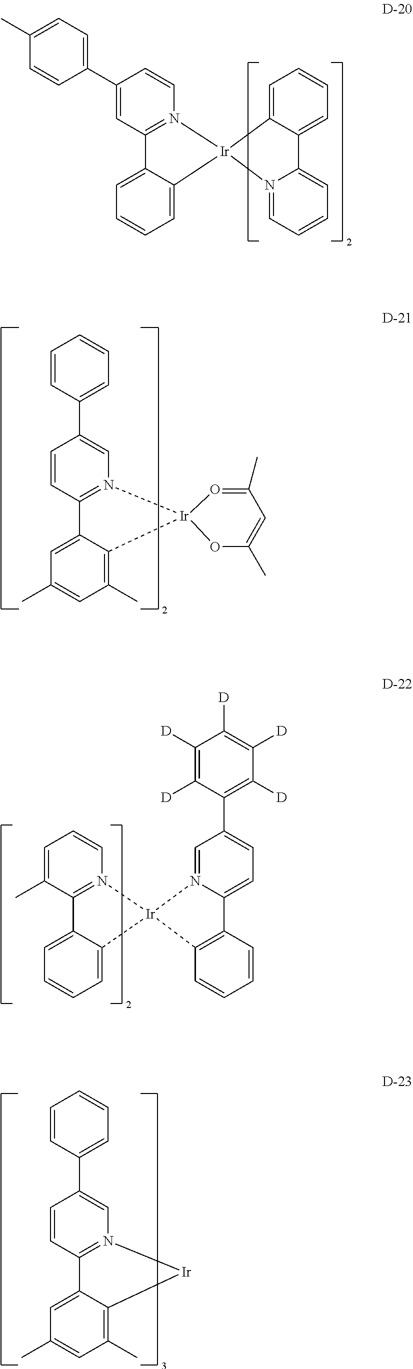

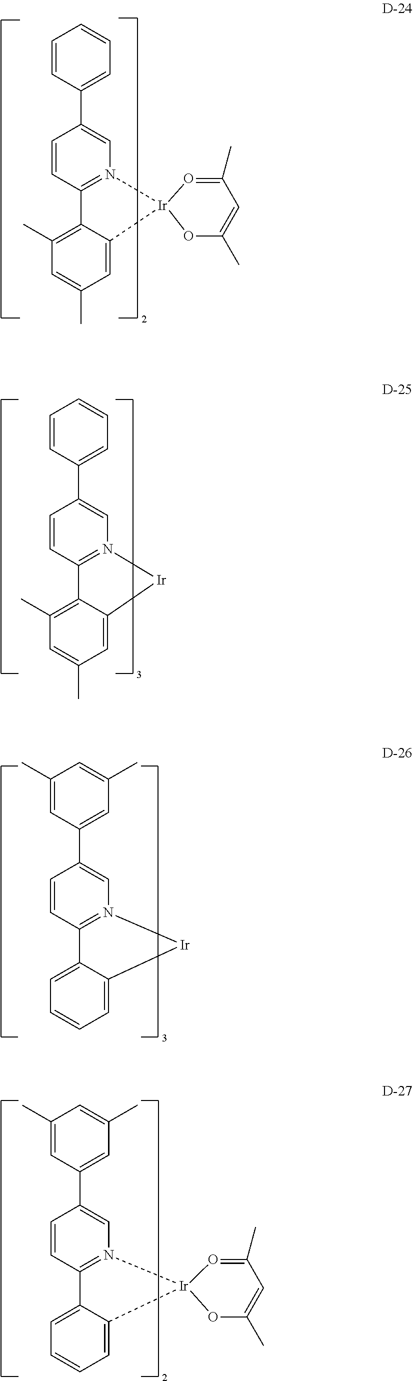

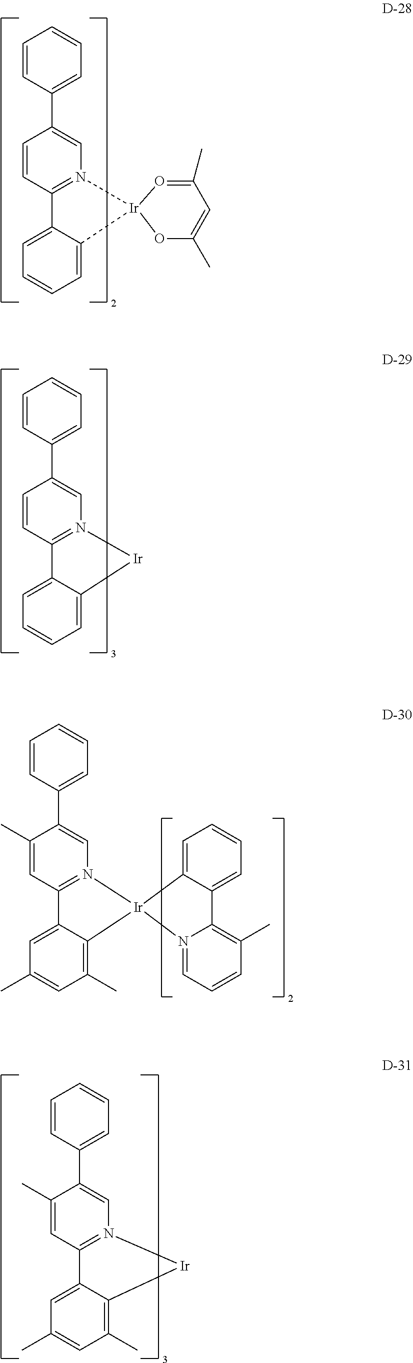

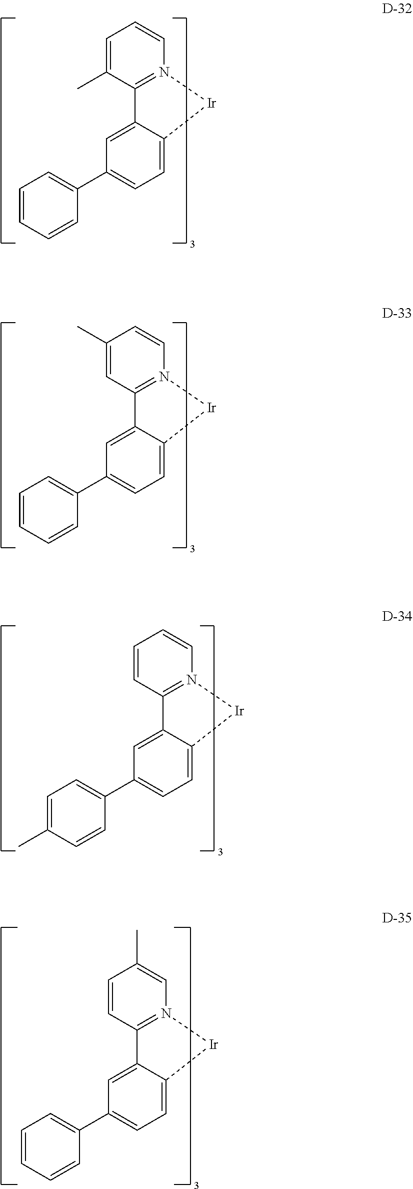

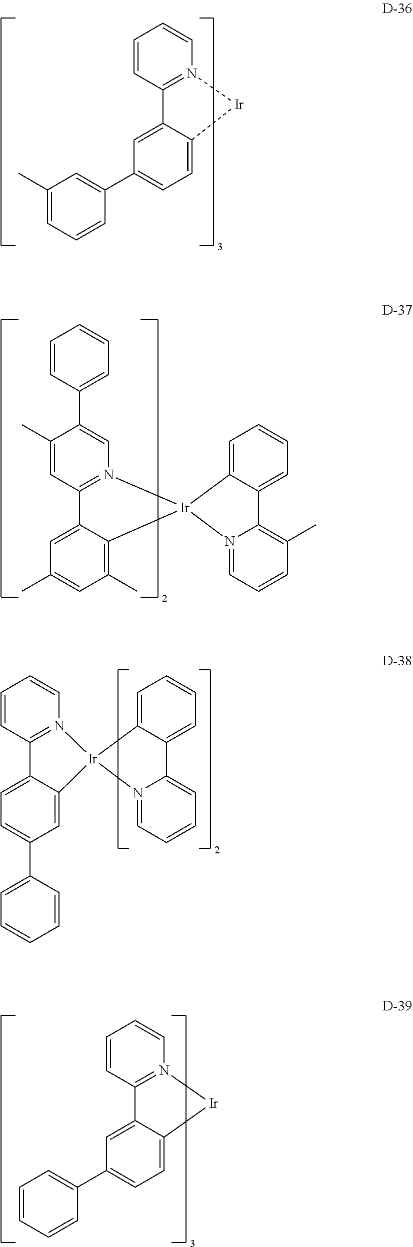

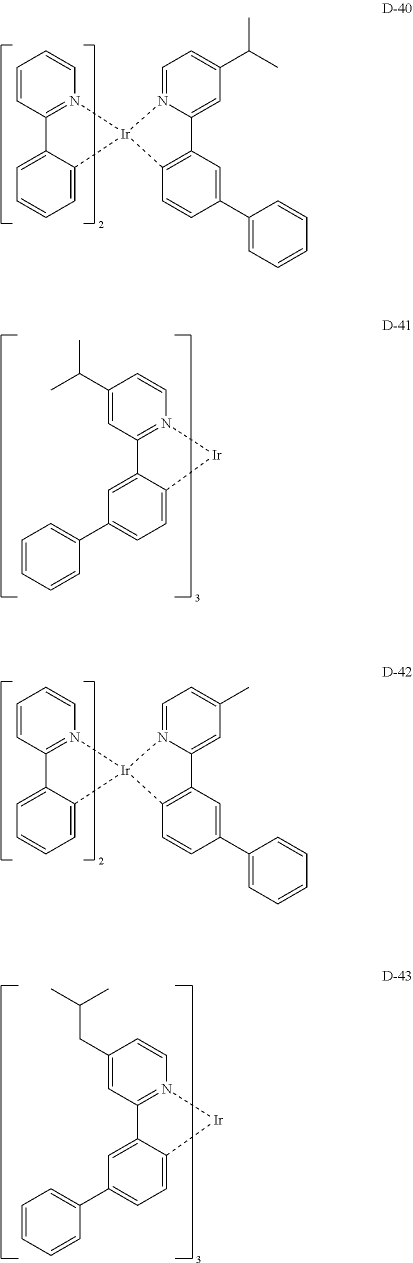

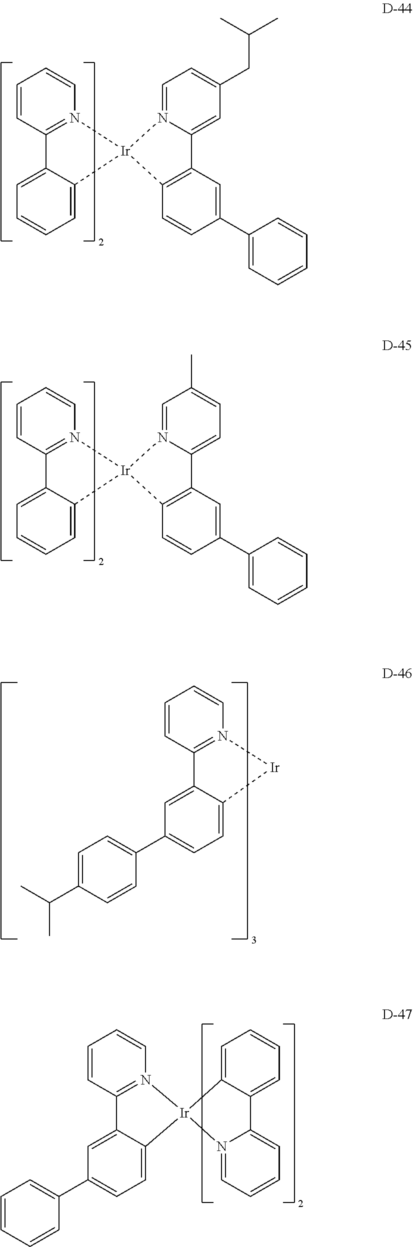

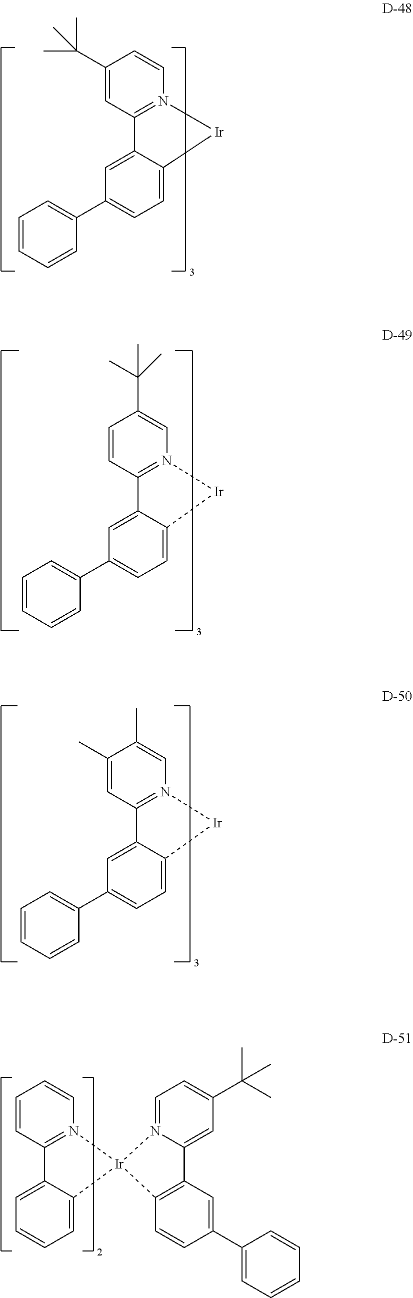

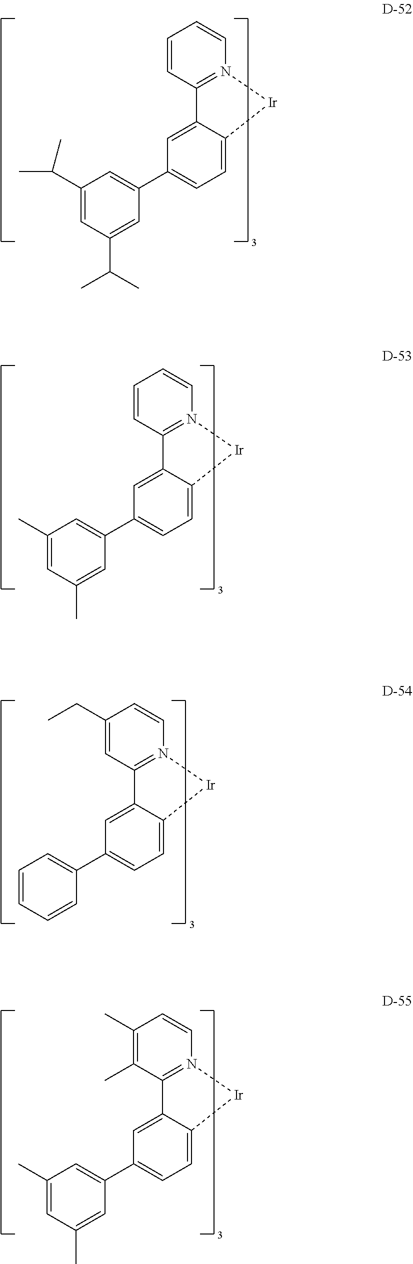

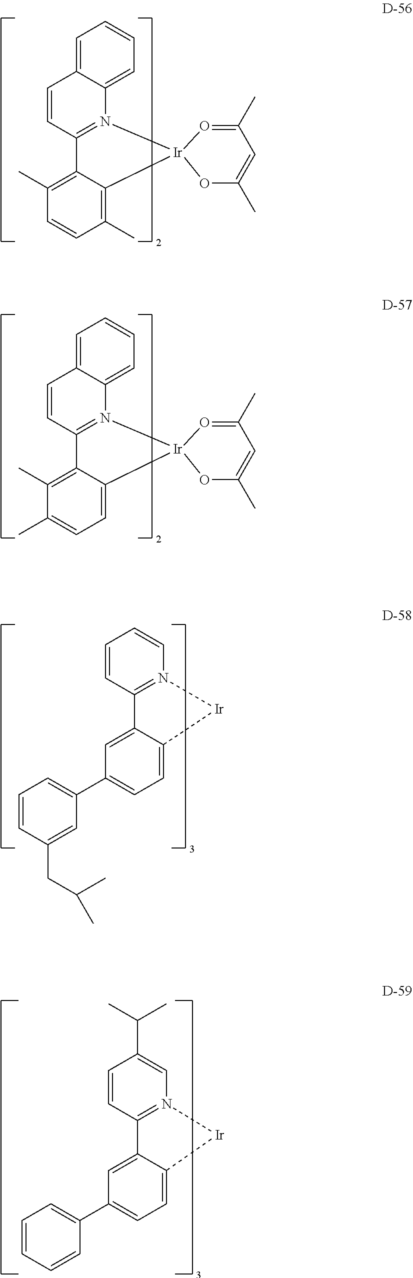

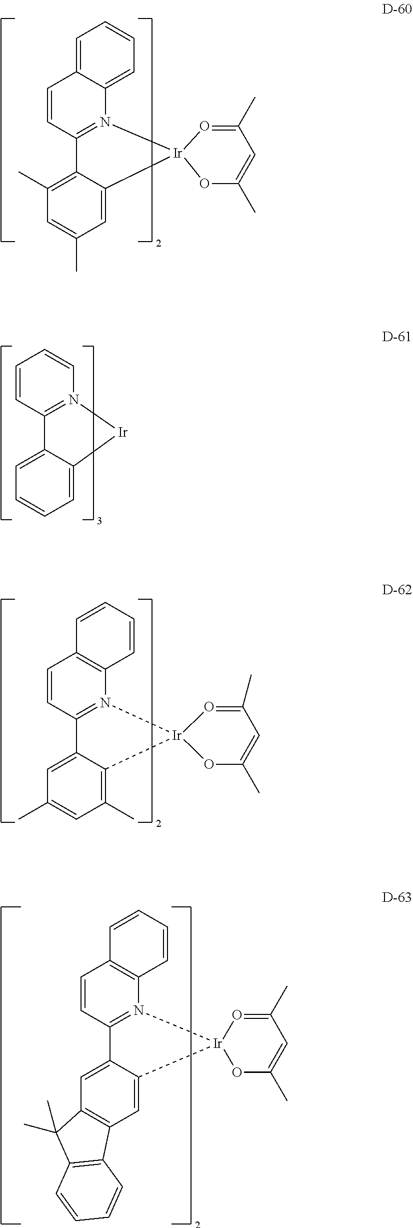

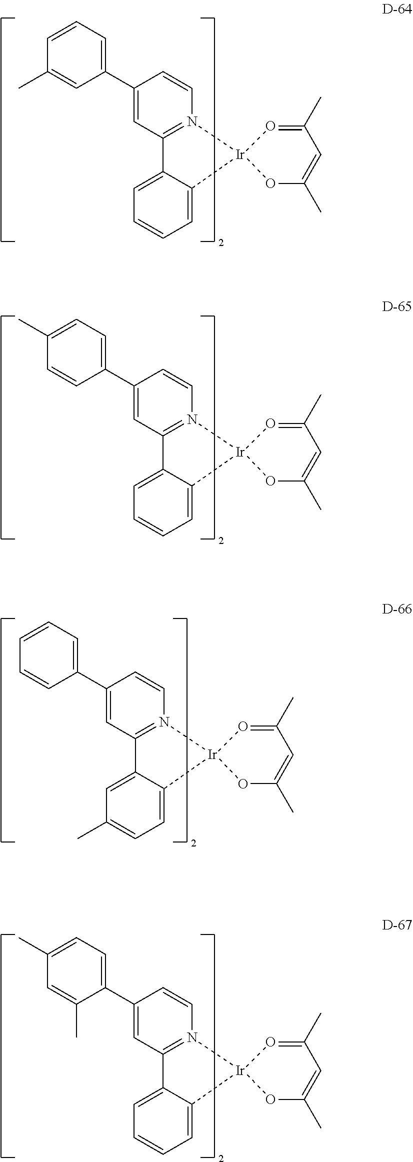

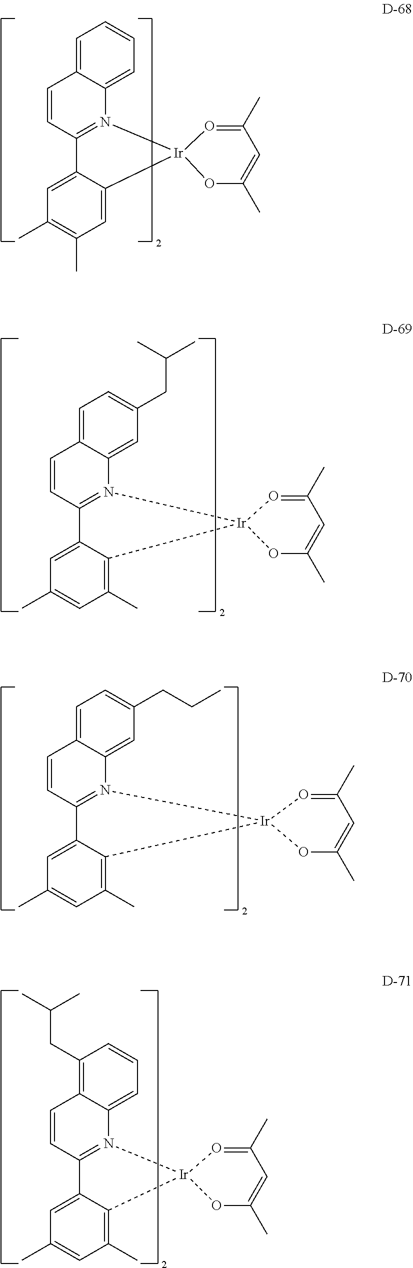

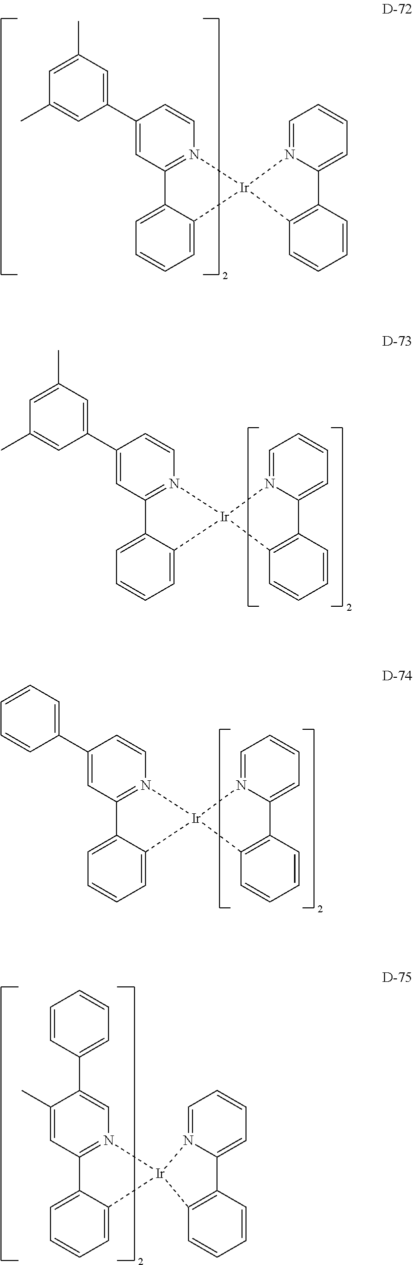

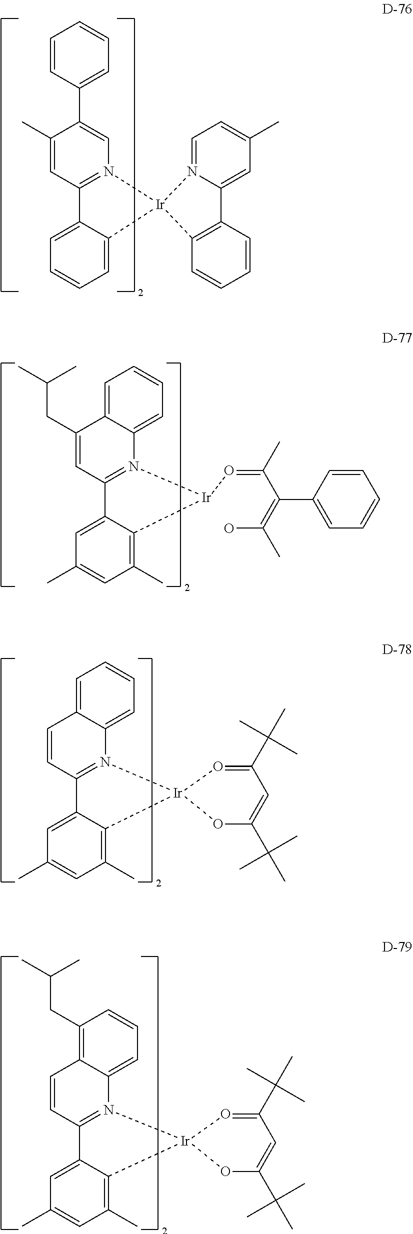

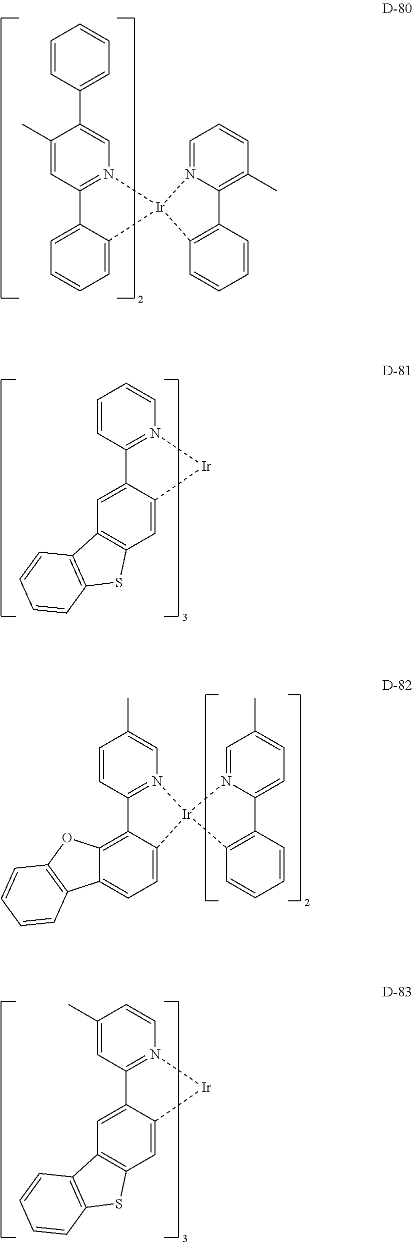

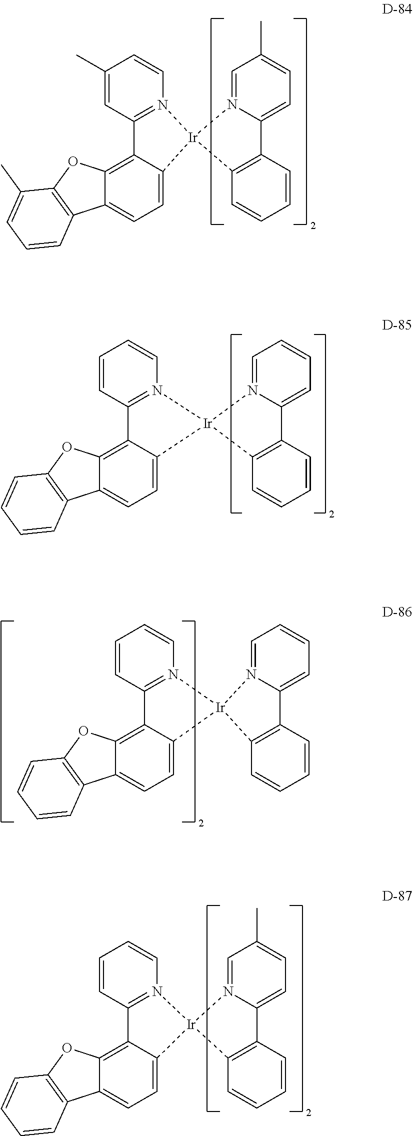

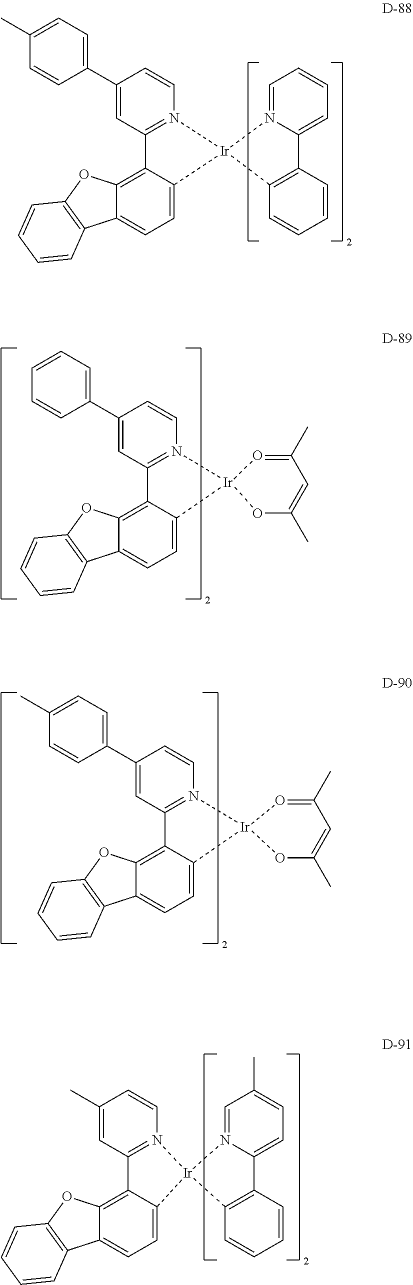

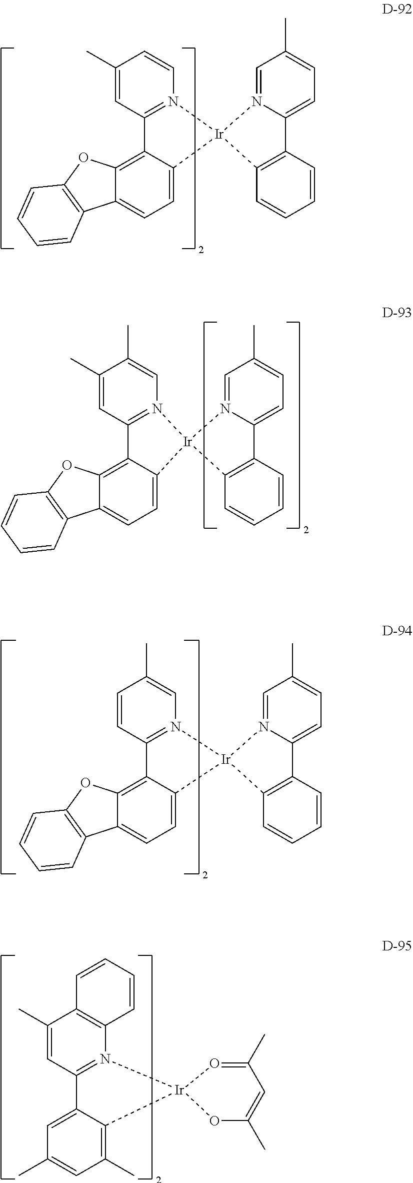

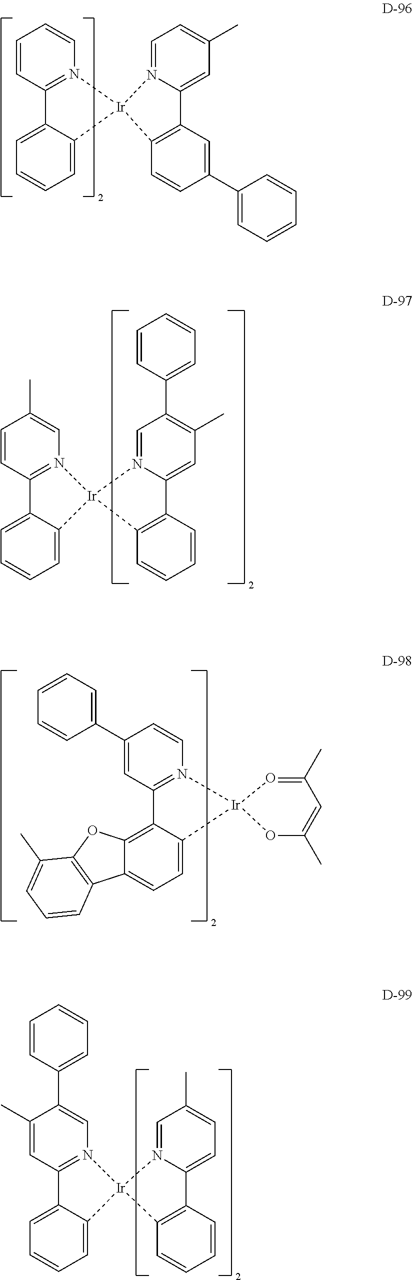

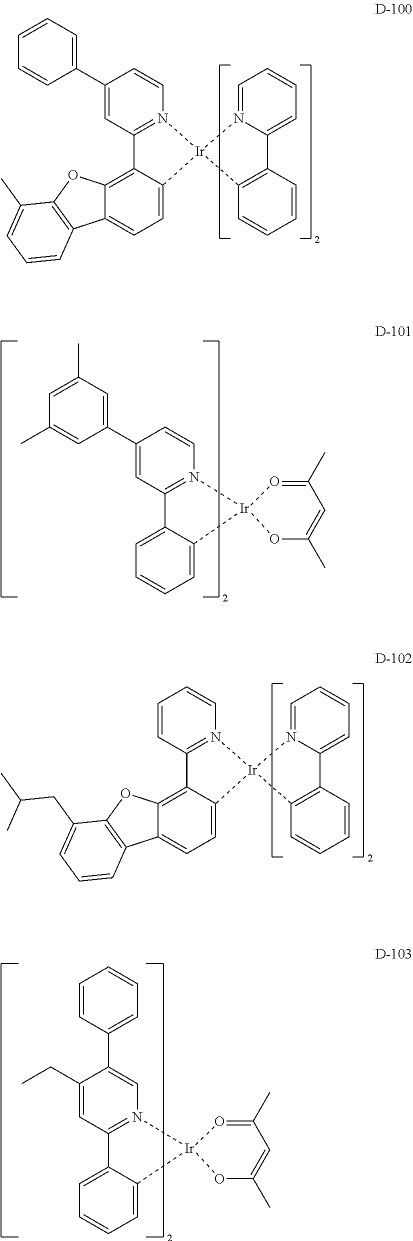

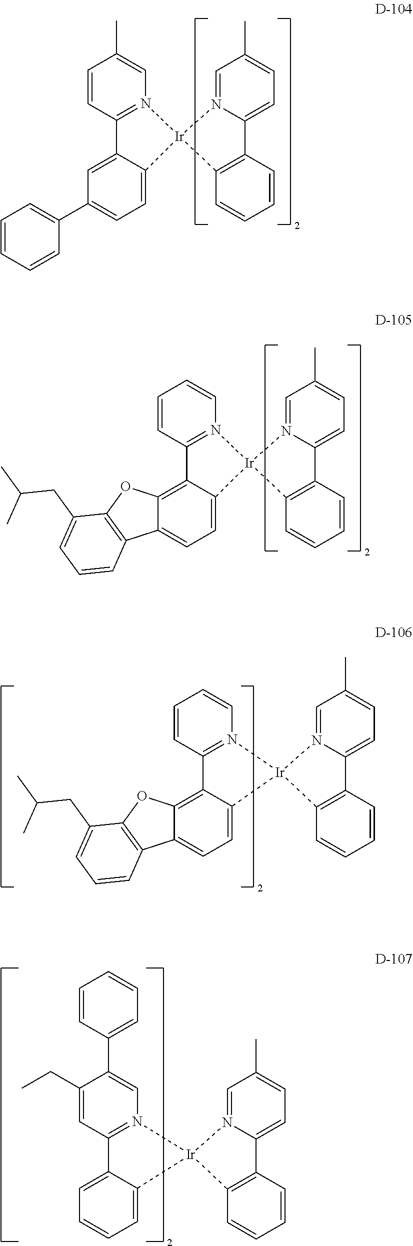

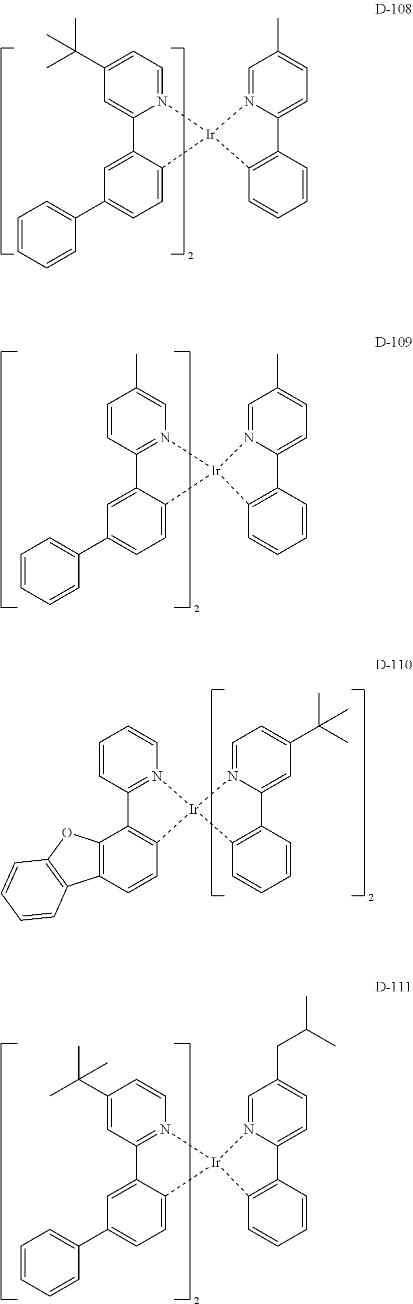

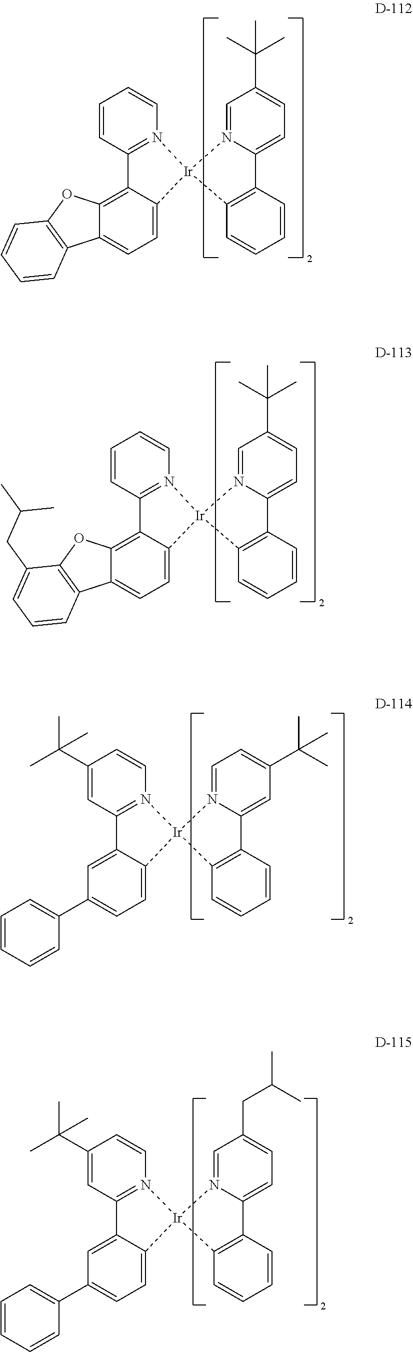

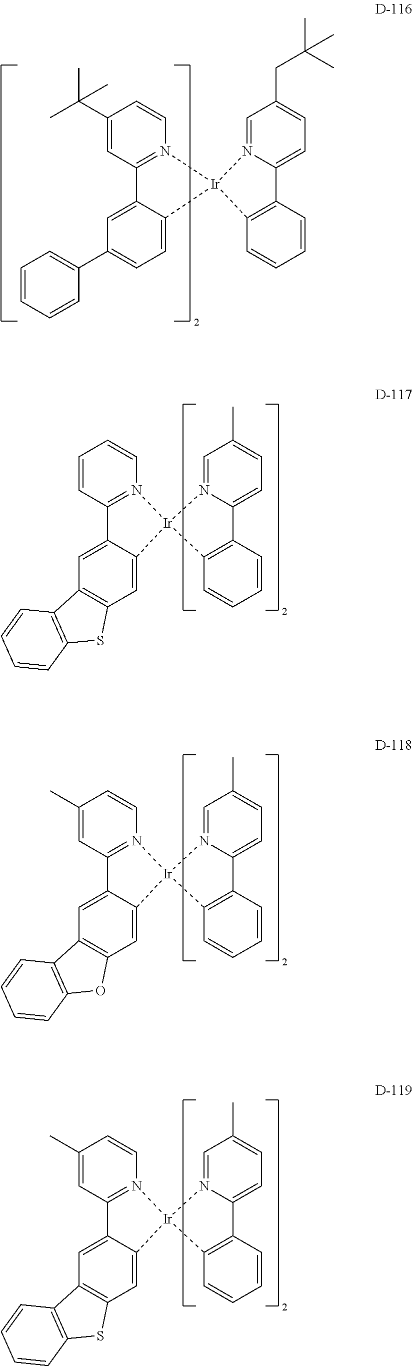

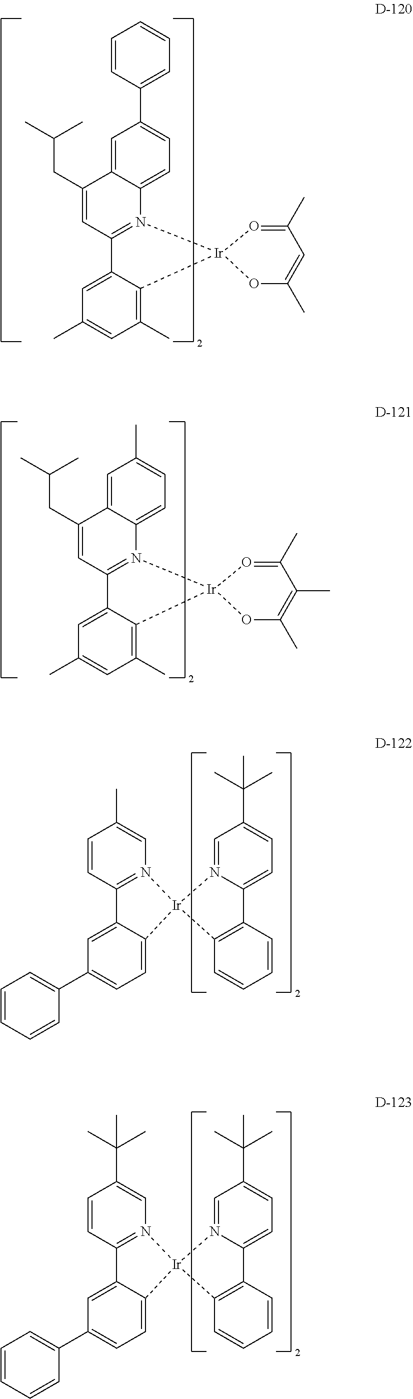

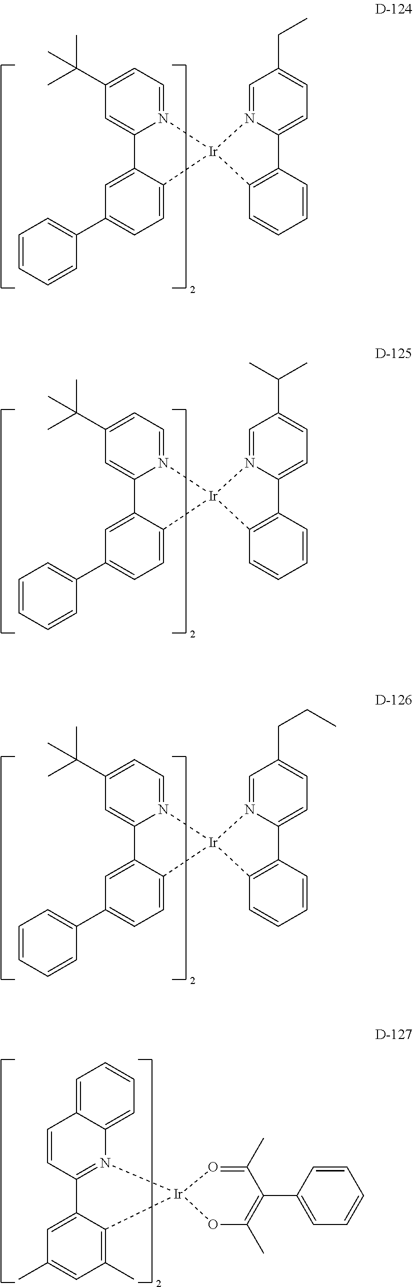

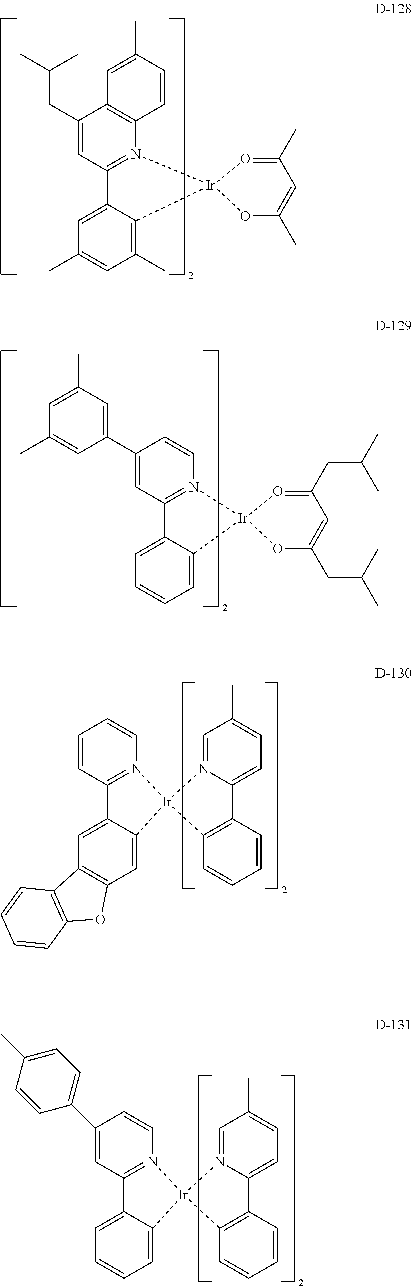

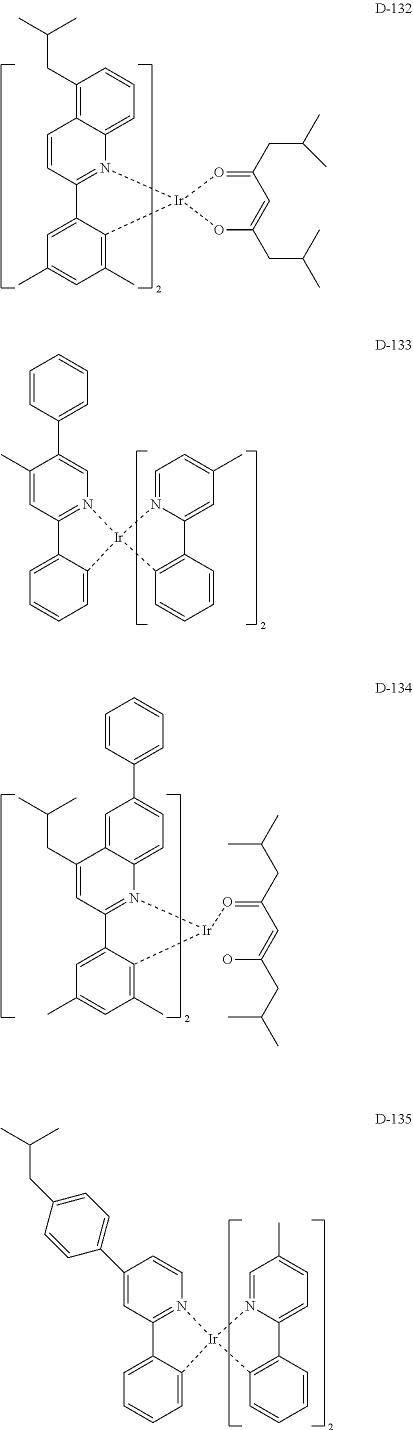

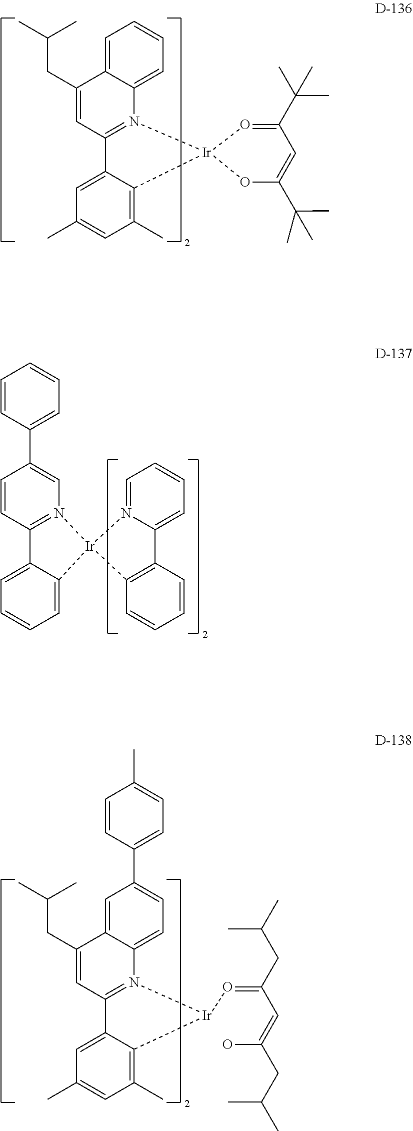

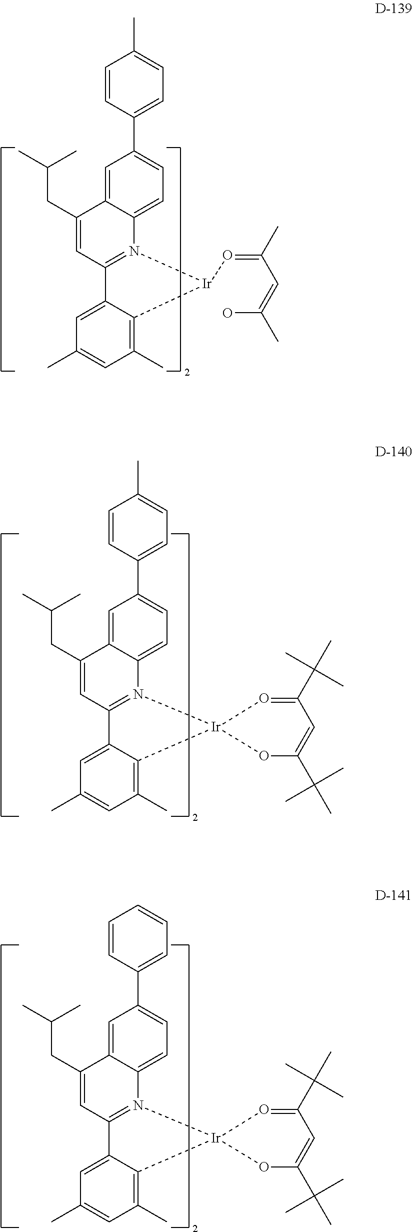

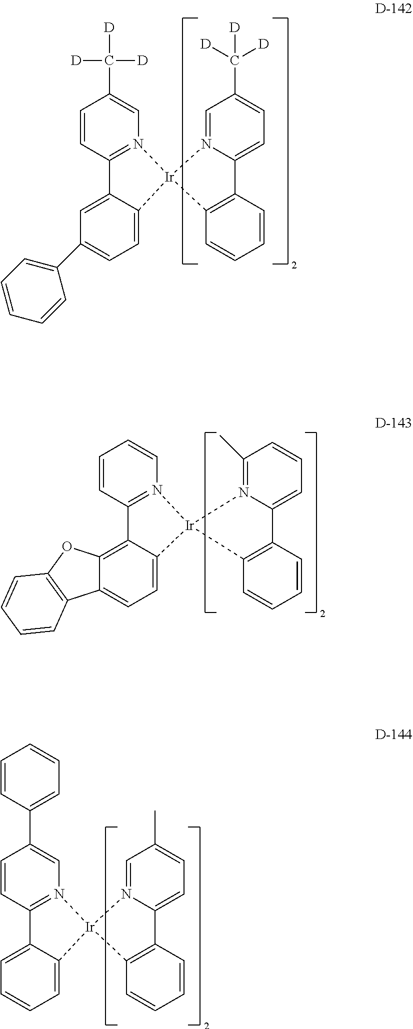

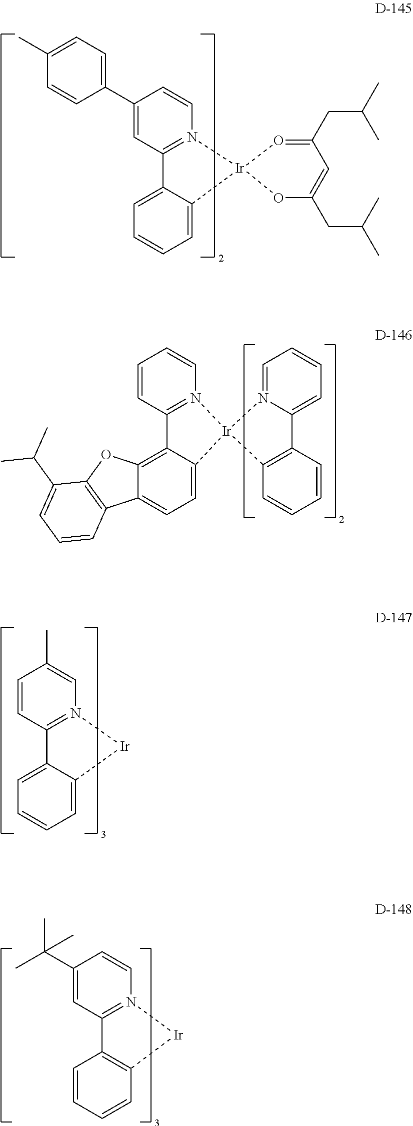

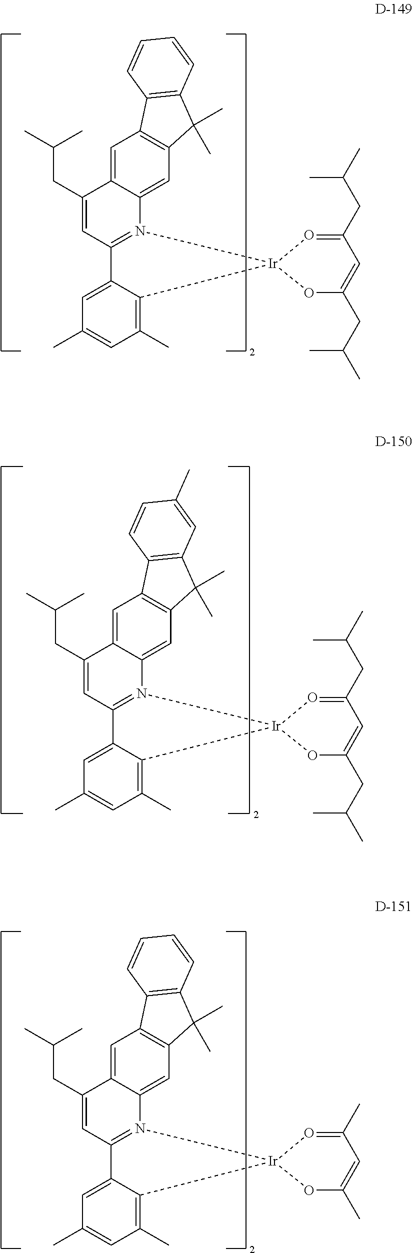

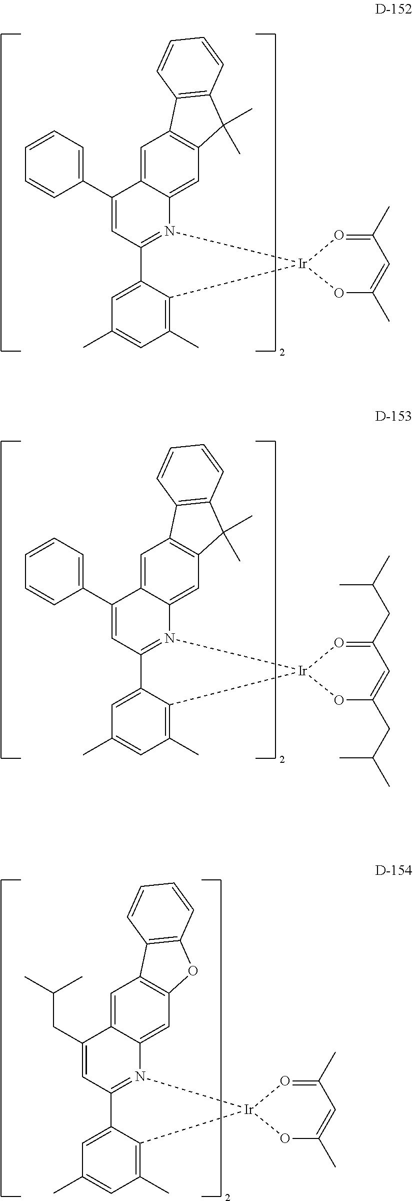

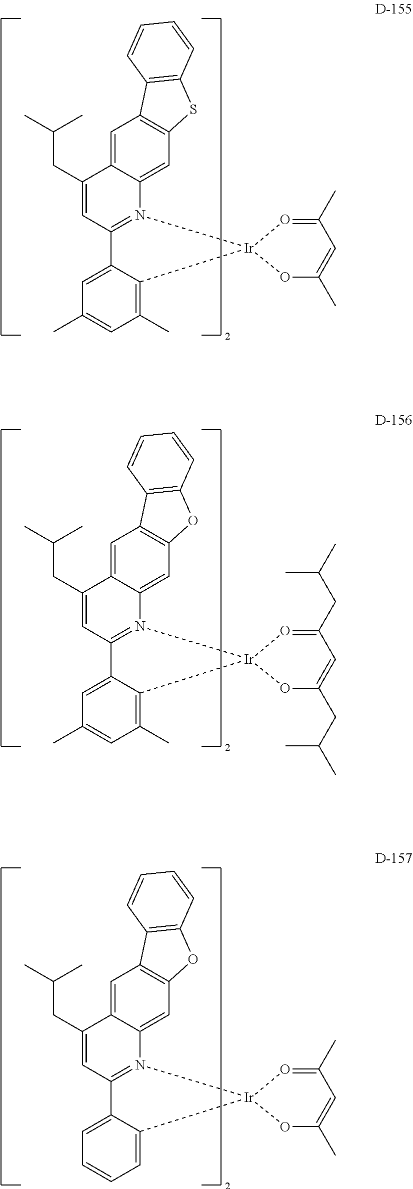

When the light-emitting layer comprises a host and a dopant, the dopant can be doped in an amount of less than 25 wt %, and preferably less than 17 wt %, based on the total amount of the dopant and host of the light-emitting layer. When the light-emitting layer is composed of two or more layers, each of the layers may be prepared to emit color different from one another. For example, the device may emit white light by preparing three light-emitting layers which emit blue, red, and green colors, respectively. Furthermore, the device may include light-emitting layers which emit yellow or orange color, if necessary.

The electron buffer layer may include an electron buffer material comprising a compound represented by formula 11, or may comprise another electron buffer compound. The thickness of the electron buffer layer may be 1 nm or more, but is not particularly limited. Specifically, the thickness of the electron buffer layer may be in the range of from 2 nm to 200 nm. The electron buffer layer may be formed on the light-emitting layer by sing known various methods such as vacuum deposition, wet film-forming methods, laser induced thermal imaging, etc. The electron buffer layer indicates a layer controlling an electron flow. Therefore, the electron buffer layer may be, for example, a layer which traps electrons, blocks electrons, or lowers an energy barrier between an electron transport zone and a light-emitting layer. In addition, the electron buffer layer may be comprised in an organic electroluminescent device which emits all colors such as blue, red, green, etc.

The electron transport zone may comprise a compound represented by formula 11, an electron transport compound, a reductive dopant, or a combination thereof. The electron transport compound may be at least one selected from the group consisting of phenanthrene-based compounds, oxazole-based compounds, isoxazole-based compounds, triazole-based compounds, isothiazole-based compounds, oxadiazole-based compounds, thiadiazole-based compounds, perylene-based compounds, anthracene-based compounds, aluminum complexes, and gallium complexes. The reductive dopant may be at least one selected from alkali metals, alkali metal compounds, alkaline earth metals, rare-earth metals, and halides, oxides, and complexes thereof. Specifically, the reductive dopant includes lithium quinolate, sodium quinolate, cesium quinolate, potassium quinolate, LiF, NaCl, CsF, Li₂O, BaO, and BaF₂, but are not limited thereto.

In addition, the electron transport layer may contain an electron transport material comprising a compound represented by formula 11. Also, the electron transport layer may further comprise the reductive dopant described above. The electron injection layer may be prepared with an electron injection material known in the art, which includes lithium quinolate, sodium quinolate, cesium quinolate, potassium quinolate, LiF, NaCl, CsF, Li₂O, BaO, and BaF₂, but is not limited thereto.

The organic electroluminescent device of the present disclosure is intended to explain one embodiment of the present disclosure, and is not meant in any way to restrict the scope of the invention. The organic electroluminescent device may be embodied in another way. For example, any one optional component such as a hole injection layer, except for a light-emitting layer, may not be comprised in the organic electroluminescent device of the present disclosure. In addition, an optional component may be further comprised therein, which includes an impurity layer such as an n-doping layer and a p-doping layer. The organic electroluminescent device may be a both side emission type in which a light-emitting layer is placed on each of both sides of the impurity layer. The two light-emitting layers on the impurity layer may emit different colors. The organic electroluminescent device may be a bottom emission type in which a first electrode is a transparent electrode and a second electrode is a reflective electrode, or may be a top emission type in which a first electrode is a reflective electrode and a second electrode is a transparent electrode. The organic electroluminescent device may have an inverted type structure in which a cathode, an electron transport layer, a light-emitting layer, a hole transport layer, a hole injection layer, and an anode are sequentially stacked on a substrate.

Originally, LUMO (lowest unoccupied molecular orbital) energy and HOMO (highest occupied molecular orbital) energy levels have negative values. However, for convenience, LUMO energy level (A) and HOMO energy level are expressed in absolute values in the present disclosure. In addition, the values of the LUMO energy level are compared based on absolute values. Values measured by density functional theory (DFT) are used for LUMO energy levels and HOMO energy levels in the present disclosure.

The LUMO energy levels may be easily measured by various known methods. Generally, LUMO energy levels are measured by cyclic voltammetry or ultraviolet photoelectron spectroscopy (UPS). Therefore, one skilled in the art may easily comprehend the electron buffer layer, light-emitting layer, and electron transport layer that satisfy the equational relationship of the LUMO energy levels of the present disclosure, and practice the present disclosure. HOMO energy levels may be easily measured in the same manner as LUMO energy levels.

According to one embodiment of the organic electroluminescent device of the present disclosure, the LUMO energy level of the light-emitting layer (Ah) and the LUMO energy level of the electron transport zone (Ae) satisfy the following equation (1), wherein Ae refers to a LUMO energy level of the electron transport zone comprising an electron transport layer and/or an electron buffer layer.

Ae≤Ah+0.5 eV (1)

For appropriate efficiency and/or long lifespan of the organic electroluminescent device, the following equation (2) is preferably satisfied.

Ae≤Ah+0.2 eV (2)

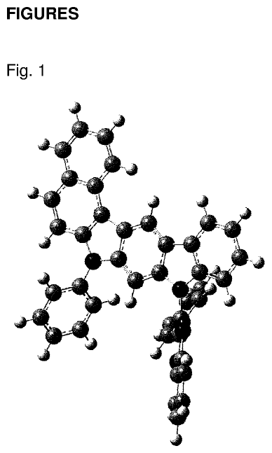

In the case of fused benzoindolocarbazole and quinoxaline derivatives contained in the light-emitting layer, as shown in FIG. 1, the donor and acceptor have a molecular structure that is mutually perpendicularly and horizontally twisted. That is, it can be confirmed that benzoindolocarbazole and quinoxaline have a dihedral angle close to 90°. This allows the device to exhibit bipolar properties through donor carbazole and electron deficient quinoxaline in the device, and to have excellent thermal stability and/or electrochemical properties due to its twisted structure. In addition, this structure enables effective charge transfer between the donor and the acceptor, and the following effects can be obtained. As shown in FIG. 1, when the electron donating group and the electron accepting group are orthogonal to each other, the transition from n to π* can be easily performed and the singlet exciton generation efficiency can be increased through reverse intersystem crossing (RISC), which can be referred to as Twisted Intramolecular Charge Transfer (TICT). In such a TICT condition, a singlet CT state and a triplet CT state can be made into a state where small energy split occurs and they are mixed. This allows free energy transfer between singlet and triplet. That is, the transition from S1 to T1, or the transition from T1 to S1 can be made relatively free of each other. Using this mixed state of S1 and T1, the charges in the S1 and T1 states, which are eventually increased to TICT, can be easily transferred to the donor T1.

In the present disclosure, a compound having a structure in which benzoindolocarbazole and quinoxaline are fused in the light-emitting layer has a chemical structure capable of increasing the generation efficiency from S1 to T1. In addition, the quinoxaline derivative exhibits a narrow energy bandgap characteristic due to strong electron-withdrawing characteristics. If the chemical structure of TICT is used, the quinoxaline derivative can have the characteristic of red migration, and the effect can be seen that the LUMO energy value is slightly lower. This can minimize the charge trap and build a more suitable energy level for the red host. A host having a TICT structure as described below has an excellent structure for improving thermal stability while reducing aggregation in a host because the molecular orientation is irregular, but the injection ability with respect to a planar orientation material may be relatively low in charge injection with other interface layers. The reason for this is that in the case of a planar orientation material, the charge transfer may be advantageous because the π-π overlap between neighboring molecules is increased and the positional disturbance is reduced, but in the case of a random orientation material, not only the state density (DOS) is widened but also the energy barrier becomes worse and the van der Waals intermolecular interaction becomes weak, which impedes the charge transfer, and current injection may not be easy. Also, the orientation effect can affect the degree of wave function overlap at the interface.

In order to compensate for these drawbacks, if an azine-based heterocyclic derivative having a high electron affinity in the electron transport zone is used as an electron transport zone material, electron injection becomes easier, thereby increasing the driving voltage, efficiency and/or lifespan of the device. In addition, the electron current characteristic can be increased by utilizing the interface dipole formation and the charge transfer effect by using the material having excellent ability to accommodate the electron transfer zone in the light-emitting layer having the TICT structure. For example, by using electron transport layers of fused indolocarbazole-based (Donor) and azine-based (Accepter), charge injection through the CT effect at the interface can be facilitated. Magnetic dipole moments can result in greater charge transfer through the interface dipole in the case of organic molecules of a polar material. For example, when a compound used as the electron transport zone and a phenanthroxazole compound or a dibenzocarbazole compound as a HOMO orbital are used, it has not only a large electronegativity and an electron-rich group, but also a rigid property as a structure in which groups such as phenanthrene and oxazole, or dibenzocarbazole are fused, and thus intermolecular transition is facilitated. In addition, the enhancement of intermolecular stacking facilitates the implementation of horizontal molecular orientation, thereby enabling rapid electronic current characteristics to be realized. This is effective in combination with the light-emitting layer, and can provide an organic electroluminescent device capable of realizing a high-purity color while having a relatively low driving voltage, and excellent luminous efficiency such as current efficiency and power efficiency.

The results according to the relationship of the LUMO energy levels of the electron transport zone (Ae) and the LUMO energy levels of the light-emitting layer (Ah) are for explaining the rough tendency of the device in accordance with the overall LUMO energy groups, and so results other than the above may be provided according to the inherent property of the specific derivatives, and the stability of the materials.

Hereinafter, the properties of the organic light-emitting diode (OLED) device according to the present disclosure will be explained in detail, but are not limited by the following examples.

### Comparative Example 1: Producing a Red Light-Emitting OLED Device Not According to the Present Disclosure

An OLED device not according to the present disclosure was produced as follows: A transparent electrode indium tin oxide (ITO) thin film (10 Ω/sq) on a glass substrate for an OLED device (GEOMATEC CO., LTD., Japan) was subjected to an ultrasonic washing with acetone and isopropyl alcohol, sequentially, and then was stored in isopropanol. The ITO substrate was then mounted on a substrate holder of a vacuum vapor deposition apparatus. Compound HI-1 was introduced into a cell of the vacuum vapor deposition apparatus, and then the pressure in the chamber of the apparatus was controlled to 10⁻⁷ torr. Thereafter, an electric current was applied to the cell to evaporate the above-introduced material, thereby forming a first hole injection layer having a thickness of 80 nm on the ITO substrate. Next, compound HI-2 was introduced into another cell of the vacuum vapor deposition apparatus and was evaporated by applying an electric current to the cell, thereby forming a second hole injection layer having a thickness of 5 nm on the first hole injection layer. Compound HT-1 was then introduced into a cell of the vacuum vapor deposition apparatus and was evaporated by applying an electric current to the cell, thereby forming a first hole transport layer having a thickness of 10 nm on the second hole injection layer. Compound HT-2 was then introduced into another cell of the vacuum vapor deposition apparatus and was evaporated by applying an electric current to the cell, thereby forming a second hole transport layer having a thickness of 60 nm on the first hole transport layer. After forming the hole injection layer and the hole transport layer, a light-emitting layer was formed thereon as follows: Compound H-139 was introduced into one cell of the vacuum vapor deposition apparatus as a host, and compound D-71 was introduced into another cell as a dopant. The two materials were evaporated at a different rate and the dopant was deposited in a doping amount of 3 wt % based on the total amount of the host and the dopant to form a light-emitting layer having a thickness of 40 nm on the second hole transport layer. Next, compound ETL-1 (Alq₃) as an electron transport material was introduced into one cell of the vacuum vapor deposition apparatus and evaporated to form an electron transport layer having a thickness of 35 nm on the light-emitting layer. After depositing compound EIL-1 as an electron injection layer having a thickness of 2 nm on the electron transport layer, an Al cathode having a thickness of 80 nm was deposited on the electron injection layer by another vacuum vapor deposition apparatus. Thus, an OLED device was produced. All the materials used for producing the OLED device were purified by vacuum sublimation at 10⁻⁶ torr.

### Comparative Example 2: Producing a Red Light-Emitting OLED Device not According to the Present Disclosure

An OLED device was produced in the same manner as in Comparative Example 1, except that compound ETL-2 (BCP) instead of compound ETL-1 was used as an electron transport material.

### Comparative Example 3: Producing a Red Light-Emitting OLED Device not According to the Present Disclosure

An OLED device was produced in the same manner as in Comparative Example 1, except that compound ETL-3:compound EIL-1 in a weight ratio of 50:50 were evaporated to form an electron transport layer of 35 nm.

### Device Examples 1 to 7: Producing a Red Light-Emitting OLED Device According to the Present Disclosure

In Device Examples 1 to 7, OLED devices were produced in the same manner as in Comparative Example 3, except that the electron transport materials recited in Table 1 in a weight ratio of 50:50 were evaporated to form an electron transport layer.

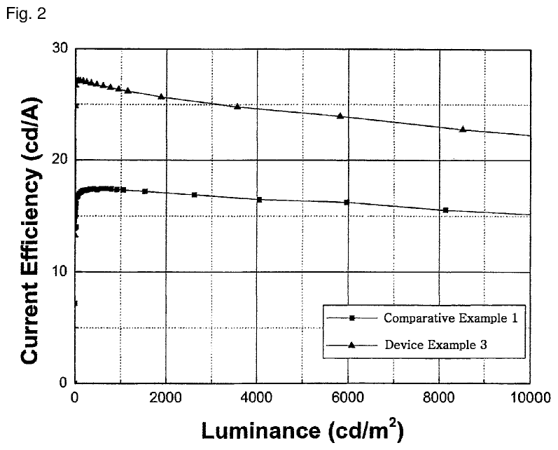

The driving voltage, luminous efficiency, and CIE color coordinates based on a luminance of 1,000 nits, and the time taken to be reduced from 100% to 90% of the luminance based on a luminance of 5,000 nits (lifespan; T90) of the OLED devices of Comparative Examples 1 to 3 and Device Examples 1 to 7 are provided in Table 1 below. In addition, a current efficiency versus a luminance of the OLED devices of Comparative Example 1 and Device Example 3 is illustrated in FIG. 2 as a graph.

TABLE 1

| | Electron | Electron | Driving | Luminous | Color | Color | Lifespan |
|---|---|---|---|---|---|---|---|
| | Buffer | Transport | Voltage | Efficiency | Coordinate | Coordinate | (T90, |
| | Material | Material | (V) | (cd/A) | (x) | (y) | hr) |
| Comparative | — | ETL-1 | 4.2 | 17.4 | 0.661 | 0.339 | 146.5 |
| Example 1 | | | | | | | |
| Comparative | — | ETL-2 | 5.5 | 20.3 | 0.660 | 0.340 | 0.2 |
| Example 2 | | | | | | | |
| Comparative | — | ETL-3:EIL-1 | 3.2 | 24.6 | 0.663 | 0.337 | 620.7 |
| Example 3 | | | | | | | |
| Device | — | B-31:EIL-1 | 3.3 | 25.9 | 0.663 | 0.337 | 750.8 |
| Example 1 | | | | | | | |
| Device | — | B-56:EIL-1 | 3.2 | 26.0 | 0.663 | 0.337 | 775.3 |
| Example 2 | | | | | | | |
| Device | — | B-100:EIL-1 | 3.1 | 26.2 | 0.663 | 0.336 | 726.9 |
| Example 3 | | | | | | | |
| Device | — | B-101:EIL-1 | 3.1 | 26.0 | 0.663 | 0.337 | 919.4 |
| Example 4 | | | | | | | |
| Device | — | B-92:EIL-1 | 3.1 | 25.3 | 0.663 | 0.337 | 783.7 |
| Example 5 | | | | | | | |
| Device | — | B-102:EIL-1 | 3.2 | 25.6 | 0.663 | 0.337 | 1075.7 |
| Example 6 | | | | | | | |
| Device | — | B-103:EIL-1 | 3.1 | 26.2 | 0.664 | 0.336 | 1280.4 |
| Example 7 | | | | | | | |

### Device Examples 8 to 10: Producing a Red Light-Emitting OLED Device According to the Present Disclosure

In Device Examples 8 to 10, OLED devices were produced in the same manner as in Comparative Example 3, except that the electron buffer material recited in Table 2 below was evaporated to form an electron buffer layer of 5 nm on the light-emitting layer, and the electron transport materials recited in Table 2 below in a weight ratio of 50:50 were evaporated to form an electron transport layer of 30 nm on the electron buffer layer.

The driving voltage, luminous efficiency, and CIE color coordinates based on a luminance of 1,000 nits, and the time taken to be reduced from 100% to 80% of the luminance based on a luminance of 5,000 nits (lifespan; T80) of the OLED devices of Device Examples 8 to 10 are provided in Table 2 below.

TABLE 2

| | Electron | Electron | Driving | Luminous | Color | Color | |
|---|---|---|---|---|---|---|---|
| | Buffer | Transport | Voltage | Efficiency | Coordinate | Coordinate | Lifespan |
| | Material | Material | (V) | (cd/A) | (x) | (y) | (T80, hr) |
| Device | B-21 | B-104:EIL-1 | 3.0 | 23.8 | 0.663 | 0.337 | 1114.3 |
| Example 8 | | | | | | | |
| Device | B-21 | B-105:EIL-1 | 3.1 | 24.0 | 0.662 | 0.337 | 1127.8 |
| Example 9 | | | | | | | |
| Device | B-21 | B-106:EIL-1 | 3.1 | 24.2 | 0.663 | 0.337 | 1238.8 |
| Example | | | | | | | |
| 10 | | | | | | | |

From Tables 1 and 2 above, it can be seen that the OLED devices of Device Examples 1 to 10, which use a compound according to the present disclosure in a light-emitting layer, and an electron buffer layer and/or an electron transport layer, provide lower driving voltages, higher efficiencies and/or longer lifespans than those of Comparative Examples 1 to 3.

### Comparative Example 4: Producing a Red Light-Emitting OLED Device not According to the Present Disclosure

An OLED device was produced in the same manner as in Device Example 7, except that compound HT-3 instead of compound HT-2 was used in the second hole transport layer, and compound EH-1 instead of compound H-139 was used in the light-emitting layer.

### Device Example 11: Producing a Red Light-Emitting OLED Device According to the Present Disclosure

An OLED device was produced in the same manner as in Comparative Example 4, except that compound H-139 was used in a light-emitting layer.

The driving voltage, luminous efficiency, and CIE color coordinates based on a luminance of 1,000 nits, and the time taken to be reduced from 100% to 90% of the luminance based on a luminance of 5,000 nits (lifespan; T90) of the OLED devices of Comparative Example 4 and Device Example 11 are provided in Table 3 below.

TABLE 3

| | Light- | Electron | Driving | Color | Color | |
|---|---|---|---|---|---|---|
| | Emitting | Transport | Voltage | Coordinate | Coordinate | Lifespan |
| | Material | Material | (V) | (x) | (y) | (T90, hr) |
| Comparative | EH-1 | B-103:EIL-1 | 4.0 | 0.663 | 0.337 | 66.5 |
| Example 4 | | | | | | |
| Device | H-139 | B-103:EIL-1 | 3.5 | 0.665 | 0.335 | 649.1 |
| Example 11 | | | | | | |

From Table 3 above, it can be seen that the OLED device of Device Example 11, in which a compound of the present disclosure was used in a light-emitting layer and an electron transport layer, provides lower driving voltage and longer lifespan compared to Comparative Example 4. In particular, an OLED device comprising a specific combination of compounds of the present disclosure may be suitable to flexible displays, lightings, and vehicle displays which require long lifespan.

### Characteristic Analysis

In order to support the theory of a combination of host and electron transport zone mentioned herein, a Hole Only Device (HOD) and an Electron Only Device (EOD) were produced to confirm charge balance characteristics in a device based on quinoxaline derivatives and benzoindolocarbazole characteristics and to compare electron current characteristics according to the electron transport layer used in the present disclosure. The device structure of HOD and EOD is as follows.

### HOD (Hole Only Device) Example

A ITO substrate was mounted on a substrate holder of a vacuum vapor deposition apparatus. Compound HI-1 was introduced into a cell of the vacuum vapor deposition apparatus, and then the pressure in the chamber of the apparatus was controlled to 10⁻⁷ torr. Thereafter, an electric current was applied to the cell to evaporate the above-introduced material, thereby forming a hole injection layer having a thickness of 10 nm on the ITO substrate. Compound HT-1 was then introduced into another cell of the vacuum vapor deposition apparatus and was evaporated by applying an electric current to the cell, thereby forming a first hole transport layer having a thickness of 10 nm on the hole injection layer. Next, compound HT-4 was introduced into another cell of the vacuum vapor deposition apparatus and was evaporated by applying an electric current to the cell, thereby forming a second hole transport layer having a thickness of 10 nm on the first hole transport layer. After forming the hole injection layer and the hole transport layers, a light-emitting layer was formed thereon as follows: Compound H-139 was introduced into one cell of the vacuum vapor deposition apparatus as a host, and compound D-71 was introduced into another cell as a dopant. The two materials were evaporated at a different rate and the dopant was deposited in a doping amount of 3 wt % based on the total amount of the host and dopant to form a light-emitting layer having a thickness of 30 nm on the second hole transport layer. Compound HT-1 was then introduced into one cell of the vacuum vapor deposition apparatus and evaporated to form an electron blocking layer having a thickness of 20 nm on the light-emitting layer. Next, an Al cathode having a thickness of 80 nm was deposited on the electron blocking layer by another vacuum vapor deposition apparatus. Thus, an OLED device was produced.

As a result, a voltage was 4.7 V at a current density of 10 mA/cm² and a voltage was 7.0 Vat a current density of 100 mA/cm².

EOD (Electron Only Device) Example

Barium and 2,9-dimethyl-4,7-diphenyl-1,10-phenanthroline (BCP) were introduced into one cell of a vacuum vapor deposition apparatus, and a current was applied to the cell to evaporate, thereby forming a hole blocking layer (HBL) having a thickness of 10 nm on ITO. Next, compound H-139 was introduced into one cell of the vacuum vapor deposition apparatus as a host, and compound D-71 was introduced into another cell as a dopant. The two materials were evaporated at a different rate and the dopant was deposited in a doping amount of 3 wt % based on the total amount of the host and the dopant to form a light-emitting layer having a thickness of 40 nm on the hole blocking layer. Compound B-103 and compound EIL-1 were introduced into one cell and another cell of the vacuum vapor deposition apparatus, respectively, and the two materials were evaporated at the same rate and doped to a 50:50 weight ratio to form an electron transport layer having a thickness of 30 nm on the light-emitting layer. After depositing compound EIL-1 as an electron injection layer having a thickness of 2 nm on the electron transport layer, an Al cathode having a thickness of 80 nm was deposited on the electron injection layer by another vacuum vapor deposition apparatus. Thus, an OLED device was produced. All the materials used for producing the OLED device were purified by vacuum sublimation at 10⁻⁶ torr.

### EOD Comparative Example 1

A device was produced in the same manner as in the EOD Example, except that compound ETL-1 was used instead of compound B-103 in the electron transport layer.

### EOD Comparative Example 2

A device was produced in the same manner as in the EOD Example, except that only compound ETL-1 was used in the electron transport layer.

The voltage at current density of 10 mA/cm², and the voltage at current density of 100 mA/cm² of the devices of the EOD Example, and EOD Comparative Examples 1 and 2 are provided in Table 4 below.

TABLE 4

| | Electron | Voltage (V) | Voltage (V) |
|---|---|---|---|
| | Transport Layer | (10 A/cm²) | (100 mA/cm²) |
| EOD Example | B-103:EIL-1 | 4.5 | 6.7 |
| EOD Comparative | ETL-1:EIL-1 | 8.1 | 12.2 |
| Example 1 | | | |
| EOD Comparative | ETL-1 | 7.1 | 10.5 |
| Example 2 | | | |

As a result of the Hole Only Device (HOD Example) and the Electron Only Device (EOD Example, and EOD Comparative Examples 1 and 2), of which the total thickness is identical, it can be seen that the hole and electron have very similar voltage characteristics, when compound B-103 is used in the electron transport layer. This indicates that the fused benzoindolocarbazole and quinoxaline derivatives used in the present disclosure had very similar hole and electron characteristics, thereby exhibiting bipolar characteristics. On the other hand, the compound ETL-1 contained in the Comparative Examples exhibited a much higher driving voltage than those of the HOD Example and the EOD Example, regardless of whether or not compound EIL-1 was doped. From this, it can be confirmed that the combination of the azine-based electron transport material of the present disclosure and the host compound of the present disclosure exhibits excellent electron current characteristics.

The compounds used in the Comparative Examples and Device Examples are shown in Table 5 below.

TABLE 5

| | |
|---|---|
| Hole Injection Layer/ Hole Transport Layer | 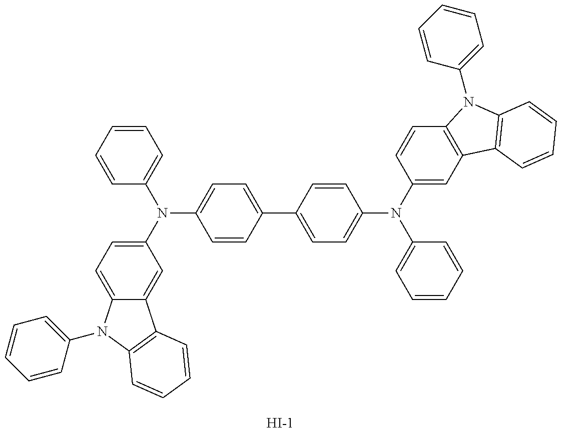 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; [I-]] |
| | 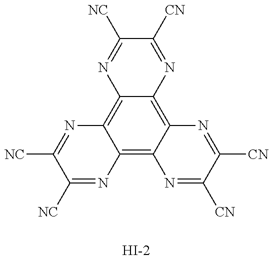 |
| | 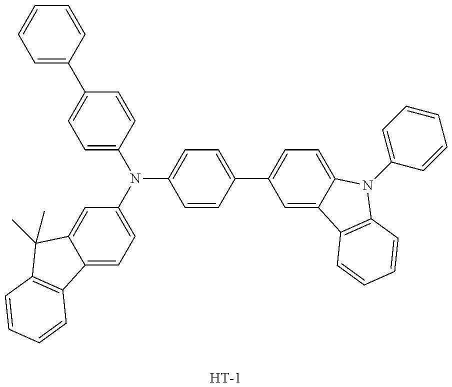 |
| | 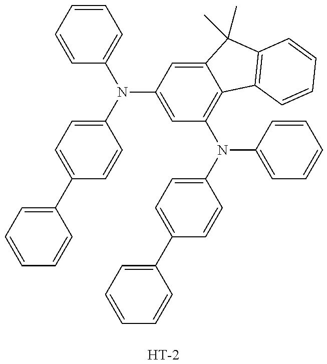 |
| | 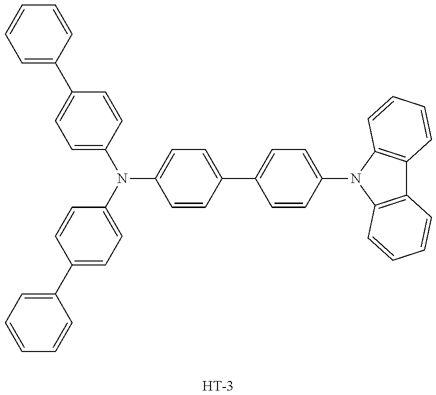 |
| | 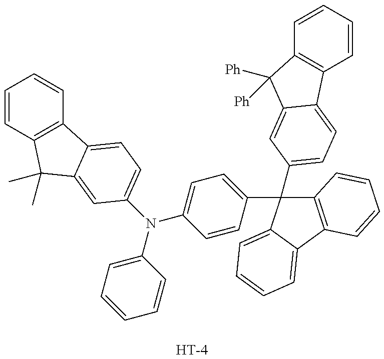 |
| Light-Emitting Layer | 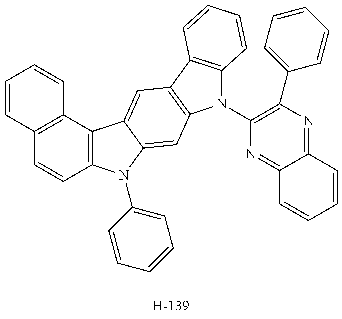 [SMILES: c1ccc(-c2nc3ccccc3nc2-n2c3ccccc3c3cc4c5c6ccccc6ccc5n(-c5ccccc5)c4cc32)cc1] |
| | 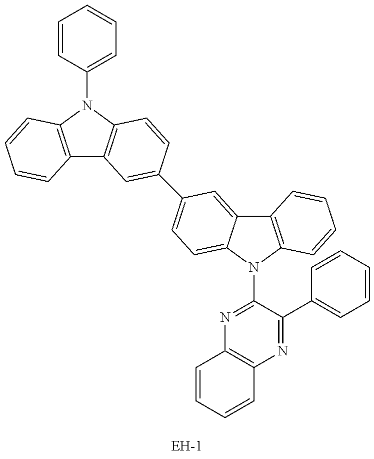 [SMILES: c1ccc(-c2nc3ccccc3nc2-n2c3ccccc3c3cc(-c4ccc5c(c4)c4ccccc4n5-c4ccccc4)ccc32)cc1] |
| | 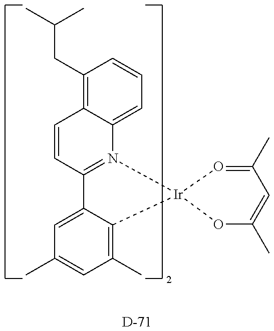 |
| Electron Buffer Layer/ Electron Transport Layer/Electron Injection Layer | 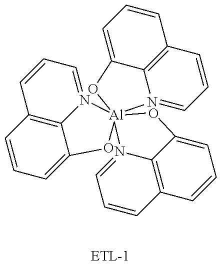 |
| | 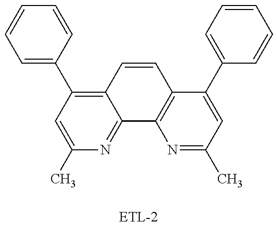 [SMILES: Cc1cc(-c2ccccc2)c2ccc3c(-c4ccccc4)cc(C)nc3c2n1] |
| | 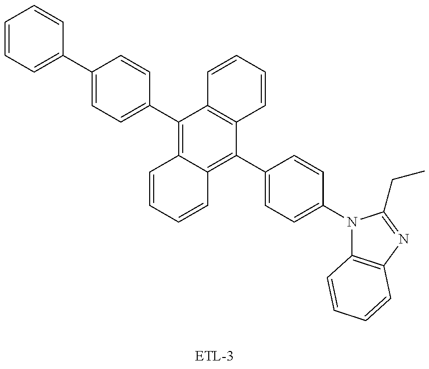 [SMILES: CCc1nc2ccccc2n1-c1ccc(-c2c3ccccc3c(-c3ccc(-c4ccccc4)cc3)c3ccccc23)cc1] |
| | 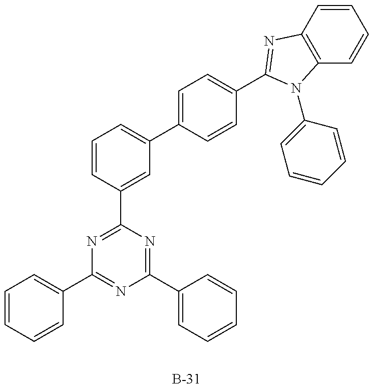 |
| | 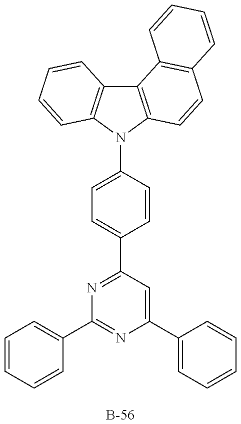 |
| | 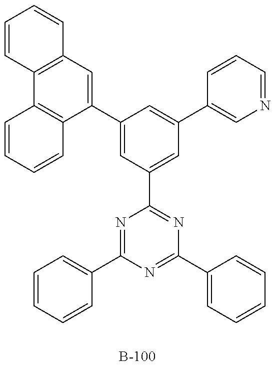 [SMILES: c1ccc(-c2nc(-c3ccccc3)nc(-c3cc(-c4cccnc4)cc(-c4cc5ccccc5c5ccccc45)c3)n2)cc1] |
| | 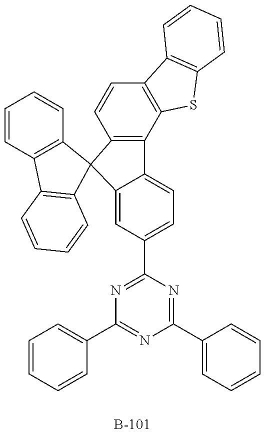 [SMILES: c1ccc(-c2nc(-c3ccccc3)nc(-c3ccc4c(c3)C3(c5ccccc5-c5ccccc53)c3ccc5c(sc6ccccc65)c3-4)n2)cc1] |
| | 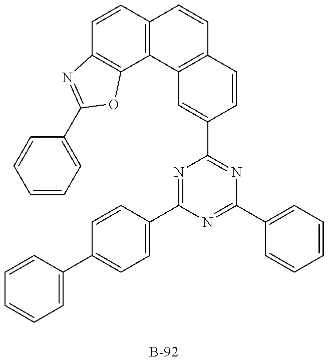 |
| | 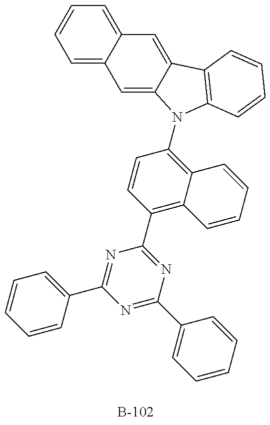 [SMILES: c1ccc(-c2nc(-c3ccccc3)nc(-c3ccc(-n4c5ccccc5c5cc6ccccc6cc54)c4ccccc34)n2)cc1] |
| | 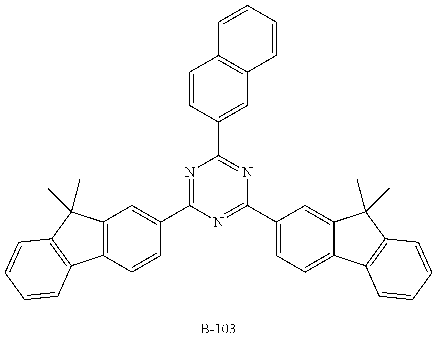 [SMILES: CC1(C)c2ccccc2-c2ccc(-c3nc(-c4ccc5c(c4)C(C)(C)c4ccccc4-5)nc(-c4ccc5ccccc5c4)n3)cc21] |
| | 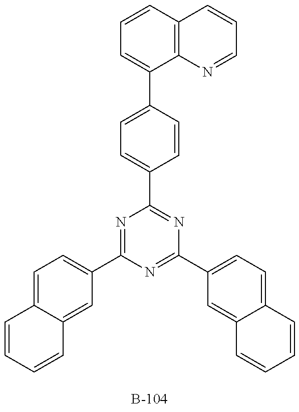 [SMILES: c1ccc2cc(-c3nc(-c4ccc(-c5cccc6cccnc56)cc4)nc(-c4ccc5ccccc5c4)n3)ccc2c1] |
| | 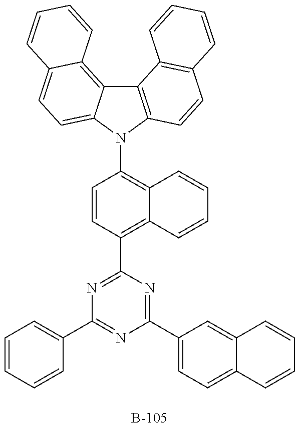 [SMILES: c1ccc(-c2nc(-c3ccc4ccccc4c3)nc(-c3ccc(-n4c5ccc6ccccc6c5c5c6ccccc6ccc54)c4ccccc34)n2)cc1] |
| | 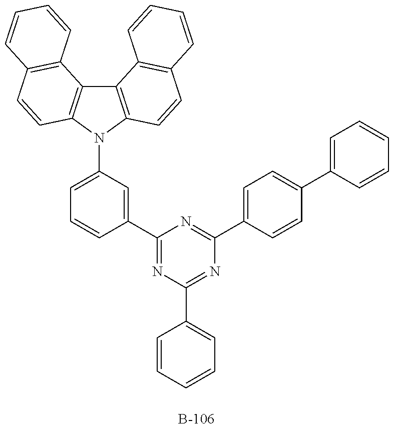 [SMILES: c1ccc(-c2ccc(-c3nc(-c4ccccc4)nc(-c4cccc(-n5c6ccc7ccccc7c6c6c7ccccc7ccc65)c4)n3)cc2)cc1] |
| | 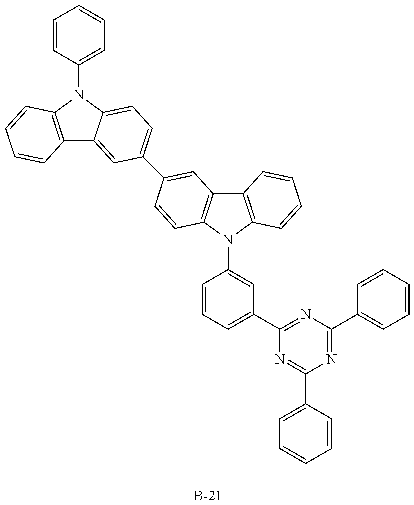 |
| | 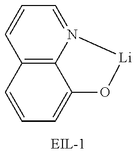 |

1. An organic electroluminescent device comprising a first electrode, a second electrode facing the first electrode, a light-emitting layer between the first electrode and the second electrode, and an electron transport zone between the light-emitting layer and the second electrode, wherein the light-emitting layer comprises a compound represented by the following formula 1: 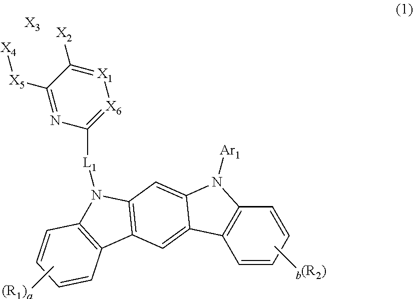
wherein,
L₁ represents a single bond, a substituted or unsubstituted (C₆-C₃₀)arylene, or a substituted or unsubstituted (5- to 30-membered)heteroarylene,
X₁ to X₆, each independently, represent N or CR₃, with a proviso that at least one of X₁ to X₆ represent N,
Ar₁ represents a substituted or unsubstituted (C6-C30)aryl, or a substituted or unsubstituted (5- to 30-membered)heteroaryl,
R₁ to R₃, each independently, represent hydrogen, deuterium, a halogen, a substituted or unsubstituted (C1-C30)alkyl, a substituted or unsubstituted (C6-C30)aryl, a substituted or unsubstituted (5- to 30-membered)heteroaryl, a substituted or unsubstituted (C3-C30)cycloalkyl, a substituted or unsubstituted (3- to 7-membered)heterocycloalkyl, a substituted or unsubstituted (C6-C30)aryl(C1-C30)alkyl, —NR₁₁R₁₂, —SiR₁₃R₁₄R₁₅, —SR₁₆, —OR₁₇, a cyano, a nitro, or a hydroxy, with a proviso that in at least one group of the adjacent two R₁ groups and the adjacent two R₂ groups, the adjacent two R₁ or the adjacent two R₂, each independently, are linked to form at least one substituted or unsubstituted benzene ring,
R₁₁ to R₁₇, each independently, represent hydrogen, deuterium, a halogen, a substituted or unsubstituted (C1-C30)alkyl, a substituted or unsubstituted (C6C30)aryl, a substituted or unsubstituted (5- to 30-membered)heteroaryl, a substituted or unsubstituted (3- to 7-membered)heterocycloalkyl, or a substituted or unsubstituted (C3-C30)cycloalkyl; or may be linked to an adjacent substituent to form a substituted or unsubstituted, mono- or polycyclic, (C3-C30) alicyclic or aromatic ring, or a combination of alicyclic and aromatic rings, whose carbon atom(s) may be replaced with at least one heteroatom selected from nitrogen, oxygen, and sulfur, and
a and b, each independently, represent an integer of 1 to 4, where if a and b, each independently, are an integer of 2 or more, each of R₁ and R₂ may be the same or different; and
the electron transport zone comprises a compound represented by the following formula 11:
wherein,
the electron transport zone comprises a compound represented by the following formula 11: 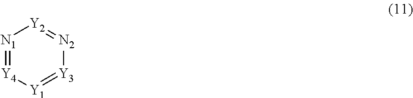
wherein,
N₁ and N₂, each independently, represent N or CR₁₈, with a proviso that at least one of N₁ and N₂ represent N,
Y₁ to Y₄, each independently, represent N or CR₁₉,
R₁₈ and R₁₉, each independently, represent hydrogen, deuterium, a halogen, a cyano, a substituted or unsubstituted (C1-C30)alkyl, a substituted or unsubstituted (C6-C50)aryl, a substituted or unsubstituted (3- to 50-membered)heteroaryl, a substituted or unsubstituted (C1-C30)cycloalkyl, a substituted or unsubstituted (3- to 7-membered)heterocycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di- (C1-C30)alkylamino, a substituted or unsubstituted mono- or di- (C6-C30)arylamino, or a substituted or unsubstituted (C1-C30)alkyl(C6-C30)arylamino; or may be linked to an adjacent substituent to form a substituted or unsubstituted, mono- or polycyclic, (C3-C30) alicyclic or aromatic ring, or a combination of alicyclic and aromatic rings, whose carbon atom(s) may be replaced with at least one heteroatom selected from nitrogen, oxygen, and sulfur,
the heteroaryl(ene) contains at least one heteroatom selected from B, N, O, S, Si, and P; and
the heterocycloalkyl contains at least one heteroatom selected from O, S, and N.

2. The organic electroluminescent device according to claim 1, wherein formula 1 is represented by any one of the following formulas 2 to 7: 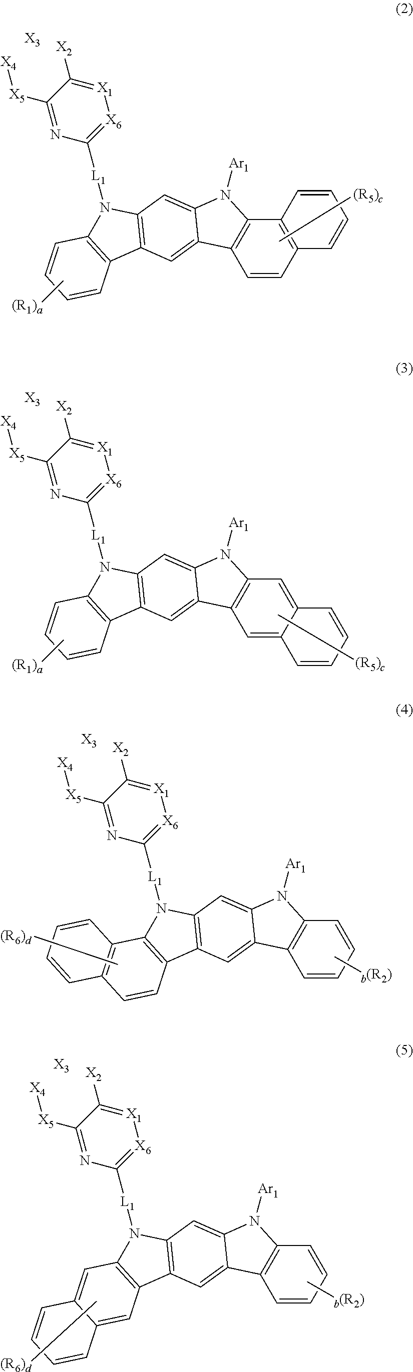 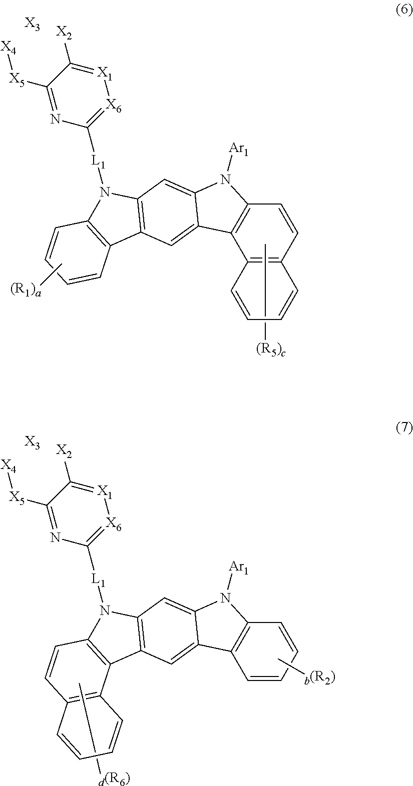
wherein,
L₁, Ar₁, R₁, R₂, X₁ to X₆a and b are as defined in formula 1,
R₅ and R₆ are each independently identical to the definition of R₁, and
c and d, each independently, represent an integer of 1 to 6, where if c and d, are an integer of 2 or more, each of R₅ and R₆ may be the same or different.

3. The organic electroluminescent device according to claim 1, wherein 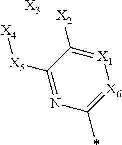
of formula 1 represents a substituted or unsubstituted quinoxalinyl, a substituted or unsubstituted quinazolinyl, a substituted or unsubstituted naphthyridinyl, a substituted or unsubstituted pyridopyrimidinyl, or a substituted or unsubstituted pyridopyrazinyl, in which * represents a bonding site with L₁.

4. The organic electroluminescent device according to claim 1, wherein formula 11 is represented by the following formula 12: 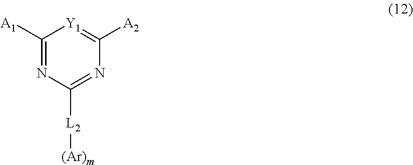
wherein,
Y₁ is as defined in formula 11,
A₁ and A₂ are each independently identical to the definition of R₁₉ of formula 11,
L₂ represents a single bond, a substituted or unsubstituted (C6-C50)arylene, or a substituted or unsubstituted (5- to 50-membered)heteroarylene,
Ar represents a substituted or unsubstituted (C6-C50)aryl, or a substituted or unsubstituted (5- to 50-membered)heteroaryl,
m represents 1 or 2, and
the heteroaryl(ene) contains at least one heteroatom selected from B, N, O, S, Si, and P.

5. The organic electroluminescent device according to claim 1, wherein substituents of the substituted alkyl, the substituted aryl(ene), the substituted heteroaryl(ene), the substituted cycloalkyl, the substituted heterocycloalkyl, the substituted alkoxy, the substituted trialkylsilyl, the substituted dialkylarylsilyl, the substituted alkyldiarylsilyl, the substituted triarylsilyl, the substituted mono- or di-alkylamino, the substituted mono- or di- arylamino, the substituted alkylarylamino, the substituted arylalkyl, the substituted benzene ring, and the substituted mono- or polycyclic, alicyclic or aromatic ring, or a combination of alicyclic and aromatic rings in L₁, Ar₁, R₁ to R₁, and R₁₁ to R₁₉, each independently, are at least one selected from the group consisting of deuterium; a halogen; a cyano; a carboxyl; a nitro; a hydroxyl; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (C3- to 7-membered)heterocycloalkyl; a (C6-C30)aryloxy; a (06-C30)arylthio; a (C6-C30)aryl unsubstituted or substituted with a (3- to 50-membered)heteroaryl; a (5- to 50-membered)heteroaryl unsubstituted or substituted with a (C1-C30)alkyl or a (C6-C30)aryl; a tri(C1-C30)alkylsilyl; a tri(C6-C30)arylsilyl; a di(C1-C30)alkyl(C6-C30)arylsilyl; a (C1-C30)alkyldi(C6-C30)arylsilyl; an amino; a mono- or di- (C1-C30)alkylamino; a mono- or di- (C6-C30)arylamino; a (C1-C30)alkyl(C6-C30)arylamino; a (C1-C30)alkylcarbonyl; a (C1-C30)alkoxycarbonyl; a (C6-C30)arylcarbonyl; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl.

6. The organic electroluminescent device according to claim 1, wherein the compound represented by formula 1 is at least one selected from the following compounds:

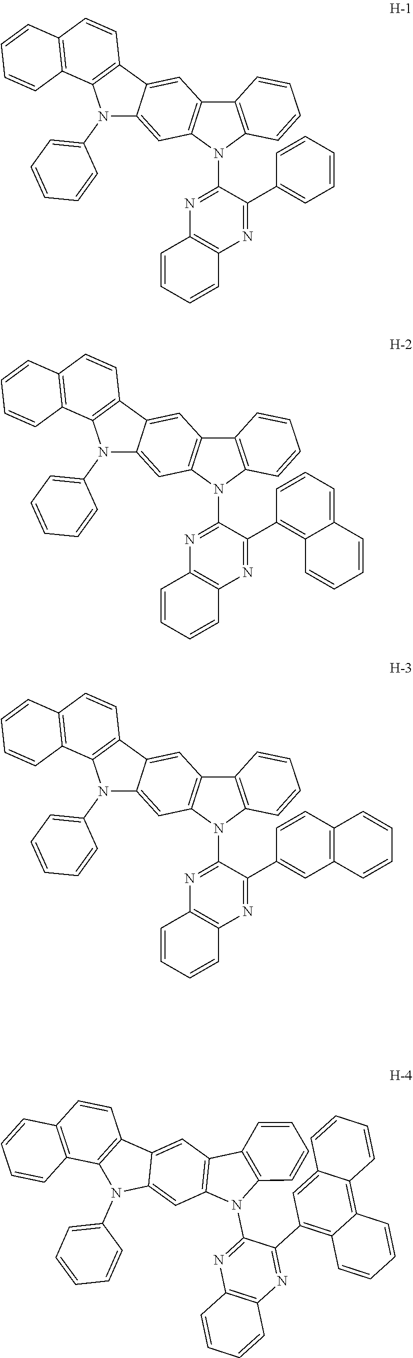 [SMILES: c1ccc(-c2nc3ccccc3nc2-n2c3ccccc3c3cc4c5ccc6ccccc6c5n(-c5ccccc5)c4cc32)cc1 ; c1ccc(-n2c3cc4c(cc3c3ccc5ccccc5c32)c2ccccc2n4-c2nc3ccccc3nc2-c2cccc3ccccc23)cc1 ; c1ccc(-n2c3cc4c(cc3c3ccc5ccccc5c32)c2ccccc2n4-c2nc3ccccc3nc2-c2ccc3ccccc3c2)cc1 ; c1ccc(-n2c3cc4c(cc3c3ccc5ccccc5c32)c2ccccc2n4-c2nc3ccccc3nc2-c2cc3ccccc3c3ccccc23)cc1]

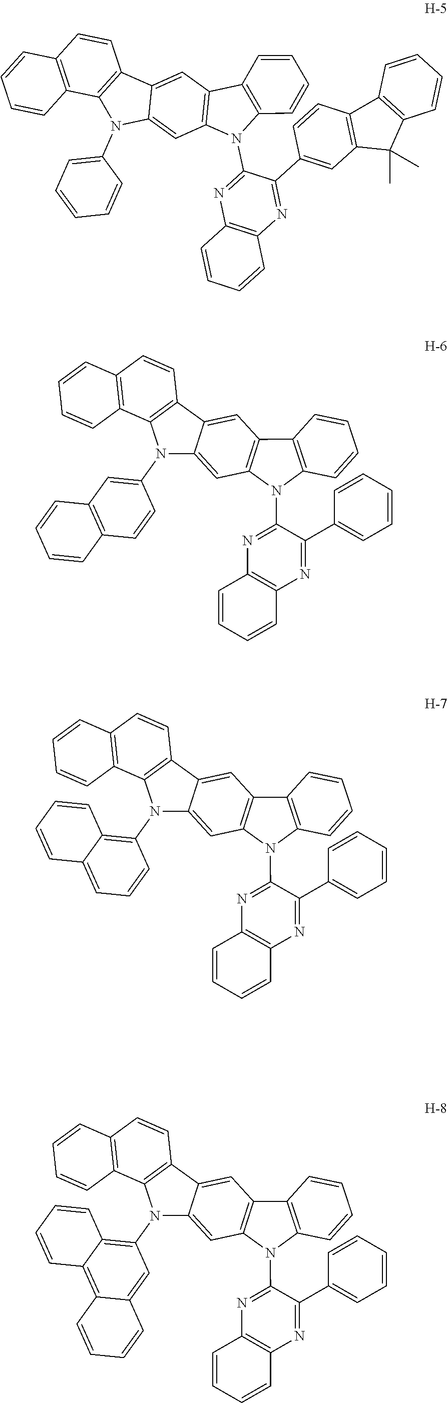 [SMILES: CC1(C)c2ccccc2-c2ccc(-c3nc4ccccc4nc3-n3c4ccccc4c4cc5c6ccc7ccccc7c6n(-c6ccccc6)c5cc43)cc21 ; c1ccc(-c2nc3ccccc3nc2-n2c3ccccc3c3cc4c5ccc6ccccc6c5n(-c5ccc6ccccc6c5)c4cc32)cc1 ; c1ccc(-c2nc3ccccc3nc2-n2c3ccccc3c3cc4c5ccc6ccccc6c5n(-c5cccc6ccccc56)c4cc32)cc1 ; c1ccc(-c2nc3ccccc3nc2-n2c3ccccc3c3cc4c5ccc6ccccc6c5n(-c5cc6ccccc6c6ccccc56)c4cc32)cc1]

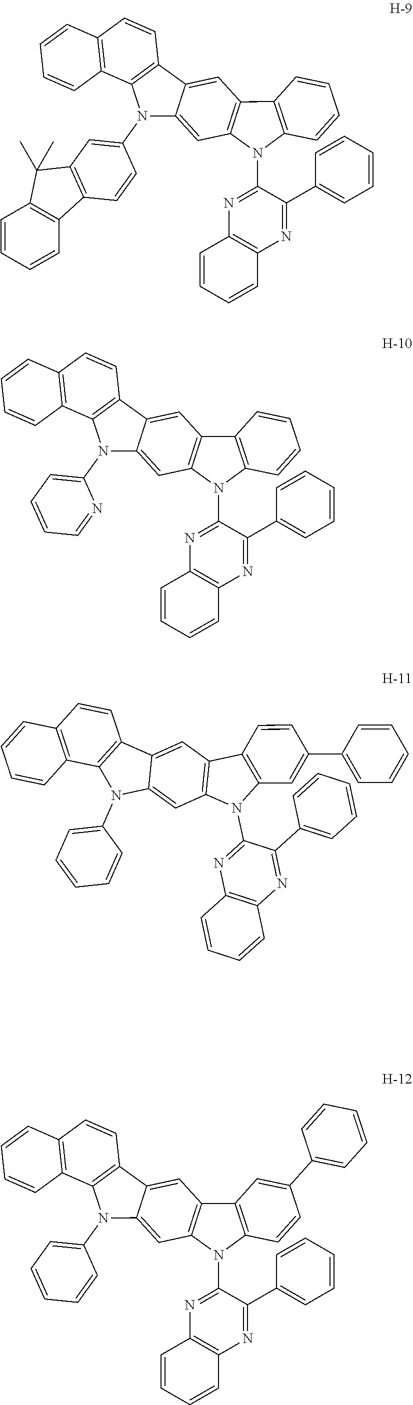 [SMILES: CC1(C)c2ccccc2-c2ccc(-n3c4cc5c(cc4c4ccc6ccccc6c43)c3ccccc3n5-c3nc4ccccc4nc3-c3ccccc3)cc21 ; c1ccc(-c2nc3ccccc3nc2-n2c3ccccc3c3cc4c5ccc6ccccc6c5n(-c5ccccn5)c4cc32)cc1 ; c1ccc(-c2ccc3c4cc5c6ccc7ccccc7c6n(-c6ccccc6)c5cc4n(-c4nc5ccccc5nc4-c4ccccc4)c3c2)cc1 ; c1ccc(-c2ccc3c(c2)c2cc4c5ccc6ccccc6c5n(-c5ccccc5)c4cc2n3-c2nc3ccccc3nc2-c2ccccc2)cc1]

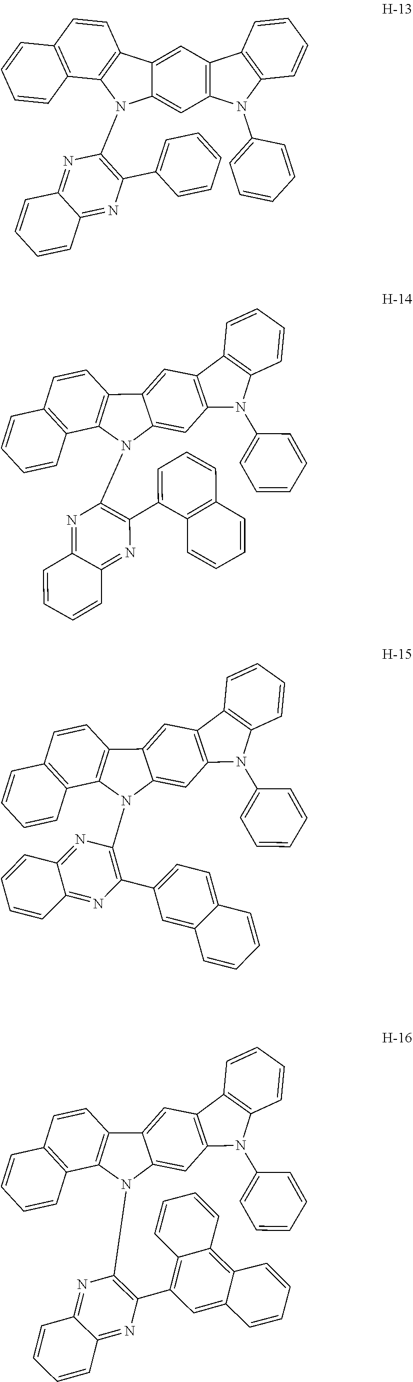 [SMILES: c1ccc(-c2nc3ccccc3nc2-n2c3cc4c(cc3c3ccc5ccccc5c32)c2ccccc2n4-c2ccccc2)cc1 ; c1ccc(-n2c3ccccc3c3cc4c5ccc6ccccc6c5n(-c5nc6ccccc6nc5-c5cccc6ccccc56)c4cc32)cc1 ; c1ccc(-n2c3ccccc3c3cc4c5ccc6ccccc6c5n(-c5nc6ccccc6nc5-c5ccc6ccccc6c5)c4cc32)cc1 ; c1ccc(-n2c3ccccc3c3cc4c5ccc6ccccc6c5n(-c5nc6ccccc6nc5-c5cc6ccccc6c6ccccc56)c4cc32)cc1]

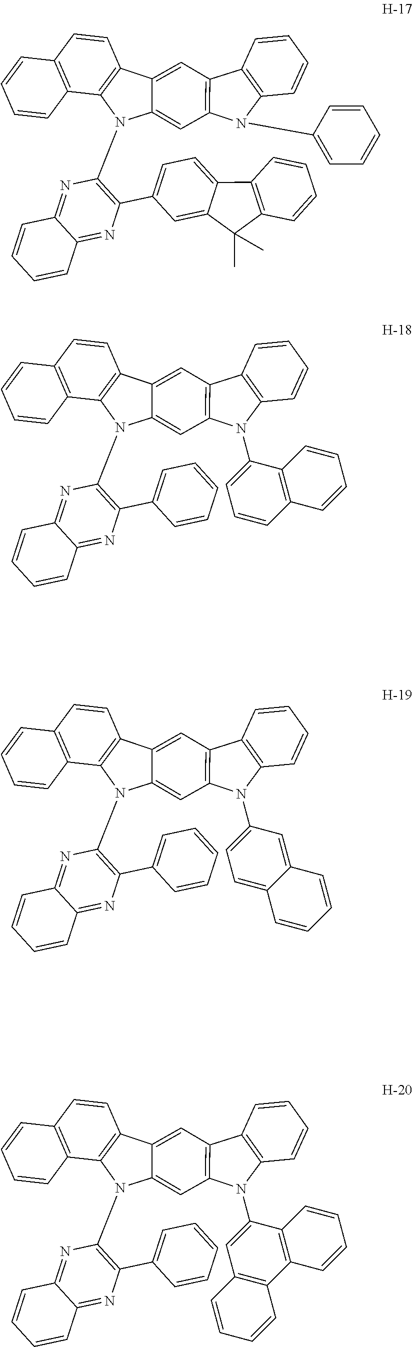 [SMILES: CC1(C)c2ccccc2-c2ccc(-c3nc4ccccc4nc3-n3c4cc5c(cc4c4ccc6ccccc6c43)c3ccccc3n5-c3ccccc3)cc21 ; c1ccc(-c2nc3ccccc3nc2-n2c3cc4c(cc3c3ccc5ccccc5c32)c2ccccc2n4-c2cccc3ccccc23)cc1 ; c1ccc(-c2nc3ccccc3nc2-n2c3cc4c(cc3c3ccc5ccccc5c32)c2ccccc2n4-c2ccc3ccccc3c2)cc1 ; c1ccc(-c2nc3ccccc3nc2-n2c3cc4c(cc3c3ccc5ccccc5c32)c2ccccc2n4-c2cc3ccccc3c3ccccc23)cc1]

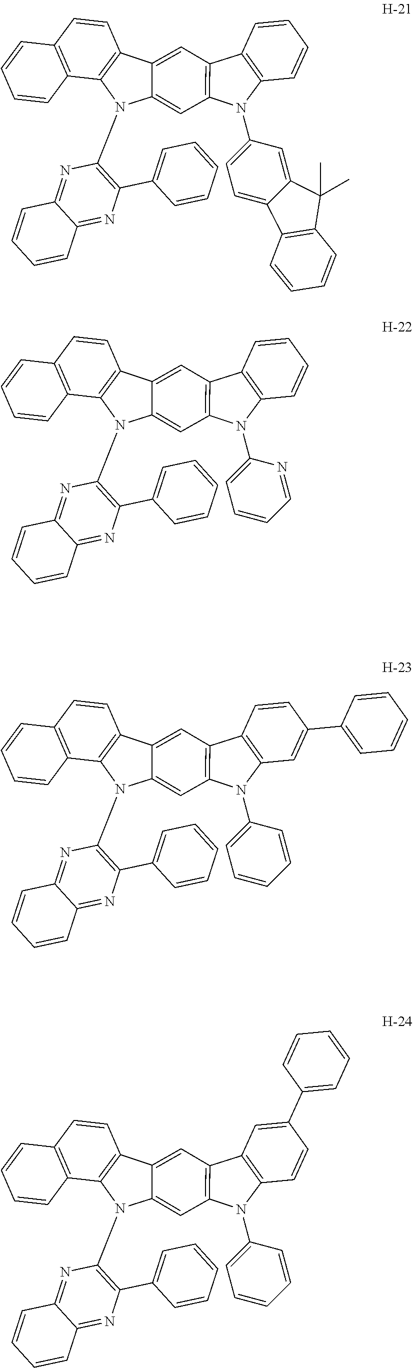 [SMILES: CC1(C)c2ccccc2-c2ccc(-n3c4ccccc4c4cc5c6ccc7ccccc7c6n(-c6nc7ccccc7nc6-c6ccccc6)c5cc43)cc21 ; c1ccc(-c2nc3ccccc3nc2-n2c3cc4c(cc3c3ccc5ccccc5c32)c2ccccc2n4-c2ccccn2)cc1 ; c1ccc(-c2ccc3c4cc5c6ccc7ccccc7c6n(-c6nc7ccccc7nc6-c6ccccc6)c5cc4n(-c4ccccc4)c3c2)cc1 ; c1ccc(-c2ccc3c(c2)c2cc4c5ccc6ccccc6c5n(-c5nc6ccccc6nc5-c5ccccc5)c4cc2n3-c2ccccc2)cc1]

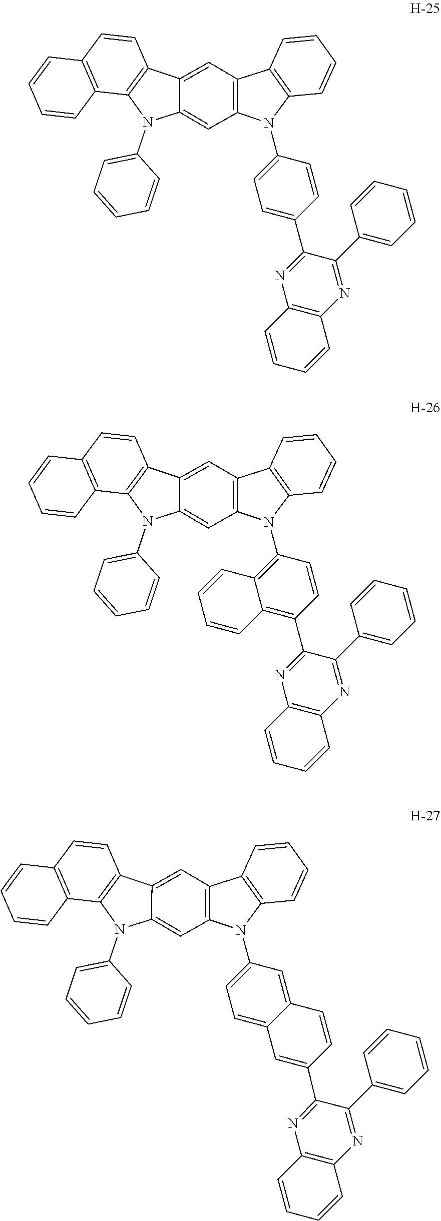 [SMILES: c1ccc(-c2nc3ccccc3nc2-c2ccc(-n3c4ccccc4c4cc5c6ccc7ccccc7c6n(-c6ccccc6)c5cc43)cc2)cc1 ; c1ccc(-c2nc3ccccc3nc2-c2ccc(-n3c4ccccc4c4cc5c6ccc7ccccc7c6n(-c6ccccc6)c5cc43)c3ccccc23)cc1 ; c1ccc(-c2nc3ccccc3nc2-c2ccc3cc(-n4c5ccccc5c5cc6c7ccc8ccccc8c7n(-c7ccccc7)c6cc54)ccc3c2)cc1]

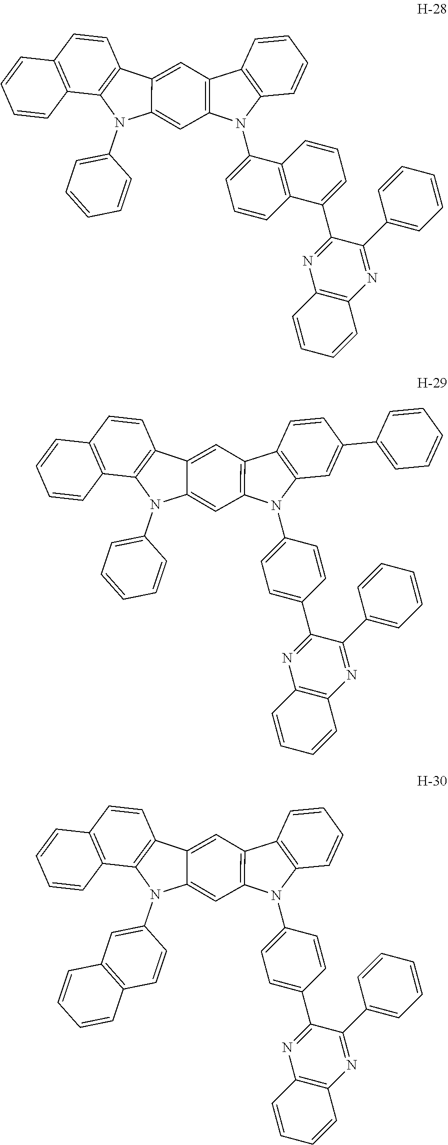 [SMILES: c1ccc(-c2nc3ccccc3nc2-c2cccc3c(-n4c5ccccc5c5cc6c7ccc8ccccc8c7n(-c7ccccc7)c6cc54)cccc23)cc1 ; c1ccc(-c2ccc3c4cc5c6ccc7ccccc7c6n(-c6ccccc6)c5cc4n(-c4ccc(-c5nc6ccccc6nc5-c5ccccc5)cc4)c3c2)cc1 ; c1ccc(-c2nc3ccccc3nc2-c2ccc(-n3c4ccccc4c4cc5c6ccc7ccccc7c6n(-c6ccc7ccccc7c6)c5cc43)cc2)cc1]

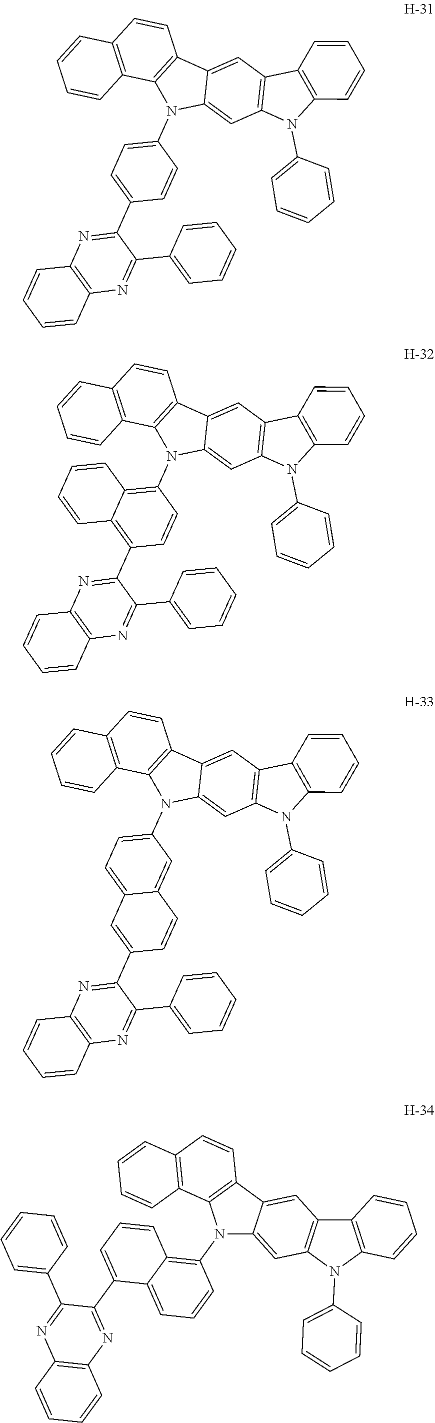 [SMILES: c1ccc(-c2nc3ccccc3nc2-c2ccc(-n3c4cc5c(cc4c4ccc6ccccc6c43)c3ccccc3n5-c3ccccc3)cc2)cc1 ; c1ccc(-c2nc3ccccc3nc2-c2ccc(-n3c4cc5c(cc4c4ccc6ccccc6c43)c3ccccc3n5-c3ccccc3)c3ccccc23)cc1 ; c1ccc(-c2nc3ccccc3nc2-c2ccc3cc(-n4c5cc6c(cc5c5ccc7ccccc7c54)c4ccccc4n6-c4ccccc4)ccc3c2)cc1 ; c1ccc(-c2nc3ccccc3nc2-c2cccc3c(-n4c5cc6c(cc5c5ccc7ccccc7c54)c4ccccc4n6-c4ccccc4)cccc23)cc1]

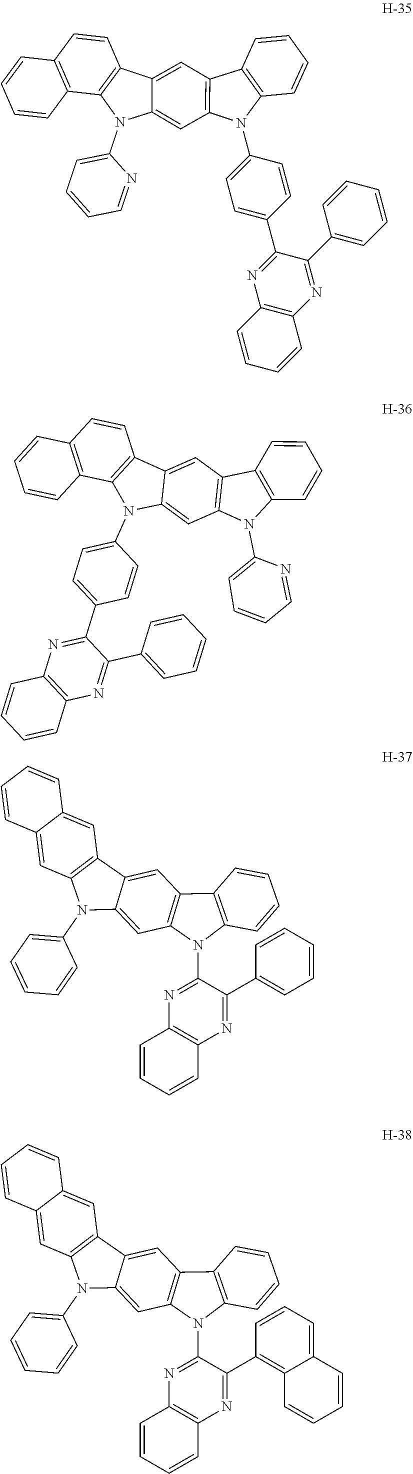

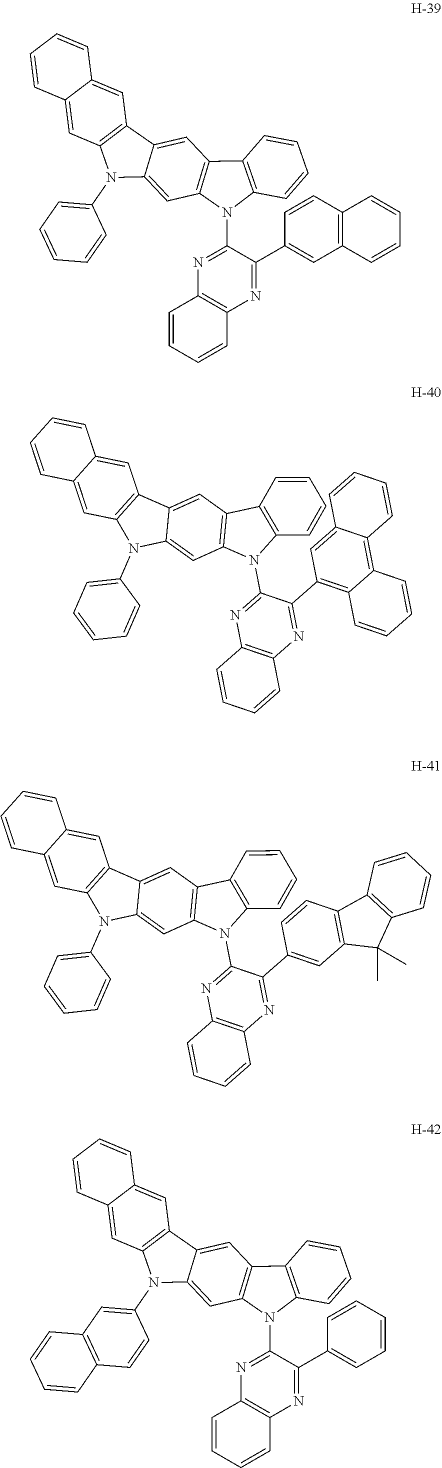 [SMILES: c1ccc(-n2c3cc4ccccc4cc3c3cc4c5ccccc5n(-c5nc6ccccc6nc5-c5ccc6ccccc6c5)c4cc32)cc1 ; c1ccc(-n2c3cc4ccccc4cc3c3cc4c5ccccc5n(-c5nc6ccccc6nc5-c5cc6ccccc6c6ccccc56)c4cc32)cc1 ; CC1(C)c2ccccc2-c2ccc(-c3nc4ccccc4nc3-n3c4ccccc4c4cc5c6cc7ccccc7cc6n(-c6ccccc6)c5cc43)cc21 ; c1ccc(-c2nc3ccccc3nc2-n2c3ccccc3c3cc4c5cc6ccccc6cc5n(-c5ccc6ccccc6c5)c4cc32)cc1]

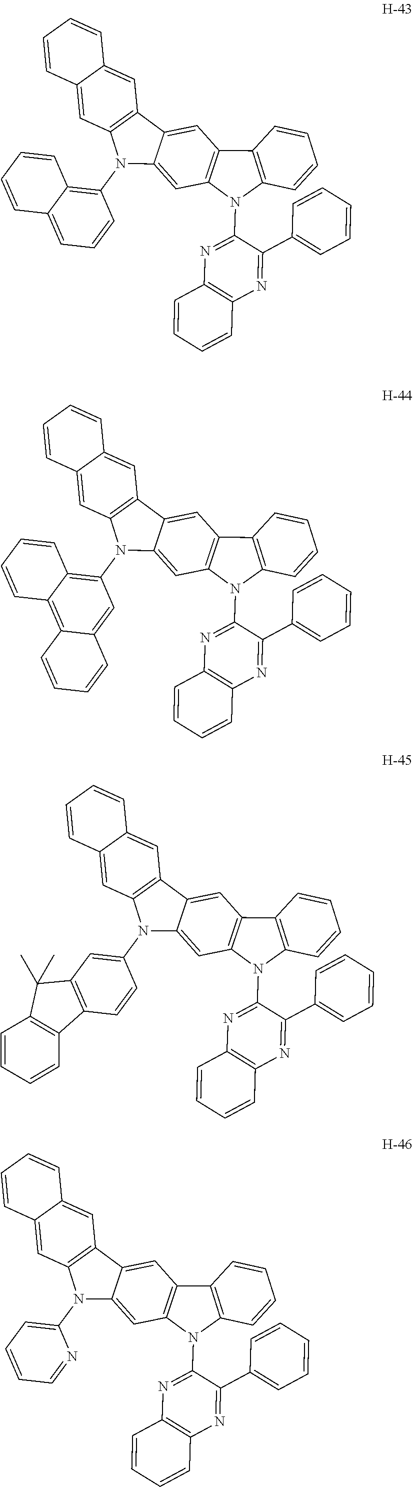 [SMILES: c1ccc(-c2nc3ccccc3nc2-n2c3ccccc3c3cc4c5cc6ccccc6cc5n(-c5cccc6ccccc56)c4cc32)cc1 ; c1ccc(-c2nc3ccccc3nc2-n2c3ccccc3c3cc4c5cc6ccccc6cc5n(-c5cc6ccccc6c6ccccc56)c4cc32)cc1 ; CC1(C)c2ccccc2-c2ccc(-n3c4cc5ccccc5cc4c4cc5c6ccccc6n(-c6nc7ccccc7nc6-c6ccccc6)c5cc43)cc21 ; c1ccc(-c2nc3ccccc3nc2-n2c3ccccc3c3cc4c5cc6ccccc6cc5n(-c5ccccn5)c4cc32)cc1]

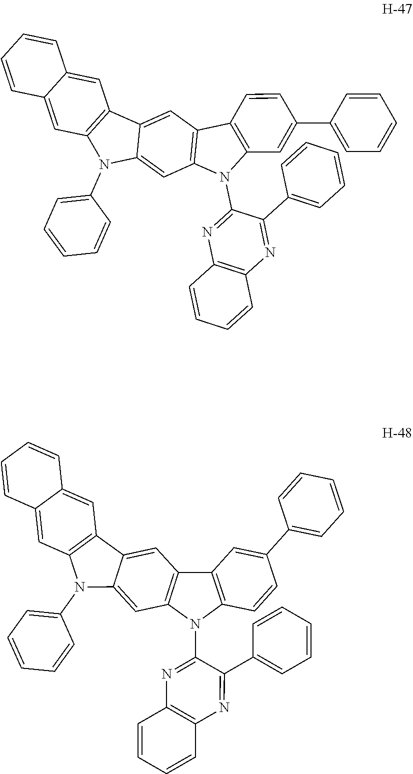 [SMILES: c1ccc(-c2ccc3c4cc5c6cc7ccccc7cc6n(-c6ccccc6)c5cc4n(-c4nc5ccccc5nc4-c4ccccc4)c3c2)cc1 ; c1ccc(-c2ccc3c(c2)c2cc4c5cc6ccccc6cc5n(-c5ccccc5)c4cc2n3-c2nc3ccccc3nc2-c2ccccc2)cc1]

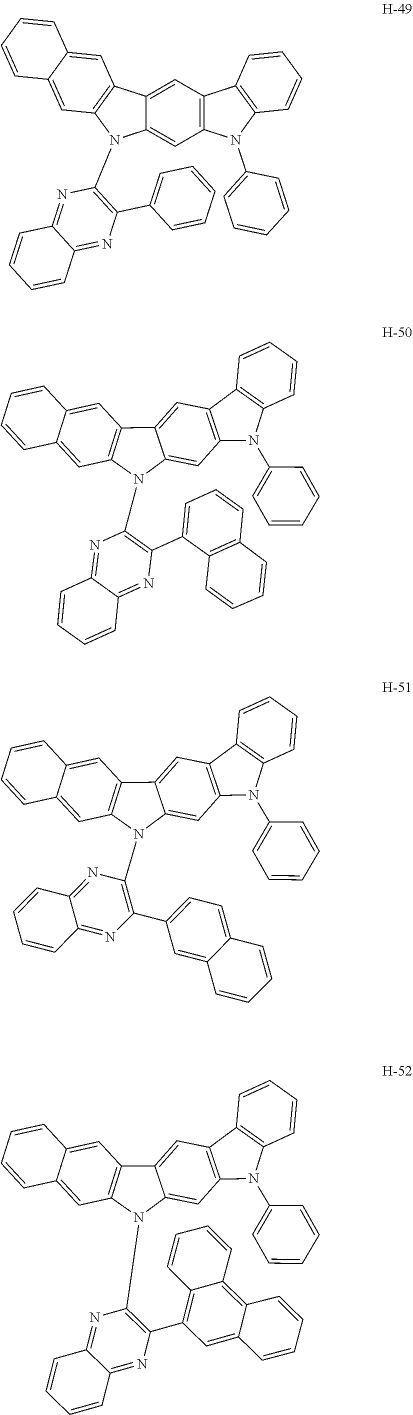 [SMILES: c1ccc(-c2nc3ccccc3nc2-n2c3cc4ccccc4cc3c3cc4c5ccccc5n(-c5ccccc5)c4cc32)cc1 ; c1ccc(-n2c3ccccc3c3cc4c5cc6ccccc6cc5n(-c5nc6ccccc6nc5-c5cccc6ccccc56)c4cc32)cc1 ; c1ccc(-n2c3ccccc3c3cc4c5cc6ccccc6cc5n(-c5nc6ccccc6nc5-c5ccc6ccccc6c5)c4cc32)cc1 ; c1ccc(-n2c3ccccc3c3cc4c5cc6ccccc6cc5n(-c5nc6ccccc6nc5-c5cc6ccccc6c6ccccc56)c4cc32)cc1]

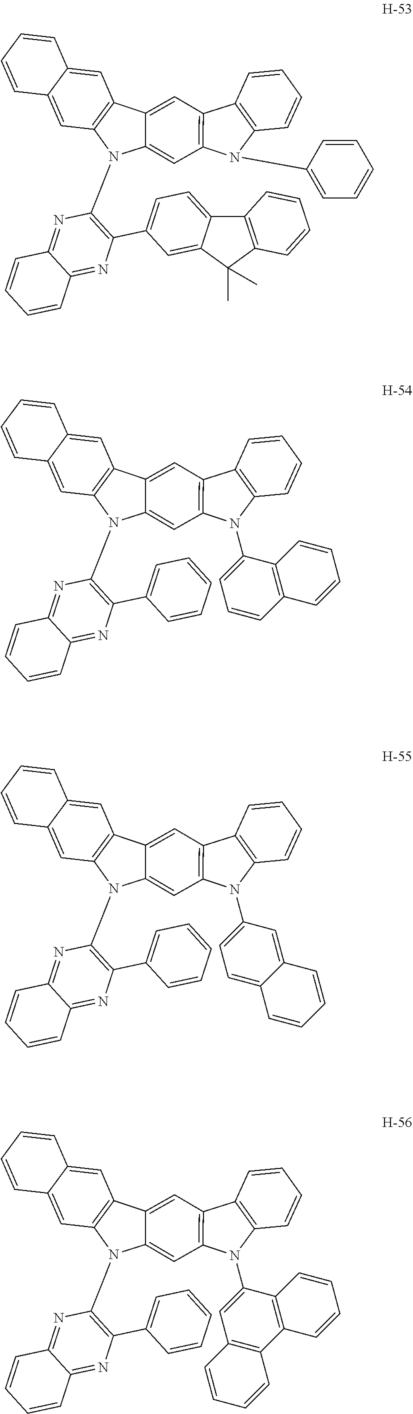 [SMILES: CC1(C)c2ccccc2-c2ccc(-c3nc4ccccc4nc3-n3c4cc5ccccc5cc4c4cc5c6ccccc6n(-c6ccccc6)c5cc43)cc21 ; c1ccc(-c2nc3ccccc3nc2-n2c3cc4ccccc4cc3c3cc4c5ccccc5n(-c5cccc6ccccc56)c4cc32)cc1 ; c1ccc(-c2nc3ccccc3nc2-n2c3cc4ccccc4cc3c3cc4c5ccccc5n(-c5ccc6ccccc6c5)c4cc32)cc1 ; c1ccc(-c2nc3ccccc3nc2-n2c3cc4ccccc4cc3c3cc4c5ccccc5n(-c5cc6ccccc6c6ccccc56)c4cc32)cc1]

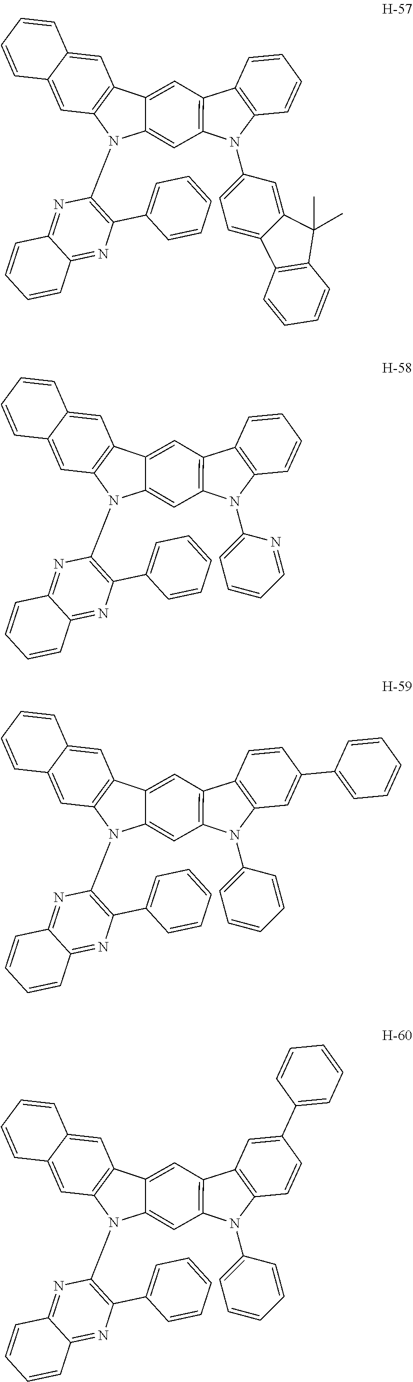 [SMILES: CC1(C)c2ccccc2-c2ccc(-n3c4ccccc4c4cc5c6cc7ccccc7cc6n(-c6nc7ccccc7nc6-c6ccccc6)c5cc43)cc21 ; c1ccc(-c2nc3ccccc3nc2-n2c3cc4ccccc4cc3c3cc4c5ccccc5n(-c5ccccn5)c4cc32)cc1 ; c1ccc(-c2ccc3c4cc5c6cc7ccccc7cc6n(-c6nc7ccccc7nc6-c6ccccc6)c5cc4n(-c4ccccc4)c3c2)cc1 ; c1ccc(-c2ccc3c(c2)c2cc4c5cc6ccccc6cc5n(-c5nc6ccccc6nc5-c5ccccc5)c4cc2n3-c2ccccc2)cc1]

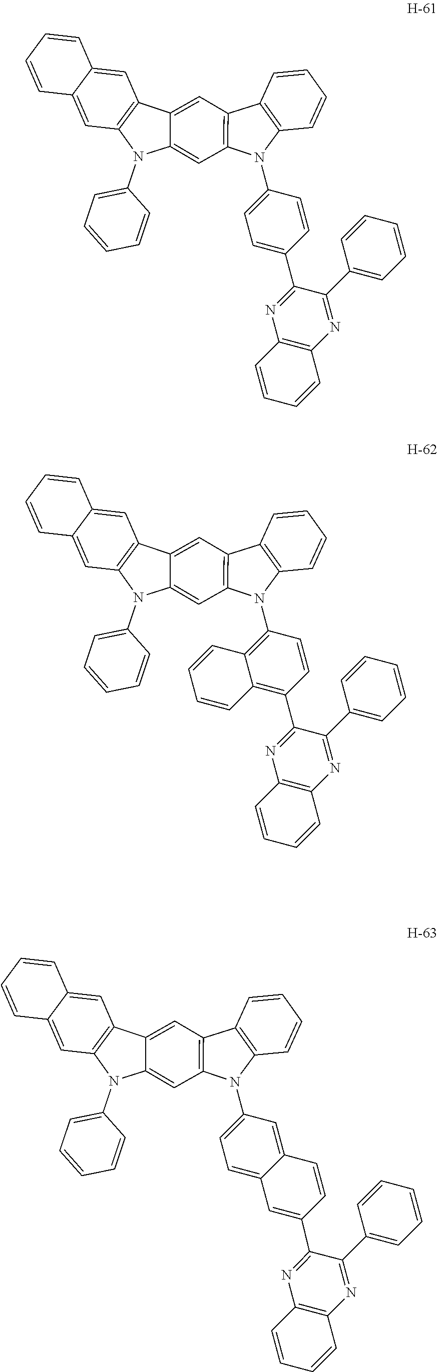 [SMILES: c1ccc(-c2nc3ccccc3nc2-c2ccc(-n3c4ccccc4c4cc5c6cc7ccccc7cc6n(-c6ccccc6)c5cc43)cc2)cc1 ; c1ccc(-c2nc3ccccc3nc2-c2ccc(-n3c4ccccc4c4cc5c6cc7ccccc7cc6n(-c6ccccc6)c5cc43)c3ccccc23)cc1 ; c1ccc(-c2nc3ccccc3nc2-c2ccc3cc(-n4c5ccccc5c5cc6c7cc8ccccc8cc7n(-c7ccccc7)c6cc54)ccc3c2)cc1]

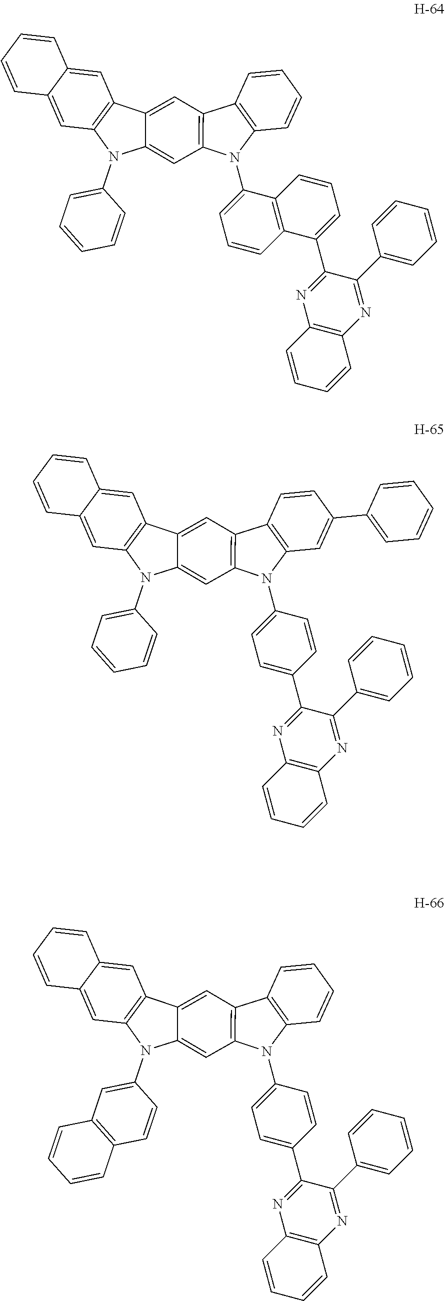 [SMILES: c1ccc(-c2nc3ccccc3nc2-c2cccc3c(-n4c5ccccc5c5cc6c7cc8ccccc8cc7n(-c7ccccc7)c6cc54)cccc23)cc1 ; c1ccc(-c2ccc3c4cc5c6cc7ccccc7cc6n(-c6ccccc6)c5cc4n(-c4ccc(-c5nc6ccccc6nc5-c5ccccc5)cc4)c3c2)cc1 ; c1ccc(-c2nc3ccccc3nc2-c2ccc(-n3c4ccccc4c4cc5c6cc7ccccc7cc6n(-c6ccc7ccccc7c6)c5cc43)cc2)cc1]

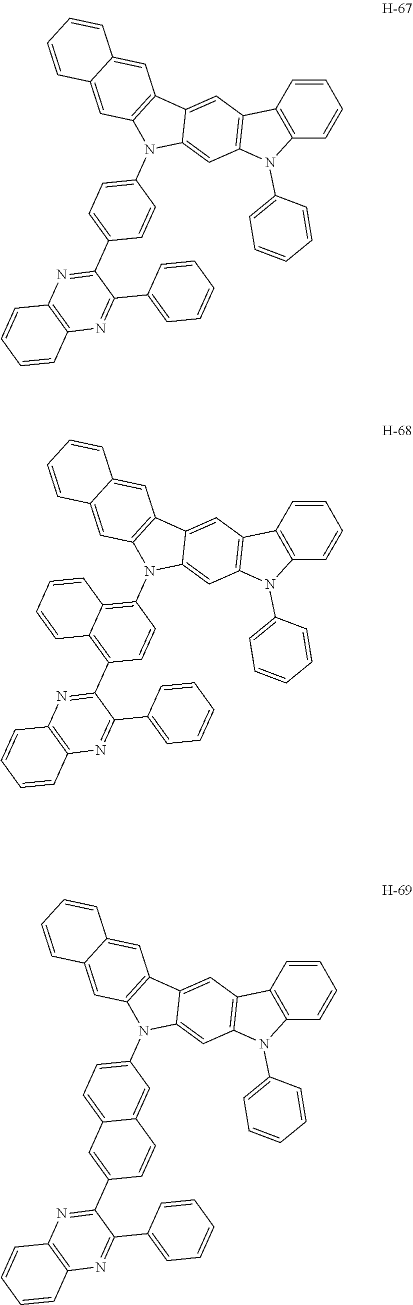 [SMILES: c1ccc(-c2nc3ccccc3nc2-c2ccc(-n3c4cc5ccccc5cc4c4cc5c6ccccc6n(-c6ccccc6)c5cc43)cc2)cc1 ; c1ccc(-c2nc3ccccc3nc2-c2ccc(-n3c4cc5ccccc5cc4c4cc5c6ccccc6n(-c6ccccc6)c5cc43)c3ccccc23)cc1 ; c1ccc(-c2nc3ccccc3nc2-c2ccc3cc(-n4c5cc6ccccc6cc5c5cc6c7ccccc7n(-c7ccccc7)c6cc54)ccc3c2)cc1]

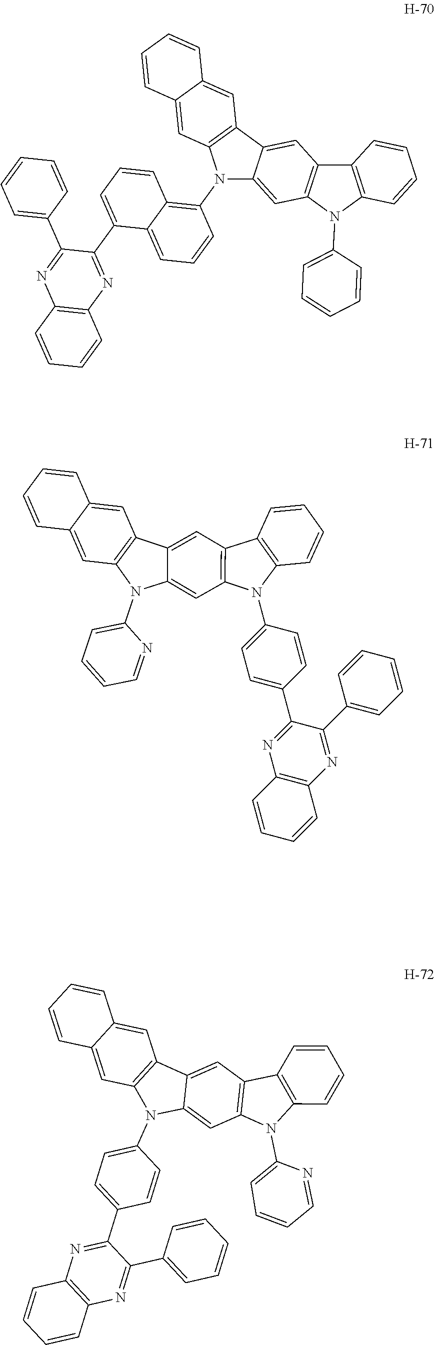 [SMILES: c1ccc(-c2nc3ccccc3nc2-c2cccc3c(-n4c5cc6ccccc6cc5c5cc6c7ccccc7n(-c7ccccc7)c6cc54)cccc23)cc1 ; c1ccc(-c2nc3ccccc3nc2-c2ccc(-n3c4ccccc4c4cc5c6cc7ccccc7cc6n(-c6ccccn6)c5cc43)cc2)cc1 ; c1ccc(-c2nc3ccccc3nc2-c2ccc(-n3c4cc5ccccc5cc4c4cc5c6ccccc6n(-c6ccccn6)c5cc43)cc2)cc1]

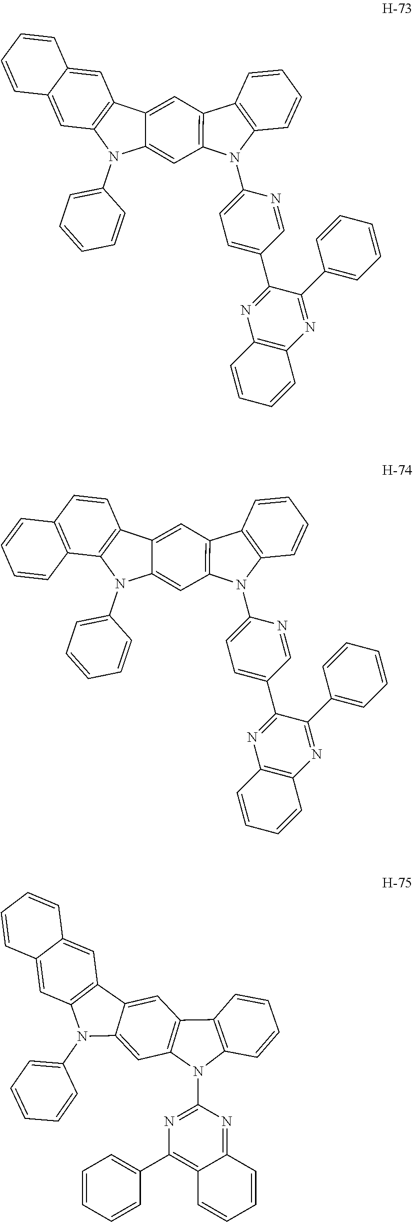 [SMILES: c1ccc(-c2nc3ccccc3nc2-c2ccc(-n3c4ccccc4c4cc5c6cc7ccccc7cc6n(-c6ccccc6)c5cc43)nc2)cc1 ; c1ccc(-c2nc3ccccc3nc2-c2ccc(-n3c4ccccc4c4cc5c6ccc7ccccc7c6n(-c6ccccc6)c5cc43)nc2)cc1 ; c1ccc(-c2nc(-n3c4ccccc4c4cc5c6cc7ccccc7cc6n(-c6ccccc6)c5cc43)nc3ccccc23)cc1]

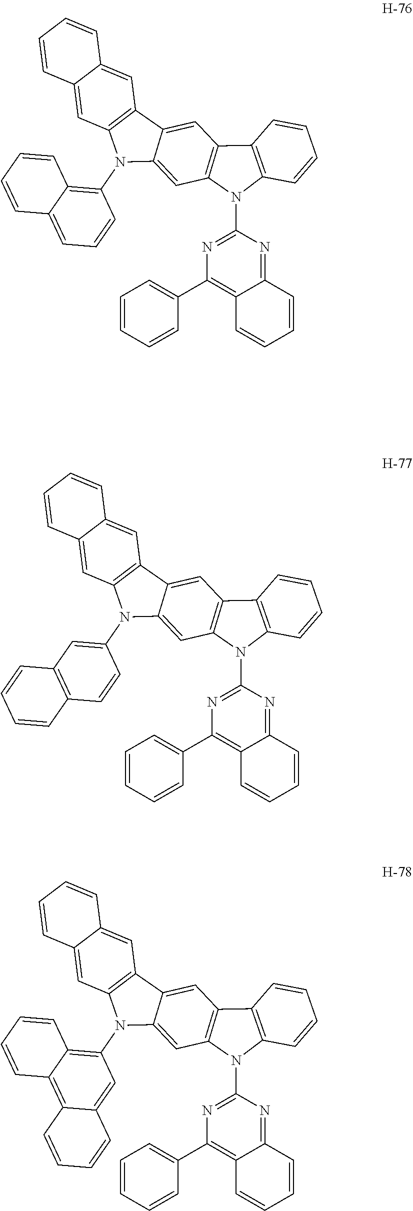 [SMILES: c1ccc(-c2nc(-n3c4ccccc4c4cc5c6cc7ccccc7cc6n(-c6cccc7ccccc67)c5cc43)nc3ccccc23)cc1 ; c1ccc(-c2nc(-n3c4ccccc4c4cc5c6cc7ccccc7cc6n(-c6ccc7ccccc7c6)c5cc43)nc3ccccc23)cc1 ; c1ccc(-c2nc(-n3c4ccccc4c4cc5c6cc7ccccc7cc6n(-c6cc7ccccc7c7ccccc67)c5cc43)nc3ccccc23)cc1]

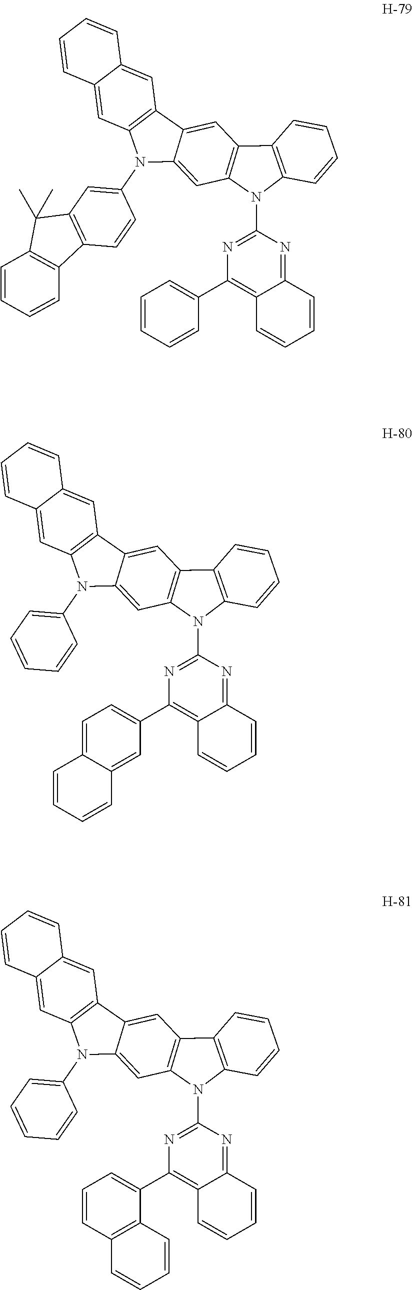 [SMILES: CC1(C)c2ccccc2-c2ccc(-n3c4cc5ccccc5cc4c4cc5c6ccccc6n(-c6nc(-c7ccccc7)c7ccccc7n6)c5cc43)cc21 ; c1ccc(-n2c3cc4ccccc4cc3c3cc4c5ccccc5n(-c5nc(-c6ccc7ccccc7c6)c6ccccc6n5)c4cc32)cc1 ; c1ccc(-n2c3cc4ccccc4cc3c3cc4c5ccccc5n(-c5nc(-c6cccc7ccccc67)c6ccccc6n5)c4cc32)cc1]

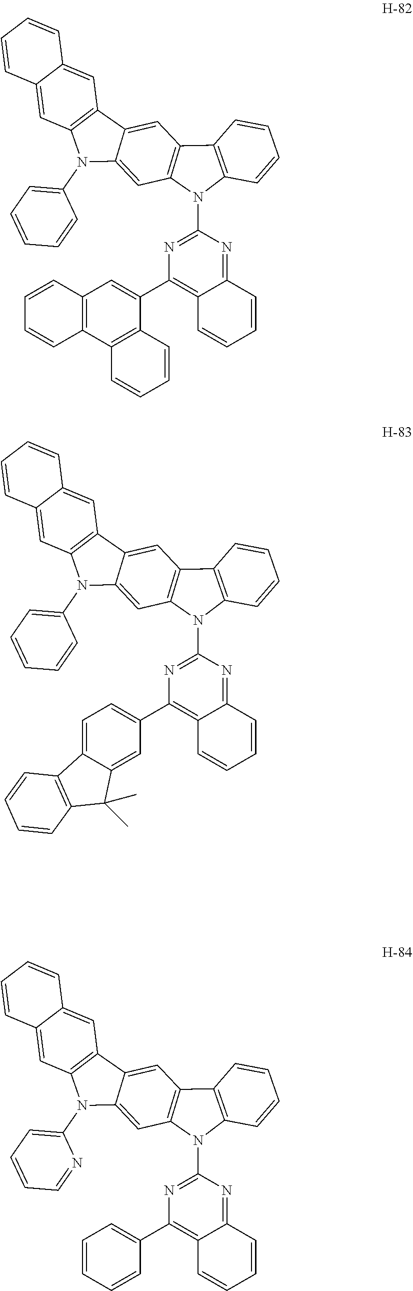 [SMILES: c1ccc(-n2c3cc4ccccc4cc3c3cc4c5ccccc5n(-c5nc(-c6cc7ccccc7c7ccccc67)c6ccccc6n5)c4cc32)cc1 ; CC1(C)c2ccccc2-c2ccc(-c3nc(-n4c5ccccc5c5cc6c7cc8ccccc8cc7n(-c7ccccc7)c6cc54)nc4ccccc34)cc21 ; c1ccc(-c2nc(-n3c4ccccc4c4cc5c6cc7ccccc7cc6n(-c6ccccn6)c5cc43)nc3ccccc23)cc1]

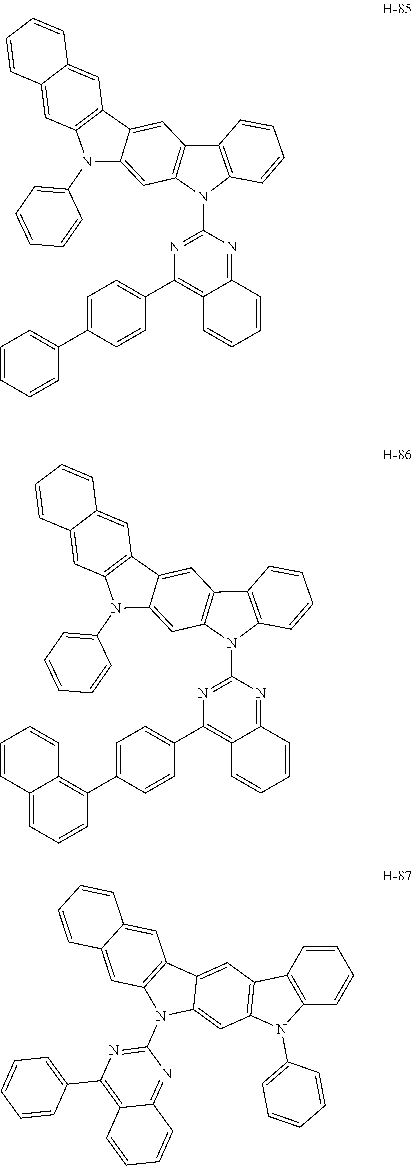 [SMILES: c1ccc(-c2ccc(-c3nc(-n4c5ccccc5c5cc6c7cc8ccccc8cc7n(-c7ccccc7)c6cc54)nc4ccccc34)cc2)cc1 ; c1ccc(-n2c3cc4ccccc4cc3c3cc4c5ccccc5n(-c5nc(-c6ccc(-c7cccc8ccccc78)cc6)c6ccccc6n5)c4cc32)cc1 ; c1ccc(-c2nc(-n3c4cc5ccccc5cc4c4cc5c6ccccc6n(-c6ccccc6)c5cc43)nc3ccccc23)cc1]

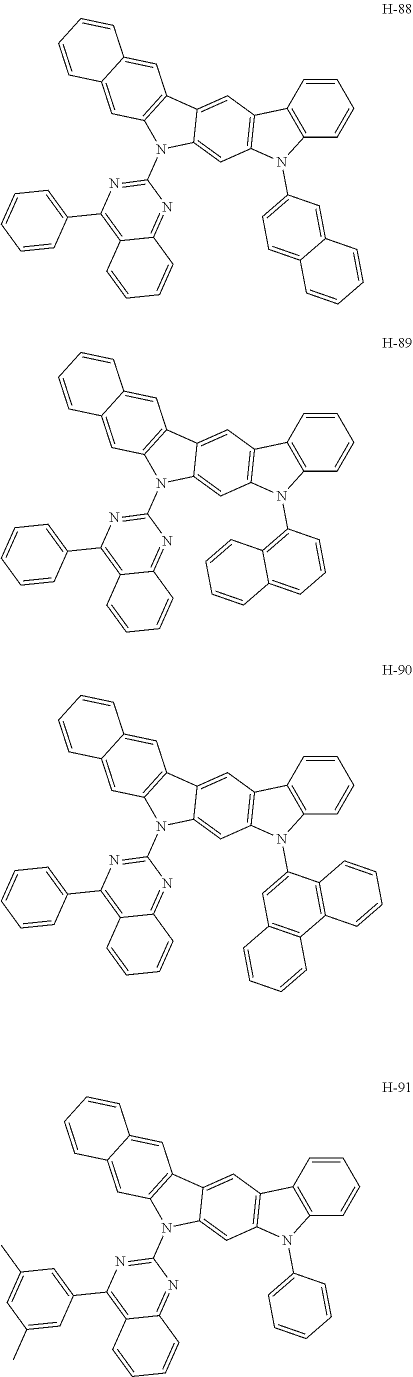 [SMILES: c1ccc(-c2nc(-n3c4cc5ccccc5cc4c4cc5c6ccccc6n(-c6ccc7ccccc7c6)c5cc43)nc3ccccc23)cc1 ; c1ccc(-c2nc(-n3c4cc5ccccc5cc4c4cc5c6ccccc6n(-c6cccc7ccccc67)c5cc43)nc3ccccc23)cc1 ; c1ccc(-c2nc(-n3c4cc5ccccc5cc4c4cc5c6ccccc6n(-c6cc7ccccc7c7ccccc67)c5cc43)nc3ccccc23)cc1 ; Cc1cc(C)cc(-c2nc(-n3c4cc5ccccc5cc4c4cc5c6ccccc6n(-c6ccccc6)c5cc43)nc3ccccc23)c1]

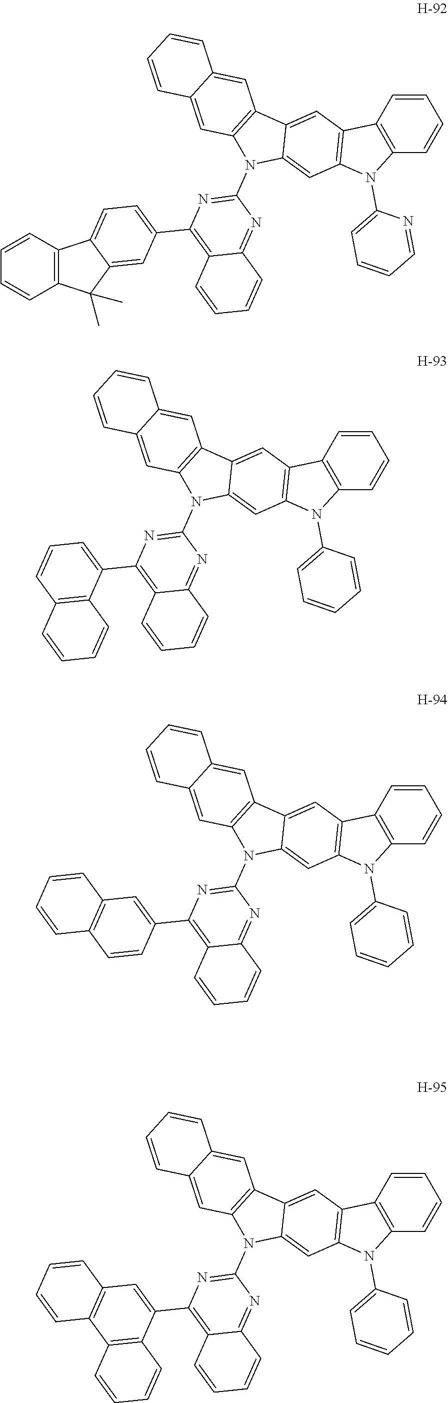 [SMILES: CC1(C)c2ccccc2-c2ccc(-c3nc(-n4c5cc6ccccc6cc5c5cc6c7ccccc7n(-c7ccccn7)c6cc54)nc4ccccc34)cc21 ; c1ccc(-n2c3ccccc3c3cc4c5cc6ccccc6cc5n(-c5nc(-c6cccc7ccccc67)c6ccccc6n5)c4cc32)cc1 ; c1ccc(-n2c3ccccc3c3cc4c5cc6ccccc6cc5n(-c5nc(-c6ccc7ccccc7c6)c6ccccc6n5)c4cc32)cc1 ; c1ccc(-n2c3ccccc3c3cc4c5cc6ccccc6cc5n(-c5nc(-c6cc7ccccc7c7ccccc67)c6ccccc6n5)c4cc32)cc1]

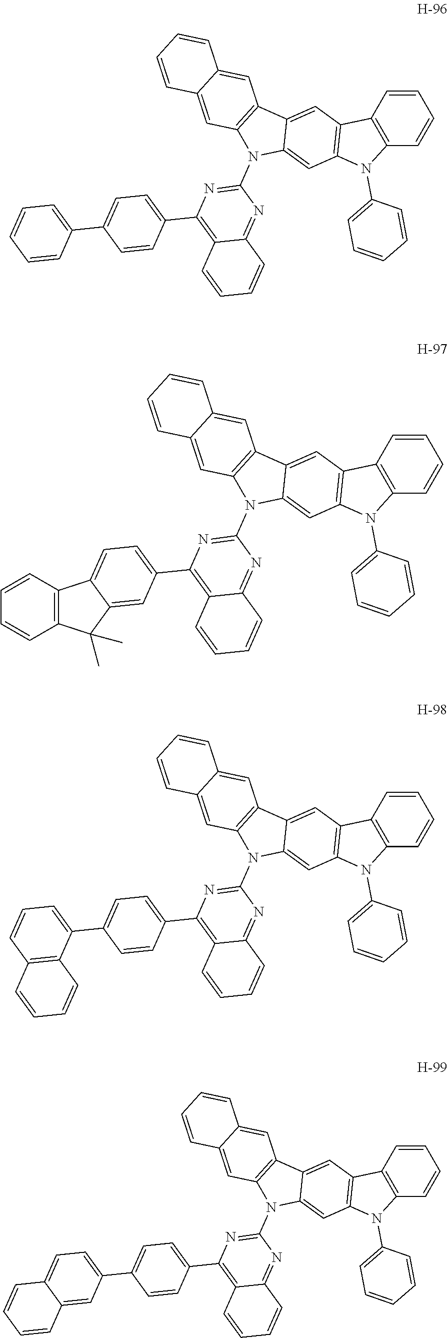 [SMILES: c1ccc(-c2ccc(-c3nc(-n4c5cc6ccccc6cc5c5cc6c7ccccc7n(-c7ccccc7)c6cc54)nc4ccccc34)cc2)cc1 ; CC1(C)c2ccccc2-c2ccc(-c3nc(-n4c5cc6ccccc6cc5c5cc6c7ccccc7n(-c7ccccc7)c6cc54)nc4ccccc34)cc21 ; c1ccc(-n2c3ccccc3c3cc4c5cc6ccccc6cc5n(-c5nc(-c6ccc(-c7cccc8ccccc78)cc6)c6ccccc6n5)c4cc32)cc1 ; c1ccc(-n2c3ccccc3c3cc4c5cc6ccccc6cc5n(-c5nc(-c6ccc(-c7ccc8ccccc8c7)cc6)c6ccccc6n5)c4cc32)cc1]

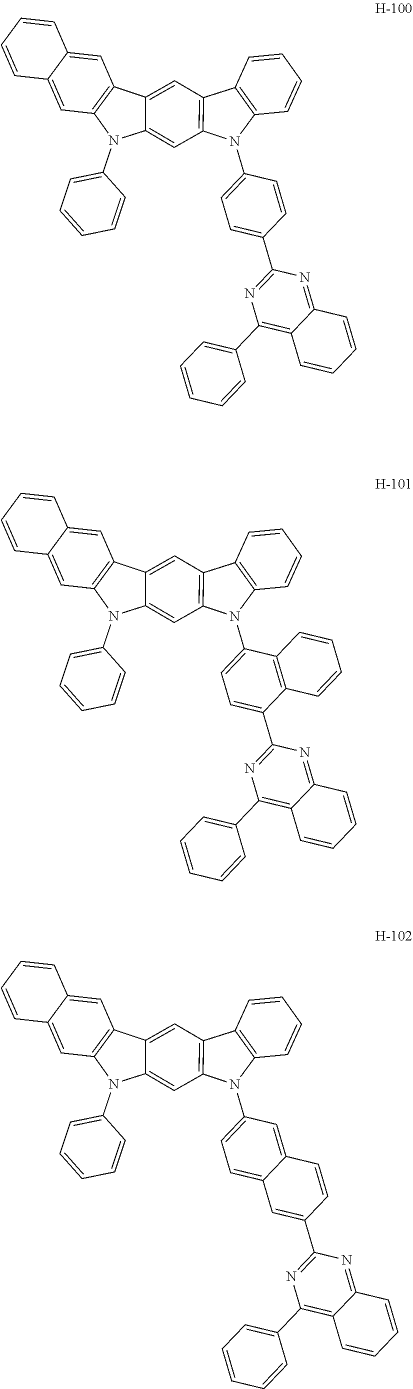 [SMILES: c1ccc(-c2nc(-c3ccc(-n4c5ccccc5c5cc6c7cc8ccccc8cc7n(-c7ccccc7)c6cc54)cc3)nc3ccccc23)cc1 ; c1ccc(-c2nc(-c3ccc(-n4c5ccccc5c5cc6c7cc8ccccc8cc7n(-c7ccccc7)c6cc54)c4ccccc34)nc3ccccc23)cc1 ; c1ccc(-c2nc(-c3ccc4cc(-n5c6ccccc6c6cc7c8cc9ccccc9cc8n(-c8ccccc8)c7cc65)ccc4c3)nc3ccccc23)cc1]

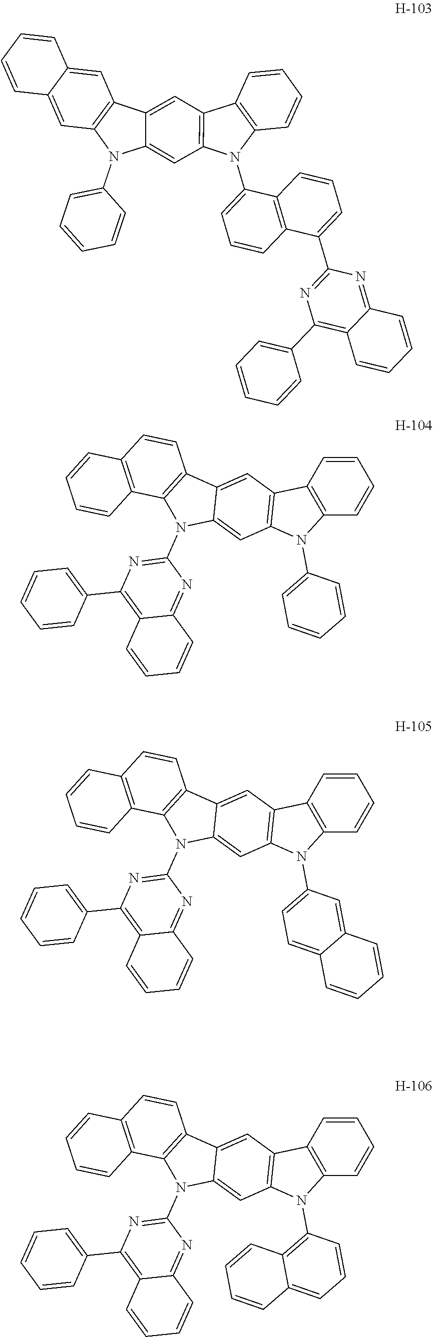 [SMILES: c1ccc(-c2nc(-c3cccc4c(-n5c6ccccc6c6cc7c8cc9ccccc9cc8n(-c8ccccc8)c7cc65)cccc34)nc3ccccc23)cc1 ; c1ccc(-c2nc(-n3c4cc5c(cc4c4ccc6ccccc6c43)c3ccccc3n5-c3ccccc3)nc3ccccc23)cc1 ; c1ccc(-c2nc(-n3c4cc5c(cc4c4ccc6ccccc6c43)c3ccccc3n5-c3ccc4ccccc4c3)nc3ccccc23)cc1 ; c1ccc(-c2nc(-n3c4cc5c(cc4c4ccc6ccccc6c43)c3ccccc3n5-c3cccc4ccccc34)nc3ccccc23)cc1]

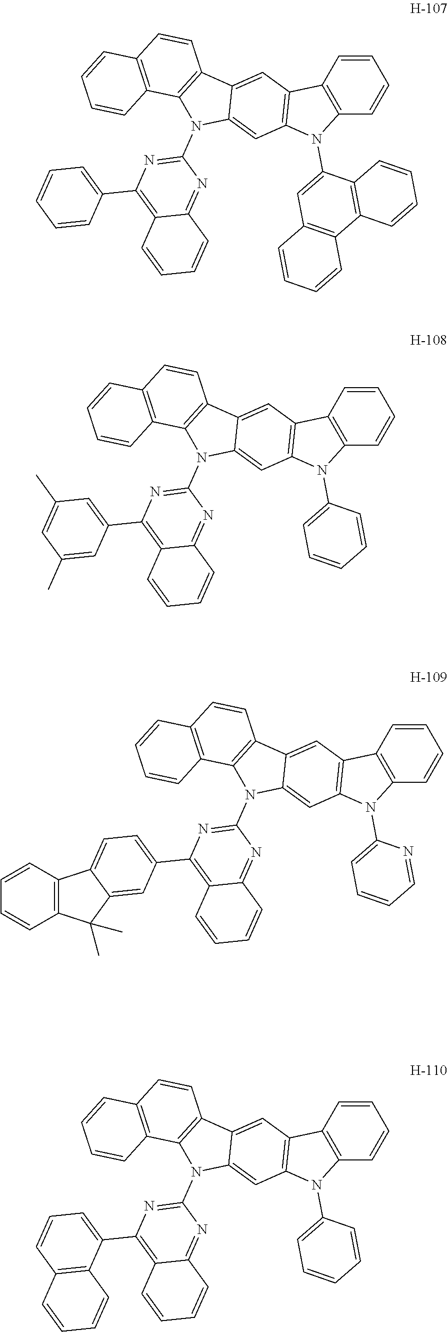 [SMILES: c1ccc(-c2nc(-n3c4cc5c(cc4c4ccc6ccccc6c43)c3ccccc3n5-c3cc4ccccc4c4ccccc34)nc3ccccc23)cc1 ; Cc1cc(C)cc(-c2nc(-n3c4cc5c(cc4c4ccc6ccccc6c43)c3ccccc3n5-c3ccccc3)nc3ccccc23)c1 ; CC1(C)c2ccccc2-c2ccc(-c3nc(-n4c5cc6c(cc5c5ccc7ccccc7c54)c4ccccc4n6-c4ccccn4)nc4ccccc34)cc21 ; c1ccc(-n2c3ccccc3c3cc4c5ccc6ccccc6c5n(-c5nc(-c6cccc7ccccc67)c6ccccc6n5)c4cc32)cc1]

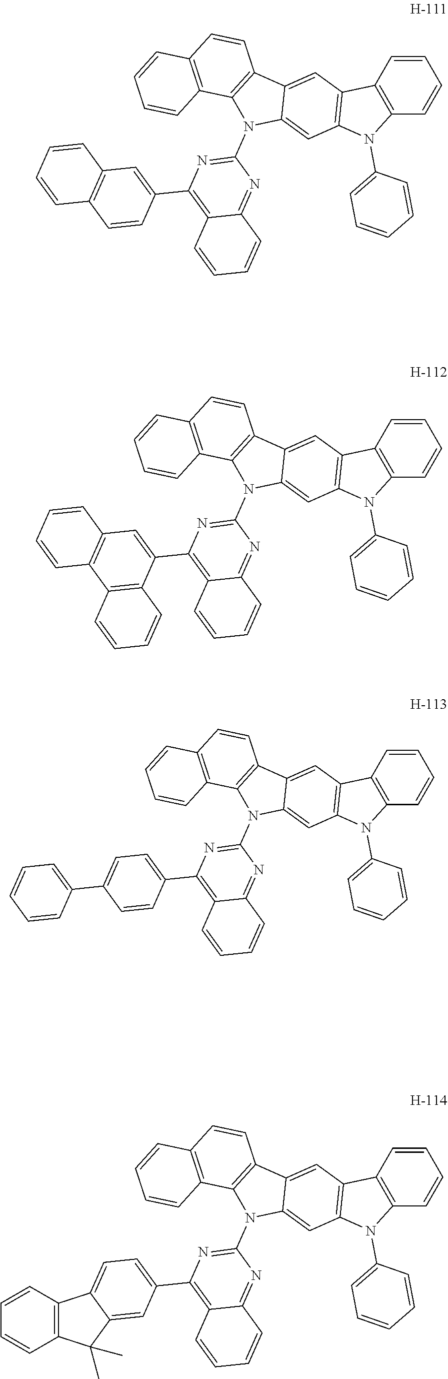 [SMILES: c1ccc(-n2c3ccccc3c3cc4c5ccc6ccccc6c5n(-c5nc(-c6ccc7ccccc7c6)c6ccccc6n5)c4cc32)cc1 ; c1ccc(-n2c3ccccc3c3cc4c5ccc6ccccc6c5n(-c5nc(-c6cc7ccccc7c7ccccc67)c6ccccc6n5)c4cc32)cc1 ; c1ccc(-c2ccc(-c3nc(-n4c5cc6c(cc5c5ccc7ccccc7c54)c4ccccc4n6-c4ccccc4)nc4ccccc34)cc2)cc1 ; CC1(C)c2ccccc2-c2ccc(-c3nc(-n4c5cc6c(cc5c5ccc7ccccc7c54)c4ccccc4n6-c4ccccc4)nc4ccccc34)cc21]

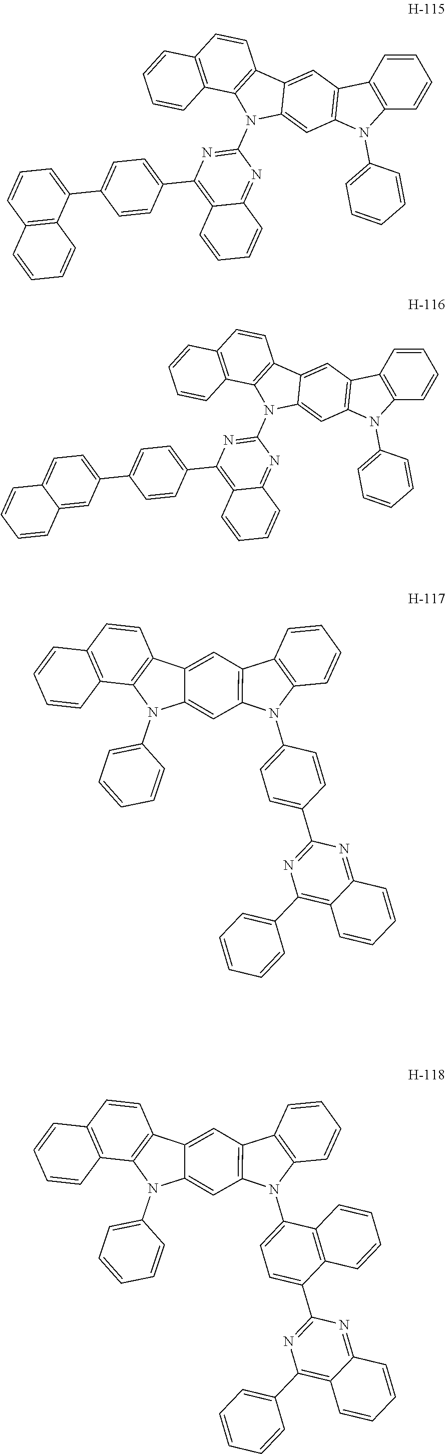 [SMILES: c1ccc(-n2c3ccccc3c3cc4c5ccc6ccccc6c5n(-c5nc(-c6ccc(-c7cccc8ccccc78)cc6)c6ccccc6n5)c4cc32)cc1 ; c1ccc(-n2c3ccccc3c3cc4c5ccc6ccccc6c5n(-c5nc(-c6ccc(-c7ccc8ccccc8c7)cc6)c6ccccc6n5)c4cc32)cc1 ; c1ccc(-c2nc(-c3ccc(-n4c5ccccc5c5cc6c7ccc8ccccc8c7n(-c7ccccc7)c6cc54)cc3)nc3ccccc23)cc1 ; c1ccc(-c2nc(-c3ccc(-n4c5ccccc5c5cc6c7ccc8ccccc8c7n(-c7ccccc7)c6cc54)c4ccccc34)nc3ccccc23)cc1]

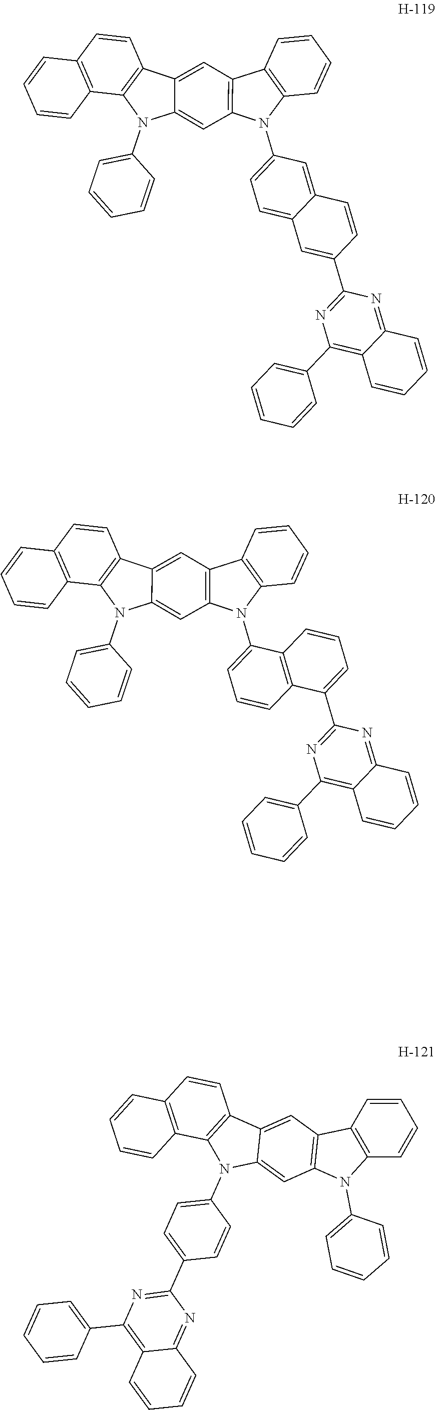 [SMILES: c1ccc(-c2nc(-c3ccc4cc(-n5c6ccccc6c6cc7c8ccc9ccccc9c8n(-c8ccccc8)c7cc65)ccc4c3)nc3ccccc23)cc1 ; c1ccc(-c2nc(-c3cccc4c(-n5c6ccccc6c6cc7c8ccc9ccccc9c8n(-c8ccccc8)c7cc65)cccc34)nc3ccccc23)cc1 ; c1ccc(-c2nc(-c3ccc(-n4c5cc6c(cc5c5ccc7ccccc7c54)c4ccccc4n6-c4ccccc4)cc3)nc3ccccc23)cc1]

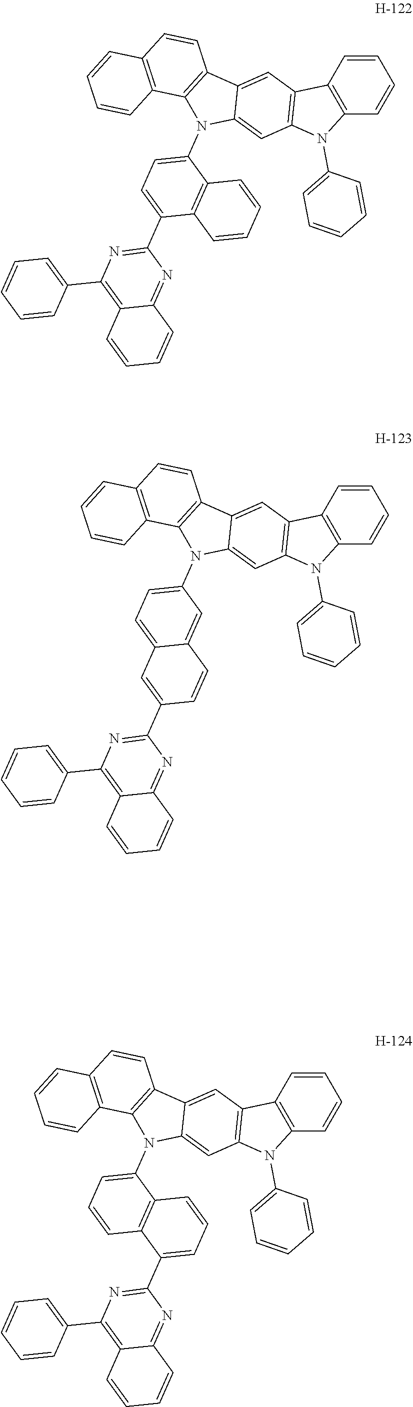 [SMILES: c1ccc(-c2nc(-c3ccc(-n4c5cc6c(cc5c5ccc7ccccc7c54)c4ccccc4n6-c4ccccc4)c4ccccc34)nc3ccccc23)cc1 ; c1ccc(-c2nc(-c3ccc4cc(-n5c6cc7c(cc6c6ccc8ccccc8c65)c5ccccc5n7-c5ccccc5)ccc4c3)nc3ccccc23)cc1 ; c1ccc(-c2nc(-c3cccc4c(-n5c6cc7c(cc6c6ccc8ccccc8c65)c5ccccc5n7-c5ccccc5)cccc34)nc3ccccc23)cc1]

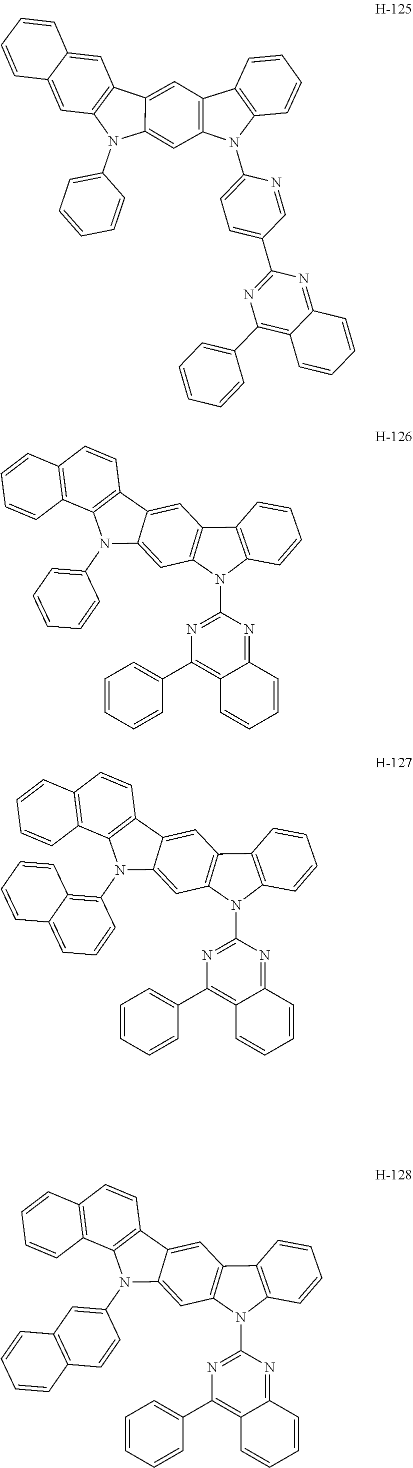 [SMILES: c1ccc(-c2nc(-c3ccc(-n4c5ccccc5c5cc6c7cc8ccccc8cc7n(-c7ccccc7)c6cc54)nc3)nc3ccccc23)cc1 ; c1ccc(-c2nc(-n3c4ccccc4c4cc5c6ccc7ccccc7c6n(-c6ccccc6)c5cc43)nc3ccccc23)cc1 ; c1ccc(-c2nc(-n3c4ccccc4c4cc5c6ccc7ccccc7c6n(-c6cccc7ccccc67)c5cc43)nc3ccccc23)cc1 ; c1ccc(-c2nc(-n3c4ccccc4c4cc5c6ccc7ccccc7c6n(-c6ccc7ccccc7c6)c5cc43)nc3ccccc23)cc1]

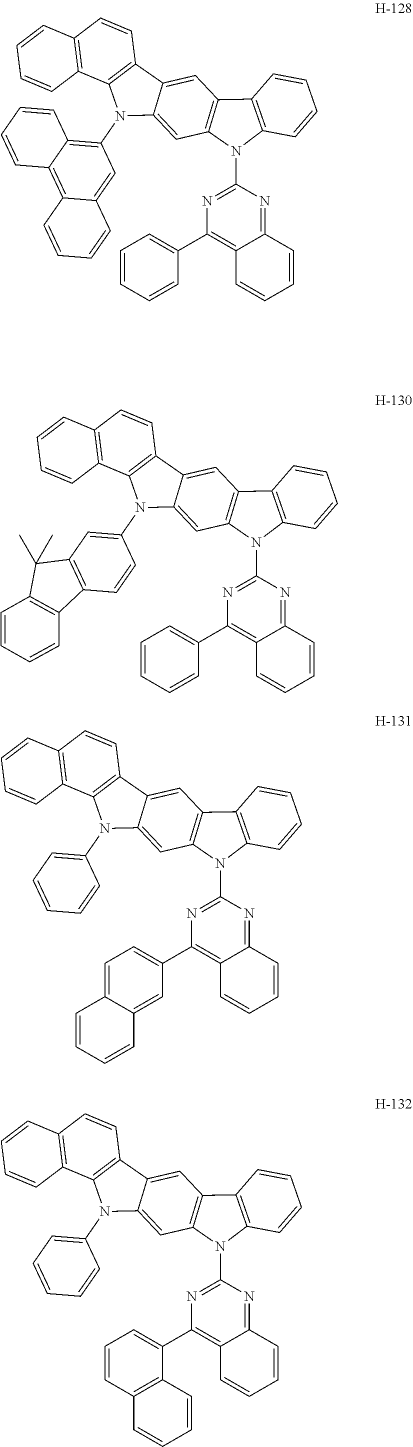 [SMILES: c1ccc(-c2nc(-n3c4ccccc4c4cc5c6ccc7ccccc7c6n(-c6cc7ccccc7c7ccccc67)c5cc43)nc3ccccc23)cc1 ; CC1(C)c2ccccc2-c2ccc(-n3c4cc5c(cc4c4ccc6ccccc6c43)c3ccccc3n5-c3nc(-c4ccccc4)c4ccccc4n3)cc21 ; c1ccc(-n2c3cc4c(cc3c3ccc5ccccc5c32)c2ccccc2n4-c2nc(-c3ccc4ccccc4c3)c3ccccc3n2)cc1 ; c1ccc(-n2c3cc4c(cc3c3ccc5ccccc5c32)c2ccccc2n4-c2nc(-c3cccc4ccccc34)c3ccccc3n2)cc1]

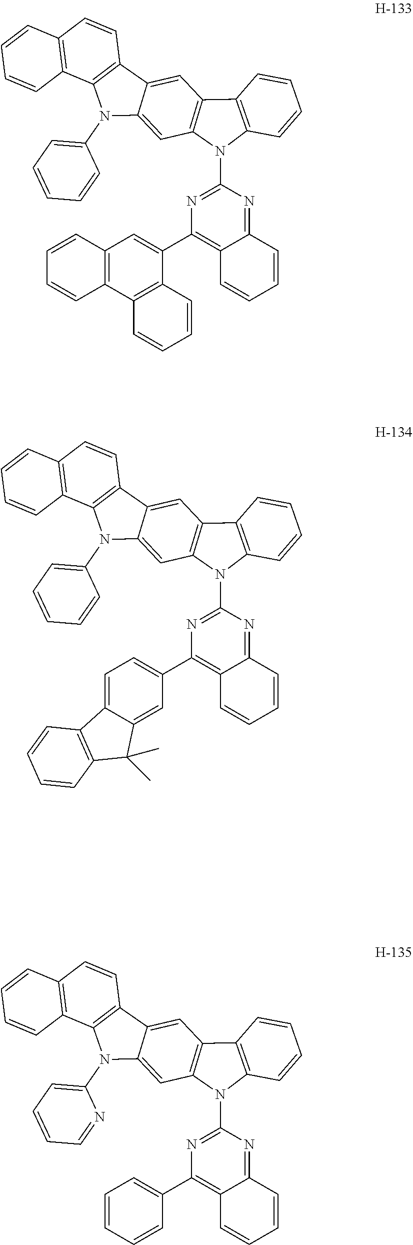 [SMILES: c1ccc(-n2c3cc4c(cc3c3ccc5ccccc5c32)c2ccccc2n4-c2nc(-c3cc4ccccc4c4ccccc34)c3ccccc3n2)cc1 ; CC1(C)c2ccccc2-c2ccc(-c3nc(-n4c5ccccc5c5cc6c7ccc8ccccc8c7n(-c7ccccc7)c6cc54)nc4ccccc34)cc21 ; c1ccc(-c2nc(-n3c4ccccc4c4cc5c6ccc7ccccc7c6n(-c6ccccn6)c5cc43)nc3ccccc23)cc1]

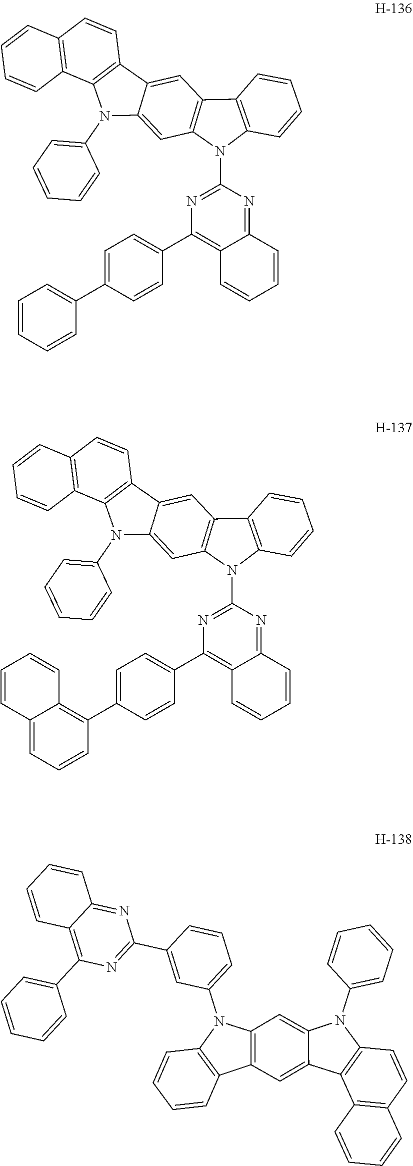 [SMILES: c1ccc(-c2ccc(-c3nc(-n4c5ccccc5c5cc6c7ccc8ccccc8c7n(-c7ccccc7)c6cc54)nc4ccccc34)cc2)cc1 ; c1ccc(-n2c3cc4c(cc3c3ccc5ccccc5c32)c2ccccc2n4-c2nc(-c3ccc(-c4cccc5ccccc45)cc3)c3ccccc3n2)cc1 ; c1ccc(-c2nc(-c3cccc(-n4c5ccccc5c5cc6c7c8ccccc8ccc7n(-c7ccccc7)c6cc54)c3)nc3ccccc23)cc1]

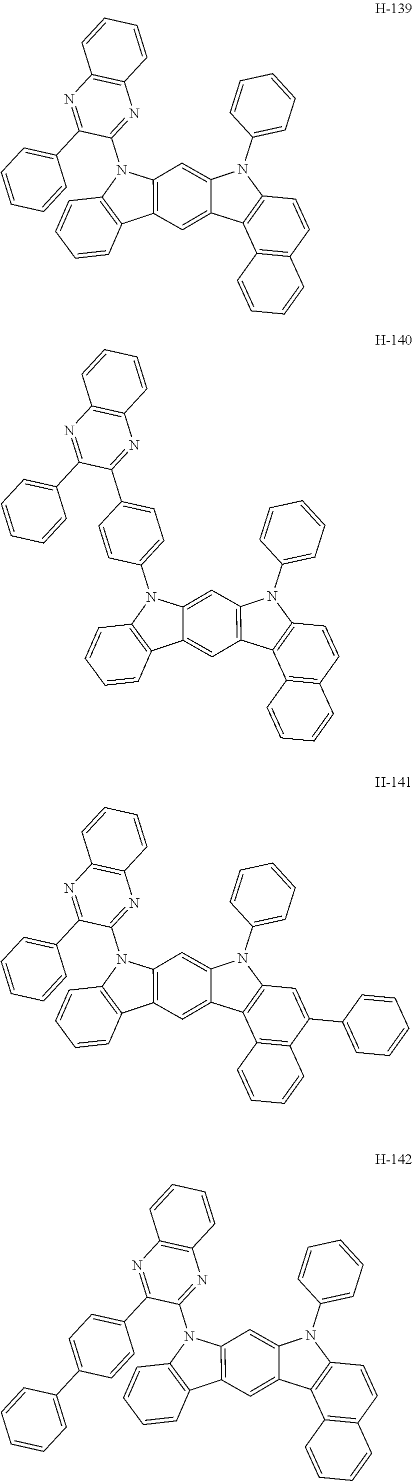 [SMILES: c1ccc(-c2nc3ccccc3nc2-n2c3ccccc3c3cc4c5c6ccccc6ccc5n(-c5ccccc5)c4cc32)cc1 ; c1ccc(-c2nc3ccccc3nc2-c2ccc(-n3c4ccccc4c4cc5c6c7ccccc7ccc6n(-c6ccccc6)c5cc43)cc2)cc1 ; c1ccc(-c2nc3ccccc3nc2-n2c3ccccc3c3cc4c5c6ccccc6c(-c6ccccc6)cc5n(-c5ccccc5)c4cc32)cc1 ; c1ccc(-c2ccc(-c3nc4ccccc4nc3-n3c4ccccc4c4cc5c6c7ccccc7ccc6n(-c6ccccc6)c5cc43)cc2)cc1]

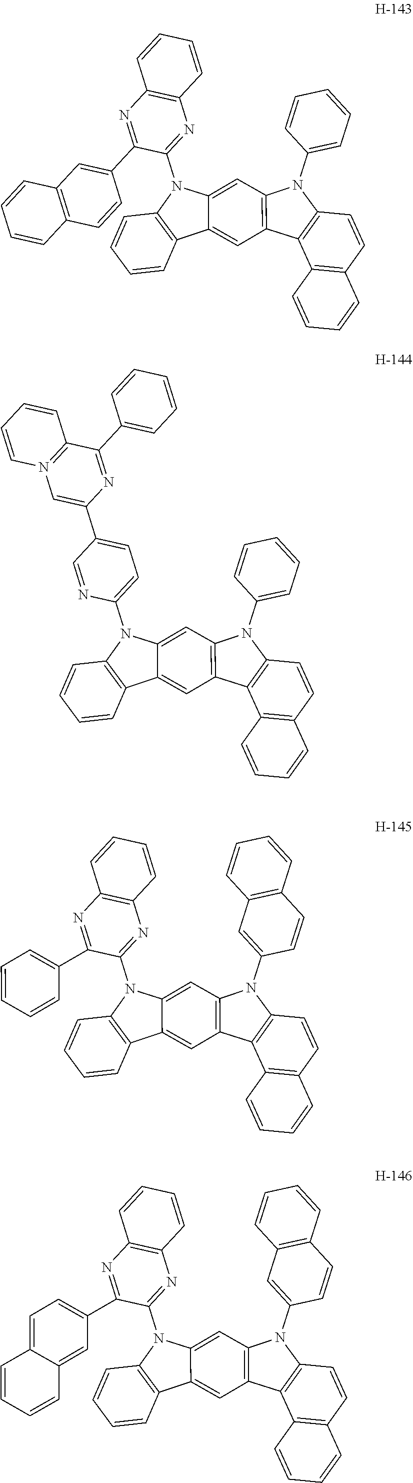

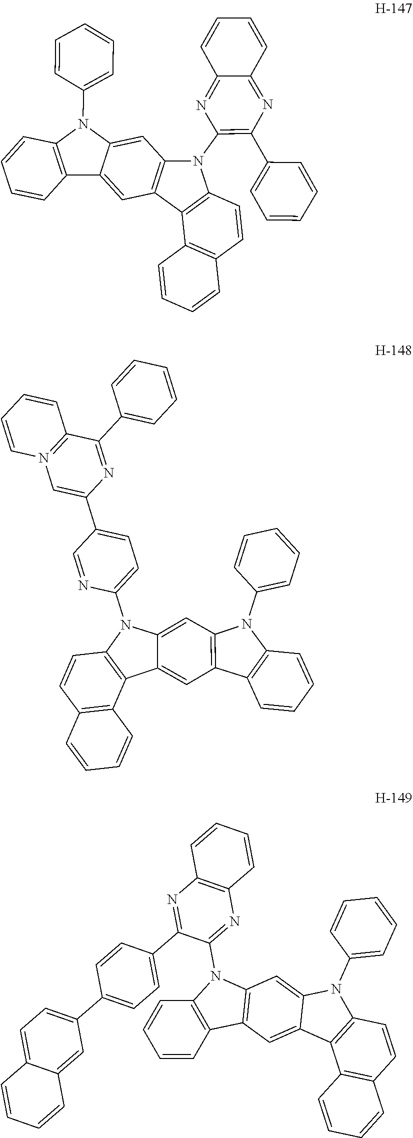

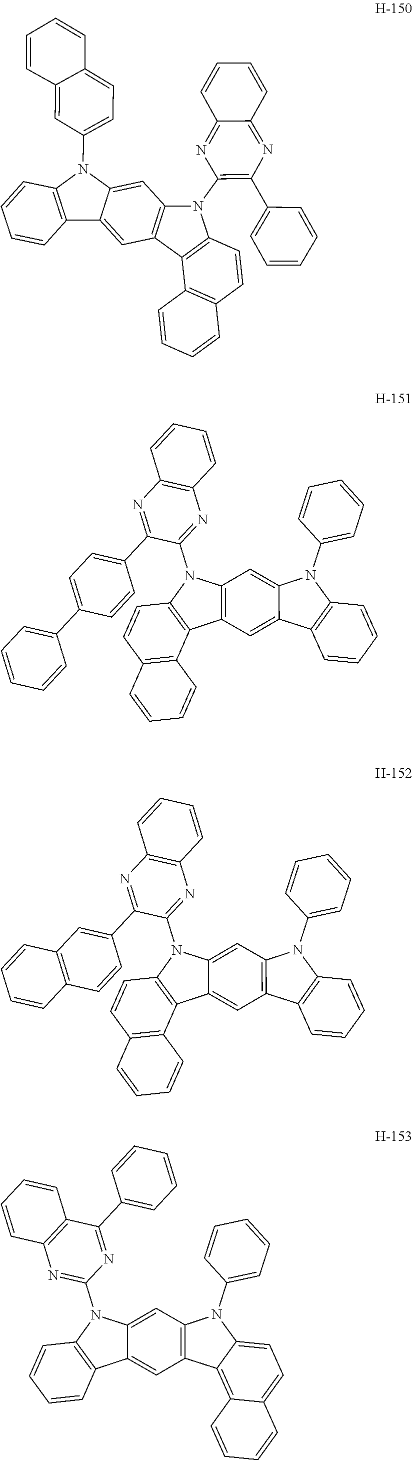 [SMILES: c1ccc(-c2nc3ccccc3nc2-n2c3cc4c(cc3c3c5ccccc5ccc32)c2ccccc2n4-c2ccc3ccccc3c2)cc1 ; c1ccc(-c2ccc(-c3nc4ccccc4nc3-n3c4cc5c(cc4c4c6ccccc6ccc43)c3ccccc3n5-c3ccccc3)cc2)cc1 ; c1ccc(-n2c3ccccc3c3cc4c5c6ccccc6ccc5n(-c5nc6ccccc6nc5-c5ccc6ccccc6c5)c4cc32)cc1 ; c1ccc(-c2nc(-n3c4ccccc4c4cc5c6c7ccccc7ccc6n(-c6ccccc6)c5cc43)nc3ccccc23)cc1]

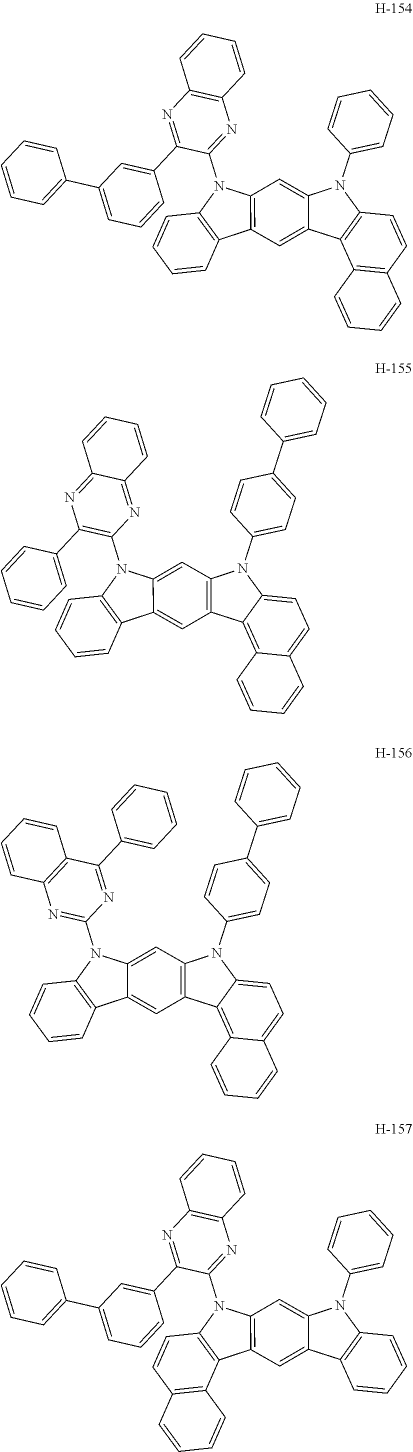 [SMILES: c1ccc(-c2cccc(-c3nc4ccccc4nc3-n3c4ccccc4c4cc5c6c7ccccc7ccc6n(-c6ccccc6)c5cc43)c2)cc1 ; c1ccc(-c2ccc(-n3c4cc5c(cc4c4c6ccccc6ccc43)c3ccccc3n5-c3nc4ccccc4nc3-c3ccccc3)cc2)cc1 ; c1ccc(-c2ccc(-n3c4cc5c(cc4c4c6ccccc6ccc43)c3ccccc3n5-c3nc(-c4ccccc4)c4ccccc4n3)cc2)cc1 ; c1ccc(-c2cccc(-c3nc4ccccc4nc3-n3c4cc5c(cc4c4c6ccccc6ccc43)c3ccccc3n5-c3ccccc3)c2)cc1]

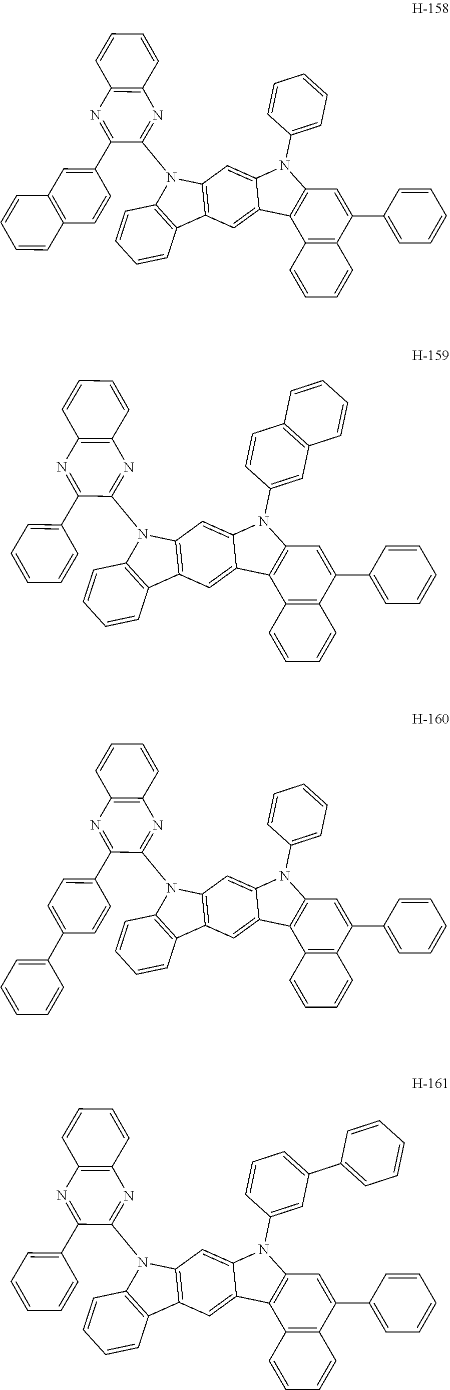 [SMILES: c1ccc(-c2cc3c(c4ccccc24)c2cc4c5ccccc5n(-c5nc6ccccc6nc5-c5ccc6ccccc6c5)c4cc2n3-c2ccccc2)cc1 ; c1ccc(-c2nc3ccccc3nc2-n2c3ccccc3c3cc4c5c6ccccc6c(-c6ccccc6)cc5n(-c5ccc6ccccc6c5)c4cc32)cc1 ; c1ccc(-c2ccc(-c3nc4ccccc4nc3-n3c4ccccc4c4cc5c6c7ccccc7c(-c7ccccc7)cc6n(-c6ccccc6)c5cc43)cc2)cc1 ; c1ccc(-c2cccc(-n3c4cc5c(cc4c4c6ccccc6c(-c6ccccc6)cc43)c3ccccc3n5-c3nc4ccccc4nc3-c3ccccc3)c2)cc1]

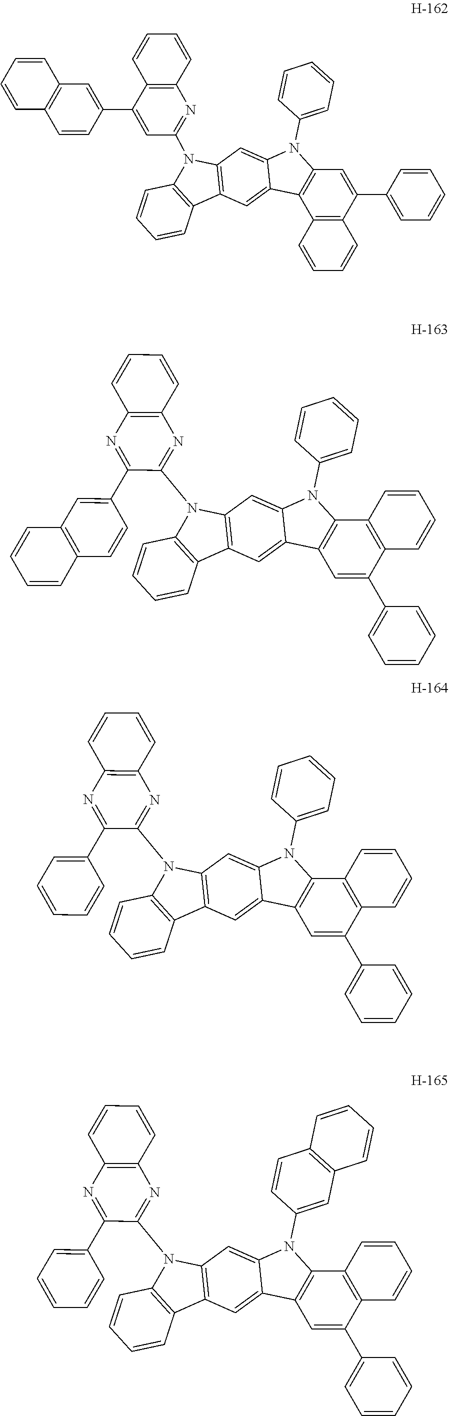 [SMILES: c1ccc(-c2cc3c(c4ccccc24)c2cc4c5ccccc5n(-c5cc(-c6ccc7ccccc7c6)c6ccccc6n5)c4cc2n3-c2ccccc2)cc1 ; c1ccc(-c2cc3c4cc5c6ccccc6n(-c6nc7ccccc7nc6-c6ccc7ccccc7c6)c5cc4n(-c4ccccc4)c3c3ccccc23)cc1 ; c1ccc(-c2nc3ccccc3nc2-n2c3ccccc3c3cc4c5cc(-c6ccccc6)c6ccccc6c5n(-c5ccccc5)c4cc32)cc1 ; c1ccc(-c2nc3ccccc3nc2-n2c3ccccc3c3cc4c5cc(-c6ccccc6)c6ccccc6c5n(-c5ccc6ccccc6c5)c4cc32)cc1]

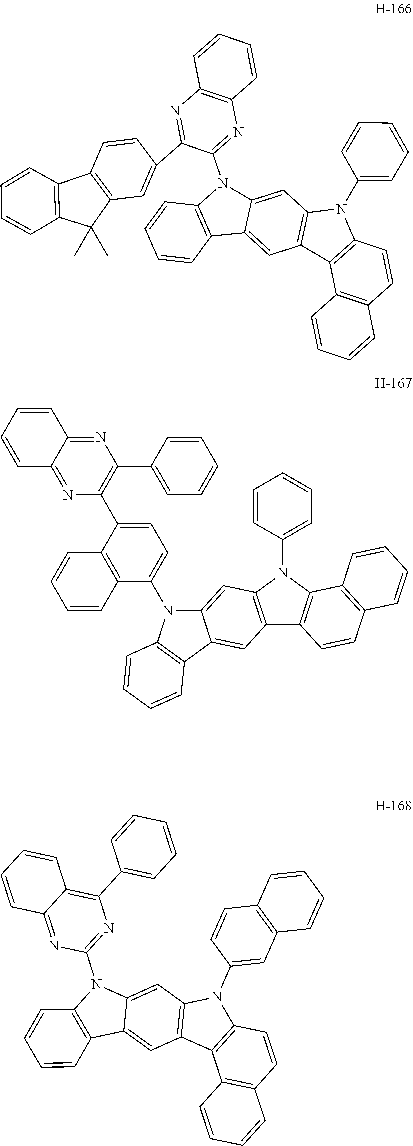 [SMILES: CC1(C)c2ccccc2-c2ccc(-c3nc4ccccc4nc3-n3c4ccccc4c4cc5c6c7ccccc7ccc6n(-c6ccccc6)c5cc43)cc21 ; c1ccc(-c2nc3ccccc3nc2-c2ccc(-n3c4ccccc4c4cc5c6ccc7ccccc7c6n(-c6ccccc6)c5cc43)c3ccccc23)cc1 ; c1ccc(-c2nc(-n3c4ccccc4c4cc5c6c7ccccc7ccc6n(-c6ccc7ccccc7c6)c5cc43)nc3ccccc23)cc1]

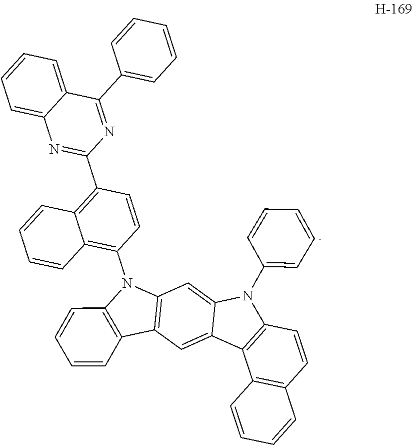 [SMILES: c1ccc(-c2nc(-c3ccc(-n4c5ccccc5c5cc6c7c8ccccc8ccc7n(-c7ccccc7)c6cc54)c4ccccc34)nc3ccccc23)cc1]

7. The organic electroluminescent device according to claim 1, wherein the compound represented by formula 11 is at least one selected from the following compounds:

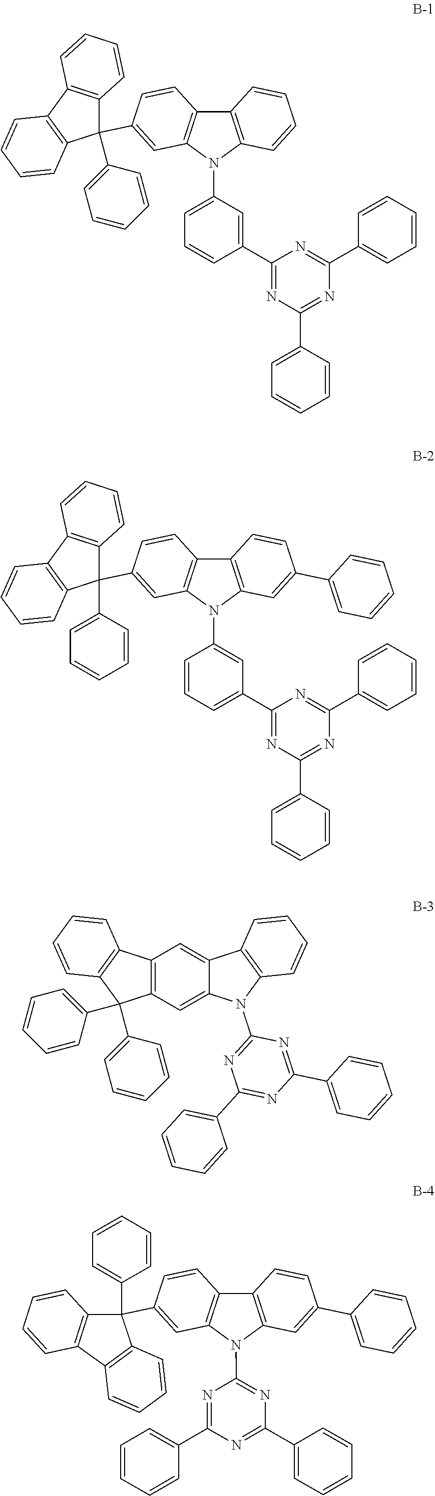 [SMILES: c1ccc(-c2nc(-c3ccccc3)nc(-c3cccc(-n4c5ccccc5c5ccc(C6(c7ccccc7)c7ccccc7-c7ccccc76)cc54)c3)n2)cc1 ; c1ccc(-c2ccc3c4ccc(C5(c6ccccc6)c6ccccc6-c6ccccc65)cc4n(-c4cccc(-c5nc(-c6ccccc6)nc(-c6ccccc6)n5)c4)c3c2)cc1 ; c1ccc(-c2nc(-c3ccccc3)nc(-n3c4ccccc4c4cc5c(cc43)C(c3ccccc3)(c3ccccc3)c3ccccc3-5)n2)cc1 ; c1ccc(-c2ccc3c4ccc(C5(c6ccccc6)c6ccccc6-c6ccccc65)cc4n(-c4nc(-c5ccccc5)nc(-c5ccccc5)n4)c3c2)cc1]

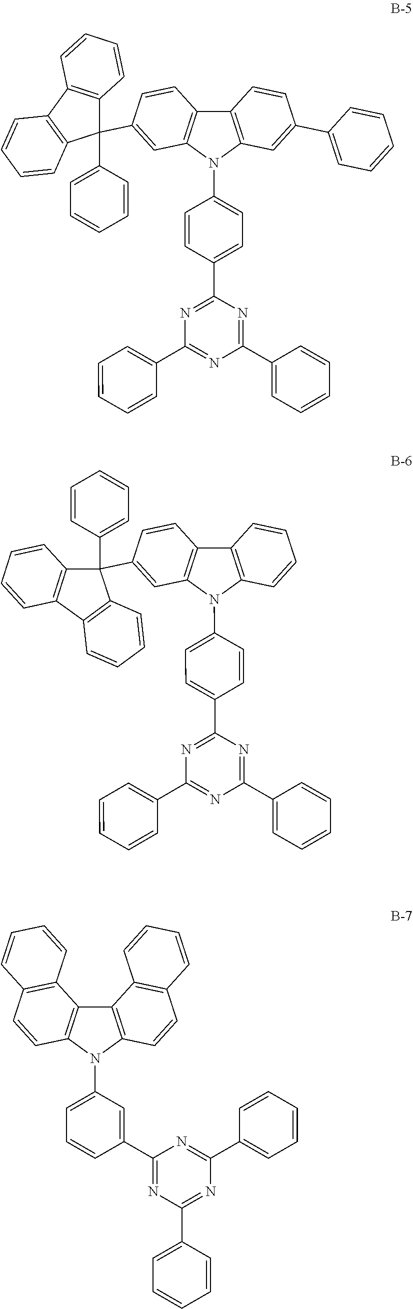 [SMILES: c1ccc(-c2ccc3c4ccc(C5(c6ccccc6)c6ccccc6-c6ccccc65)cc4n(-c4ccc(-c5nc(-c6ccccc6)nc(-c6ccccc6)n5)cc4)c3c2)cc1 ; c1ccc(-c2nc(-c3ccccc3)nc(-c3ccc(-n4c5ccccc5c5ccc(C6(c7ccccc7)c7ccccc7-c7ccccc76)cc54)cc3)n2)cc1 ; c1ccc(-c2nc(-c3ccccc3)nc(-c3cccc(-n4c5ccc6ccccc6c5c5c6ccccc6ccc54)c3)n2)cc1]

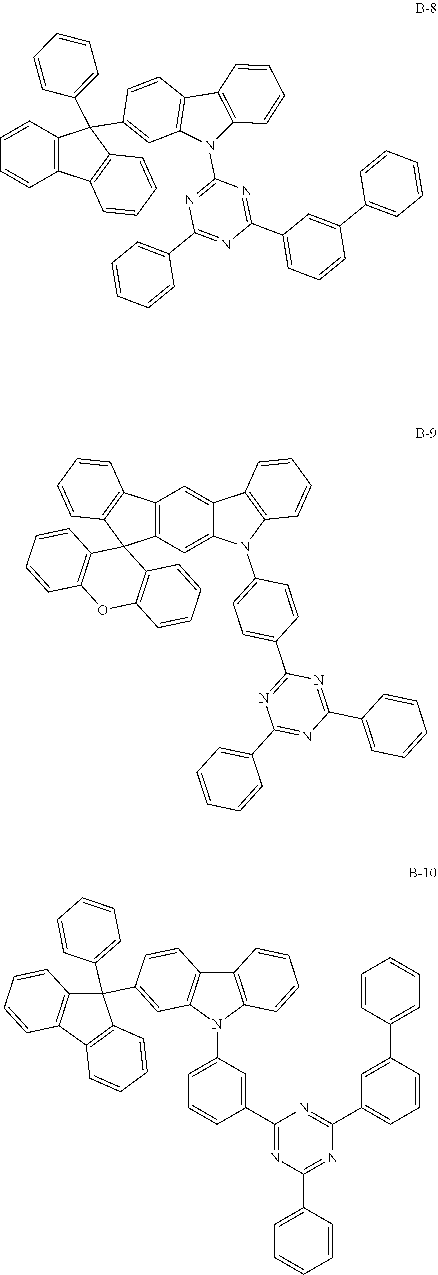 [SMILES: c1ccc(-c2cccc(-c3nc(-c4ccccc4)nc(-n4c5ccccc5c5ccc(C6(c7ccccc7)c7ccccc7-c7ccccc76)cc54)n3)c2)cc1 ; c1ccc(-c2nc(-c3ccccc3)nc(-c3ccc(-n4c5ccccc5c5cc6c(cc54)C4(c5ccccc5Oc5ccccc54)c4ccccc4-6)cc3)n2)cc1 ; c1ccc(-c2cccc(-c3nc(-c4ccccc4)nc(-c4cccc(-n5c6ccccc6c6ccc(C7(c8ccccc8)c8ccccc8-c8ccccc87)cc65)c4)n3)c2)cc1]

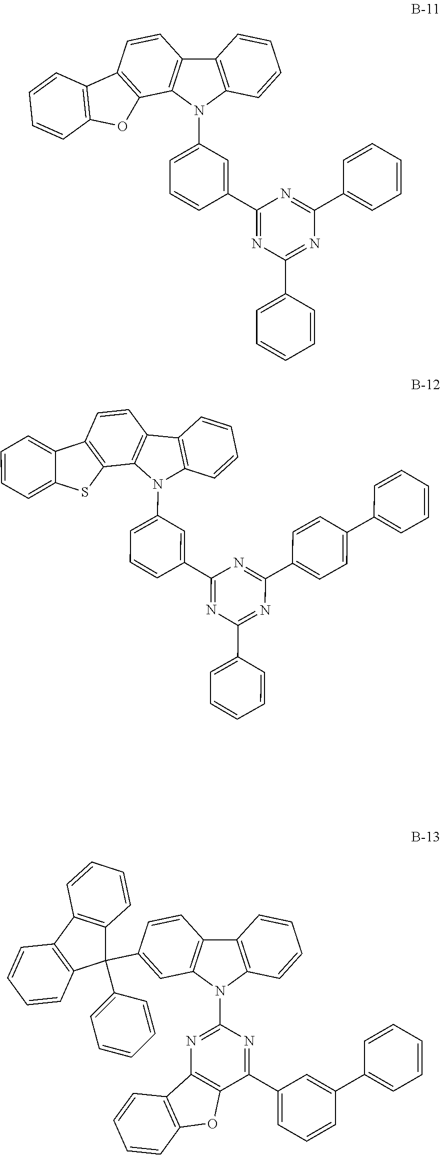 [SMILES: c1ccc(-c2nc(-c3ccccc3)nc(-c3cccc(-n4c5ccccc5c5ccc6c7ccccc7oc6c54)c3)n2)cc1 ; c1ccc(-c2ccc(-c3nc(-c4ccccc4)nc(-c4cccc(-n5c6ccccc6c6ccc7c8ccccc8sc7c65)c4)n3)cc2)cc1 ; c1ccc(-c2cccc(-c3nc(-n4c5ccccc5c5ccc(C6(c7ccccc7)c7ccccc7-c7ccccc76)cc54)nc4c3oc3ccccc34)c2)cc1]

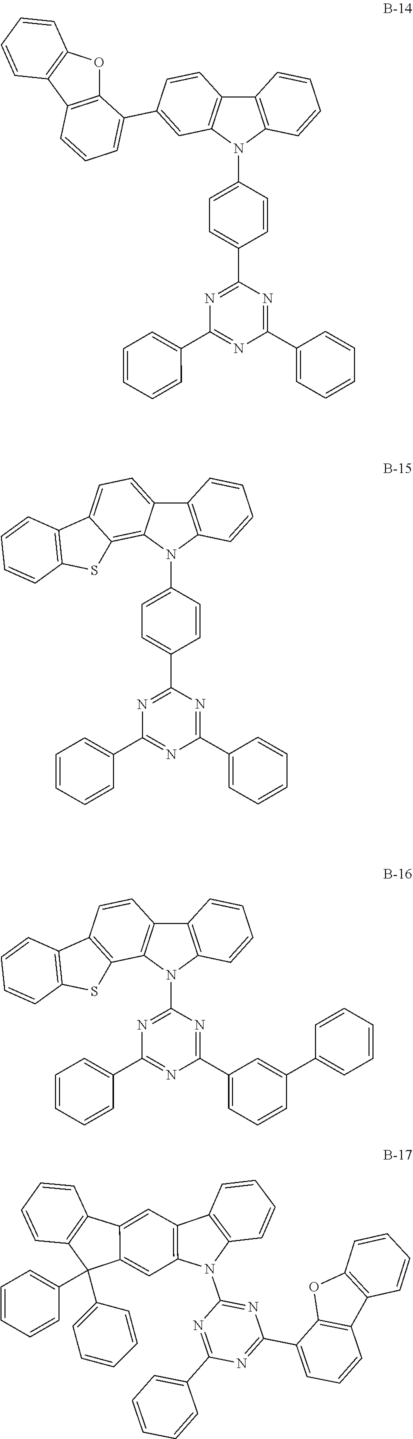 [SMILES: c1ccc(-c2nc(-c3ccccc3)nc(-c3ccc(-n4c5ccccc5c5ccc(-c6cccc7c6oc6ccccc67)cc54)cc3)n2)cc1 ; c1ccc(-c2nc(-c3ccccc3)nc(-c3ccc(-n4c5ccccc5c5ccc6c7ccccc7sc6c54)cc3)n2)cc1 ; c1ccc(-c2cccc(-c3nc(-c4ccccc4)nc(-n4c5ccccc5c5ccc6c7ccccc7sc6c54)n3)c2)cc1 ; c1ccc(-c2nc(-c3cccc4c3oc3ccccc34)nc(-n3c4ccccc4c4cc5c(cc43)C(c3ccccc3)(c3ccccc3)c3ccccc3-5)n2)cc1]

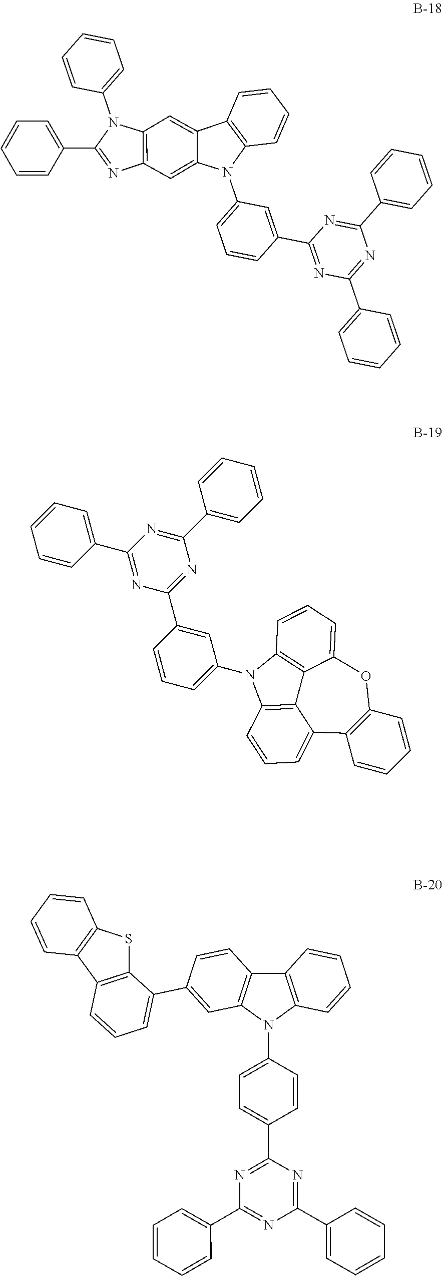 [SMILES: c1ccc(-c2nc(-c3ccccc3)nc(-c3cccc(-n4c5ccccc5c5cc6c(cc54)nc(-c4ccccc4)n6-c4ccccc4)c3)n2)cc1 ; c1ccc(-c2nc(-c3ccccc3)nc(-c3cccc(-n4c5cccc6oc7ccccc7c7cccc4c7c65)c3)n2)cc1 ; c1ccc(-c2nc(-c3ccccc3)nc(-c3ccc(-n4c5ccccc5c5ccc(-c6cccc7c6sc6ccccc67)cc54)cc3)n2)cc1]

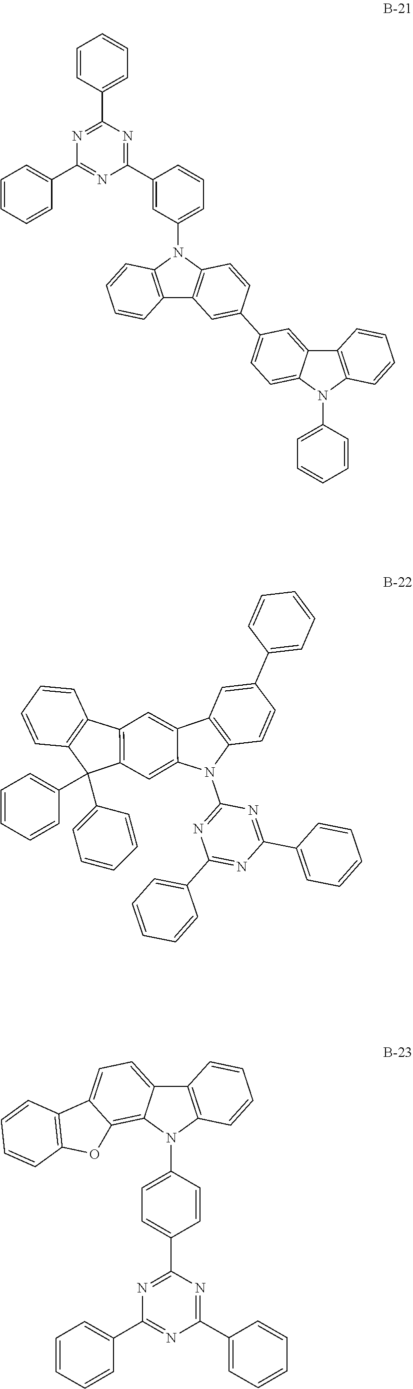 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc3c(c2)c2cc4c(cc2n3-c2nc(-c3ccccc3)nc(-c3ccccc3)n2)C(c2ccccc2)(c2ccccc2)c2ccccc2-4)cc1 ; c1ccc(-c2nc(-c3ccccc3)nc(-c3ccc(-n4c5ccccc5c5ccc6c7ccccc7oc6c54)cc3)n2)cc1]

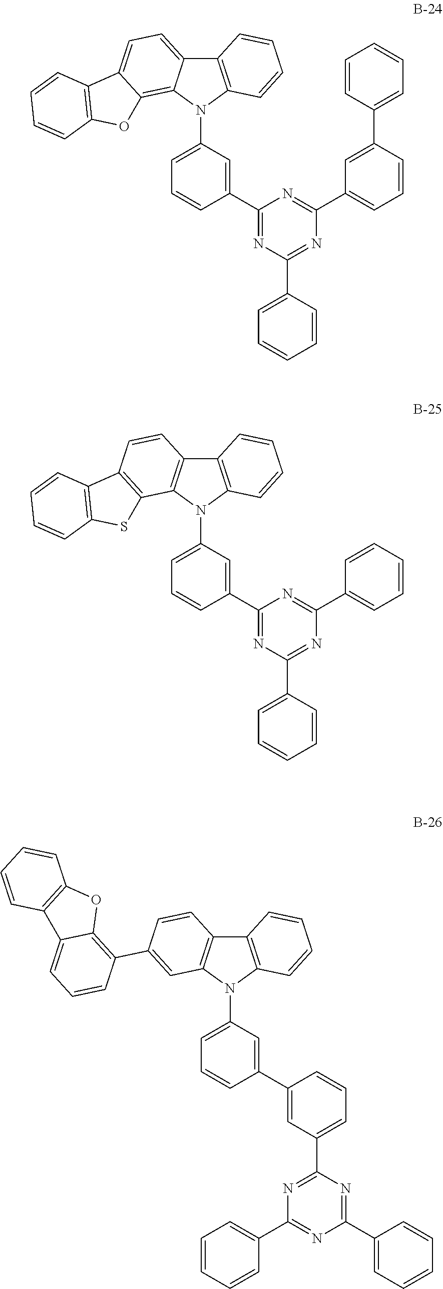 [SMILES: c1ccc(-c2cccc(-c3nc(-c4ccccc4)nc(-c4cccc(-n5c6ccccc6c6ccc7c8ccccc8oc7c65)c4)n3)c2)cc1 ; c1ccc(-c2nc(-c3ccccc3)nc(-c3cccc(-n4c5ccccc5c5ccc6c7ccccc7sc6c54)c3)n2)cc1 ; c1ccc(-c2nc(-c3ccccc3)nc(-c3cccc(-c4cccc(-n5c6ccccc6c6ccc(-c7cccc8c7oc7ccccc78)cc65)c4)c3)n2)cc1]

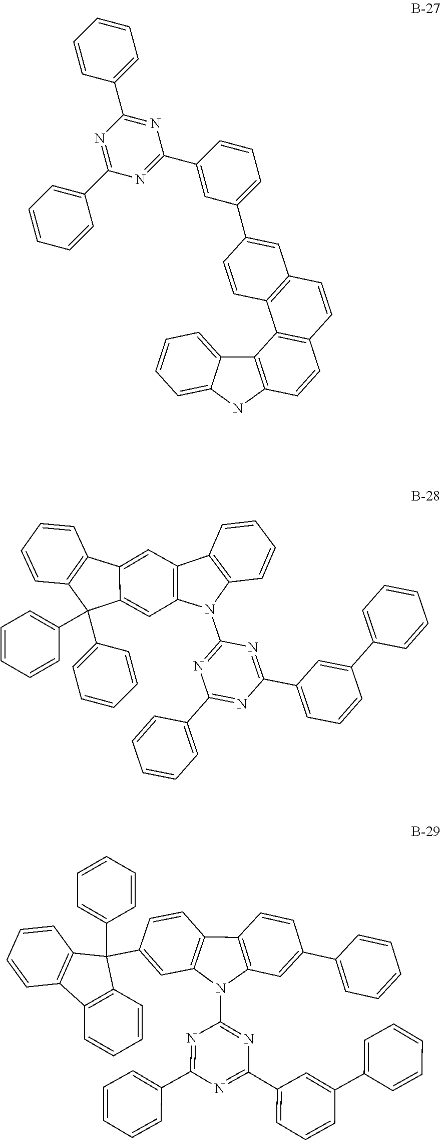 [SMILES: c1ccc(-c2nc(-c3ccccc3)nc(-c3cccc(-c4ccc5c(ccc6ccc7[nH]c8ccccc8c7c65)c4)c3)n2)cc1 ; c1ccc(-c2cccc(-c3nc(-c4ccccc4)nc(-n4c5ccccc5c5cc6c(cc54)C(c4ccccc4)(c4ccccc4)c4ccccc4-6)n3)c2)cc1 ; c1ccc(-c2cccc(-c3nc(-c4ccccc4)nc(-n4c5cc(-c6ccccc6)ccc5c5ccc(C6(c7ccccc7)c7ccccc7-c7ccccc76)cc54)n3)c2)cc1]

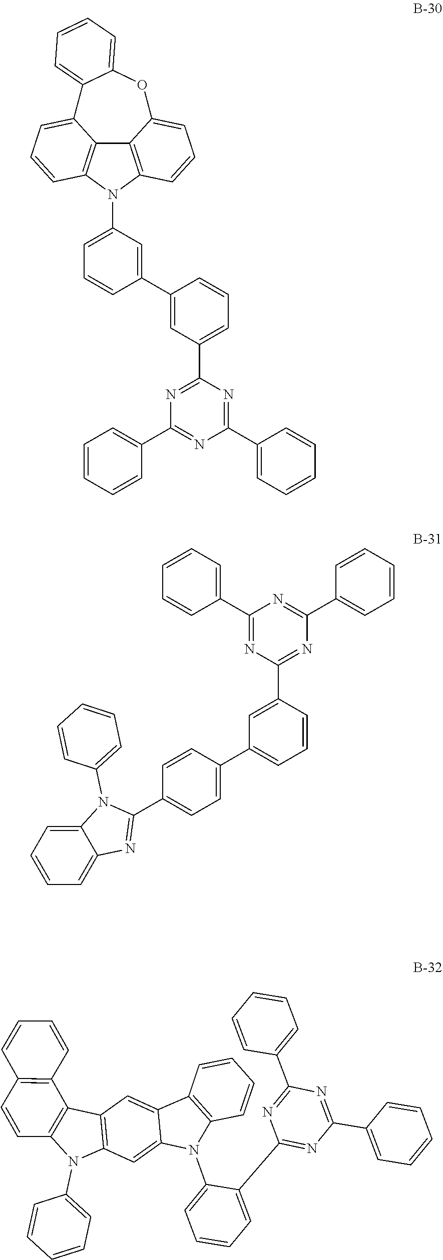 [SMILES: c1ccc(-c2nc(-c3ccccc3)nc(-c3cccc(-c4cccc(-n5c6cccc7oc8ccccc8c8cccc5c8c76)c4)c3)n2)cc1 ; c1ccc(-c2nc(-c3ccccc3)nc(-c3cccc(-c4ccc(-c5nc6ccccc6n5-c5ccccc5)cc4)c3)n2)cc1 ; c1ccc(-c2nc(-c3ccccc3)nc(-c3ccccc3-n3c4ccccc4c4cc5c6c7ccccc7ccc6n(-c6ccccc6)c5cc43)n2)cc1]

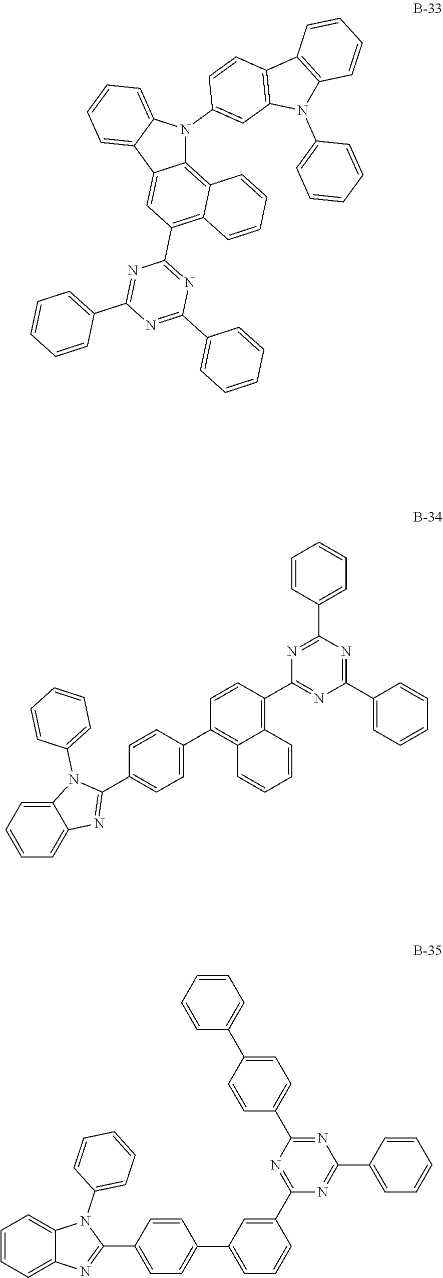 [SMILES: c1ccc(-c2nc(-c3ccccc3)nc(-c3cc4c5ccccc5n(-c5ccc6c7ccccc7n(-c7ccccc7)c6c5)c4c4ccccc34)n2)cc1 ; c1ccc(-c2nc(-c3ccccc3)nc(-c3ccc(-c4ccc(-c5nc6ccccc6n5-c5ccccc5)cc4)c4ccccc34)n2)cc1 ; c1ccc(-c2ccc(-c3nc(-c4ccccc4)nc(-c4cccc(-c5ccc(-c6nc7ccccc7n6-c6ccccc6)cc5)c4)n3)cc2)cc1]

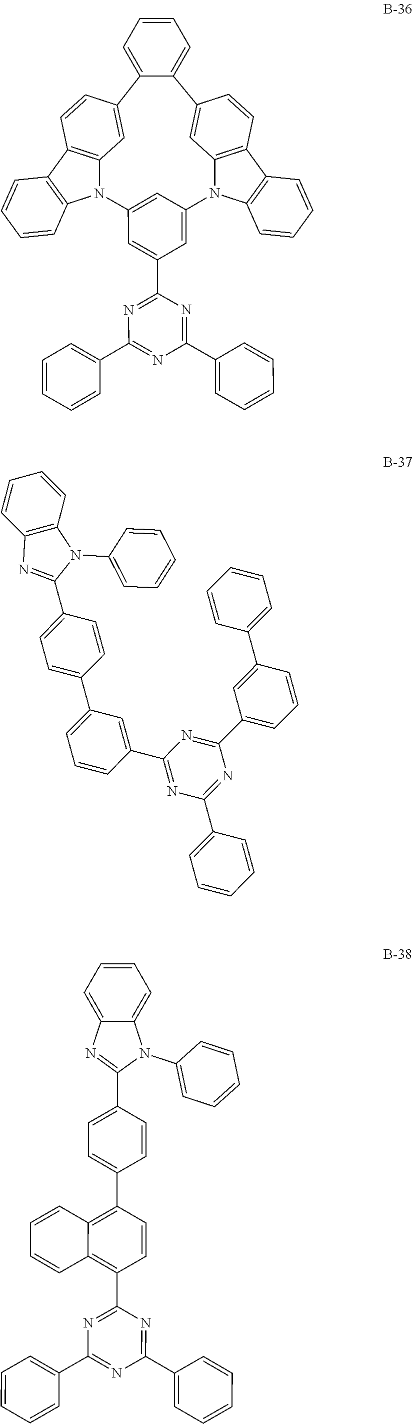 [SMILES: c1ccc(-c2nc(-c3ccccc3)nc(-c3cc4cc(c3)n3c5ccccc5c5ccc(cc53)c3ccccc3c3ccc5c6ccccc6n4c5c3)n2)cc1 ; c1ccc(-c2cccc(-c3nc(-c4ccccc4)nc(-c4cccc(-c5ccc(-c6nc7ccccc7n6-c6ccccc6)cc5)c4)n3)c2)cc1 ; c1ccc(-c2nc(-c3ccccc3)nc(-c3ccc(-c4ccc(-c5nc6ccccc6n5-c5ccccc5)cc4)c4ccccc34)n2)cc1]

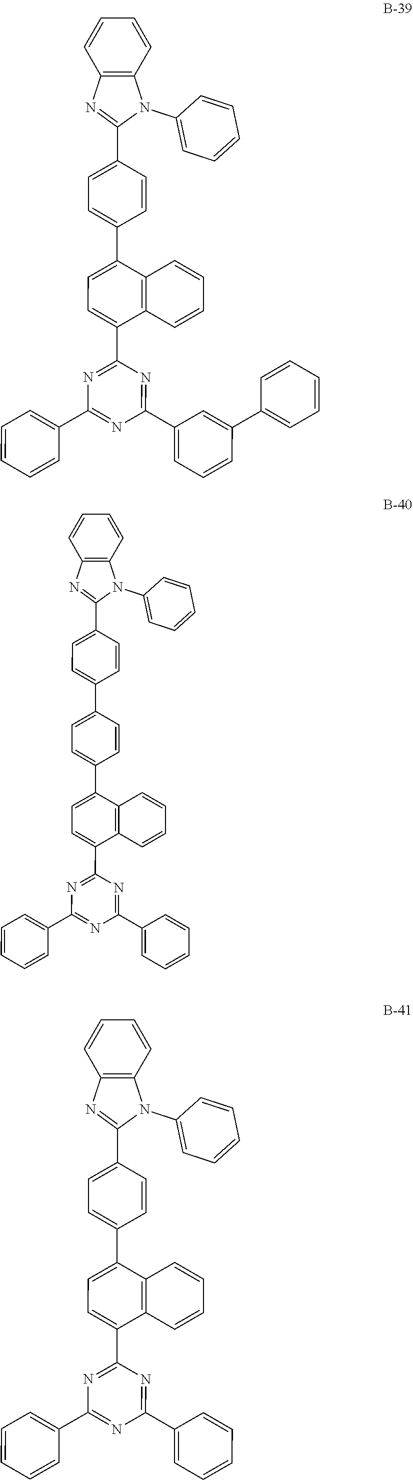 [SMILES: c1ccc(-c2cccc(-c3nc(-c4ccccc4)nc(-c4ccc(-c5ccc(-c6nc7ccccc7n6-c6ccccc6)cc5)c5ccccc45)n3)c2)cc1 ; c1ccc(-c2nc(-c3ccccc3)nc(-c3ccc(-c4ccc(-c5ccc(-c6nc7ccccc7n6-c6ccccc6)cc5)cc4)c4ccccc34)n2)cc1 ; c1ccc(-c2nc(-c3ccccc3)nc(-c3ccc(-c4ccc(-c5nc6ccccc6n5-c5ccccc5)cc4)c4ccccc34)n2)cc1]

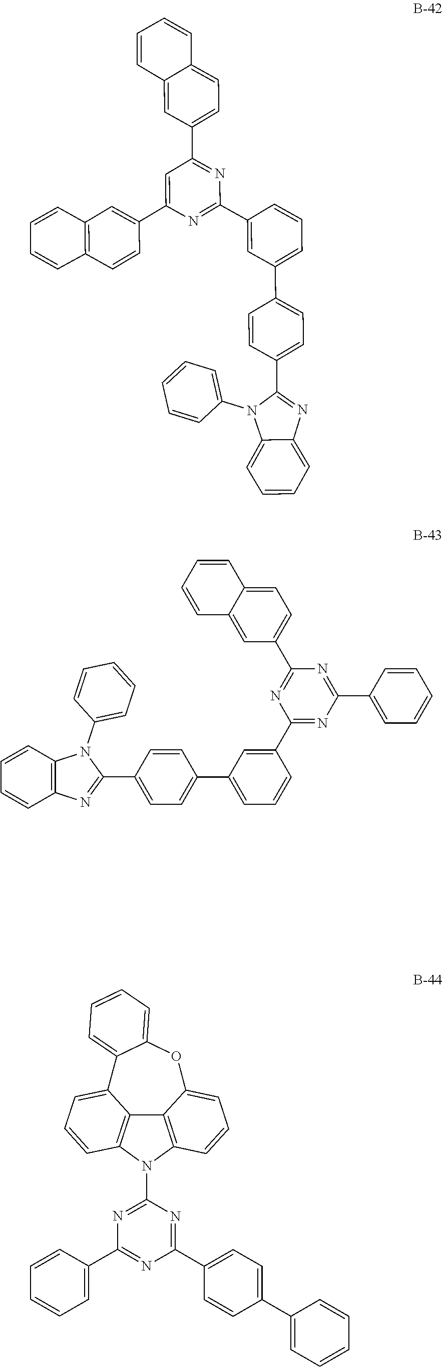 [SMILES: c1ccc(-n2c(-c3ccc(-c4cccc(-c5nc(-c6ccc7ccccc7c6)cc(-c6ccc7ccccc7c6)n5)c4)cc3)nc3ccccc32)cc1 ; c1ccc(-c2nc(-c3cccc(-c4ccc(-c5nc6ccccc6n5-c5ccccc5)cc4)c3)nc(-c3ccc4ccccc4c3)n2)cc1 ; c1ccc(-c2ccc(-c3nc(-c4ccccc4)nc(-n4c5cccc6oc7ccccc7c7cccc4c7c65)n3)cc2)cc1]

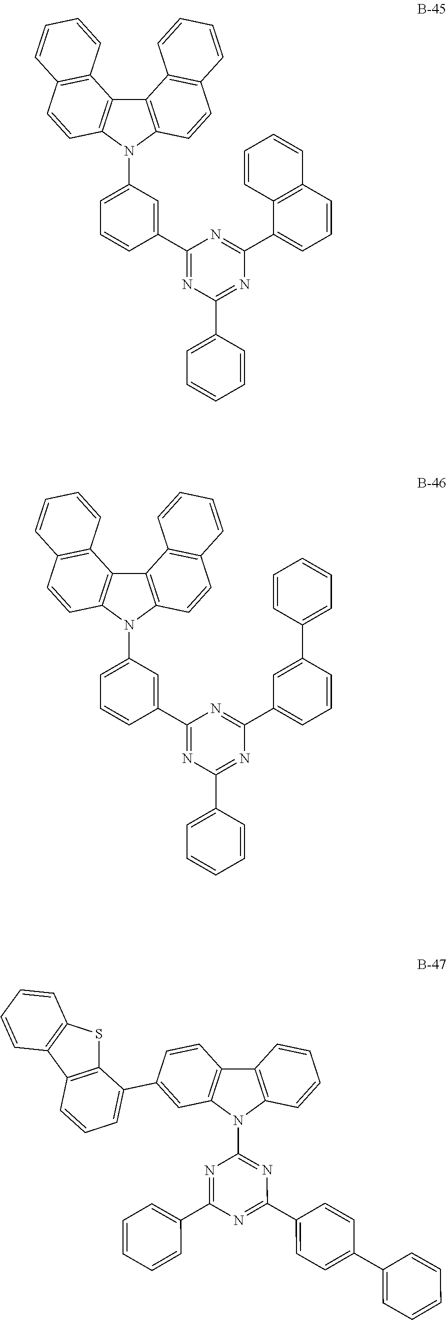 [SMILES: c1ccc(-c2nc(-c3cccc(-n4c5ccc6ccccc6c5c5c6ccccc6ccc54)c3)nc(-c3cccc4ccccc34)n2)cc1 ; c1ccc(-c2cccc(-c3nc(-c4ccccc4)nc(-c4cccc(-n5c6ccc7ccccc7c6c6c7ccccc7ccc65)c4)n3)c2)cc1 ; c1ccc(-c2ccc(-c3nc(-c4ccccc4)nc(-n4c5ccccc5c5ccc(-c6cccc7c6sc6ccccc67)cc54)n3)cc2)cc1]

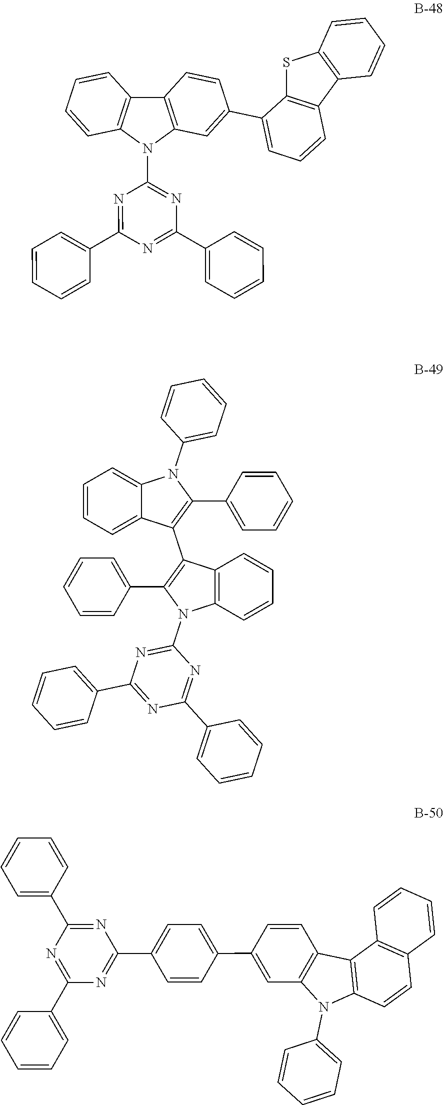 [SMILES: c1ccc(-c2nc(-c3ccccc3)nc(-n3c4ccccc4c4ccc(-c5cccc6c5sc5ccccc56)cc43)n2)cc1 ; c1ccc(-c2nc(-c3ccccc3)nc(-n3c(-c4ccccc4)c(-c4c(-c5ccccc5)n(-c5ccccc5)c5ccccc45)c4ccccc43)n2)cc1 ; c1ccc(-c2nc(-c3ccccc3)nc(-c3ccc(-c4ccc5c6c7ccccc7ccc6n(-c6ccccc6)c5c4)cc3)n2)cc1]

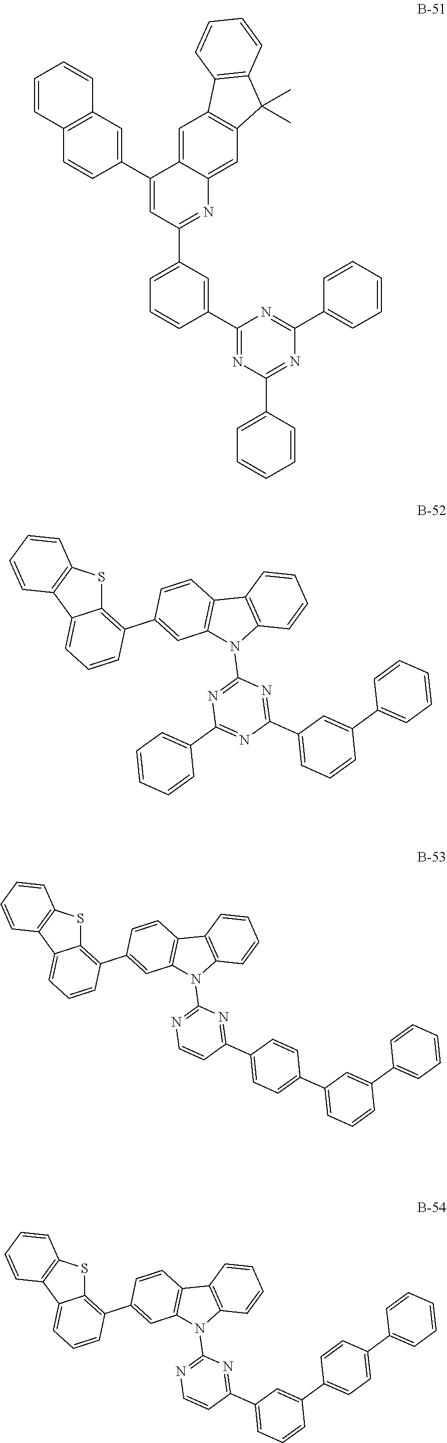 [SMILES: CC1(C)c2ccccc2-c2cc3c(-c4ccc5ccccc5c4)cc(-c4cccc(-c5nc(-c6ccccc6)nc(-c6ccccc6)n5)c4)nc3cc21 ; c1ccc(-c2cccc(-c3nc(-c4ccccc4)nc(-n4c5ccccc5c5ccc(-c6cccc7c6sc6ccccc67)cc54)n3)c2)cc1 ; c1ccc(-c2cccc(-c3ccc(-c4ccnc(-n5c6ccccc6c6ccc(-c7cccc8c7sc7ccccc78)cc65)n4)cc3)c2)cc1 ; c1ccc(-c2ccc(-c3cccc(-c4ccnc(-n5c6ccccc6c6ccc(-c7cccc8c7sc7ccccc78)cc65)n4)c3)cc2)cc1]

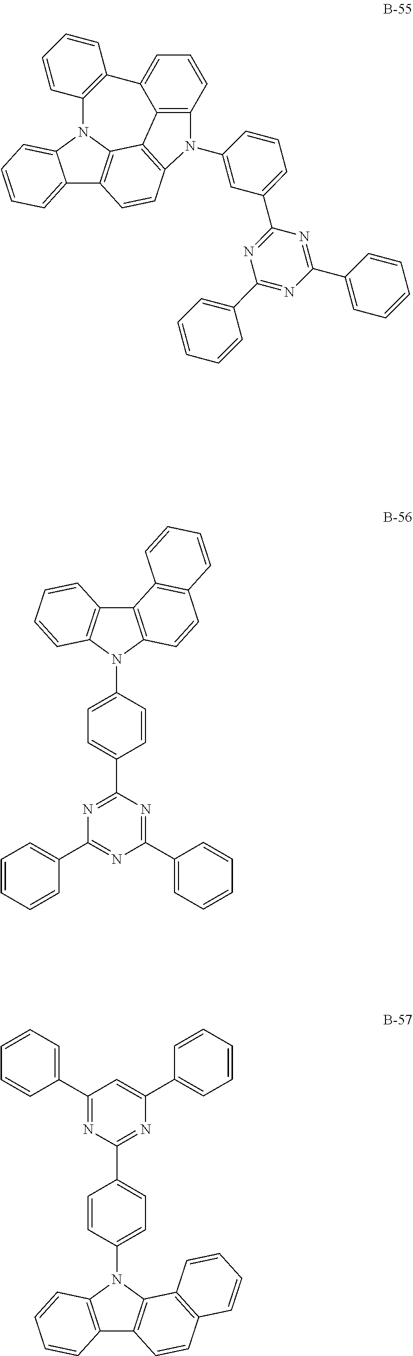 [SMILES: c1ccc(-c2nc(-c3ccccc3)nc(-c3cccc(-n4c5cccc6c7ccccc7n7c8ccccc8c8ccc4c(c65)c87)c3)n2)cc1 ; c1ccc(-c2nc(-c3ccccc3)nc(-c3ccc(-n4c5ccccc5c5c6ccccc6ccc54)cc3)n2)cc1 ; c1ccc(-c2cc(-c3ccccc3)nc(-c3ccc(-n4c5ccccc5c5ccc6ccccc6c54)cc3)n2)cc1]

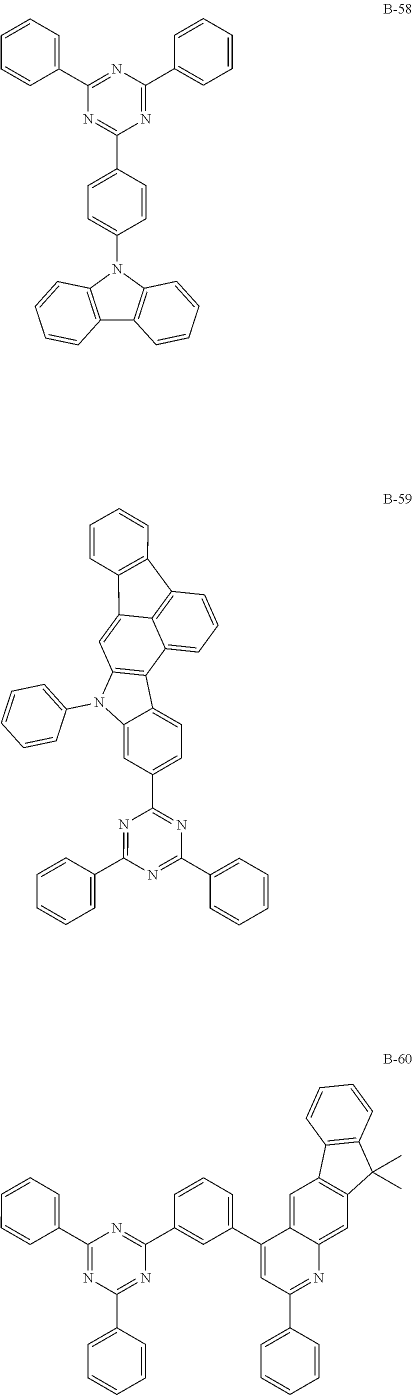 [SMILES: c1ccc(-c2nc(-c3ccccc3)nc(-c3ccc(-n4c5ccccc5c5ccccc54)cc3)n2)cc1 ; c1ccc(-c2nc(-c3ccccc3)nc(-c3ccc4c5c6cccc7c6c(cc5n(-c5ccccc5)c4c3)-c3ccccc3-7)n2)cc1 ; CC1(C)c2ccccc2-c2cc3c(-c4cccc(-c5nc(-c6ccccc6)nc(-c6ccccc6)n5)c4)cc(-c4ccccc4)nc3cc21]

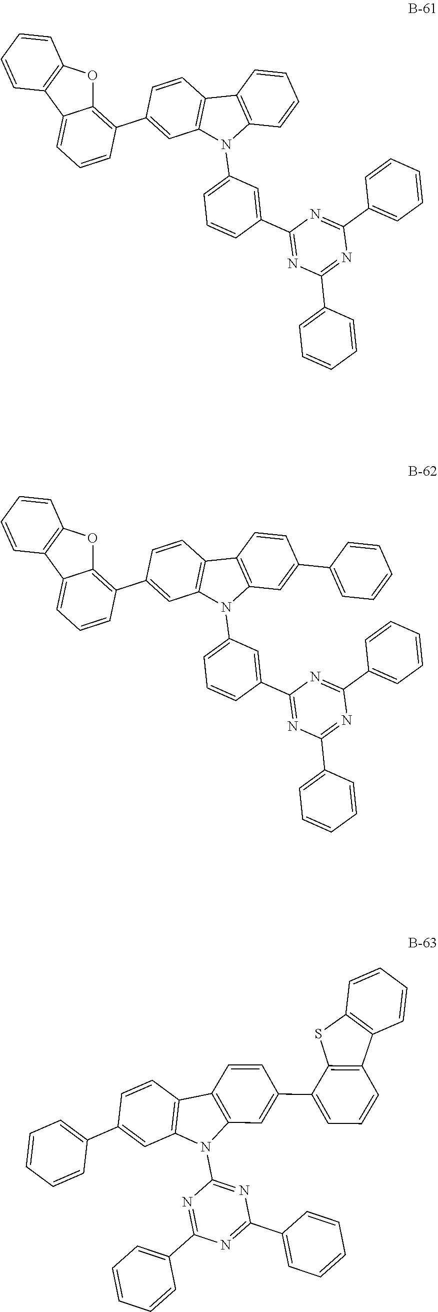 [SMILES: c1ccc(-c2nc(-c3ccccc3)nc(-c3cccc(-n4c5ccccc5c5ccc(-c6cccc7c6oc6ccccc67)cc54)c3)n2)cc1 ; c1ccc(-c2ccc3c4ccc(-c5cccc6c5oc5ccccc56)cc4n(-c4cccc(-c5nc(-c6ccccc6)nc(-c6ccccc6)n5)c4)c3c2)cc1 ; c1ccc(-c2ccc3c4ccc(-c5cccc6c5sc5ccccc56)cc4n(-c4nc(-c5ccccc5)nc(-c5ccccc5)n4)c3c2)cc1]

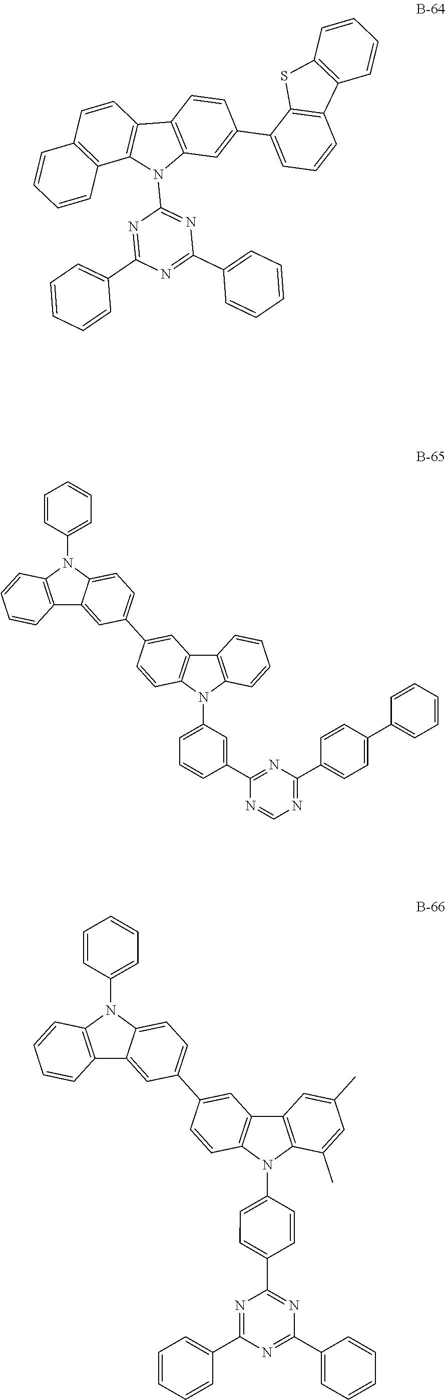 [SMILES: c1ccc(-c2nc(-c3ccccc3)nc(-n3c4cc(-c5cccc6c5sc5ccccc56)ccc4c4ccc5ccccc5c43)n2)cc1 ; c1ccc(-c2ccc(-c3ncnc(-c4cccc(-n5c6ccccc6c6cc(-c7ccc8c(c7)c7ccccc7n8-c7ccccc7)ccc65)c4)n3)cc2)cc1 ; Cc1cc(C)c2c(c1)c1cc(-c3ccc4c(c3)c3ccccc3n4-c3ccccc3)ccc1n2-c1ccc(-c2nc(-c3ccccc3)nc(-c3ccccc3)n2)cc1]

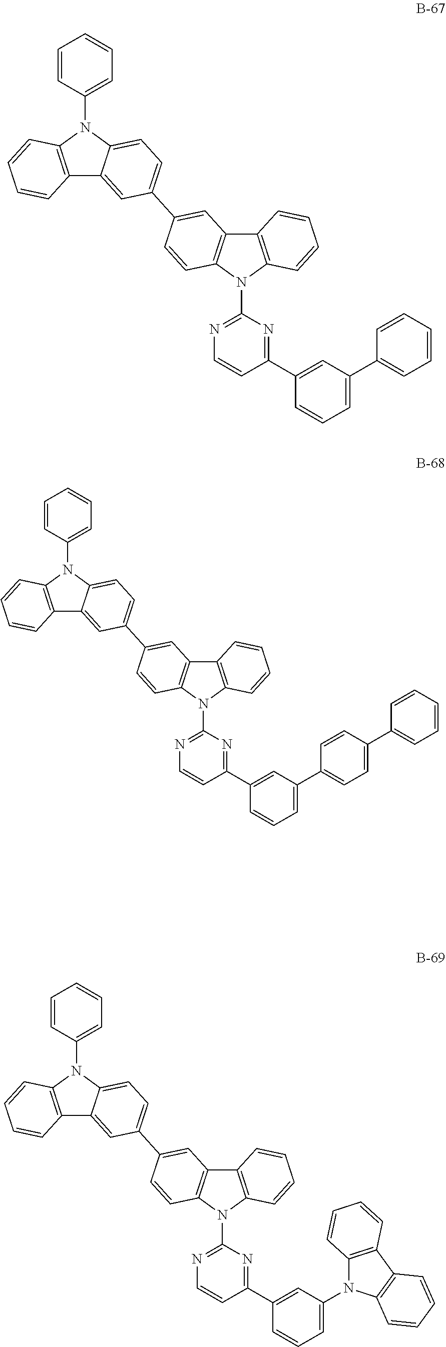 [SMILES: c1ccc(-c2cccc(-c3ccnc(-n4c5ccccc5c5cc(-c6ccc7c(c6)c6ccccc6n7-c6ccccc6)ccc54)n3)c2)cc1 ; c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1 ; c1ccc(-n2c3ccccc3c3cc(-c4ccc5c(c4)c4ccccc4n5-c4nccc(-c5cccc(-n6c7ccccc7c7ccccc76)c5)n4)ccc32)cc1]

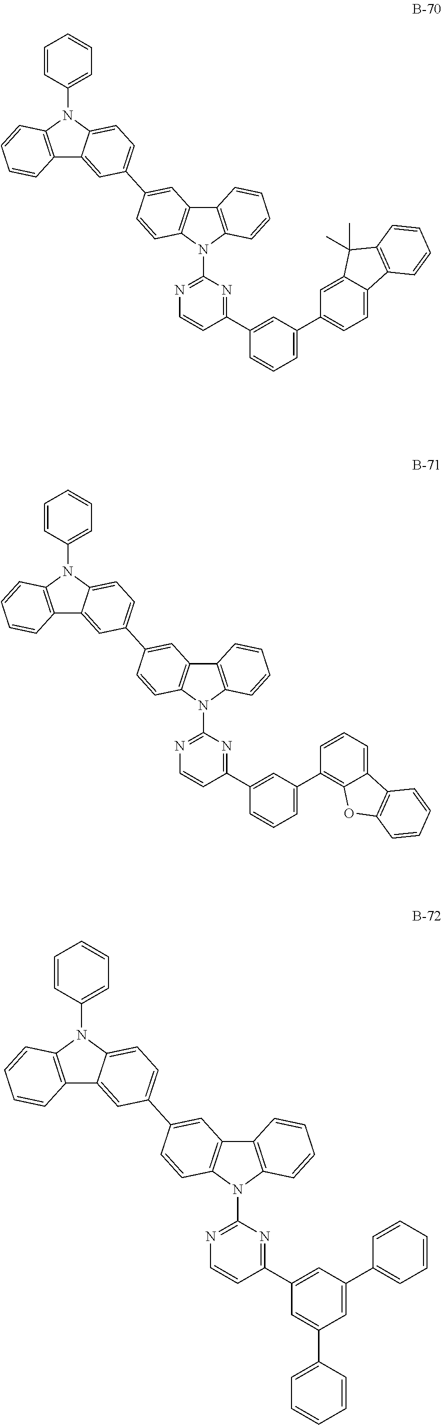 [SMILES: CC1(C)c2ccccc2-c2ccc(-c3cccc(-c4ccnc(-n5c6ccccc6c6cc(-c7ccc8c(c7)c7ccccc7n8-c7ccccc7)ccc65)n4)c3)cc21 ; c1ccc(-n2c3ccccc3c3cc(-c4ccc5c(c4)c4ccccc4n5-c4nccc(-c5cccc(-c6cccc7c6oc6ccccc67)c5)n4)ccc32)cc1 ; c1ccc(-c2cc(-c3ccccc3)cc(-c3ccnc(-n4c5ccccc5c5cc(-c6ccc7c(c6)c6ccccc6n7-c6ccccc6)ccc54)n3)c2)cc1]

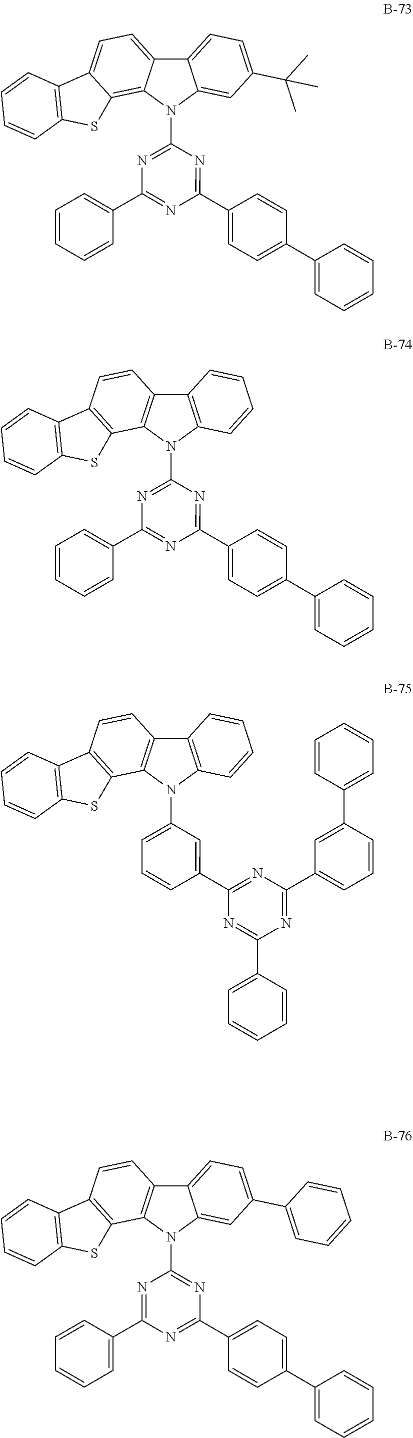 [SMILES: CC(C)(C)c1ccc2c3ccc4c5ccccc5sc4c3n(-c3nc(-c4ccccc4)nc(-c4ccc(-c5ccccc5)cc4)n3)c2c1 ; c1ccc(-c2ccc(-c3nc(-c4ccccc4)nc(-n4c5ccccc5c5ccc6c7ccccc7sc6c54)n3)cc2)cc1 ; c1ccc(-c2cccc(-c3nc(-c4ccccc4)nc(-c4cccc(-n5c6ccccc6c6ccc7c8ccccc8sc7c65)c4)n3)c2)cc1 ; c1ccc(-c2ccc(-c3nc(-c4ccccc4)nc(-n4c5cc(-c6ccccc6)ccc5c5ccc6c7ccccc7sc6c54)n3)cc2)cc1]

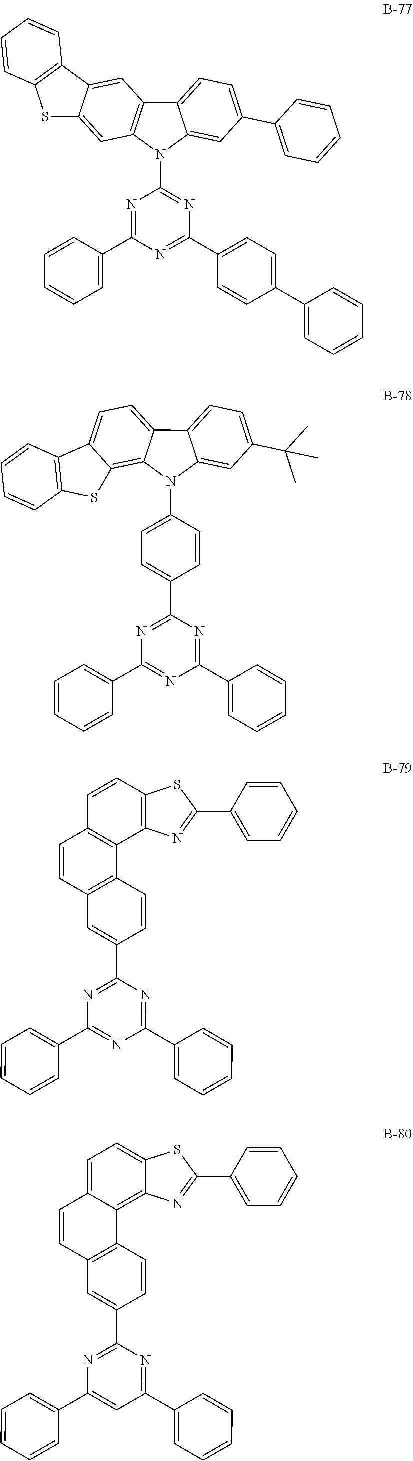 [SMILES: c1ccc(-c2ccc(-c3nc(-c4ccccc4)nc(-n4c5cc(-c6ccccc6)ccc5c5cc6c(cc54)sc4ccccc46)n3)cc2)cc1 ; CC(C)(C)c1ccc2c3ccc4c5ccccc5sc4c3n(-c3ccc(-c4nc(-c5ccccc5)nc(-c5ccccc5)n4)cc3)c2c1 ; c1ccc(-c2nc(-c3ccccc3)nc(-c3ccc4c(ccc5ccc6sc(-c7ccccc7)nc6c54)c3)n2)cc1 ; c1ccc(-c2cc(-c3ccccc3)nc(-c3ccc4c(ccc5ccc6sc(-c7ccccc7)nc6c54)c3)n2)cc1]

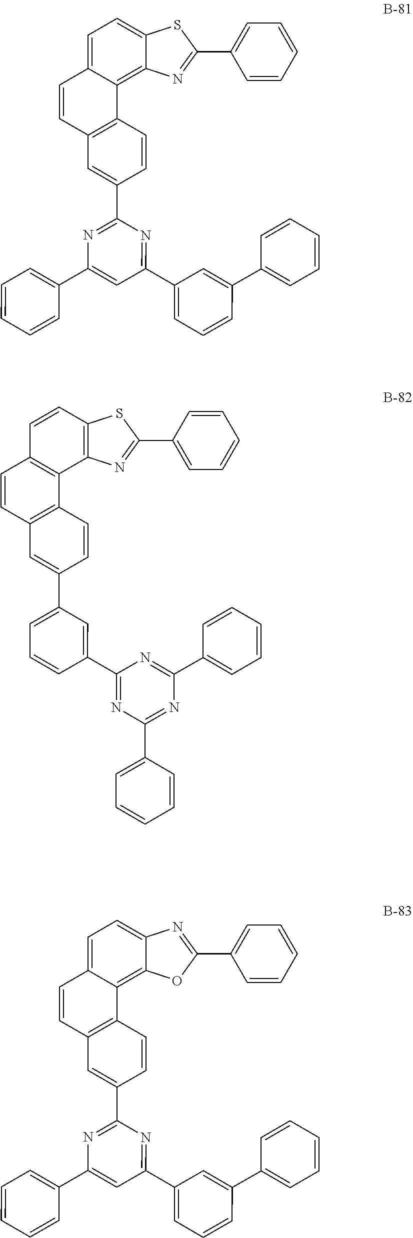 [SMILES: c1ccc(-c2cccc(-c3cc(-c4ccccc4)nc(-c4ccc5c(ccc6ccc7sc(-c8ccccc8)nc7c65)c4)n3)c2)cc1 ; c1ccc(-c2nc(-c3ccccc3)nc(-c3cccc(-c4ccc5c(ccc6ccc7sc(-c8ccccc8)nc7c65)c4)c3)n2)cc1 ; c1ccc(-c2cccc(-c3cc(-c4ccccc4)nc(-c4ccc5c(ccc6ccc7nc(-c8ccccc8)oc7c65)c4)n3)c2)cc1]

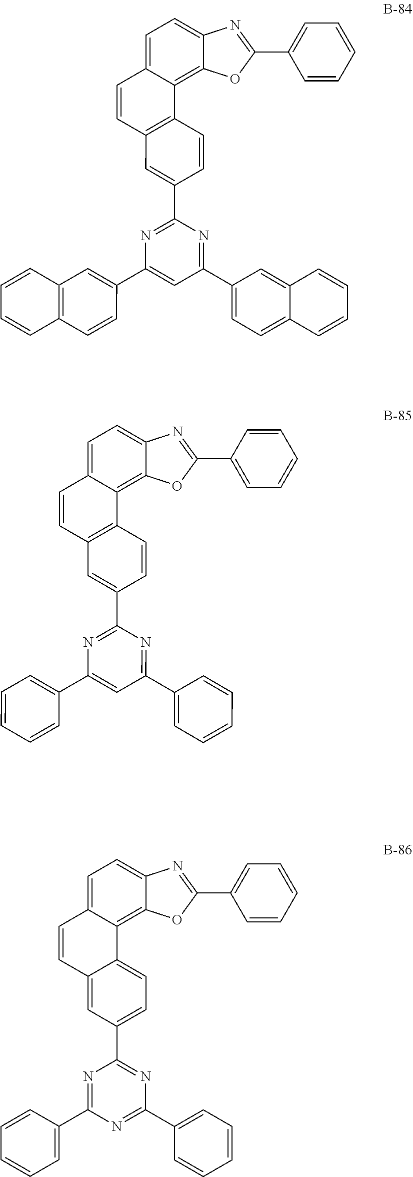 [SMILES: c1ccc(-c2nc3ccc4ccc5cc(-c6nc(-c7ccc8ccccc8c7)cc(-c7ccc8ccccc8c7)n6)ccc5c4c3o2)cc1 ; c1ccc(-c2cc(-c3ccccc3)nc(-c3ccc4c(ccc5ccc6nc(-c7ccccc7)oc6c54)c3)n2)cc1 ; c1ccc(-c2nc(-c3ccccc3)nc(-c3ccc4c(ccc5ccc6nc(-c7ccccc7)oc6c54)c3)n2)cc1]

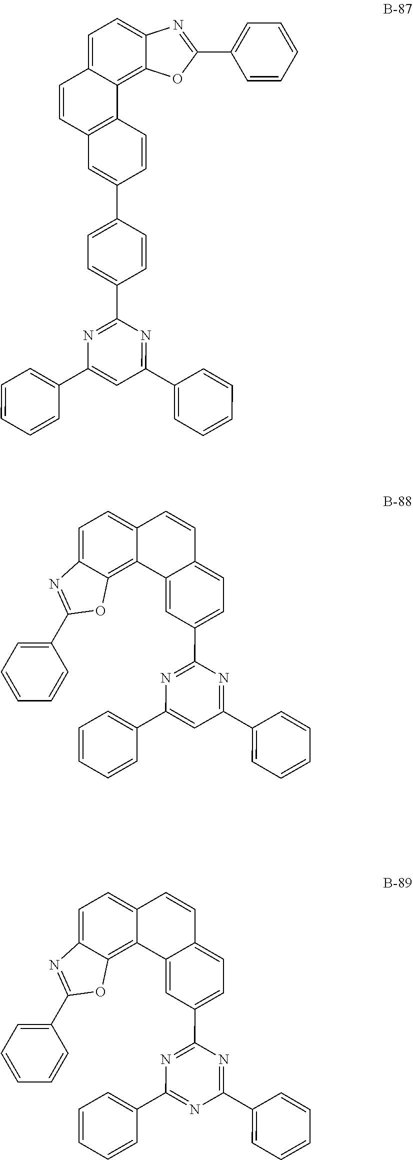 [SMILES: c1ccc(-c2cc(-c3ccccc3)nc(-c3ccc(-c4ccc5c(ccc6ccc7nc(-c8ccccc8)oc7c65)c4)cc3)n2)cc1 ; c1ccc(-c2cc(-c3ccccc3)nc(-c3ccc4ccc5ccc6nc(-c7ccccc7)oc6c5c4c3)n2)cc1 ; c1ccc(-c2nc(-c3ccccc3)nc(-c3ccc4ccc5ccc6nc(-c7ccccc7)oc6c5c4c3)n2)cc1]

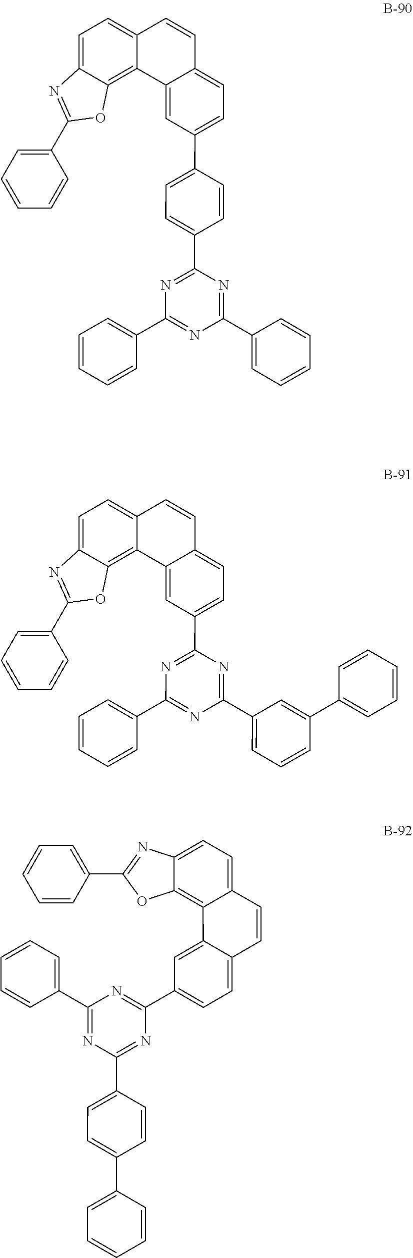 [SMILES: c1ccc(-c2nc(-c3ccccc3)nc(-c3ccc(-c4ccc5ccc6ccc7nc(-c8ccccc8)oc7c6c5c4)cc3)n2)cc1 ; c1ccc(-c2cccc(-c3nc(-c4ccccc4)nc(-c4ccc5ccc6ccc7nc(-c8ccccc8)oc7c6c5c4)n3)c2)cc1 ; c1ccc(-c2ccc(-c3nc(-c4ccccc4)nc(-c4ccc5ccc6ccc7nc(-c8ccccc8)oc7c6c5c4)n3)cc2)cc1]

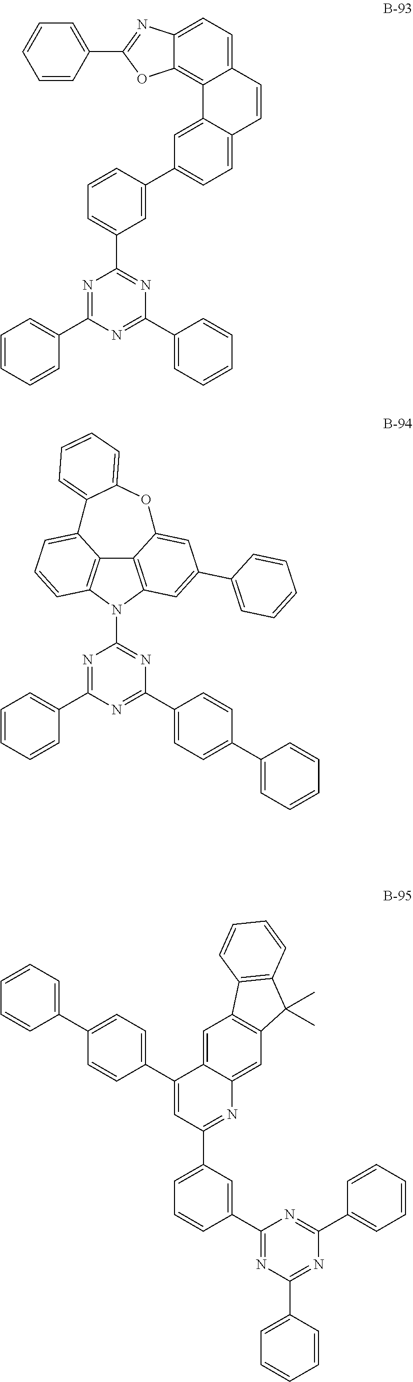 [SMILES: c1ccc(-c2nc(-c3ccccc3)nc(-c3cccc(-c4ccc5ccc6ccc7nc(-c8ccccc8)oc7c6c5c4)c3)n2)cc1 ; c1ccc(-c2ccc(-c3nc(-c4ccccc4)nc(-n4c5cc(-c6ccccc6)cc6oc7ccccc7c7cccc4c7c65)n3)cc2)cc1 ; CC1(C)c2ccccc2-c2cc3c(-c4ccc(-c5ccccc5)cc4)cc(-c4cccc(-c5nc(-c6ccccc6)nc(-c6ccccc6)n5)c4)nc3cc21]

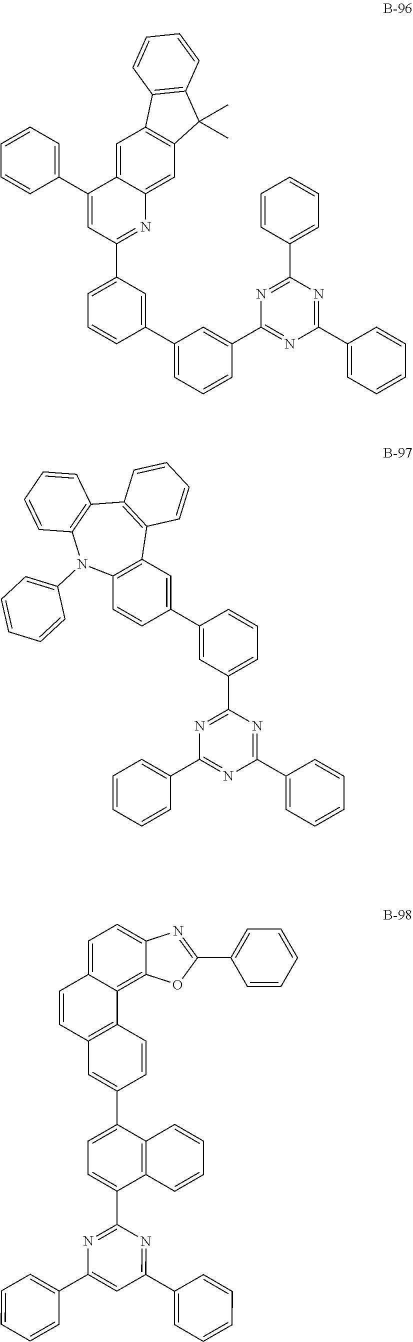 [SMILES: CC1(C)c2ccccc2-c2cc3c(-c4ccccc4)cc(-c4cccc(-c5cccc(-c6nc(-c7ccccc7)nc(-c7ccccc7)n6)c5)c4)nc3cc21 ; c1ccc(-c2nc(-c3ccccc3)nc(-c3cccc(-c4ccc5c(c4)-c4ccccc4-c4ccccc4N5c4ccccc4)c3)n2)cc1 ; c1ccc(-c2cc(-c3ccccc3)nc(-c3ccc(-c4ccc5c(ccc6ccc7nc(-c8ccccc8)oc7c65)c4)c4ccccc34)n2)cc1]

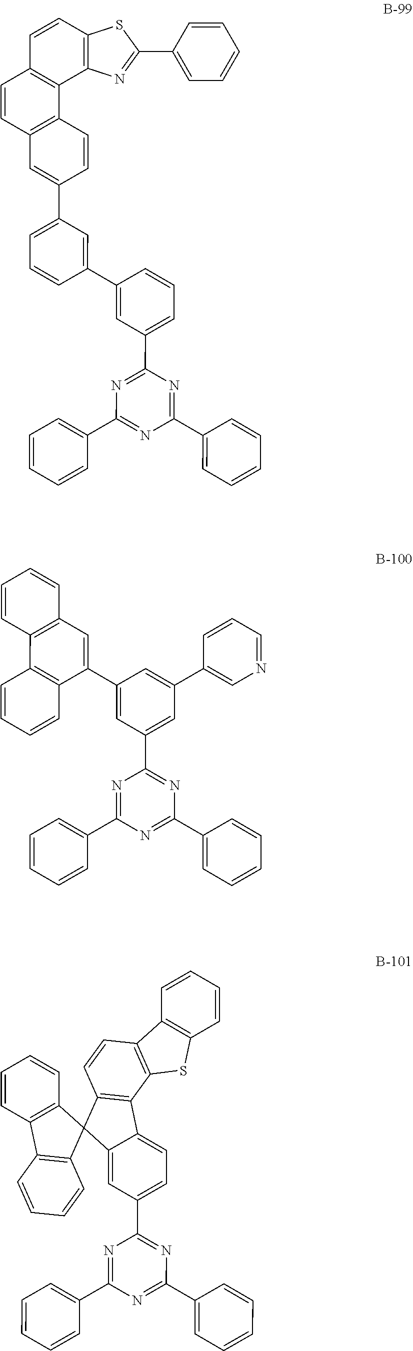 [SMILES: c1ccc(-c2nc(-c3ccccc3)nc(-c3cccc(-c4cccc(-c5ccc6c(ccc7ccc8sc(-c9ccccc9)nc8c76)c5)c4)c3)n2)cc1 ; c1ccc(-c2nc(-c3ccccc3)nc(-c3cc(-c4cccnc4)cc(-c4cc5ccccc5c5ccccc45)c3)n2)cc1 ; c1ccc(-c2nc(-c3ccccc3)nc(-c3ccc4c(c3)C3(c5ccccc5-c5ccccc53)c3ccc5c(sc6ccccc65)c3-4)n2)cc1]

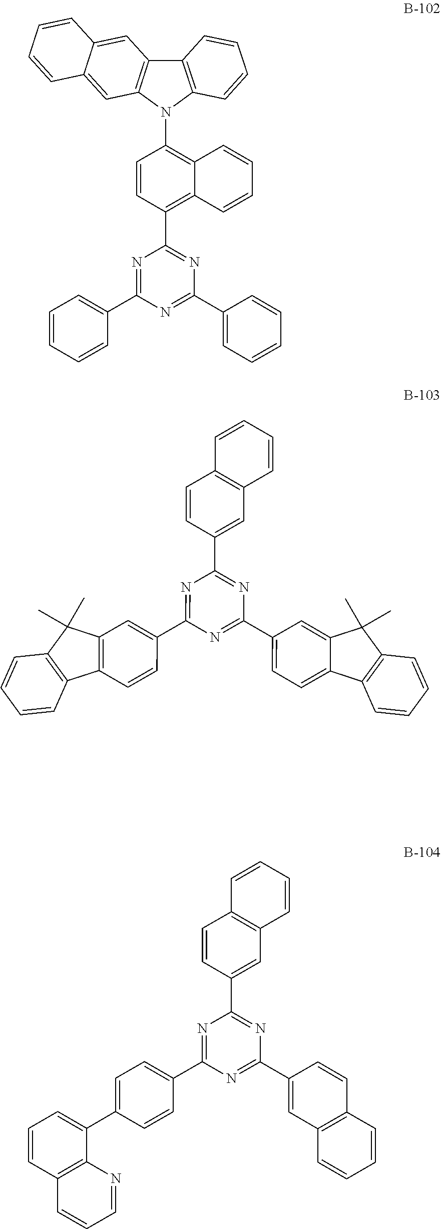 [SMILES: c1ccc(-c2nc(-c3ccccc3)nc(-c3ccc(-n4c5ccccc5c5cc6ccccc6cc54)c4ccccc34)n2)cc1 ; CC1(C)c2ccccc2-c2ccc(-c3nc(-c4ccc5c(c4)C(C)(C)c4ccccc4-5)nc(-c4ccc5ccccc5c4)n3)cc21 ; c1ccc2cc(-c3nc(-c4ccc(-c5cccc6cccnc56)cc4)nc(-c4ccc5ccccc5c4)n3)ccc2c1]

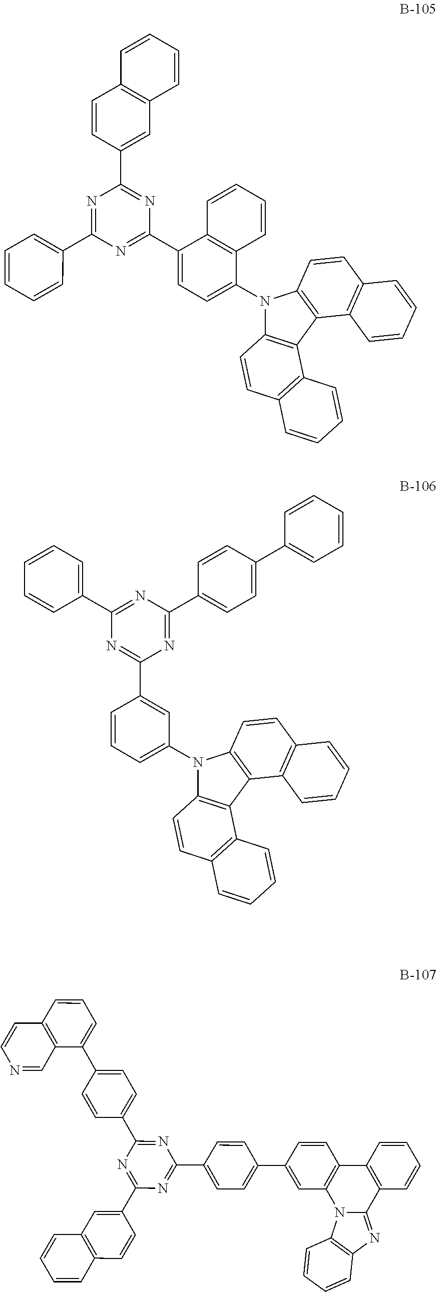 [SMILES: c1ccc(-c2nc(-c3ccc4ccccc4c3)nc(-c3ccc(-n4c5ccc6ccccc6c5c5c6ccccc6ccc54)c4ccccc34)n2)cc1 ; c1ccc(-c2ccc(-c3nc(-c4ccccc4)nc(-c4cccc(-n5c6ccc7ccccc7c6c6c7ccccc7ccc65)c4)n3)cc2)cc1 ; c1ccc2cc(-c3nc(-c4ccc(-c5ccc6c7ccccc7c7nc8ccccc8n7c6c5)cc4)nc(-c4ccc(-c5cccc6ccncc56)cc4)n3)ccc2c1]

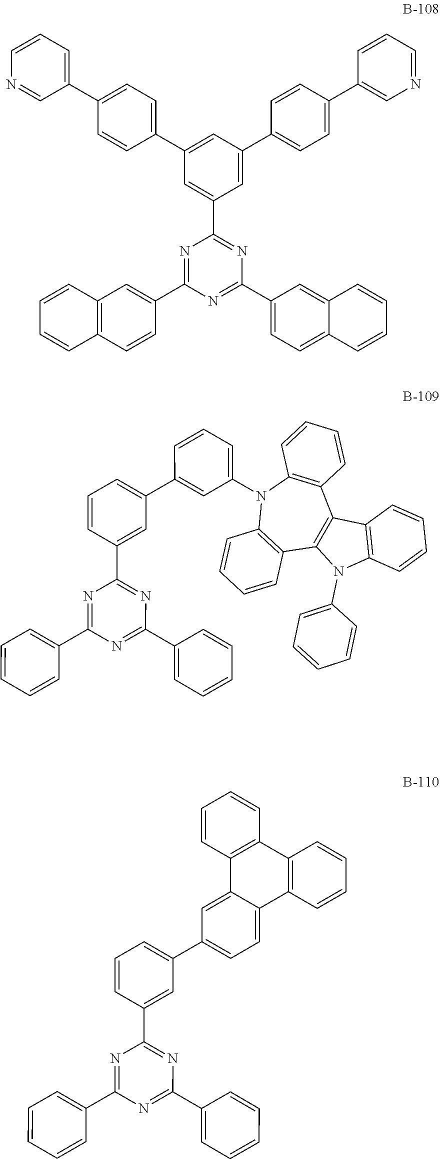 [SMILES: c1cncc(-c2ccc(-c3cc(-c4ccc(-c5cccnc5)cc4)cc(-c4nc(-c5ccc6ccccc6c5)nc(-c5ccc6ccccc6c5)n4)c3)cc2)c1 ; c1ccc(-c2nc(-c3ccccc3)nc(-c3cccc(-c4cccc(N5c6ccccc6-c6c(n(-c7ccccc7)c7ccccc67)-c6ccccc65)c4)c3)n2)cc1 ; c1ccc(-c2nc(-c3ccccc3)nc(-c3cccc(-c4ccc5c6ccccc6c6ccccc6c5c4)c3)n2)cc1]

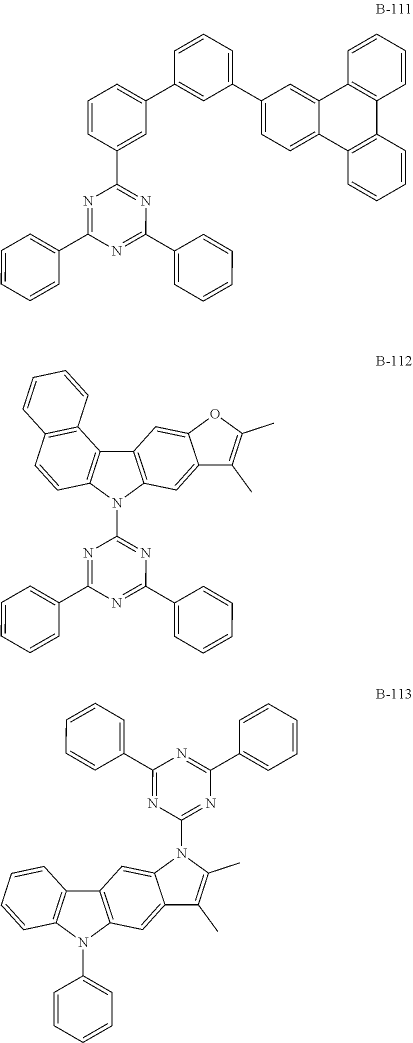 [SMILES: c1ccc(-c2nc(-c3ccccc3)nc(-c3cccc(-c4cccc(-c5ccc6c7ccccc7c7ccccc7c6c5)c4)c3)n2)cc1 ; Cc1oc2cc3c4c5ccccc5ccc4n(-c4nc(-c5ccccc5)nc(-c5ccccc5)n4)c3cc2c1C ; Cc1c(C)n(-c2nc(-c3ccccc3)nc(-c3ccccc3)n2)c2cc3c4ccccc4n(-c4ccccc4)c3cc12]

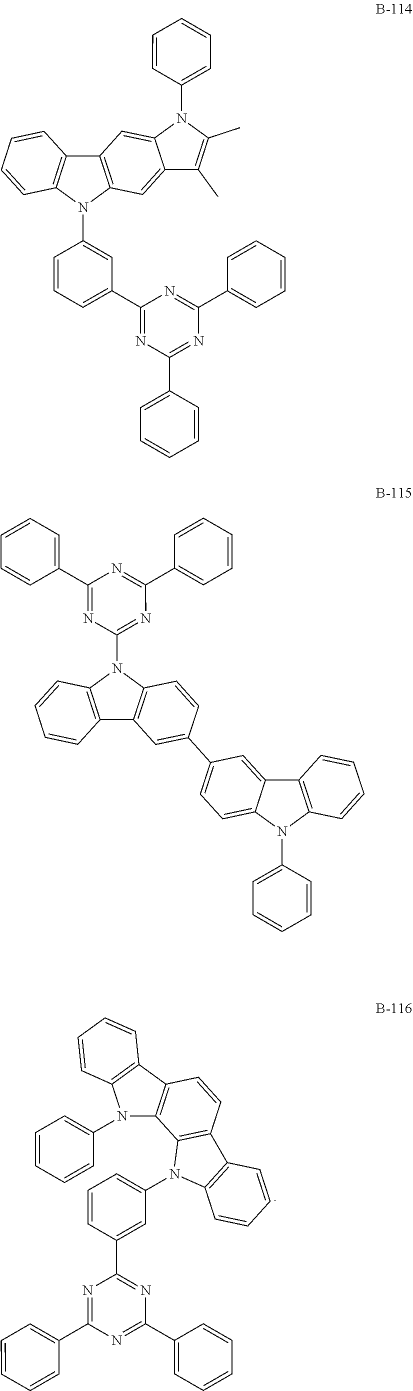 [SMILES: Cc1c(C)n(-c2ccccc2)c2cc3c4ccccc4n(-c4cccc(-c5nc(-c6ccccc6)nc(-c6ccccc6)n5)c4)c3cc12 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3cccc(-n4c5ccccc5c5ccc6c7ccccc7n(-c7ccccc7)c6c54)c3)n2)cc1]

8. The organic electroluminescent device according to claim 1, wherein a LUMO energy level of the light-emitting layer (Ah) and a LUMO energy level of the electron transport zone (Ae) satisfy the following equation 1:
Ae≤Ah+0.5 eV (1)
with a proviso that the comparison of the energy levels is based on absolute values.

9. The organic electroluminescent device according to claim 1, wherein the electron transport zone comprises at least one of an electron transport layer and an electron buffer layer, and at least one of the electron transport layer and the electron buffer layer comprises the compound represented by the formula 11.

10. The organic electroluminescent device according to claim 1, wherein the electron transport zone further comprises an electron transport compound, a reductive dopant, or the combination thereof.
